(19) United States
(12) Patent Application Publication
(10) Pub. No.: US 2025/0133959 A1
(43) Pub. Date: Apr. 24, 2025

(54) ORGANIC LIGHT-EMITTING DEVICES

(71) Applicant: SAMSUNG DISPLAY CO., LTD., Yongin-si (KR)

(72) Inventors: Hwan-Hee CHO, Yongin-si (KR); Mi-Kyung KIM, Yongin-si (KR); Se-Hun KIM, Yongin-si (KR); Dong-Hyun KIM, Yongin-si (KR); Chang-Woong CHU, Yongin-si (KR)

(21) Appl. No.: 19/006,049

(22) Filed: Dec. 30, 2024

Related U.S. Application Data
(63) Continuation of application No. 17/099,679, filed on Nov. 16, 2020, now Pat. No. 12,193,322.
Application No. 17/099,679 is a continuation-in-part of application No. 14/691,521, filed on Apr. 20, 2015, now Pat. No. 10,840,454.
Application No. 14/691,521 is a continuation-in-part of application No. 14/061,667, filed on Oct. 23, 2013, now Pat. No. 9,012,903.

(30) Foreign Application Priority Data
Jun. 14, 2013 (KR) 10-2013-0068640

(51) Int. Cl. H10K 85/60; C09K 11/02; C09K 11/06; H10K 50/13; H10K 50/15; H10K 85/30

(52) U.S. Cl. CPC H10K 85/636; C09K 11/02; C09K 11/06; H10K 85/342; H10K 85/633; H10K 85/654; H10K 85/6572; H10K 85/6574; C09K 2211/1007; C09K 2211/1029; C09K 2211/185; H10K 50/13; H10K 50/15; H10K 85/615

(57) ABSTRACT

An organic light-emitting device includes: a first electrode; a second electrode; and an organic layer between the first electrode and the second electrode. The organic layer includes an emission layer, and the emission layer includes at least one light-emitting material represented by one of Formulas 1 and 2. The organic layer further includes at least one hole-transporting material represented by one of Formulas 2(1) and 2(2).

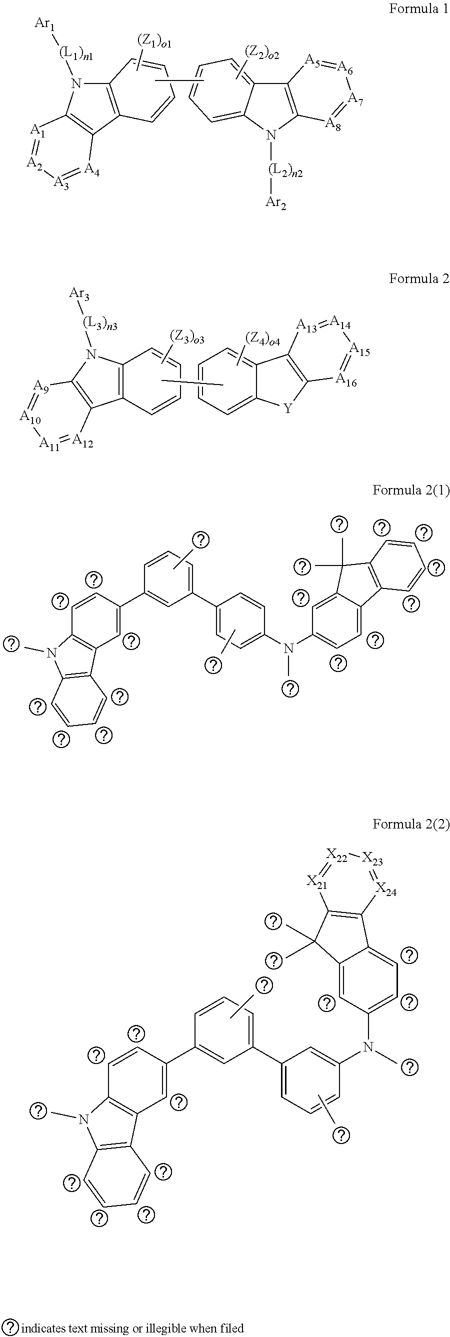

### CROSS-REFERENCE TO RELATED APPLICATION(S)

This application is a continuation of U.S. application Ser. No. 17/099,679, filed Nov. 16, 2020, to be issued as U.S. Pat. No. 12,193,322 on Jan. 7, 2025, which is a continuation-in-part of U.S. application Ser. No. 14/691,521 filed Apr. 20, 2015, now U.S. Pat. No. 10,840,454 issued on Nov. 17, 2020, which is a continuation-in-part of U.S. application Ser. No. 14/061,667 filed Oct. 23, 2013, now U.S. Pat. No. 9,012,903 issued on Apr. 21, 2015, each of which claims priority to and the benefit of Korean Patent Application No. 10-2013-0068640, filed on Jun. 14, 2013 in the Korean Intellectual Property Office, the entire contents of all of which are incorporated herein by reference.

### BACKGROUND

### 1. Technical Field

The present invention relates to an organic light-emitting device.

### 2. Description of the Related Art

Organic light-emitting devices (OLEDs) are self-emitting devices that have advantages such as wide viewing angles, good contrast, quick response times, and good luminance, driving voltage, and response speed characteristics. Also, OLEDs can provide multicolored images.

A typical OLED has a structure including a substrate, and an anode, a hole transport layer, an emission layer, an electron transport layer, and a cathode sequentially stacked on the substrate. In this regard, the hole transport layer, the emission layer, and the electron transport layer are organic thin films formed of organic compounds.

An operating principle of an OLED having the above-described structure may be as follows. When a voltage is applied between the anode and the cathode, holes injected from the anode move to the emission layer via the hole transport layer, and electrons injected from the cathode move to the emission layer via the electron transport layer. The holes and electrons recombine in the emission layer to generate excitons. When the excitons drop from an excited state to a ground state, light is emitted.

### SUMMARY

Aspects of embodiments of the present invention are directed toward an organic light-emitting device (OLED) having high efficiency and a long lifespan.

According to an aspect of an embodiment of the present invention, an organic light-emitting device includes: a first electrode; a second electrode; and an organic layer between the first electrode and the second electrode. In some embodiments, the organic layer includes an emission layer, and the emission layer includes a light-emitting material represented by one of Formulas 1 and 2, and a hole-transporting material represented by one of Formulas 2(1) and 2(2).

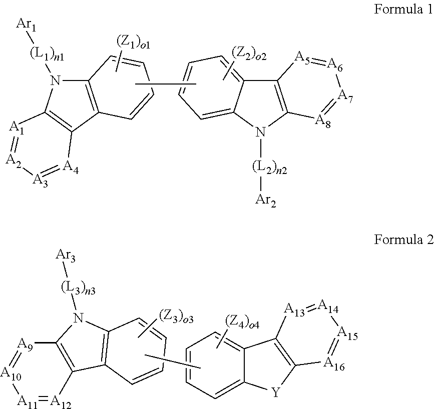

In Formulas 1 and 2, A₁ is CR₁ or N; A₂ is CR₂ or N; A₃ is CR₃ or N; A₄ is CR₄ or N; A₅ is CR₅ or N; A₆ is CR₆ or N; A₇ is CR₇ or N; A₈ is CR₈ or N; A₉ is CR₉ or N; A₁₀ is CR₁₀ or N; A₁₁ is CR₁₁ or N; A₁₂ is CR₁₂ or N; A₁₃ is CR₁₃ or N; A₁₄ is CR₁₄ or N; A₁₅ is CR₁₅ or N; and A₁₆ is CR₁₆ or N. R₁ to R₁₆ are each independently a hydrogen atom, a deuterium atom, a halogen atom, a C₁-C₆₀ alkyl group, a C₆-C₆₀ aryl group, a C₁-C₆₀ heteroaryl group, or —N(Q₁)(Q₂)(Q₃) (where Q₁ to Q₃ are each independently a C₁-C₆₀ alkyl group, a C₆-C₆₀ aryl group, or a C₁-C₆₀ heteroaryl group). Two or more of R₁ to R₁₆ may optionally combine to form a C₆-C₂₀ saturated ring or a C₆-C₂₀ unsaturated ring. Y is O, S, or C(R₃₁)(R₃₂).

In Formulas 1 and 2, n1 to n3 are each independently an integer of 0 to 3. L₁ to L₃ are each independently a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₂-C₁₀ heterocycloalkylene group, a substituted or unsubstituted C₂-C₁₀ heterocycloalkenylene group, or a substituted or unsubstituted C₁-C₆₀ heteroarylene group.

In Formulas 1 and 2, Ar₁ to Ar₃ are each independently: i) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₁-C₆₀ heteroaryl group, or —Si(Q₁)(Q₂)(Q₃) (where Q₁ to Q₃ are each independently a substituted or unsubstituted C₁-C₁₀ alkyl group or a substituted or unsubstituted C₆-C₃₀ aryl group); or ii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, and a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₁-C₆₀ heteroaryl group, or —Si(Q₁)(Q₂)(Q₃) (where Q₁ to Q₃ are each independently a substituted or unsubstituted C₁-C₁₀ alkyl group or a substituted or unsubstituted C₆-C₃₀ aryl group).

In Formulas 1 and 2, Z₁ to Z₄, R₃₁, and R₃₂ are each independently: i) a hydrogen atom, a deuterium atom, a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, and a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In Formulas 1 and 2, o1 to o4 are each independently an integer of 0 to 3.

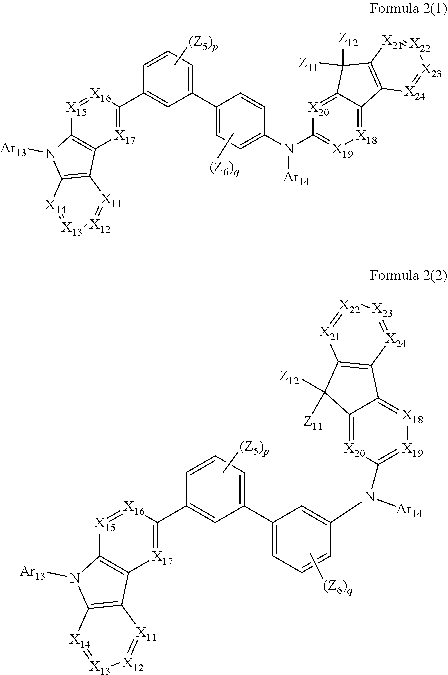

In Formulas 2(1) and 2(2), X₁₁ is CR₁₁ or N; X₁₂ is CR₁₂ or N; X₁₃ is CR₁₃ or N; X₁₄ is CR₁₄ or N; X₁₅ is CR₁₅ or N; X₁₆ is CR₁₆ or N; X₁₇ is CR₁₇ or N; X₁₈ is CR₁₈ or N; X₁₉ is CR₁₉ or N; X₂₀ is CR₂₀ or N; X₂₁ is CR₂₁ or N; X₂₂ is CR₂₂ or N; X₂₃ is CR₂₃ or N; and X₂₄ is CR₂₄ or N.

In Formulas 2(1) and 2(2), Z₅, Z₆, and R₁₁ to R₂₄ are each independently: i) a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or v) —N(Q₁₁)(Q₁₂), —Si(Q₁₃)(Q₁₄)(Q₁₅), or —B(Q₁₆)(Q₁₇) (where Q₁₁ to Q₁₇ are each independently a C₁-C₆₀ alkyl group, a C₁-C₆₀ alkoxy group, a C₆-C₆₀ aryl group, or a C₁-C₆₀ heteroaryl group).

In Formulas 2(1) and 2(2), Ar₁₃ and Ar₁₄ are each independently: i) a C₃-C₁₀ cycloalkyl group, a C₃-C₁₀ heterocycloalkyl group, a C₃-C₁₀ cycloalkenyl group, a C₃-C₁ heterocycloalkenyl group, a C₆-C₆₀ aryl group, or a C₁-C₆₀ heteroaryl group; or ii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In Formulas 2(1) and 2(2), p and q are each independently an integer from 1 to 4; and Z₁₁ and Z₁₂ are each independently: i) a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

### DETAILED DESCRIPTION OF THE DRAWINGS

The above and other features and advantages of the present invention will become more apparent by reference to the following detailed description when considered together with the attached drawings in which:

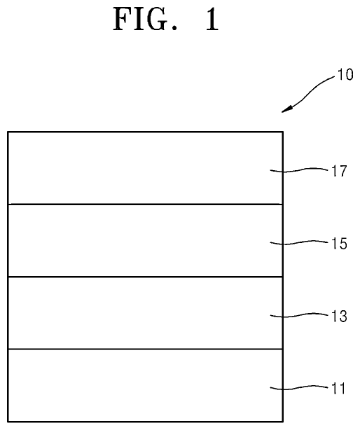

FIG. 1 is a schematic view of a structure of an organic light-emitting device (OLED) according to an embodiment of the present invention;

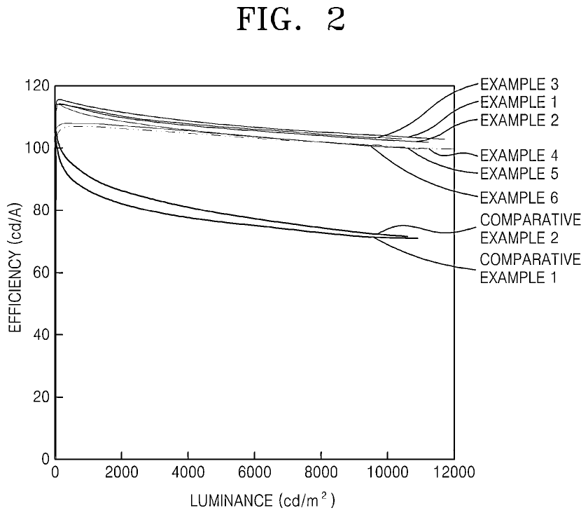

FIG. 2 is a graph comparing the luminance and efficiency of the OLEDs prepared according to Examples 1-6 to the luminance and efficiency of the OLEDs prepared according to Comparative Examples 1 and 2; and

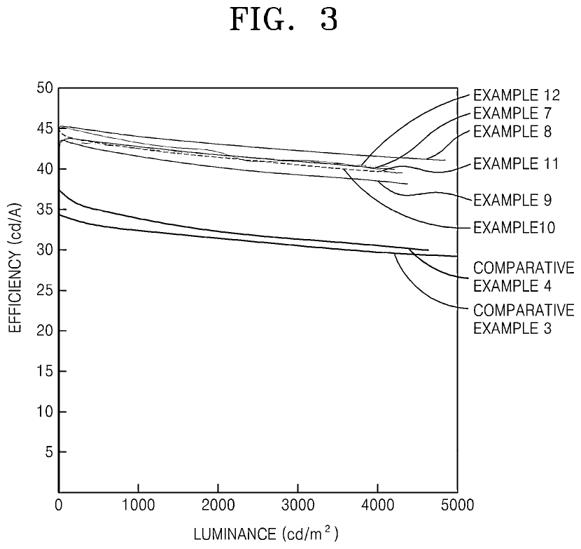

FIG. 3 is a graph comparing the luminance and efficiency of the OLEDs prepared according to Examples 7-12 to the luminance and efficiency of the OLEDs prepared according to Comparative Examples 3 and 4;

FIG. 4 is a schematic view of a structure of an OLED according to an embodiment of the present invention;

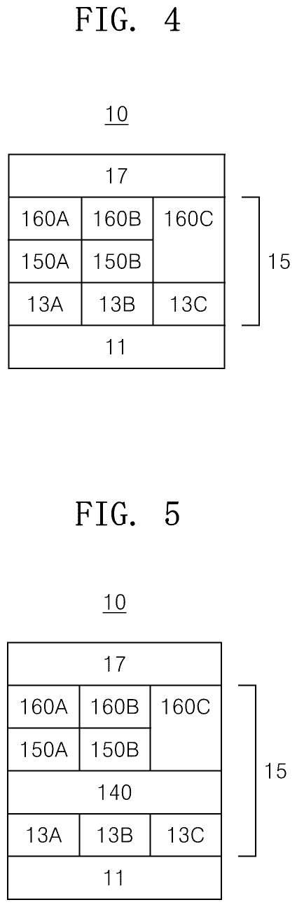

FIG. 5 is a schematic view of a structure of an OLED according to an embodiment of the present invention.

### DETAILED DESCRIPTION

Reference will now be made to certain embodiments of the present invention, examples of which are illustrated in the accompanying drawings, where like reference numerals refer to like elements throughout. As those skilled in the art would recognize, the described embodiments may be modified in many ways, and therefore should not be construed as limiting. Accordingly, the embodiments are described below, by referring to the figures, merely to explain aspects of the present disclosure.

As used herein, the term “and/or” includes any and all combinations of one or more of the associated listed items. Expressions such as “at least one of,” when preceding a list of elements, modify the entire list of elements and do not modify the individual elements of the list. Also, in the context of the present application, when a first element is referred to as being “on” a second element, it can be directly on the second element or be indirectly on the second element with one or more intervening elements therebetween.

FIG. 1 is a cross-sectional view schematically illustrating a structure of an organic light-emitting device (OLED) 10 according to an embodiment of the present invention. The OLED 10 includes a substrate 11, a first electrode 13, an organic layer 15, and a second electrode 17. Hereinafter, structures and methods of manufacturing OLEDs according to embodiments of the present invention will be described with reference to FIG. 1.

A substrate 11 may be any suitable substrate commonly used in OLEDs. In some embodiments, the substrate 11 may be a glass substrate or a transparent plastic substrate with mechanical strength, thermal stability, transparency, surface smoothness, ease of handling, and water resistance.

A first electrode 13 may be formed on the substrate 11 by depositing or sputtering a first electrode-forming material. When the first electrode 13 is an anode, a material having a high work function may be used as the first electrode-forming material to facilitate hole injection. The first electrode 13 may be a reflective electrode or a transmission electrode (e.g., a transparent electrode). Non-limiting examples of the first electrode-forming material include transparent and conductive materials, such as indium tin oxide (ITO), indium zinc oxide (IZO), stannic oxide (SnO₂), and zinc oxide (ZnO). Alternatively, the first electrode 13 may be formed as a reflective electrode using magnesium (Mg), aluminum (Al), aluminum-lithium (Al—Li), calcium (Ca), magnesium-indium (Mg—In), or magnesium-silver (Mg—Ag).

The first electrode 13 may have a single-layer structure or a multi-layer structure including at least two layers. For example, the first electrode 13 may have a three-layer structure of ITO/Ag/ITO, but is not limited thereto.

An organic layer 15 may be disposed on the first electrode 13. The organic layer 15 may include a plurality of layers between the first electrode 13 and the second electrode 17 in the OLED 10. The organic layer 15 may include an emission layer (EML) and at least one additional layer, such as a hole injection layer (HIL), a hole transport layer (HTL), a functional layer having both hole injection and hole transport capabilities (hereinafter, referred to as a “H-functional layer”), a buffer layer, an electron blocking layer (EBL), a hole blocking layer (HBL), an electron transport layer (ETL), an electron injection layer (EIL), and/or a functional layer having both electron injection and transport capabilities (hereinafter, referred to as an “E-functional layer”). In some embodiments, the organic layer 15 may include, in sequential order, an HIL, an HTL, a buffer layer, an EML, an ETL, and an EIL.

In some embodiments, for example, the organic layer 15 includes an emission layer (EML), and a hole-transporting region is disposed between the first electrode and the emission layer. The hole-transporting region may include a hole transport layer and a buffer layer, and the buffer layer may be disposed between the hole transport layer and the emission layer.

The HIL may be formed on the first electrode 13 by various methods, such as vacuum deposition, spin coating, casting, and Langmuir-Blodgett (LB) deposition. When the HIL is formed by vacuum deposition, the vacuum deposition conditions may vary depending on the compound used to form the HIL, and the desired structural and thermal properties of the HIL to be formed. For example, the vacuum deposition may be performed at a temperature of about 100° C. to about 500° C., a pressure of about 10⁻⁸ torr to about 10⁻³ torr, and a deposition rate of about 0.01 Å/sec to about 100 Å/sec. However, the deposition conditions are not limited thereto.

When the HIL is formed by spin coating, spin coating conditions may vary depending on a compound used to form the HIL, and desired structural and thermal properties of the HIL to be formed. For example, the spin coating may be performed at a coating rate of about 2,000 rpm to about 5,000 rpm, and the temperature at which heat treatment is performed to remove solvent after coating may be about 80° C. to about 200° C. However, the spin coating conditions are not limited thereto.

The HIL may be formed of any suitable hole-injecting material commonly used to form an HIL. Non-limiting examples of the hole-injecting material include N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl group-N,N′-diphenylbenzidine) (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline/poly(4-styrenesulfonate) (Pain/PSS.

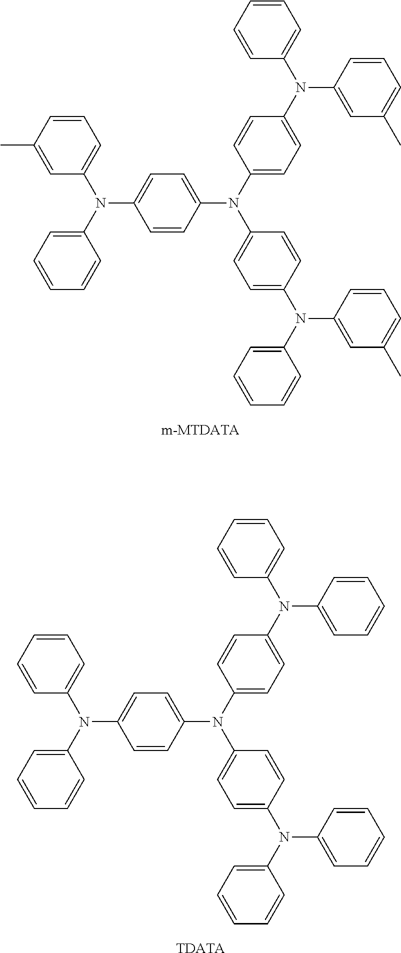

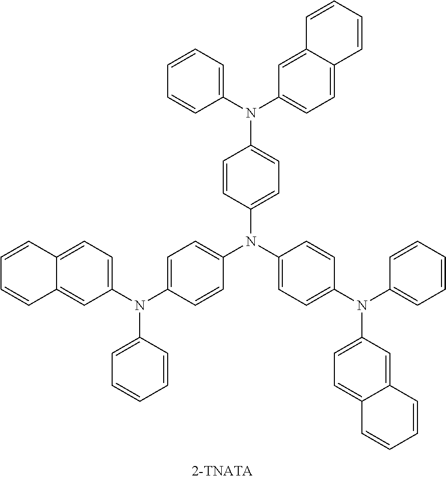 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

The thickness of the HIL may be about 100 Å to about 10,000 Å, for example, about 100 Å to about 1,000 Å. When the thickness of the HIL is within either of the foregoing ranges, the HIL may have satisfactory hole injection ability without a substantial increase in driving voltage.

Then, an HTL may be formed on the HIL by various methods, such as vacuum deposition, spin coating, casting, and LB deposition. When the HTL is formed by vacuum deposition or spin coating, the vacuum deposition conditions or spin coating conditions may be similar to those described above for the formation of the HIL, though the conditions may vary depending on the compound used to form the HTL. The HTL may include at least one hole-transporting material represented by one of Formulas 2(1) and 2(2). Additionally, in embodiments including a hole-transport region comprising a hole transport layer and a buffer layer disposed between the first electrode and the emission layer, the buffer layer and/or the hole transport layer may include at least one hole-transporting material represented by one of Formulas 2(1) and 2(2).

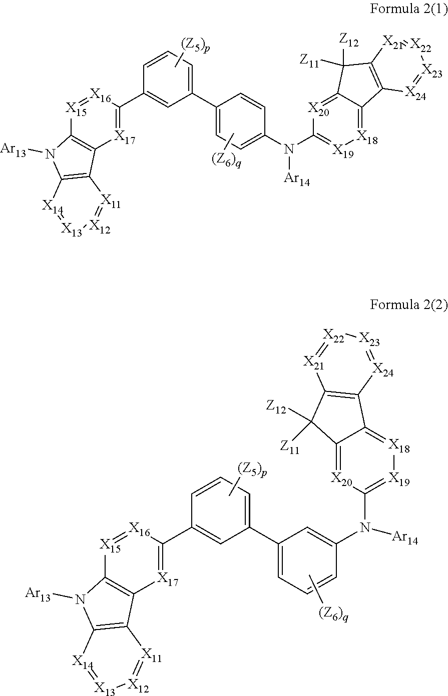

In Formula 2(1) and Formula 2(2), X₁₁ may be CR₁₁ or N; X₁₂ may be CR₁₂ or N; X₁₃ may be CR₁₃ or N; X₁₄ may be CR₁₄ or N; X₁₅ may be CR₁₅ or N; X₁₆ may be CR₁₆ or N; X₁₇ may be CR₁₇ or N; X₁₈ may be CR₁₈ or N; X₁₉ may be CR₁₉ or N; X₂₀ may be CR₂₀ or N; X₂₁ may be CR₂₁ or N; X₂₂ may be CR₂₂ or N; X₂₃ may be CR₂₃ or N; and X₂₄ may be CR₂₄ or N.

For example, in Formula 2(1) or Formula 2(2), X₁₁ may be C(R₁₁), X₁₂ may be C(R₁₂), X₁₃ may be C(R₁₃), X₁₄ may be C(R₁₄), X₁₅ may be C(R₁₅), X₁₆ may be C(R₁₆), X₁₇ may be C(R₁₇), X₁₈ may be C(R₁₈), X₁₉ may be C(R₁₉), X₂₀ may be C(R₂₀), X₂₁ may be C(R₂₁), X₂₂ may be C(R₂₂), X₂₃ may be C(R₂₃), and X₂₄ may be C(R₂₄), but Formulas 2(1) and 2(2) are not limited thereto.

In some embodiments, in Formula 2(1) or Formula 2(2), Ar₁₃ and Ar₁₄ may each independently be: i) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₂-C₆₀ heteroaryl group; or ii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In some embodiments, in Formula 2(1) or Formula 2(2), Ar₁₃ and Ar₁₄ may each independently be: i) a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzoxazolyl group, a dibenzofuranyl group, a dibenzothiophenyl group, or a benzocarbazolyl group; or ii) a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolylene group, a tetrazolyl group, an oxadiazolyl group, a triazinyl group, a benzoxazolyl group, a dibenzofuranyl group, a dibenzothiophenyl group, or a benzocarbazolyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₁-C₂₀ heteroaryl group. However, Ar₁₃ and Ar₁₄ are not limited thereto.

In some other embodiments, in Formula 2(1) or Formula 2(2), Ar₁₃ and Ar₁₄ may each independently be: i) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group; or ii) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group. However, Ar₁₃ and Ar₁₄ are not limited thereto.

In some other embodiments, in Formula 2(1) or Formula 2(2), Ar₁₃ and Ar₁₄ may each independently be represented by one of Formulas 3-1 to 3-20, but Ar₁₃ and Ar₁₄ are not limited thereto. When Ar₁₃ and/or Ar₁₄ are represented by one of Formulas 3-1 to 3-20, * represents a binding site to N.

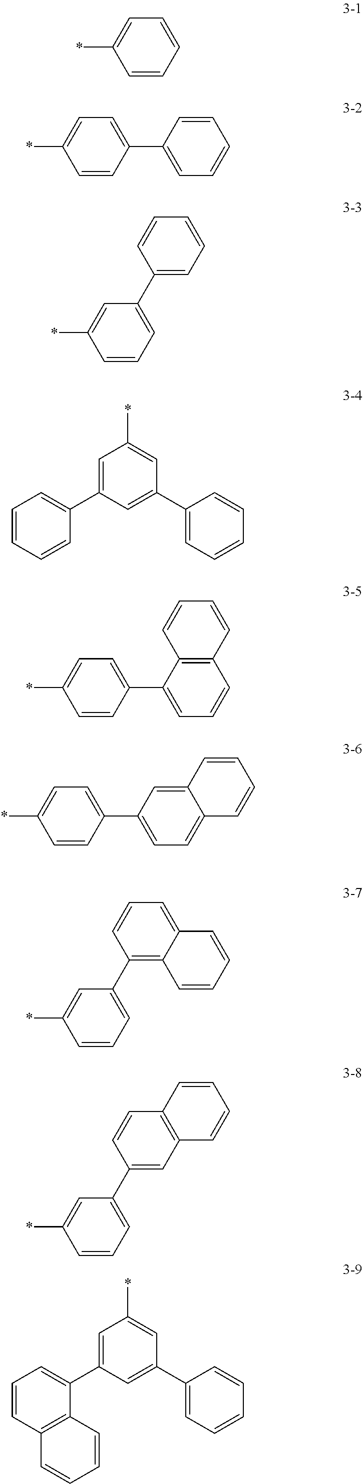

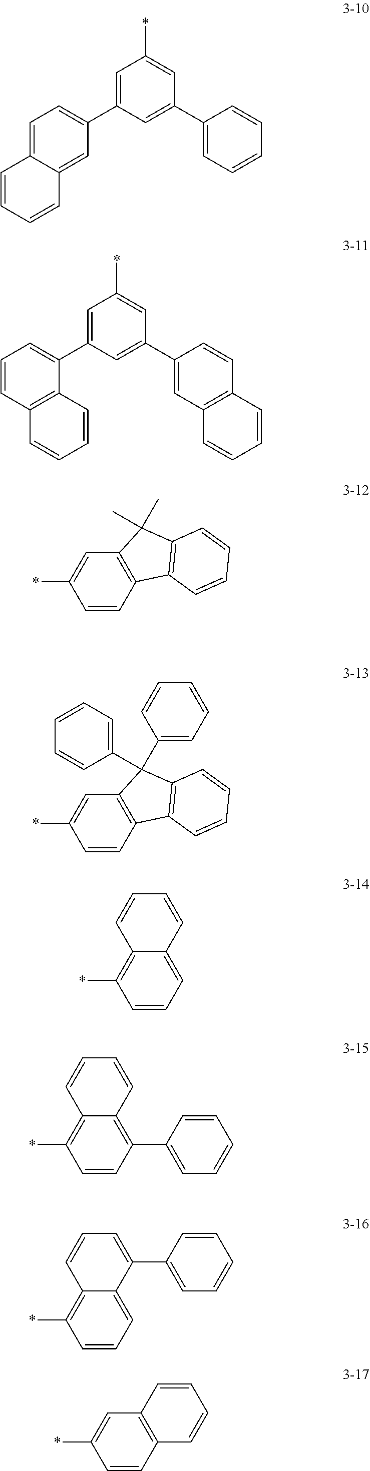

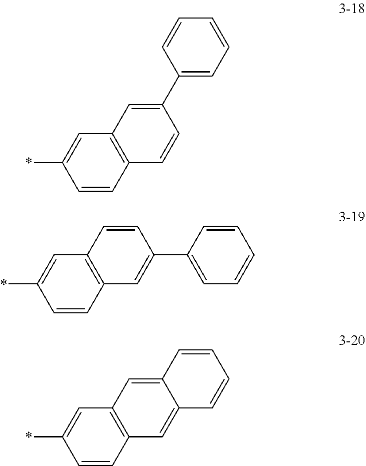

In Formula 2(1) or Formula 2(2), Z₁₁ and Z₁₂ may each independently be: i) a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In some embodiments, in Formula 2(1) or Formula 2(2), Z₁₁ and Z₁₂ may each independently be: i) a C₁-C₂₀ alkyl group; or ii) a C₁-C₂₀ alkyl group that is substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group; or iii) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group; or iv) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group. However, Z₁₁ and Z₁₂ are not limited thereto.

In some other embodiments, in Formula 2(1) or Formula 2(2), Z₁₁ and Z₁₂ may each independently be a methyl group, an ethyl group, a propyl group, a butyl group, a pentyl group, a hexyl group, a heptyl group. For example, Z₁₁ and Z₁₂ may each independently be a moiety represented by one of Formulas 3-1 to 3-20, but Z₁₁ and Z₁₂ are not limited thereto. When Z₁₁ and/or Z₁₂ are represented by Formulas 3-1 to 3-20, * represents a carbon atom of a fluorene-based ring of Formula 2(1) or Formula 2(2).

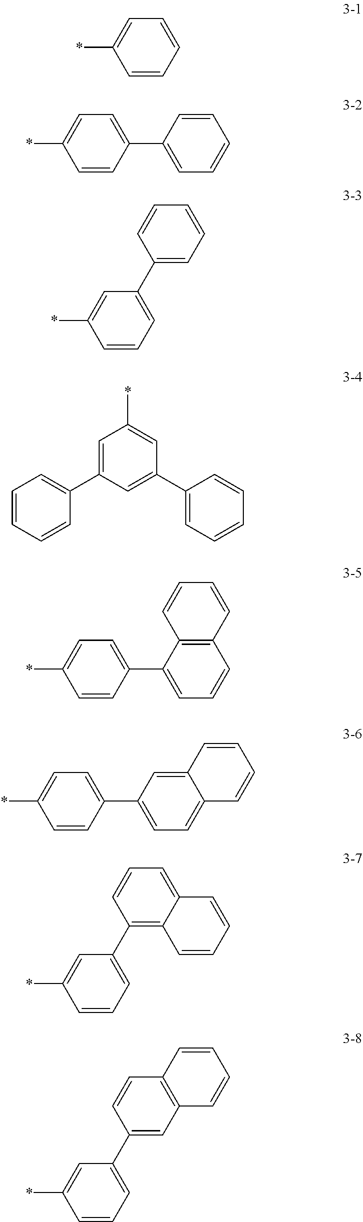

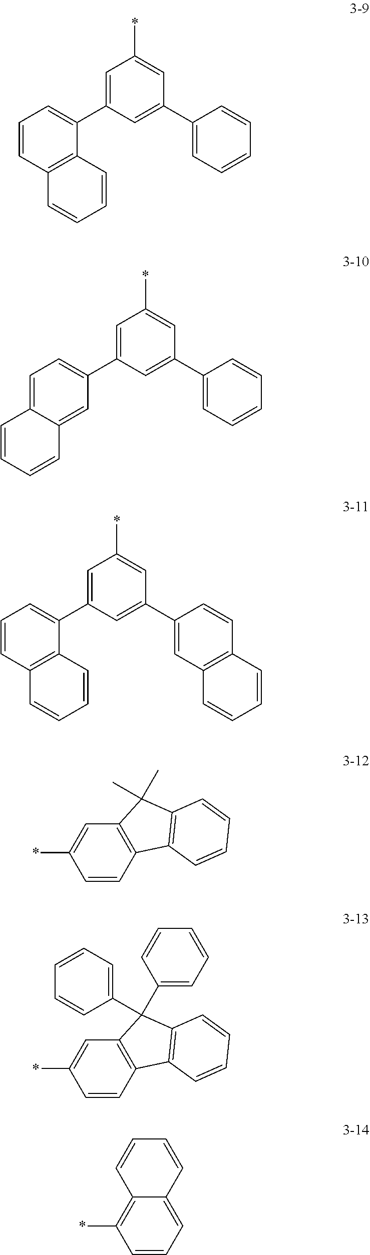

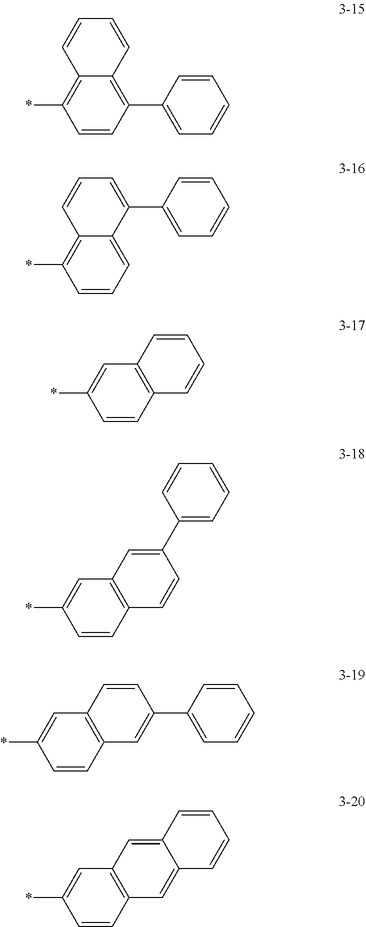

In Formula 2(1) or Formula 2(2), Z₅, Z₆, and R₁₁ to R₂₄ may each independently be: i) a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or v) —N(Q₁₁)(Q₁₂), —Si(Q₁₃)(Q₁₄)(Q₁₅), or —B(Q₁₆)(Q₁₇) (where Q₁₁ to Q₁₇ are each independently a C₁-C₆₀ alkyl group, a C₁-C₆₀ alkoxy group, a C₆-C₆₀ aryl group, or a C₁-C₆₀ heteroaryl group). However, Z₅, Z₆, and R₁₁ to R₂₄ are not limited thereto.

In some embodiments, in Formula 2(1) or Formula 2(2), Z₅, Z₆, and R₁₁ to R₂₄ may each independently be: i) a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, or a C₁-C₂₀ alkyl group; or ii) a C₁-C₂₀ alkyl group that is substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group; or iii) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group; or iv) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, or a triazinyl group. However, Z₅, Z₆, and R₁₁ to R₂₄ are not limited thereto.

In some other embodiments, in Formula 2(1) or Formula 2(2), Z₅, Z₆, and R₁₁ to R₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, or a C₁-C₂₀ alkyl group. However, Z₅, Z₆, and R₁₁ to R₂₄ are not limited thereto.

In some other embodiments, in Formula 2(1) or Formula 2(2), Z₅, Z₆, and R₁₁ to R₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a methyl group, an ethyl group, a propyl group, a butyl group, a pentyl group, a hexyl group, a heptyl group, or a compound represented by one of Formulas 3-1 to 3-20. However, Z₅, Z₆, and R₁₁ to R₂₄ are not limited thereto.

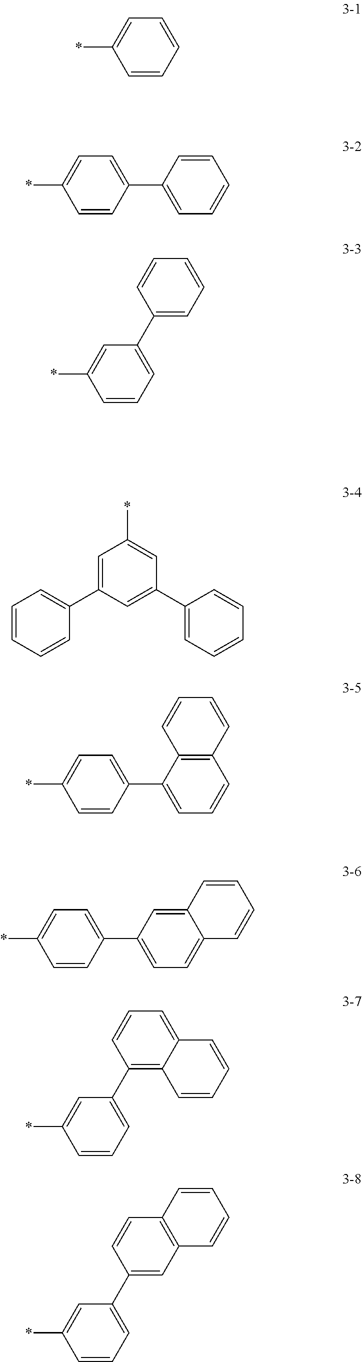

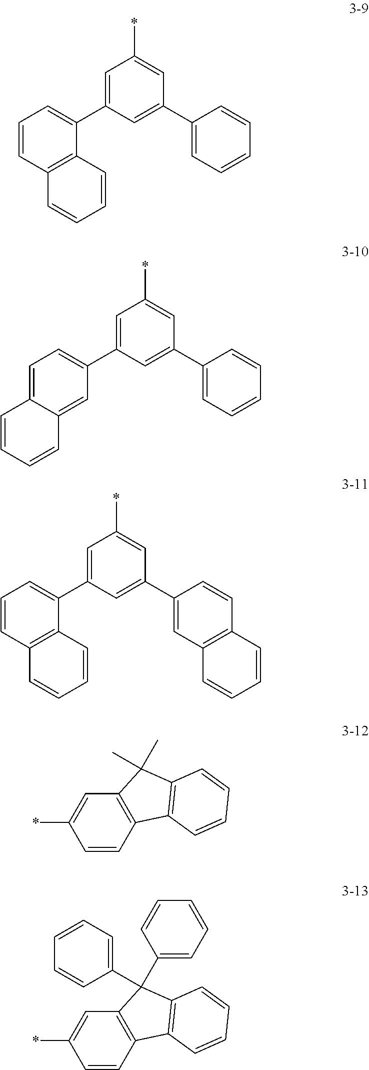 [SMILES: *c1cc(-c2ccccc2)cc(-c2cccc3ccccc23)c1 ; *c1cc(-c2ccccc2)cc(-c2ccc3ccccc3c2)c1 ; *c1cc(-c2ccc3ccccc3c2)cc(-c2cccc3ccccc23)c1 ; *c1ccc2c(c1)C(C)(C)c1ccccc1-2 ; *c1ccc2c(c1)C(c1ccccc1)(c1ccccc1)c1ccccc1-2]

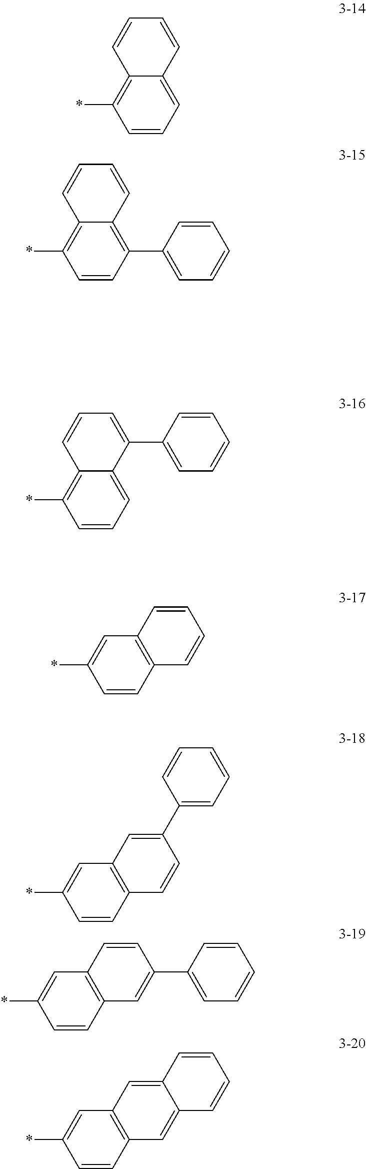

In Formula 2(1) and Formula 2(2), p indicates the number of Z₅s, and is an integer of 1 to 4. When p is 2 or greater, the Z₅s may be identical to or different from each other. In Formula 2(1) or Formula 2(2), q indicates the number of Z₆s, and is an integer from 1 to 4. When q is 2 or greater, the Z₆s may be identical to or different from each other.

According to an embodiment of the present invention, the hole-transporting material may be represented by one of Formulas 2A and 2B, but the hole-transporting material is not limited thereto.

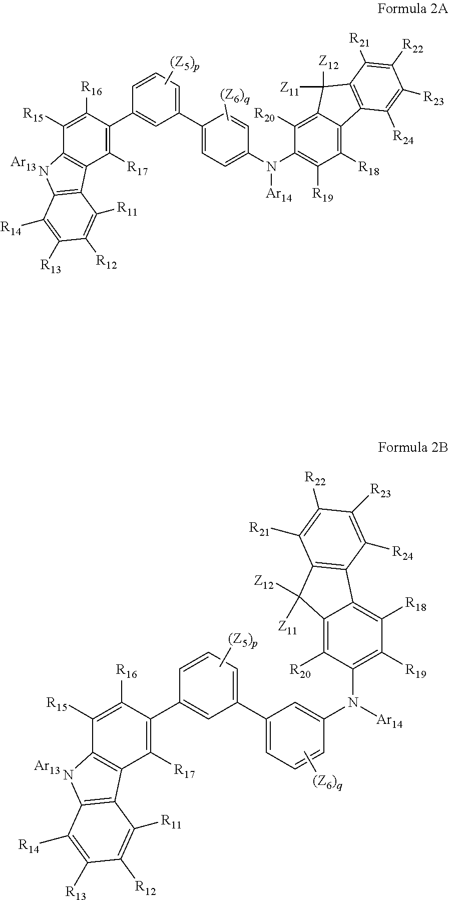

In Formula 2A and Formula 2B, p and q are each independently an integer of 1 to 4, and Ar₁₃ and Ar₁₄ may each independently be represented by one of Formulas 3-1 to 3-20; Z₁₁ and Z₁₂ may each independently be represented by a C₁-C₂₀ alkyl group or one of Formulas 3-1 to 3-20.

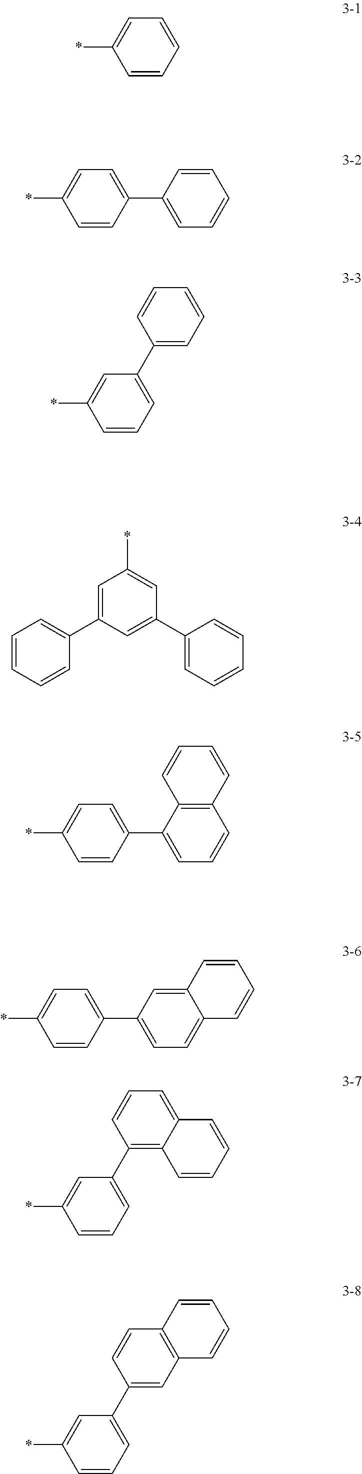

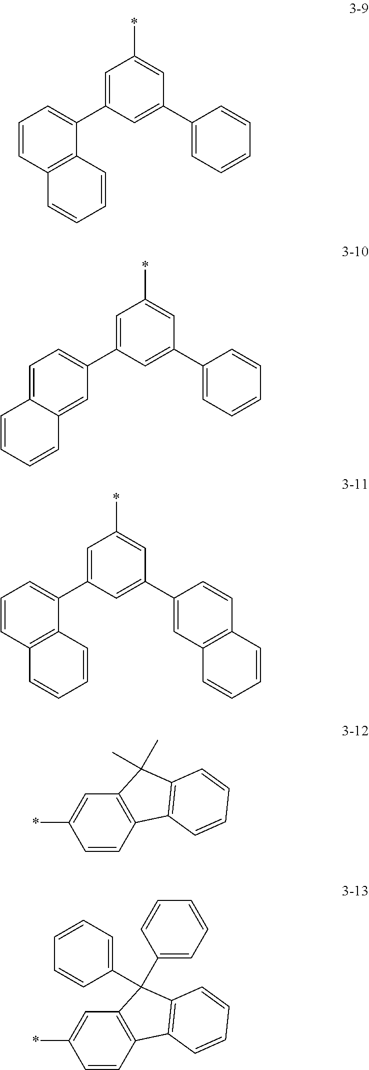 [SMILES: *c1cc(-c2ccccc2)cc(-c2cccc3ccccc23)c1 ; *c1cc(-c2ccccc2)cc(-c2ccc3ccccc3c2)c1 ; *c1cc(-c2ccc3ccccc3c2)cc(-c2cccc3ccccc23)c1 ; *c1ccc2c(c1)C(C)(C)c1ccccc1-2 ; *c1ccc2c(c1)C(c1ccccc1)(c1ccccc1)c1ccccc1-2]

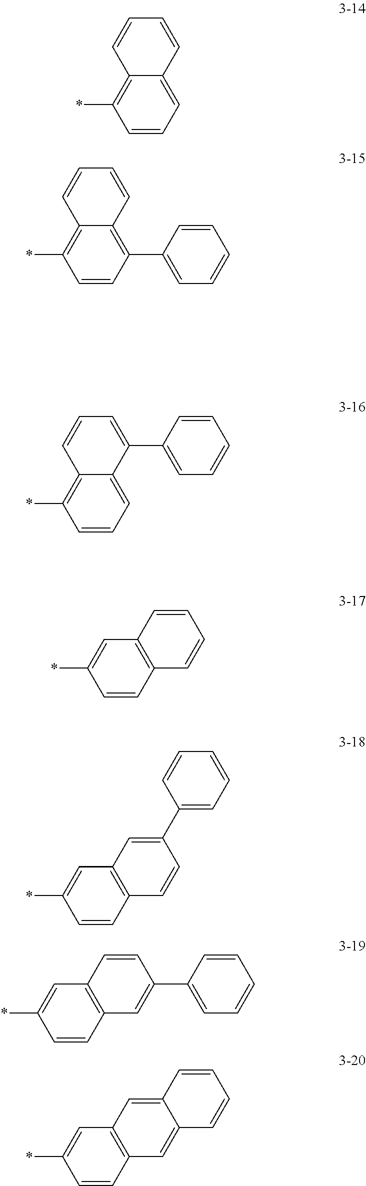

In Formula 2A and Formula 2B3, Z₅, Z₆, and R₁₁ to R₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂o alkyl group, or a group represented by one of Formulas 3-1 to 3-20.

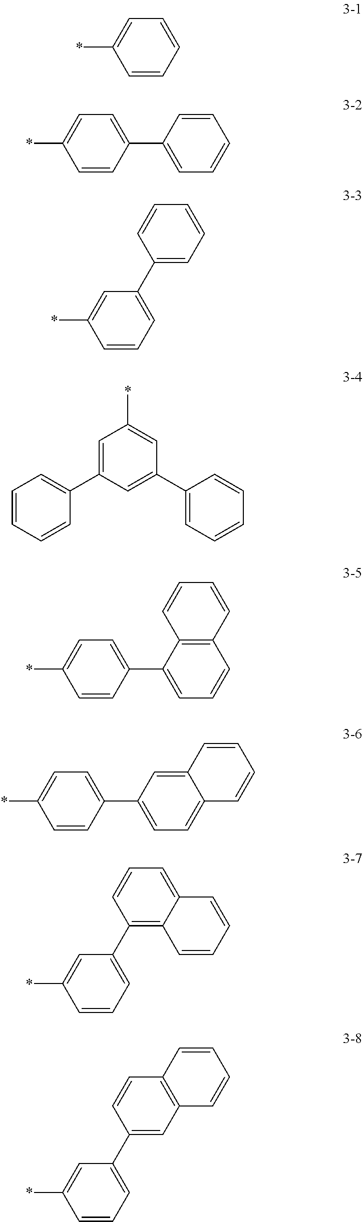

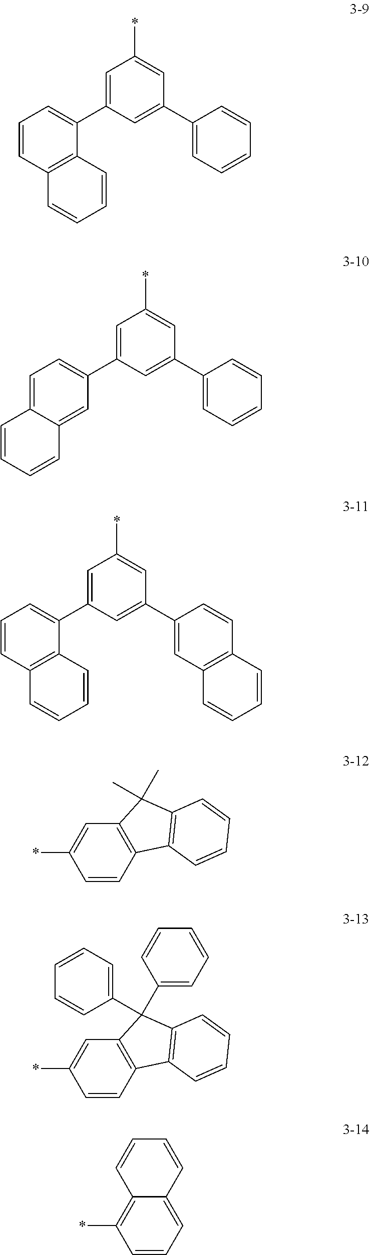

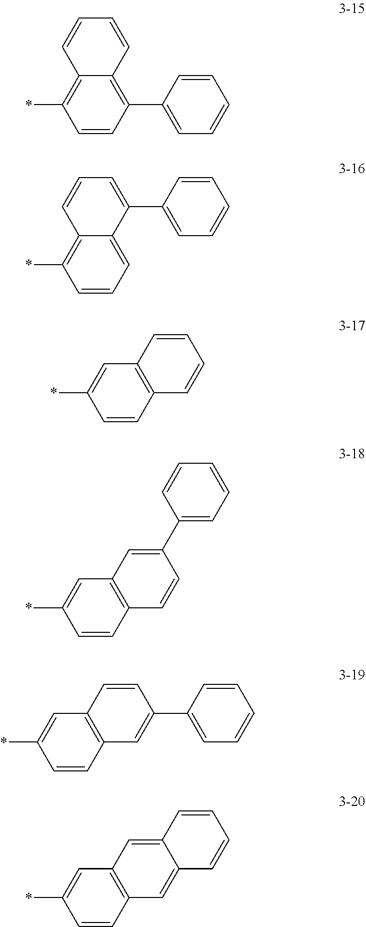

In some other embodiments, the hole-transporting material may be at least one of Compounds 6-1 to 6-144, but the hole-transporting material is not limited thereto.

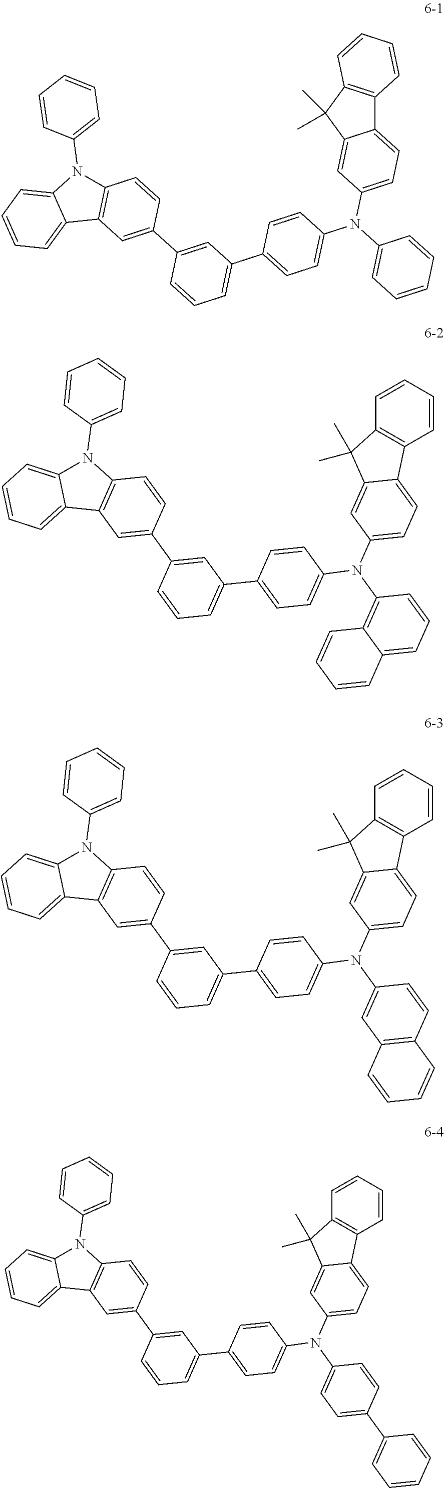 [SMILES: CC1(C)c2ccccc2-c2ccc(N(c3ccccc3)c3ccc(-c4cccc(-c5ccc6c(c5)c5ccccc5n6-c5ccccc5)c4)cc3)cc21 ; CC1(C)c2ccccc2-c2ccc(N(c3ccc(-c4cccc(-c5ccc6c(c5)c5ccccc5n6-c5ccccc5)c4)cc3)c3cccc4ccccc34)cc21 ; CC1(C)c2ccccc2-c2ccc(N(c3ccc(-c4cccc(-c5ccc6c(c5)c5ccccc5n6-c5ccccc5)c4)cc3)c3ccc4ccccc4c3)cc21 ; CC1(C)c2ccccc2-c2ccc(N(c3ccc(-c4ccccc4)cc3)c3ccc(-c4cccc(-c5ccc6c(c5)c5ccccc5n6-c5ccccc5)c4)cc3)cc21]

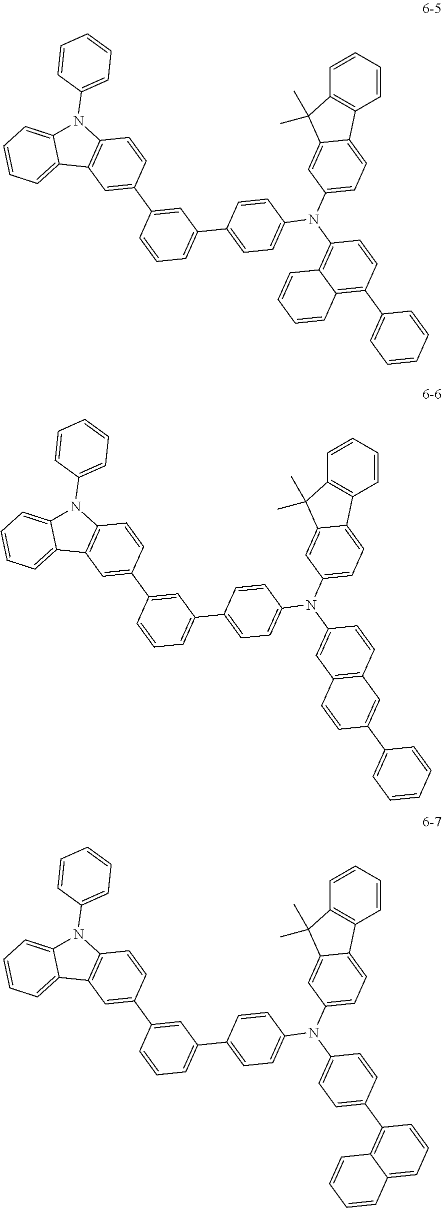 [SMILES: CC1(C)c2ccccc2-c2ccc(N(c3ccc(-c4cccc(-c5ccc6c(c5)c5ccccc5n6-c5ccccc5)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5ccccc5)c4)cc3)c3ccc4cc(-c5ccccc5)ccc4c3)cc21 ; CC1(C)c2ccccc2-c2ccc(N(c3ccc(-c4cccc(-c5ccc6c(c5)c5ccccc5n6-c5ccccc5)c4)cc3)c3ccc(-c4cccc5ccccc45)cc3)cc21]

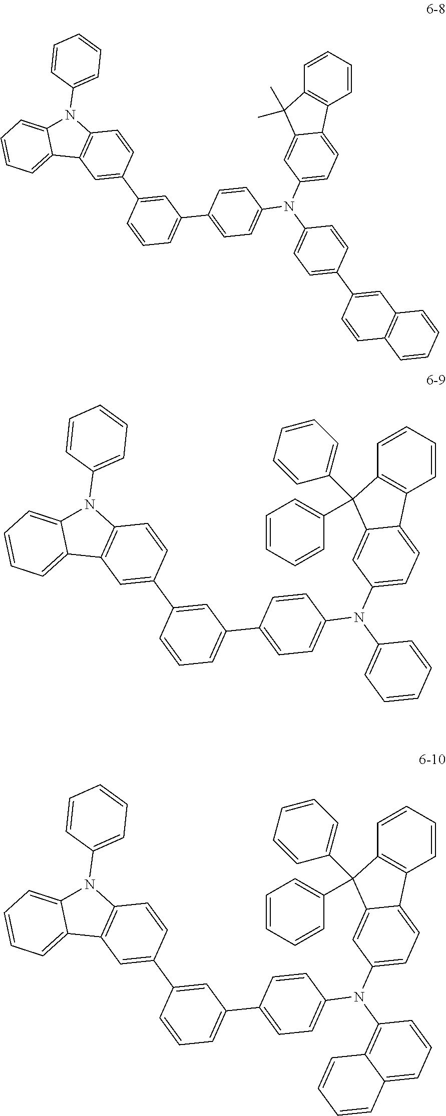 [SMILES: CC1(C)c2ccccc2-c2ccc(N(c3ccc(-c4cccc(-c5ccc6c(c5)c5ccccc5n6-c5ccccc5)c4)cc3)c3ccc(-c4ccc5ccccc5c4)cc3)cc21 ; c1ccc(N(c2ccc(-c3cccc(-c4ccc5c(c4)c4ccccc4n5-c4ccccc4)c3)cc2)c2ccc3c(c2)C(c2ccccc2)(c2ccccc2)c2ccccc2-3)cc1 ; c1ccc(-n2c3ccccc3c3cc(-c4cccc(-c5ccc(N(c6ccc7c(c6)C(c6ccccc6)(c6ccccc6)c6ccccc6-7)c6cccc7ccccc67)cc5)c4)ccc32)cc1]

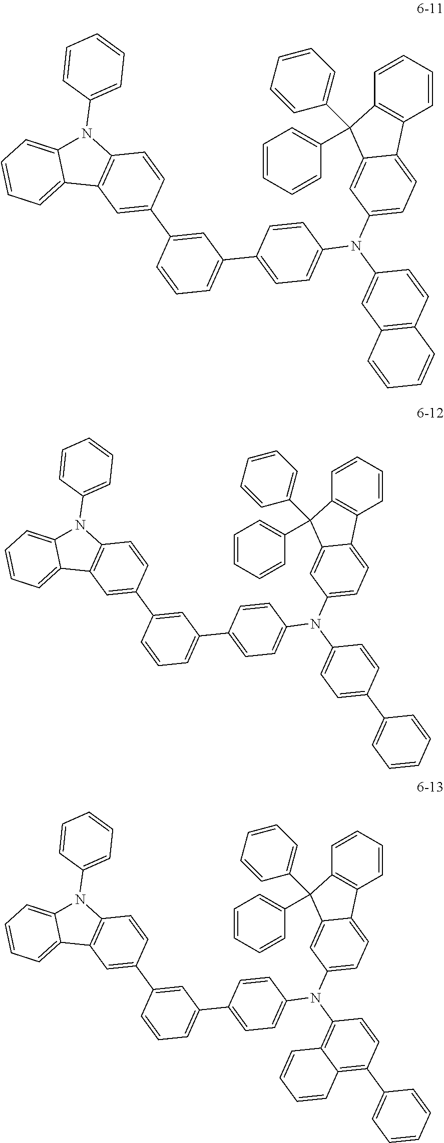 [SMILES: c1ccc(-n2c3ccccc3c3cc(-c4cccc(-c5ccc(N(c6ccc7c(c6)C(c6ccccc6)(c6ccccc6)c6ccccc6-7)c6ccc7ccccc7c6)cc5)c4)ccc32)cc1 ; c1ccc(-c2ccc(N(c3ccc(-c4cccc(-c5ccc6c(c5)c5ccccc5n6-c5ccccc5)c4)cc3)c3ccc4c(c3)C(c3ccccc3)(c3ccccc3)c3ccccc3-4)cc2)cc1 ; c1ccc(-c2ccc(N(c3ccc(-c4cccc(-c5ccc6c(c5)c5ccccc5n6-c5ccccc5)c4)cc3)c3ccc4c(c3)C(c3ccccc3)(c3ccccc3)c3ccccc3-4)c3ccccc23)cc1]

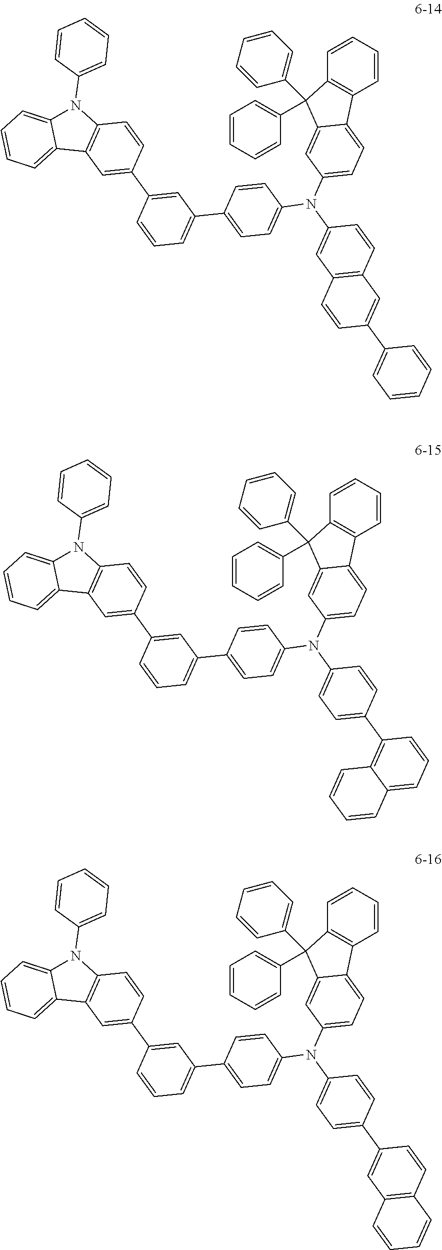 [SMILES: c1ccc(-c2ccc3cc(N(c4ccc(-c5cccc(-c6ccc7c(c6)c6ccccc6n7-c6ccccc6)c5)cc4)c4ccc5c(c4)C(c4ccccc4)(c4ccccc4)c4ccccc4-5)ccc3c2)cc1 ; c1ccc(-n2c3ccccc3c3cc(-c4cccc(-c5ccc(N(c6ccc(-c7cccc8ccccc78)cc6)c6ccc7c(c6)C(c6ccccc6)(c6ccccc6)c6ccccc6-7)cc5)c4)ccc32)cc1 ; c1ccc(-n2c3ccccc3c3cc(-c4cccc(-c5ccc(N(c6ccc(-c7ccc8ccccc8c7)cc6)c6ccc7c(c6)C(c6ccccc6)(c6ccccc6)c6ccccc6-7)cc5)c4)ccc32)cc1]

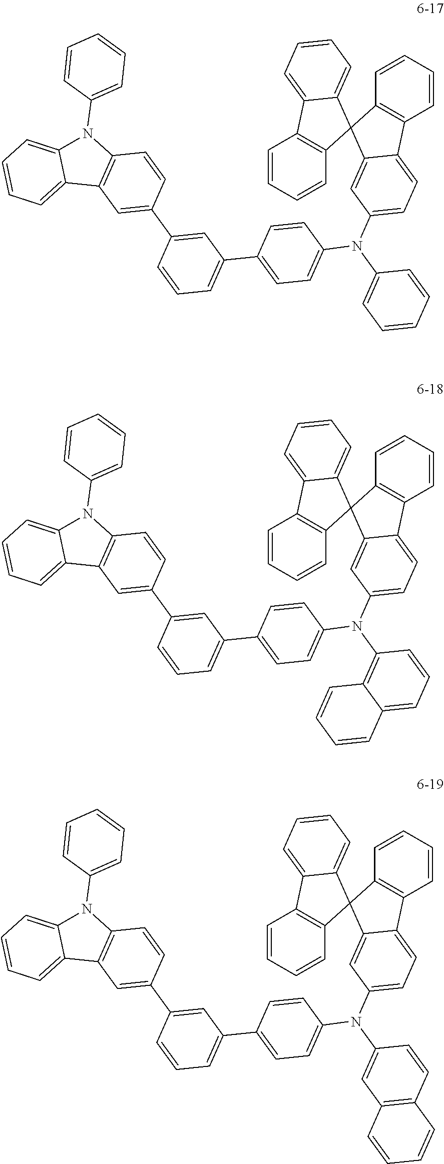 [SMILES: c1ccc(N(c2ccc(-c3cccc(-c4ccc5c(c4)c4ccccc4n5-c4ccccc4)c3)cc2)c2ccc3c(c2)C2(c4ccccc4-c4ccccc42)c2ccccc2-3)cc1 ; c1ccc(-n2c3ccccc3c3cc(-c4cccc(-c5ccc(N(c6ccc7c(c6)C6(c8ccccc8-c8ccccc86)c6ccccc6-7)c6cccc7ccccc67)cc5)c4)ccc32)cc1 ; c1ccc(-n2c3ccccc3c3cc(-c4cccc(-c5ccc(N(c6ccc7c(c6)C6(c8ccccc8-c8ccccc86)c6ccccc6-7)c6ccc7ccccc7c6)cc5)c4)ccc32)cc1]

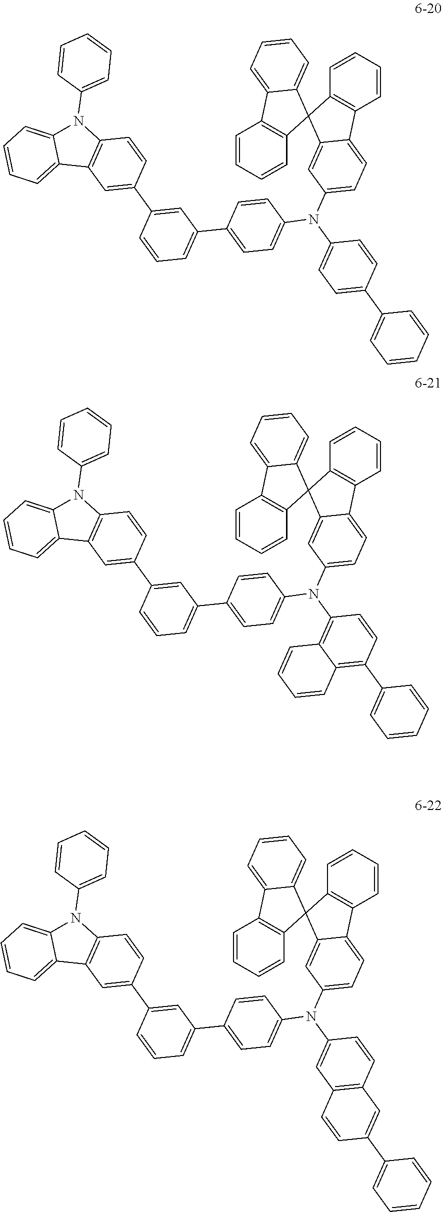 [SMILES: c1ccc(-c2ccc(N(c3ccc(-c4cccc(-c5ccc6c(c5)c5ccccc5n6-c5ccccc5)c4)cc3)c3ccc4c(c3)C3(c5ccccc5-c5ccccc53)c3ccccc3-4)cc2)cc1 ; c1ccc(-c2ccc(N(c3ccc(-c4cccc(-c5ccc6c(c5)c5ccccc5n6-c5ccccc5)c4)cc3)c3ccc4c(c3)C3(c5ccccc5-c5ccccc53)c3ccccc3-4)c3ccccc23)cc1 ; c1ccc(-c2ccc3cc(N(c4ccc(-c5cccc(-c6ccc7c(c6)c6ccccc6n7-c6ccccc6)c5)cc4)c4ccc5c(c4)C4(c6ccccc6-c6ccccc64)c4ccccc4-5)ccc3c2)cc1]

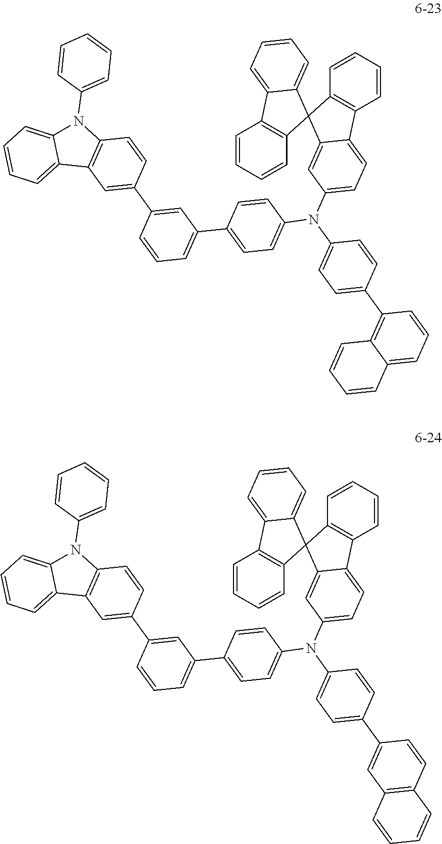 [SMILES: c1ccc(-n2c3ccccc3c3cc(-c4cccc(-c5ccc(N(c6ccc(-c7cccc8ccccc78)cc6)c6ccc7c(c6)C6(c8ccccc8-c8ccccc86)c6ccccc6-7)cc5)c4)ccc32)cc1 ; c1ccc(-n2c3ccccc3c3cc(-c4cccc(-c5ccc(N(c6ccc(-c7ccc8ccccc8c7)cc6)c6ccc7c(c6)C6(c8ccccc8-c8ccccc86)c6ccccc6-7)cc5)c4)ccc32)cc1]

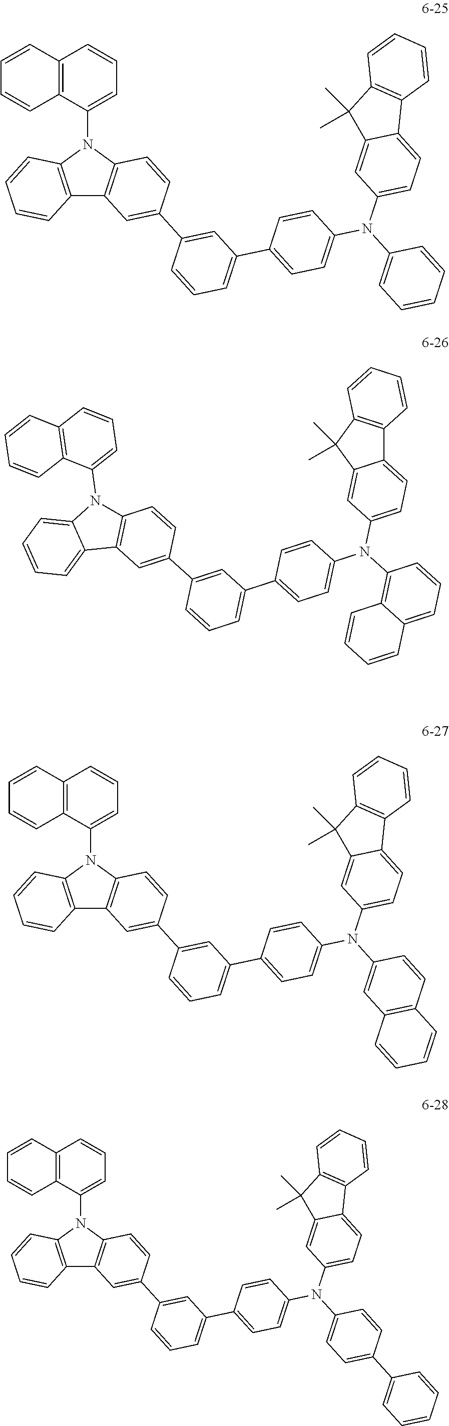 [SMILES: CC1(C)c2ccccc2-c2ccc(N(c3ccccc3)c3ccc(-c4cccc(-c5ccc6c(c5)c5ccccc5n6-c5cccc6ccccc56)c4)cc3)cc21 ; CC1(C)c2ccccc2-c2ccc(N(c3ccc(-c4cccc(-c5ccc6c(c5)c5ccccc5n6-c5cccc6ccccc56)c4)cc3)c3cccc4ccccc34)cc21 ; CC1(C)c2ccccc2-c2ccc(N(c3ccc(-c4cccc(-c5ccc6c(c5)c5ccccc5n6-c5cccc6ccccc56)c4)cc3)c3ccc4ccccc4c3)cc21 ; CC1(C)c2ccccc2-c2ccc(N(c3ccc(-c4ccccc4)cc3)c3ccc(-c4cccc(-c5ccc6c(c5)c5ccccc5n6-c5cccc6ccccc56)c4)cc3)cc21]

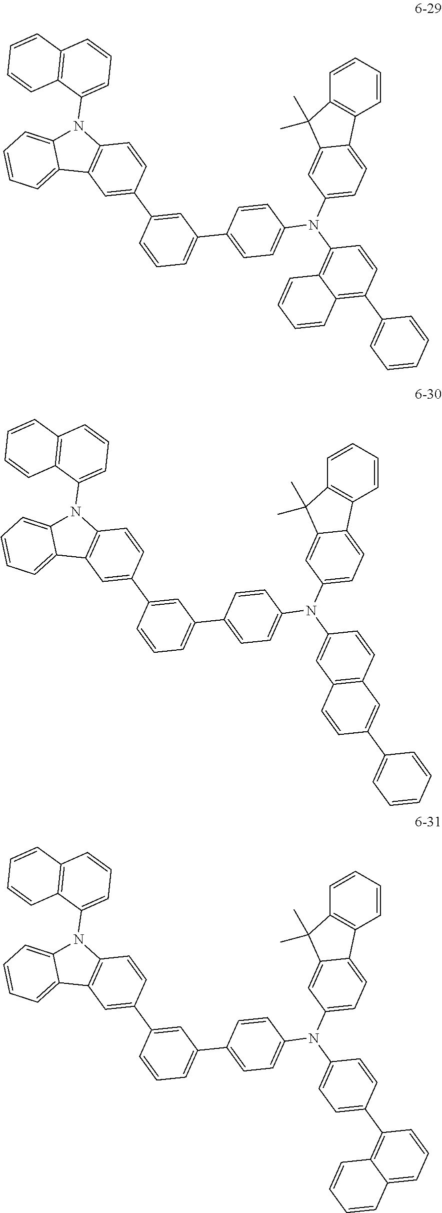 [SMILES: CC1(C)c2ccccc2-c2ccc(N(c3ccc(-c4cccc(-c5ccc6c(c5)c5ccccc5n6-c5cccc6ccccc56)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5cccc6ccccc56)c4)cc3)c3ccc4cc(-c5ccccc5)ccc4c3)cc21 ; CC1(C)c2ccccc2-c2ccc(N(c3ccc(-c4cccc(-c5ccc6c(c5)c5ccccc5n6-c5cccc6ccccc56)c4)cc3)c3ccc(-c4cccc5ccccc45)cc3)cc21]

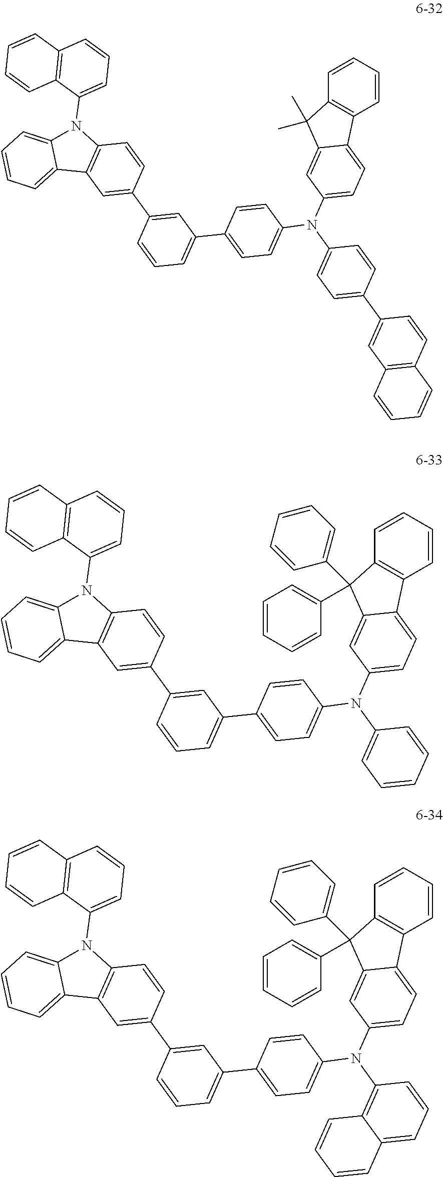 [SMILES: CC1(C)c2ccccc2-c2ccc(N(c3ccc(-c4cccc(-c5ccc6c(c5)c5ccccc5n6-c5cccc6ccccc56)c4)cc3)c3ccc(-c4ccc5ccccc5c4)cc3)cc21 ; c1ccc(N(c2ccc(-c3cccc(-c4ccc5c(c4)c4ccccc4n5-c4cccc5ccccc45)c3)cc2)c2ccc3c(c2)C(c2ccccc2)(c2ccccc2)c2ccccc2-3)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4cccc5ccccc45)cc32)cc1]

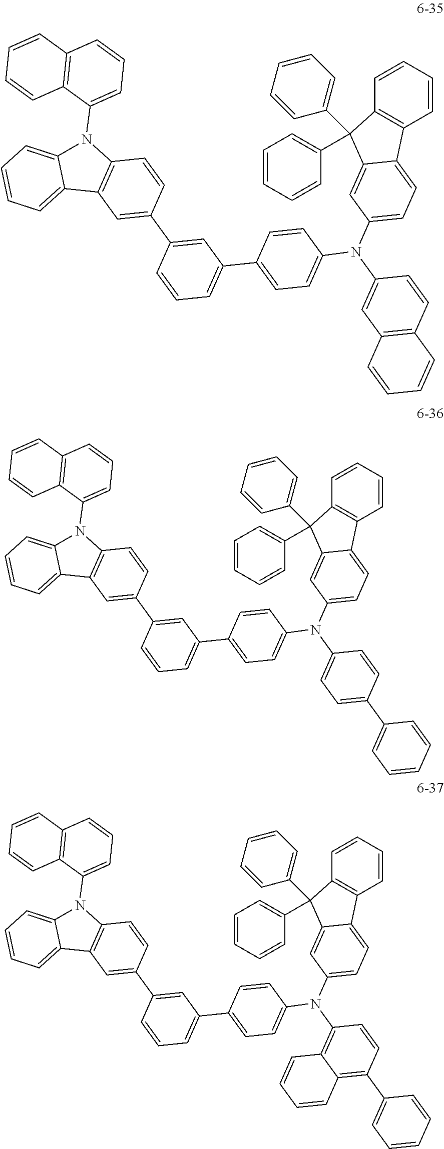 [SMILES: c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc5ccccc5c4)cc32)cc1 ; c1ccc(-c2ccc(N(c3ccc(-c4cccc(-c5ccc6c(c5)c5ccccc5n6-c5cccc6ccccc56)c4)cc3)c3ccc4c(c3)C(c3ccccc3)(c3ccccc3)c3ccccc3-4)cc2)cc1 ; c1ccc(-c2ccc(N(c3ccc(-c4cccc(-c5ccc6c(c5)c5ccccc5n6-c5cccc6ccccc56)c4)cc3)c3ccc4c(c3)C(c3ccccc3)(c3ccccc3)c3ccccc3-4)c3ccccc23)cc1]

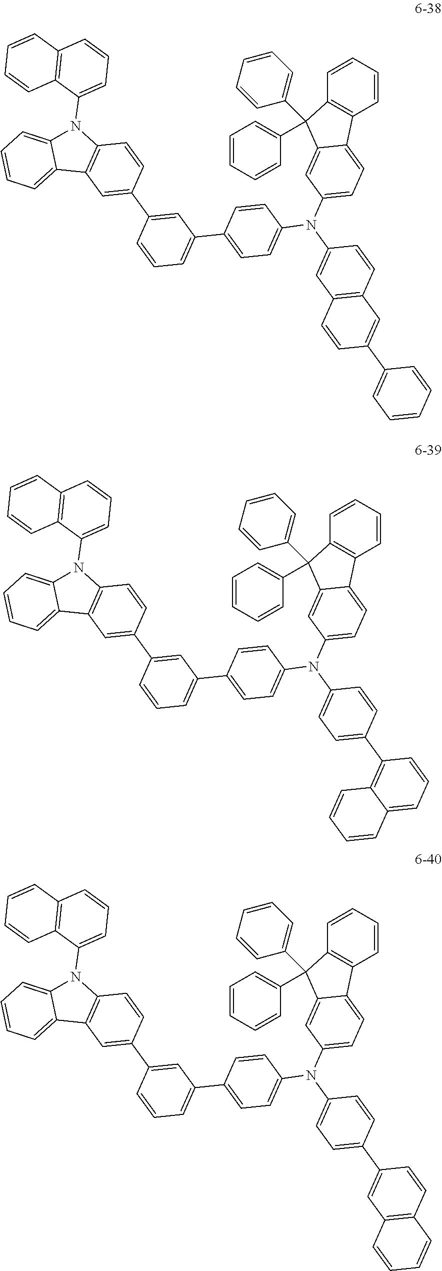 [SMILES: c1ccc(-c2ccc3cc(N(c4ccc(-c5cccc(-c6ccc7c(c6)c6ccccc6n7-c6cccc7ccccc67)c5)cc4)c4ccc5c(c4)C(c4ccccc4)(c4ccccc4)c4ccccc4-5)ccc3c2)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc(-c5cccc6ccccc56)cc4)cc32)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc(-c5ccc6ccccc6c5)cc4)cc32)cc1]

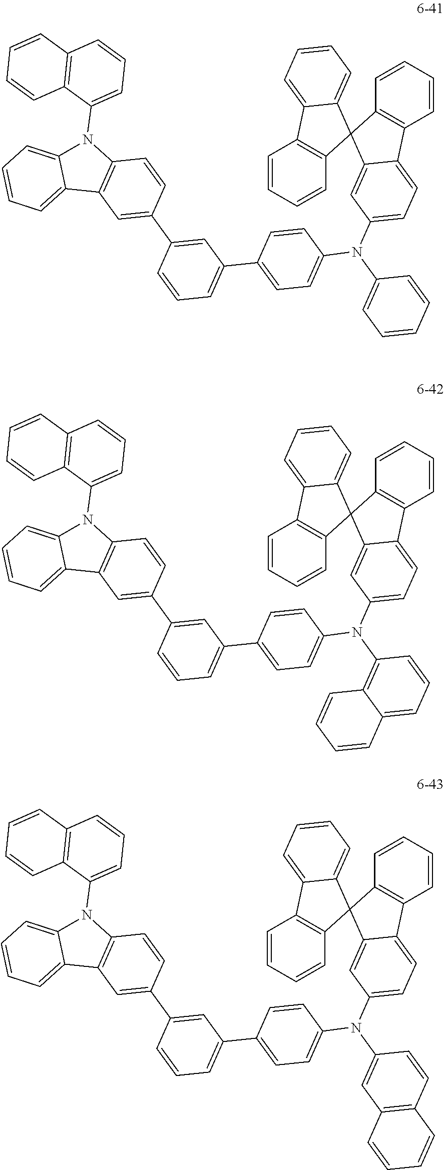 [SMILES: c1ccc(N(c2ccc(-c3cccc(-c4ccc5c(c4)c4ccccc4n5-c4cccc5ccccc45)c3)cc2)c2ccc3c(c2)C2(c4ccccc4-c4ccccc42)c2ccccc2-3)cc1 ; c1cc(-c2ccc(N(c3ccc4c(c3)C3(c5ccccc5-c5ccccc53)c3ccccc3-4)c3cccc4ccccc34)cc2)cc(-c2ccc3c(c2)c2ccccc2n3-c2cccc3ccccc23)c1 ; c1cc(-c2ccc(N(c3ccc4c(c3)C3(c5ccccc5-c5ccccc53)c3ccccc3-4)c3ccc4ccccc4c3)cc2)cc(-c2ccc3c(c2)c2ccccc2n3-c2cccc3ccccc23)c1]

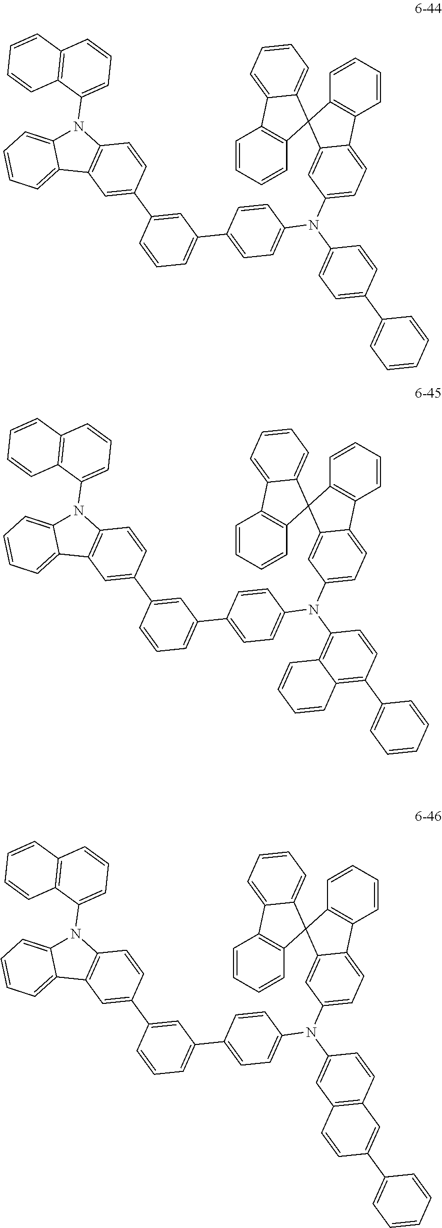 [SMILES: c1ccc(-c2ccc(N(c3ccc(-c4cccc(-c5ccc6c(c5)c5ccccc5n6-c5cccc6ccccc56)c4)cc3)c3ccc4c(c3)C3(c5ccccc5-c5ccccc53)c3ccccc3-4)cc2)cc1 ; c1ccc(-c2ccc(N(c3ccc(-c4cccc(-c5ccc6c(c5)c5ccccc5n6-c5cccc6ccccc56)c4)cc3)c3ccc4c(c3)C3(c5ccccc5-c5ccccc53)c3ccccc3-4)c3ccccc23)cc1 ; c1ccc(-c2ccc3cc(N(c4ccc(-c5cccc(-c6ccc7c(c6)c6ccccc6n7-c6cccc7ccccc67)c5)cc4)c4ccc5c(c4)C4(c6ccccc6-c6ccccc64)c4ccccc4-5)ccc3c2)cc1]

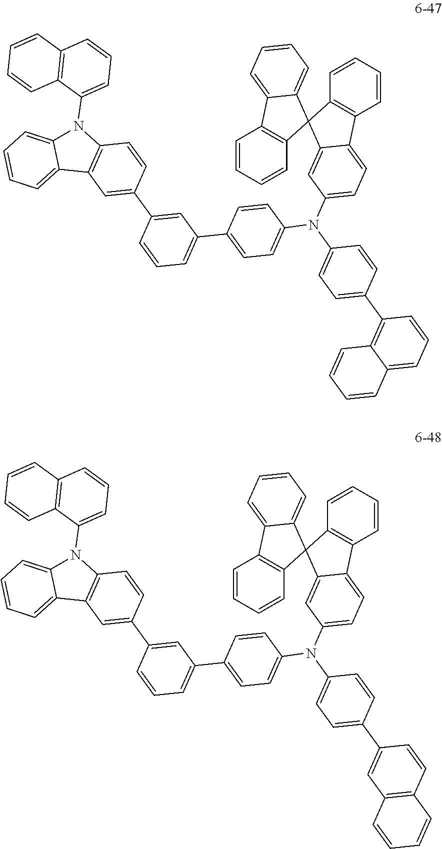 [SMILES: c1cc(-c2ccc(N(c3ccc(-c4cccc5ccccc45)cc3)c3ccc4c(c3)C3(c5ccccc5-c5ccccc53)c3ccccc3-4)cc2)cc(-c2ccc3c(c2)c2ccccc2n3-c2cccc3ccccc23)c1 ; c1cc(-c2ccc(N(c3ccc(-c4ccc5ccccc5c4)cc3)c3ccc4c(c3)C3(c5ccccc5-c5ccccc53)c3ccccc3-4)cc2)cc(-c2ccc3c(c2)c2ccccc2n3-c2cccc3ccccc23)c1]

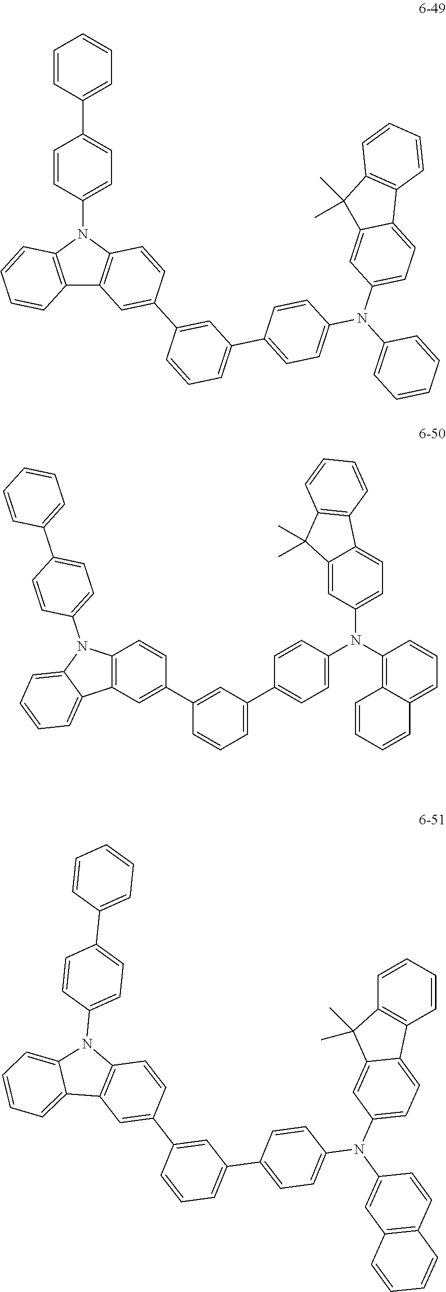 [SMILES: CC1(C)c2ccccc2-c2ccc(N(c3ccccc3)c3ccc(-c4cccc(-c5ccc6c(c5)c5ccccc5n6-c5ccc(-c6ccccc6)cc5)c4)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3cccc4ccccc34)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc4ccccc4c3)cc21]

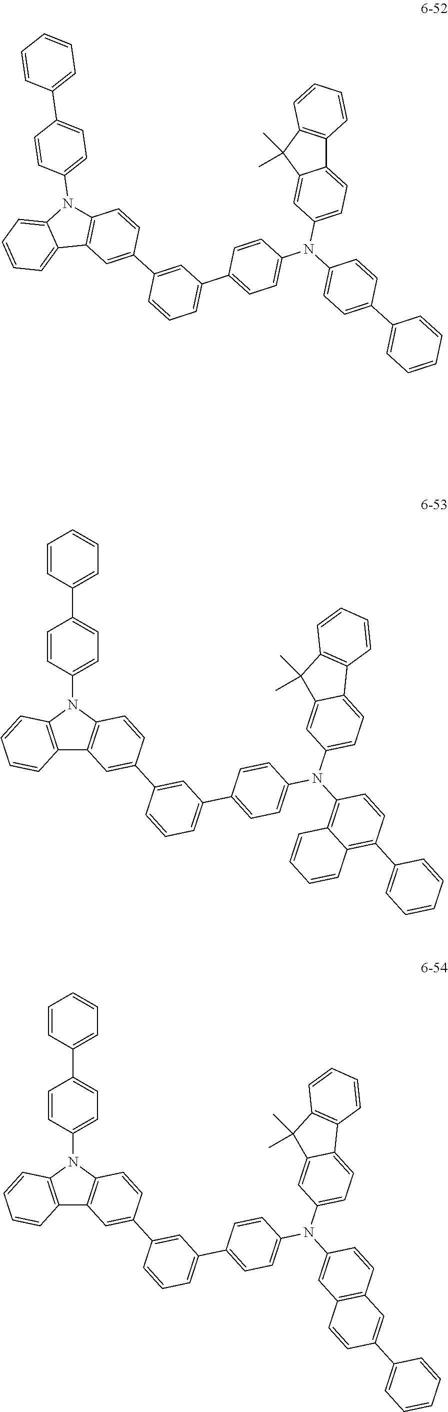 [SMILES: CC1(C)c2ccccc2-c2ccc(N(c3ccc(-c4ccccc4)cc3)c3ccc(-c4cccc(-c5ccc6c(c5)c5ccccc5n6-c5ccc(-c6ccccc6)cc5)c4)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc4cc(-c5ccccc5)ccc4c3)cc21]

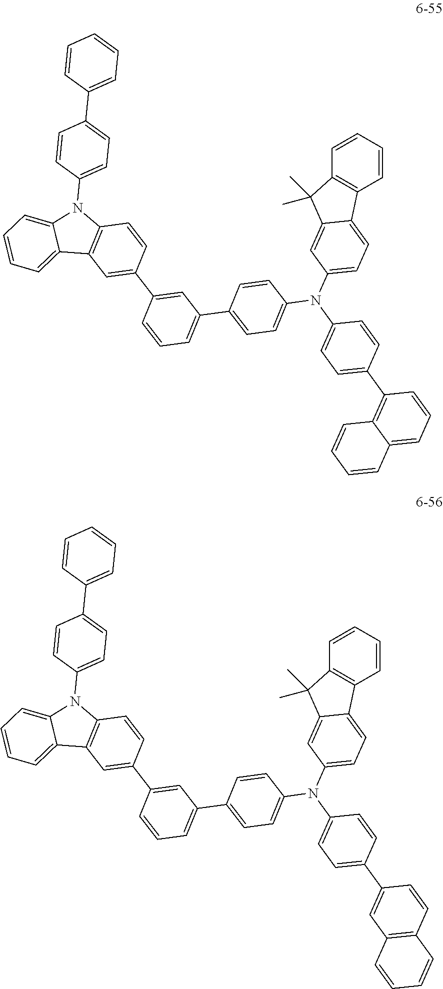 [SMILES: CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4cccc5ccccc45)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4ccc5ccccc5c4)cc3)cc21]

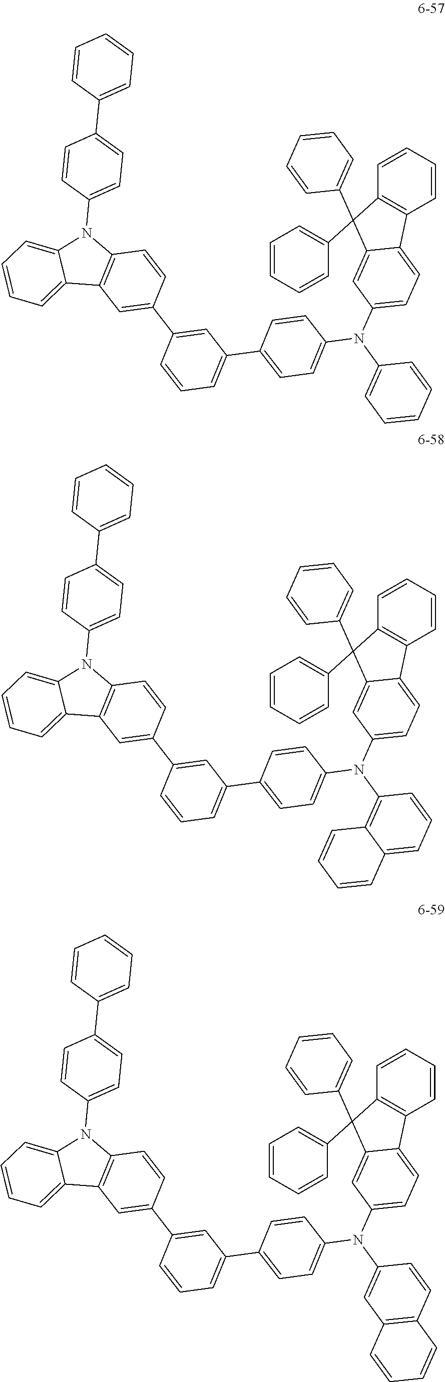 [SMILES: c1ccc(-c2ccc(-n3c4ccccc4c4cc(-c5cccc(-c6ccc(N(c7ccccc7)c7ccc8c(c7)C(c7ccccc7)(c7ccccc7)c7ccccc7-8)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7cccc8ccccc78)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc8ccccc8c7)cc6)c5)ccc43)cc2)cc1]

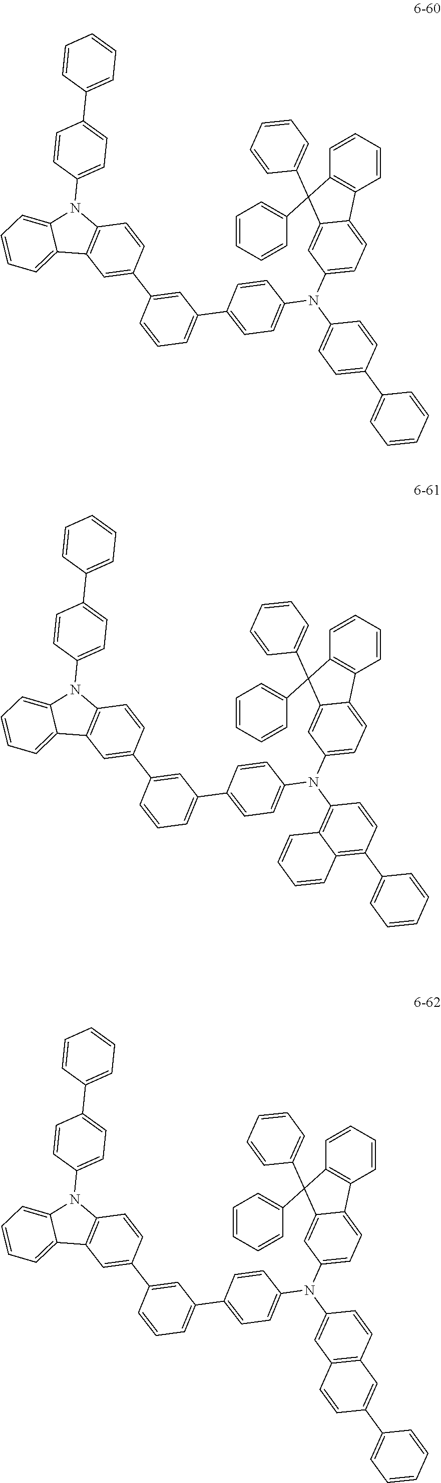 [SMILES: c1ccc(-c2ccc(N(c3ccc(-c4cccc(-c5ccc6c(c5)c5ccccc5n6-c5ccc(-c6ccccc6)cc5)c4)cc3)c3ccc4c(c3)C(c3ccccc3)(c3ccccc3)c3ccccc3-4)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc(-c8ccccc8)c8ccccc78)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc8cc(-c9ccccc9)ccc8c7)cc6)c5)ccc43)cc2)cc1]

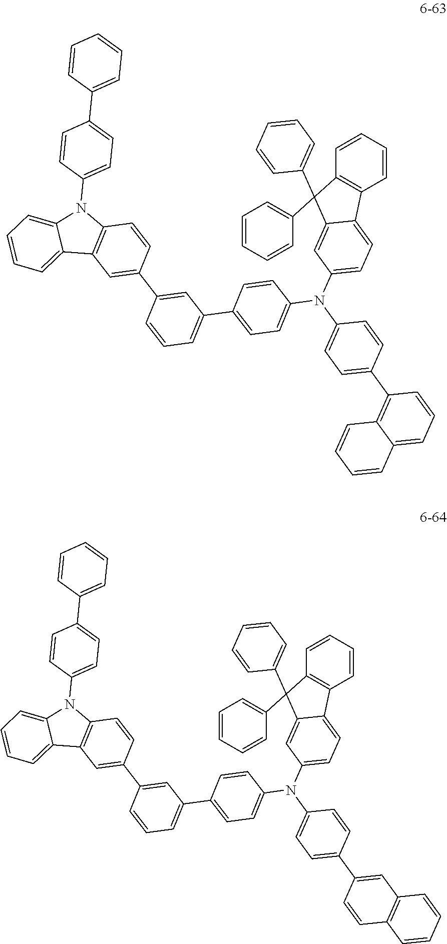 [SMILES: c1ccc(-c2ccc(-n3c4ccccc4c4cc(-c5cccc(-c6ccc(N(c7ccc(-c8cccc9ccccc89)cc7)c7ccc8c(c7)C(c7ccccc7)(c7ccccc7)c7ccccc7-8)cc6)c5)ccc43)cc2)cc1 ; c1ccc(-c2ccc(-n3c4ccccc4c4cc(-c5cccc(-c6ccc(N(c7ccc(-c8ccc9ccccc9c8)cc7)c7ccc8c(c7)C(c7ccccc7)(c7ccccc7)c7ccccc7-8)cc6)c5)ccc43)cc2)cc1]

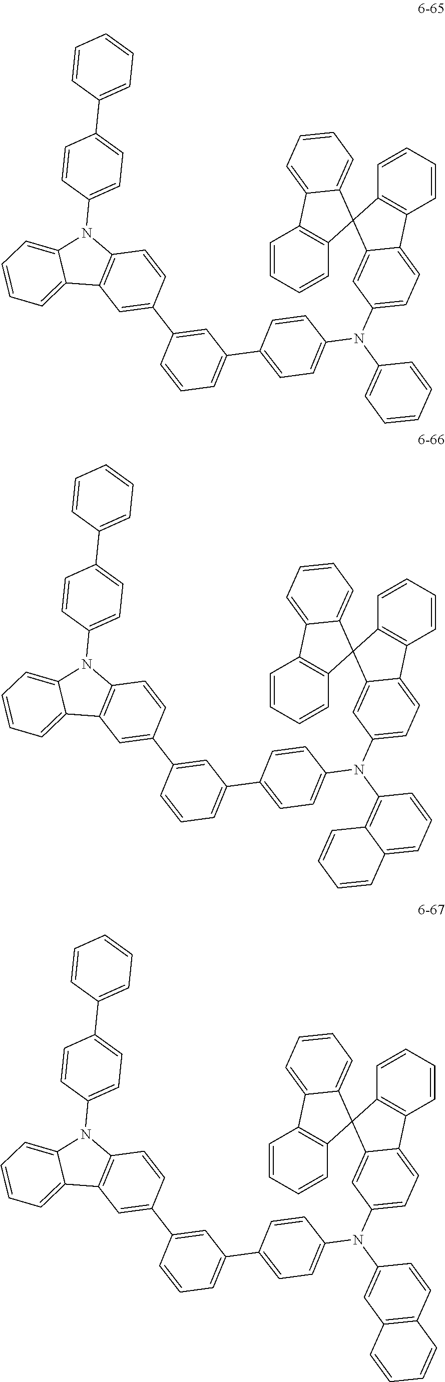 [SMILES: c1ccc(-c2ccc(-n3c4ccccc4c4cc(-c5cccc(-c6ccc(N(c7ccccc7)c7ccc8c(c7)C7(c9ccccc9-c9ccccc97)c7ccccc7-8)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7cccc8ccccc78)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc8ccccc8c7)cc6)c5)ccc43)cc2)cc1]

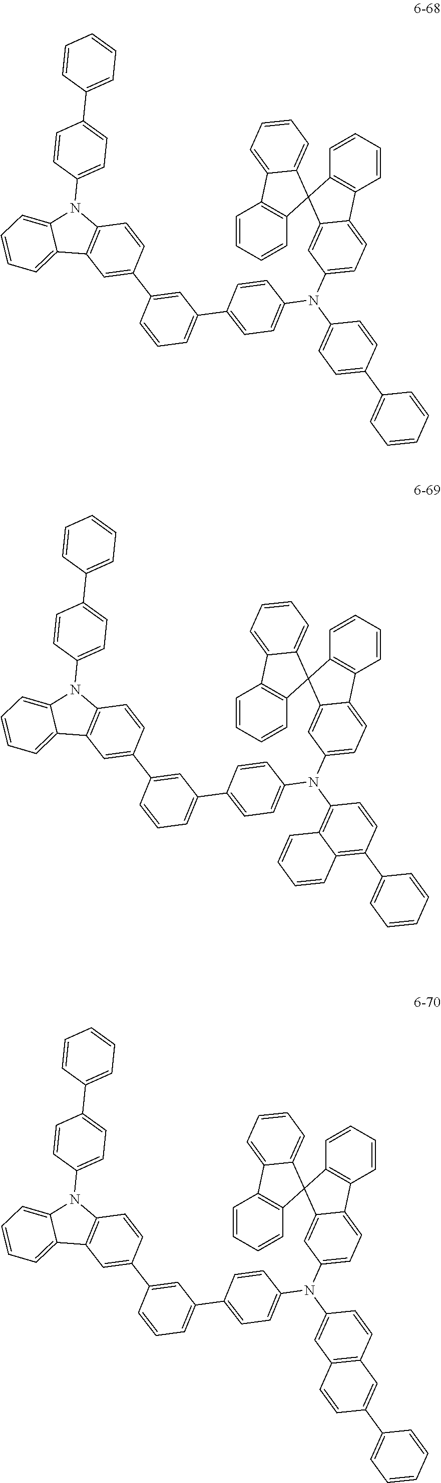 [SMILES: c1ccc(-c2ccc(N(c3ccc(-c4cccc(-c5ccc6c(c5)c5ccccc5n6-c5ccc(-c6ccccc6)cc5)c4)cc3)c3ccc4c(c3)C3(c5ccccc5-c5ccccc53)c3ccccc3-4)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc(-c8ccccc8)c8ccccc78)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc8cc(-c9ccccc9)ccc8c7)cc6)c5)ccc43)cc2)cc1]

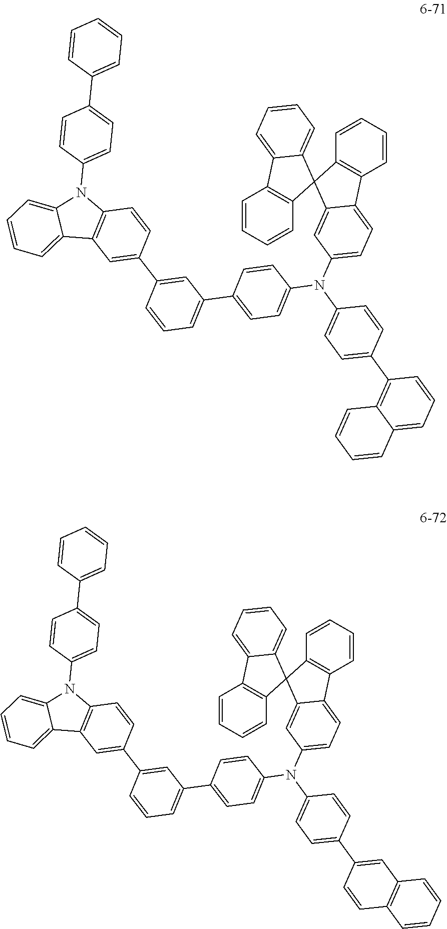 [SMILES: c1ccc(-c2ccc(-n3c4ccccc4c4cc(-c5cccc(-c6ccc(N(c7ccc(-c8cccc9ccccc89)cc7)c7ccc8c(c7)C7(c9ccccc9-c9ccccc97)c7ccccc7-8)cc6)c5)ccc43)cc2)cc1 ; c1ccc(-c2ccc(-n3c4ccccc4c4cc(-c5cccc(-c6ccc(N(c7ccc(-c8ccc9ccccc9c8)cc7)c7ccc8c(c7)C7(c9ccccc9-c9ccccc97)c7ccccc7-8)cc6)c5)ccc43)cc2)cc1]

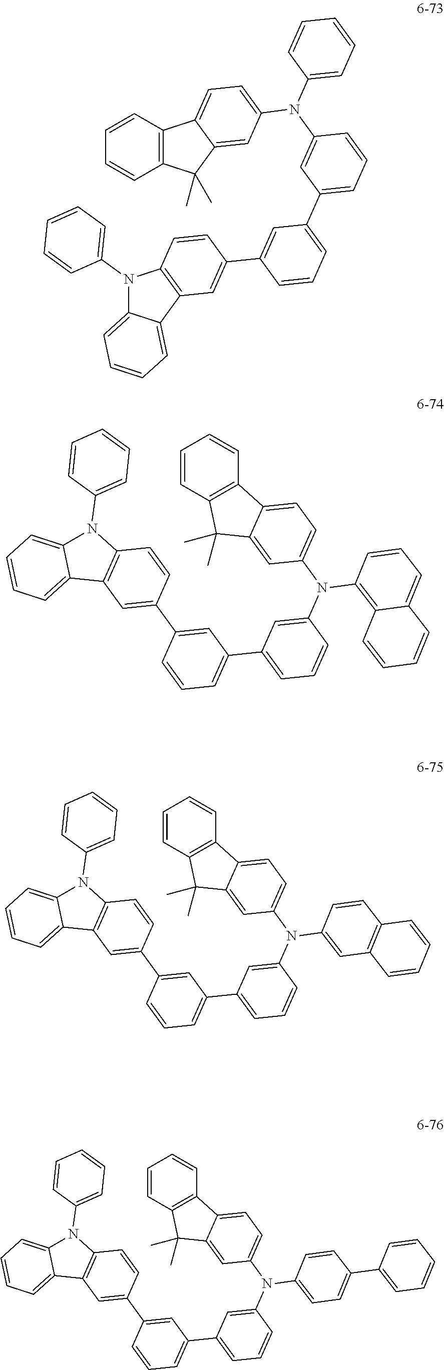 [SMILES: CC1(C)c2ccccc2-c2ccc(N(c3ccccc3)c3cccc(-c4cccc(-c5ccc6c(c5)c5ccccc5n6-c5ccccc5)c4)c3)cc21 ; CC1(C)c2ccccc2-c2ccc(N(c3cccc(-c4cccc(-c5ccc6c(c5)c5ccccc5n6-c5ccccc5)c4)c3)c3cccc4ccccc34)cc21 ; CC1(C)c2ccccc2-c2ccc(N(c3cccc(-c4cccc(-c5ccc6c(c5)c5ccccc5n6-c5ccccc5)c4)c3)c3ccc4ccccc4c3)cc21 ; CC1(C)c2ccccc2-c2ccc(N(c3ccc(-c4ccccc4)cc3)c3cccc(-c4cccc(-c5ccc6c(c5)c5ccccc5n6-c5ccccc5)c4)c3)cc21]

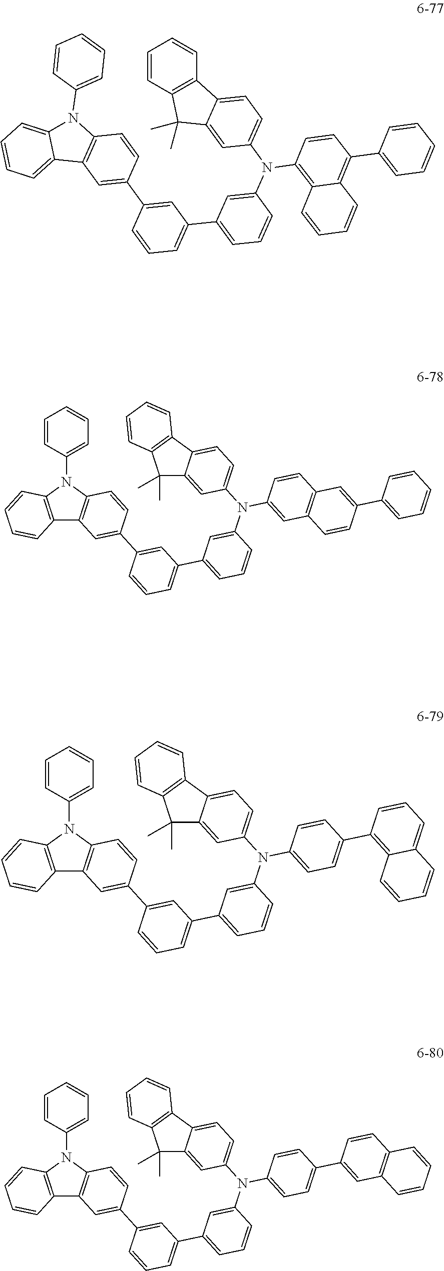 [SMILES: CC1(C)c2ccccc2-c2ccc(N(c3cccc(-c4cccc(-c5ccc6c(c5)c5ccccc5n6-c5ccccc5)c4)c3)c3ccc(-c4ccccc4)c4ccccc34)cc21 ; CC1(C)c2ccccc2-c2ccc(N(c3cccc(-c4cccc(-c5ccc6c(c5)c5ccccc5n6-c5ccccc5)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5ccccc5)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5ccccc5)c4)c3)cc21]

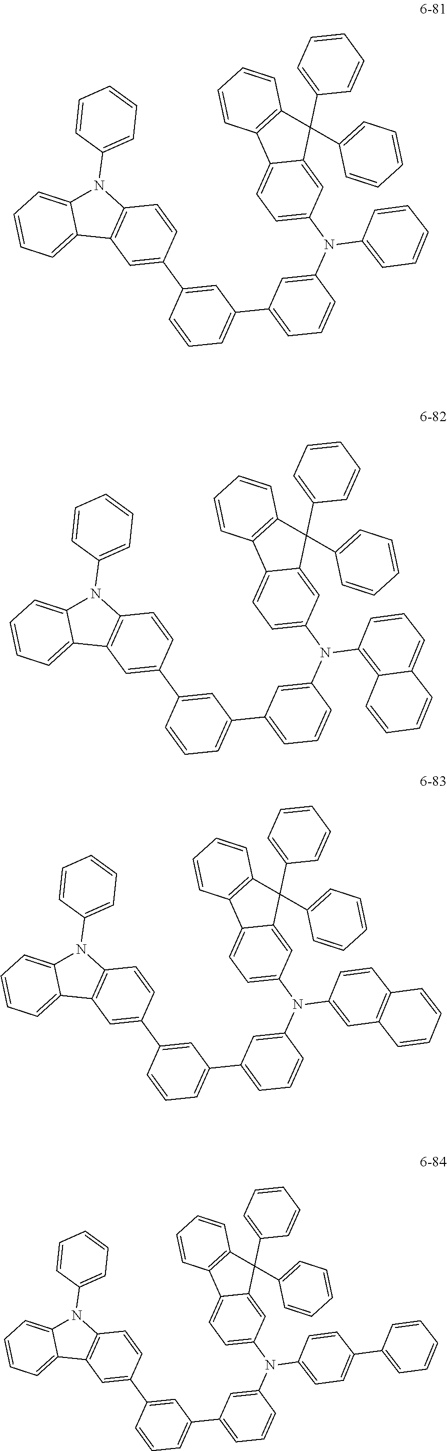 [SMILES: c1ccc(N(c2cccc(-c3cccc(-c4ccc5c(c4)c4ccccc4n5-c4ccccc4)c3)c2)c2ccc3c(c2)C(c2ccccc2)(c2ccccc2)c2ccccc2-3)cc1 ; c1ccc(-n2c3ccccc3c3cc(-c4cccc(-c5cccc(N(c6ccc7c(c6)C(c6ccccc6)(c6ccccc6)c6ccccc6-7)c6cccc7ccccc67)c5)c4)ccc32)cc1 ; c1ccc(-n2c3ccccc3c3cc(-c4cccc(-c5cccc(N(c6ccc7c(c6)C(c6ccccc6)(c6ccccc6)c6ccccc6-7)c6ccc7ccccc7c6)c5)c4)ccc32)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

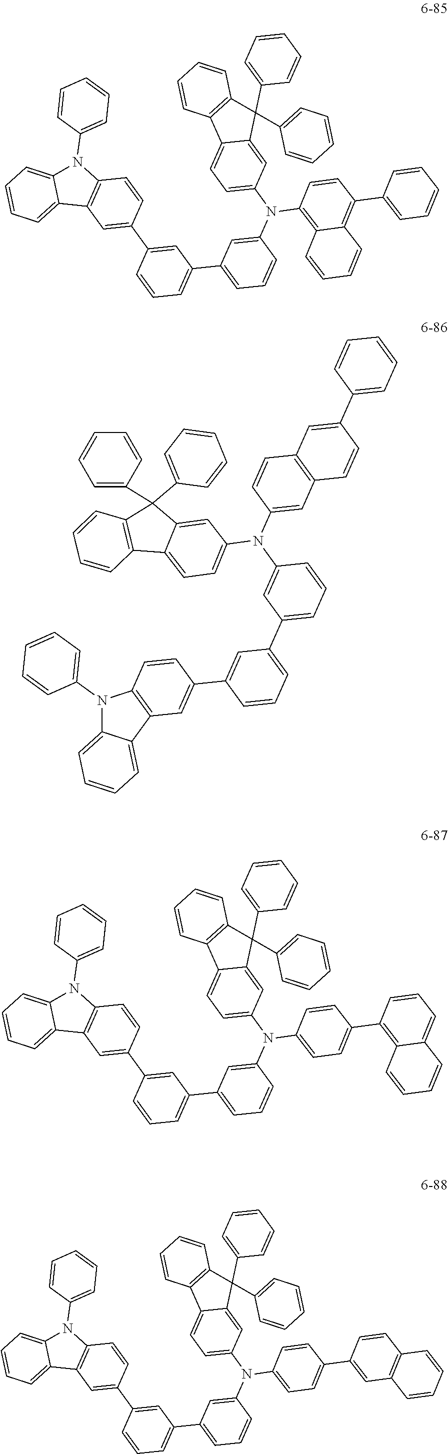

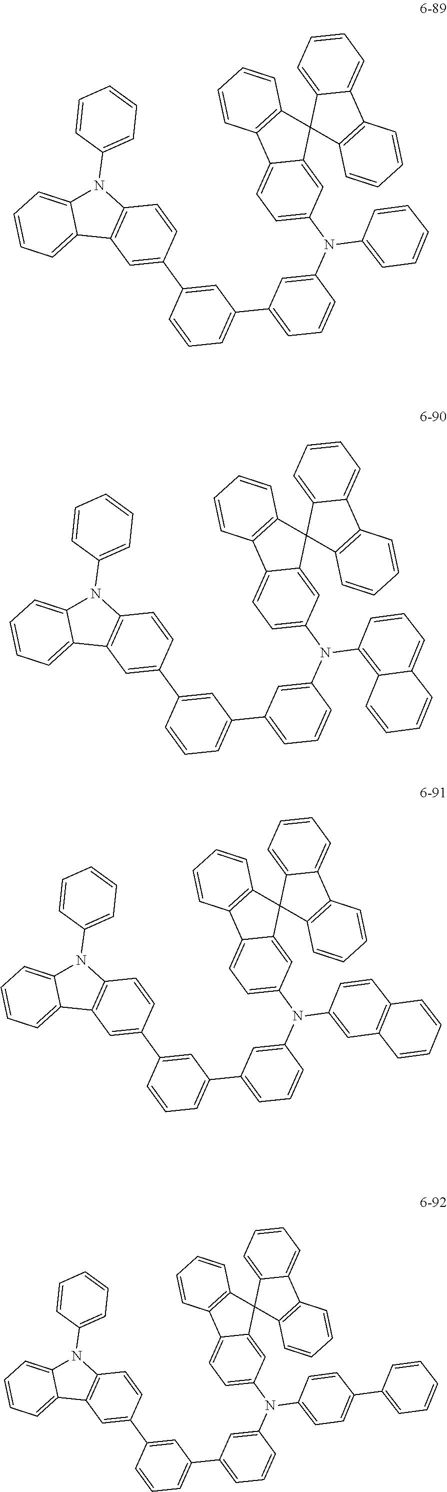 [SMILES: c1ccc(N(c2cccc(-c3cccc(-c4ccc5c(c4)c4ccccc4n5-c4ccccc4)c3)c2)c2ccc3c(c2)C2(c4ccccc4-c4ccccc42)c2ccccc2-3)cc1 ; c1ccc(-n2c3ccccc3c3cc(-c4cccc(-c5cccc(N(c6ccc7c(c6)C6(c8ccccc8-c8ccccc86)c6ccccc6-7)c6cccc7ccccc67)c5)c4)ccc32)cc1 ; c1ccc(-n2c3ccccc3c3cc(-c4cccc(-c5cccc(N(c6ccc7c(c6)C6(c8ccccc8-c8ccccc86)c6ccccc6-7)c6ccc7ccccc7c6)c5)c4)ccc32)cc1 ; c1ccc(-c2ccc(N(c3cccc(-c4cccc(-c5ccc6c(c5)c5ccccc5n6-c5ccccc5)c4)c3)c3ccc4c(c3)C3(c5ccccc5-c5ccccc53)c3ccccc3-4)cc2)cc1]

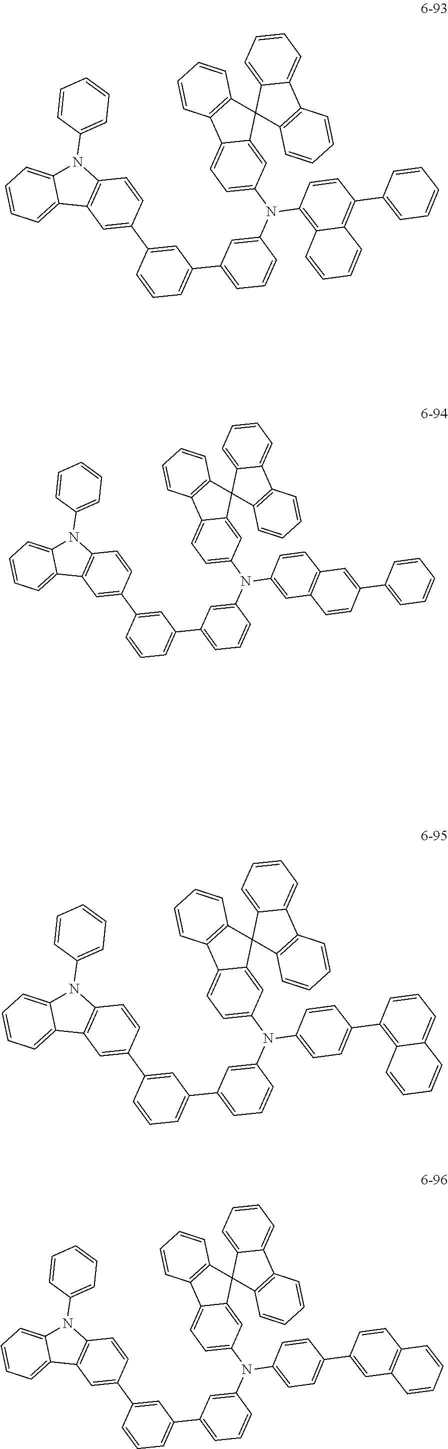

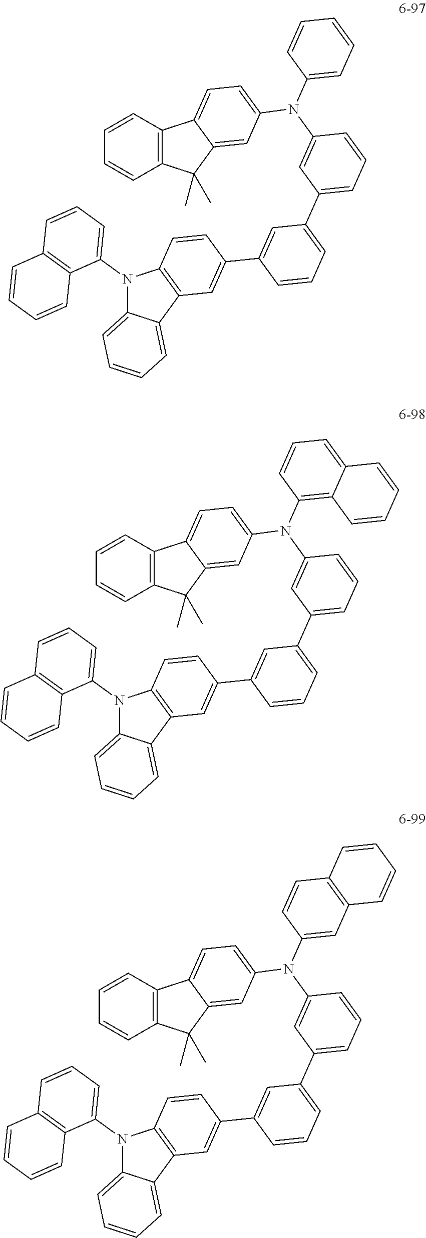 [SMILES: CC1(C)c2ccccc2-c2ccc(N(c3ccccc3)c3cccc(-c4cccc(-c5ccc6c(c5)c5ccccc5n6-c5cccc6ccccc56)c4)c3)cc21 ; CC1(C)c2ccccc2-c2ccc(N(c3cccc(-c4cccc(-c5ccc6c(c5)c5ccccc5n6-c5cccc6ccccc56)c4)c3)c3cccc4ccccc34)cc21 ; CC1(C)c2ccccc2-c2ccc(N(c3cccc(-c4cccc(-c5ccc6c(c5)c5ccccc5n6-c5cccc6ccccc56)c4)c3)c3ccc4ccccc4c3)cc21]

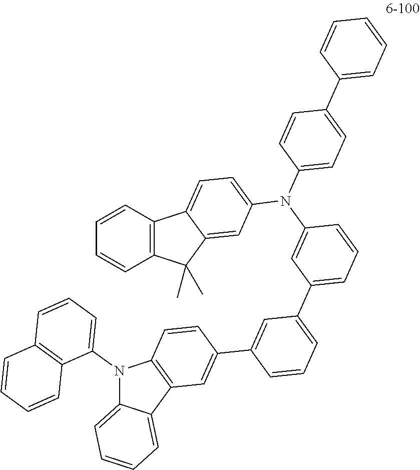 [SMILES: CC1(C)c2ccccc2-c2ccc(N(c3ccc(-c4ccccc4)cc3)c3cccc(-c4cccc(-c5ccc6c(c5)c5ccccc5n6-c5cccc6ccccc56)c4)c3)cc21]

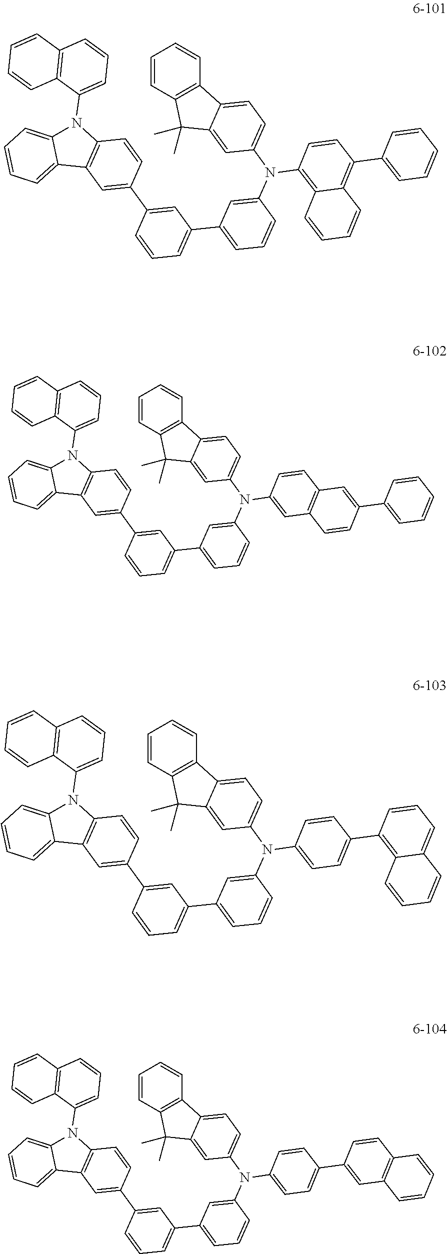 [SMILES: CC1(C)c2ccccc2-c2ccc(N(c3cccc(-c4cccc(-c5ccc6c(c5)c5ccccc5n6-c5cccc6ccccc56)c4)c3)c3ccc(-c4ccccc4)c4ccccc34)cc21 ; CC1(C)c2ccccc2-c2ccc(N(c3cccc(-c4cccc(-c5ccc6c(c5)c5ccccc5n6-c5cccc6ccccc56)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5cccc6ccccc56)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5cccc6ccccc56)c4)c3)cc21]

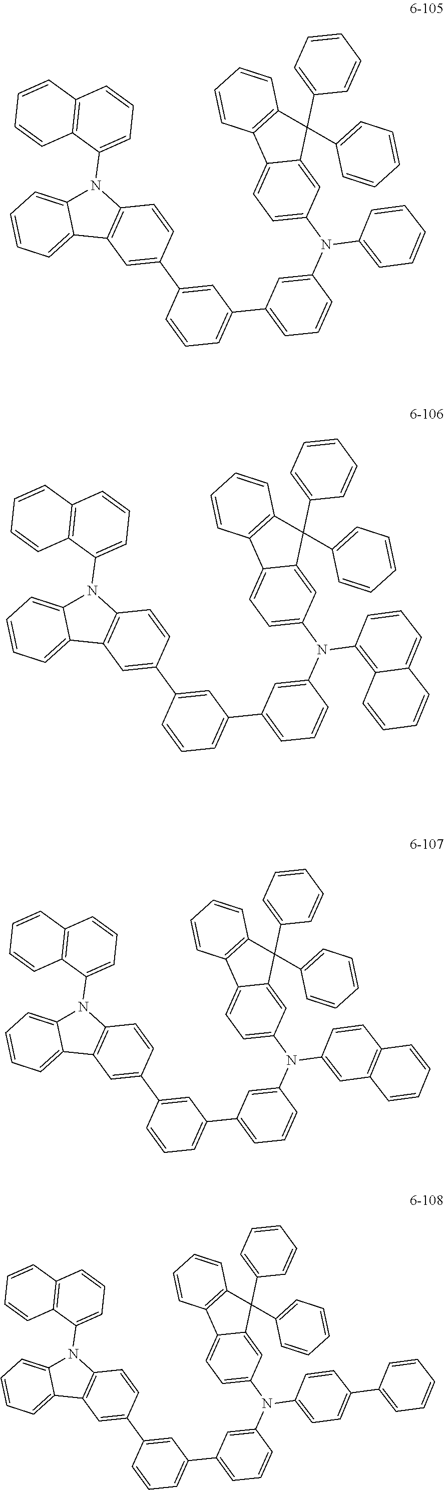 [SMILES: c1ccc(N(c2cccc(-c3cccc(-c4ccc5c(c4)c4ccccc4n5-c4cccc5ccccc45)c3)c2)c2ccc3c(c2)C(c2ccccc2)(c2ccccc2)c2ccccc2-3)cc1 ; c1ccc(C2(c3ccccc3)c3ccccc3-c3ccc(N(c4cccc(-c5cccc(-c6ccc7c(c6)c6ccccc6n7-c6cccc7ccccc67)c5)c4)c4cccc5ccccc45)cc32)cc1 ; c1ccc(C2(c3ccccc3)c3ccccc3-c3ccc(N(c4cccc(-c5cccc(-c6ccc7c(c6)c6ccccc6n7-c6cccc7ccccc67)c5)c4)c4ccc5ccccc5c4)cc32)cc1 ; c1ccc(-c2ccc(N(c3cccc(-c4cccc(-c5ccc6c(c5)c5ccccc5n6-c5cccc6ccccc56)c4)c3)c3ccc4c(c3)C(c3ccccc3)(c3ccccc3)c3ccccc3-4)cc2)cc1]

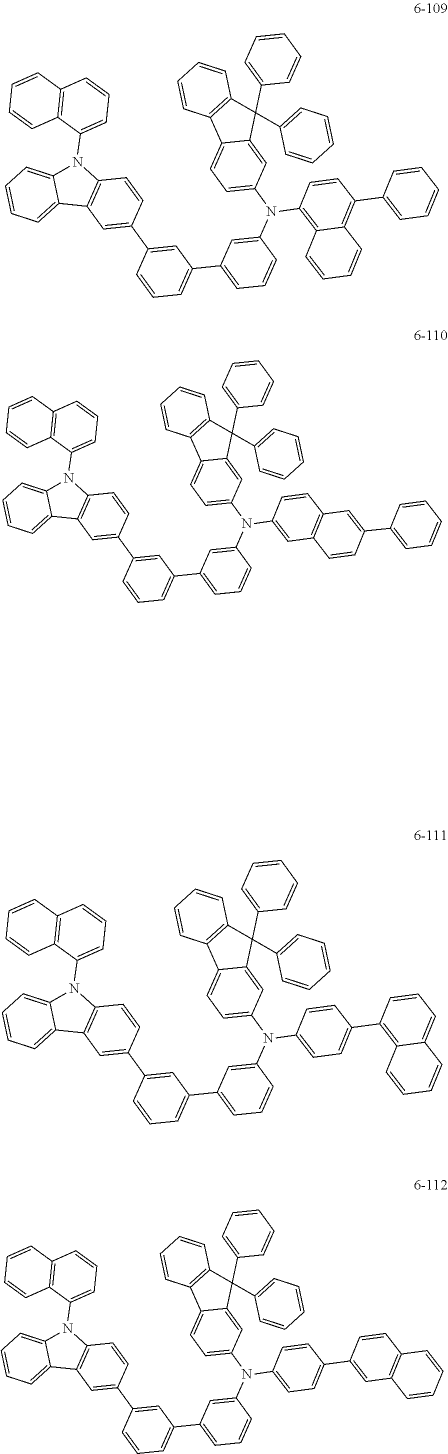

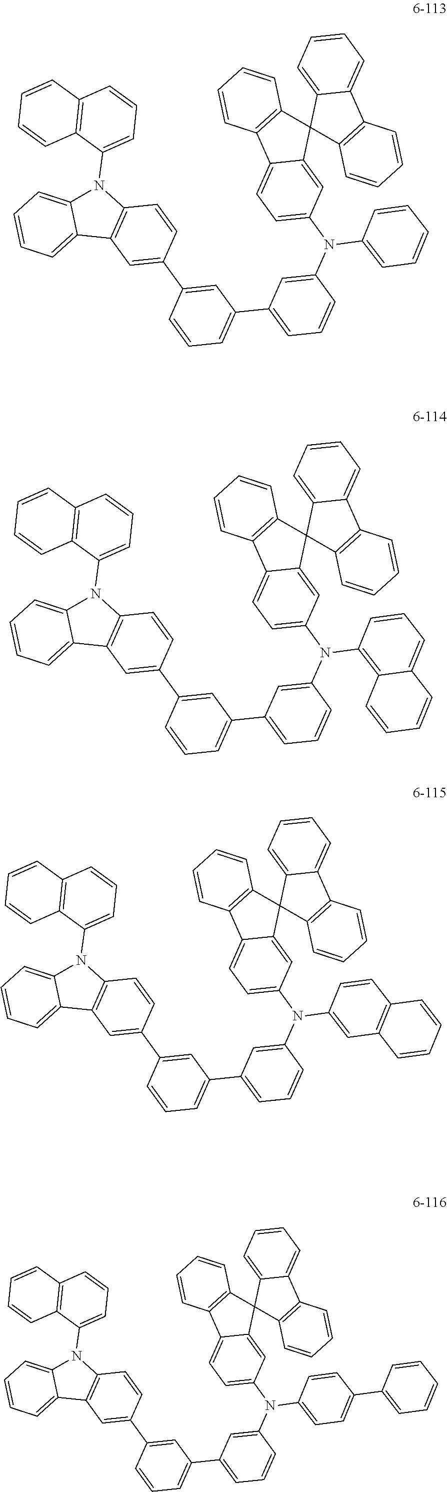 [SMILES: c1ccc(N(c2cccc(-c3cccc(-c4ccc5c(c4)c4ccccc4n5-c4cccc5ccccc45)c3)c2)c2ccc3c(c2)C2(c4ccccc4-c4ccccc42)c2ccccc2-3)cc1 ; c1cc(-c2cccc(N(c3ccc4c(c3)C3(c5ccccc5-c5ccccc53)c3ccccc3-4)c3cccc4ccccc34)c2)cc(-c2ccc3c(c2)c2ccccc2n3-c2cccc3ccccc23)c1 ; c1cc(-c2cccc(N(c3ccc4c(c3)C3(c5ccccc5-c5ccccc53)c3ccccc3-4)c3ccc4ccccc4c3)c2)cc(-c2ccc3c(c2)c2ccccc2n3-c2cccc3ccccc23)c1 ; c1ccc(-c2ccc(N(c3cccc(-c4cccc(-c5ccc6c(c5)c5ccccc5n6-c5cccc6ccccc56)c4)c3)c3ccc4c(c3)C3(c5ccccc5-c5ccccc53)c3ccccc3-4)cc2)cc1]

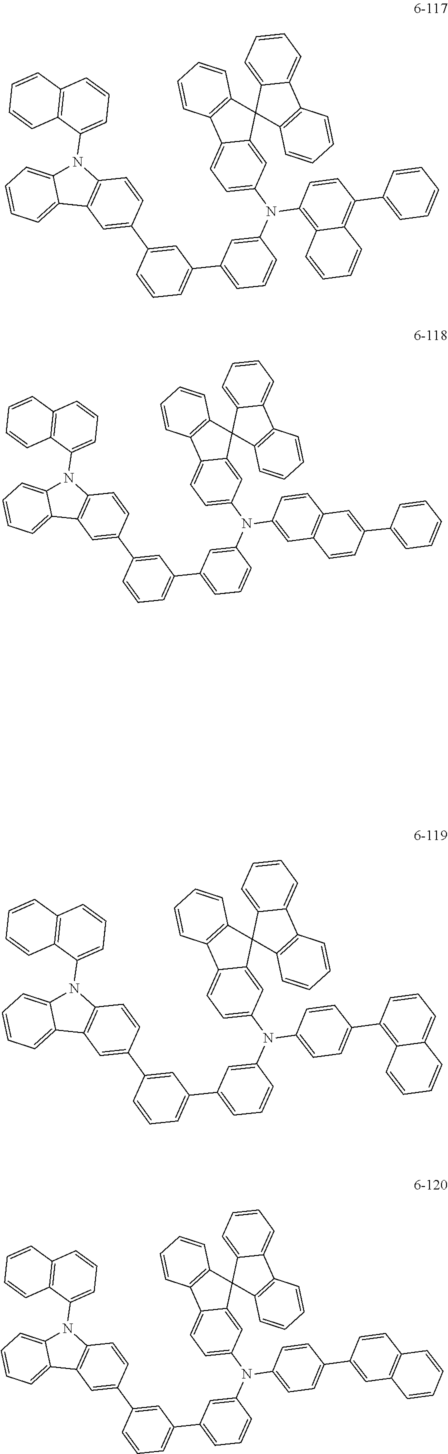

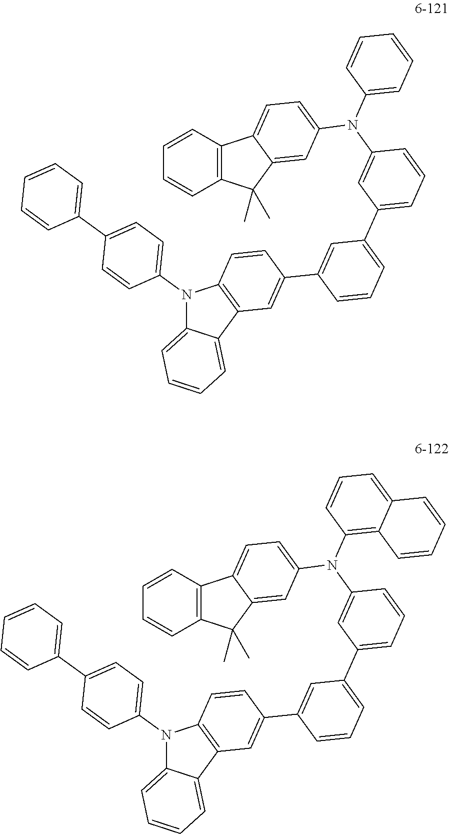 [SMILES: CC1(C)c2ccccc2-c2ccc(N(c3ccccc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3cccc(-c4cccc(-c5ccc6c(c5)c5ccccc5n6-c5ccc(-c6ccccc6)cc5)c4)c3)c3cccc4ccccc34)cc21]

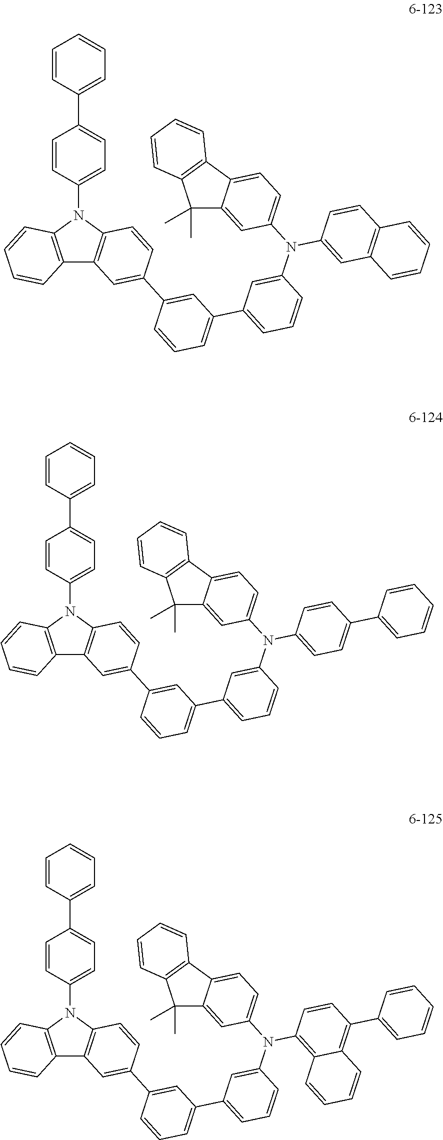 [SMILES: CC1(C)c2ccccc2-c2ccc(N(c3cccc(-c4cccc(-c5ccc6c(c5)c5ccccc5n6-c5ccc(-c6ccccc6)cc5)c4)c3)c3ccc4ccccc4c3)cc21 ; CC1(C)c2ccccc2-c2ccc(N(c3ccc(-c4ccccc4)cc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3cccc(-c4cccc(-c5ccc6c(c5)c5ccccc5n6-c5ccc(-c6ccccc6)cc5)c4)c3)c3ccc(-c4ccccc4)c4ccccc34)cc21]

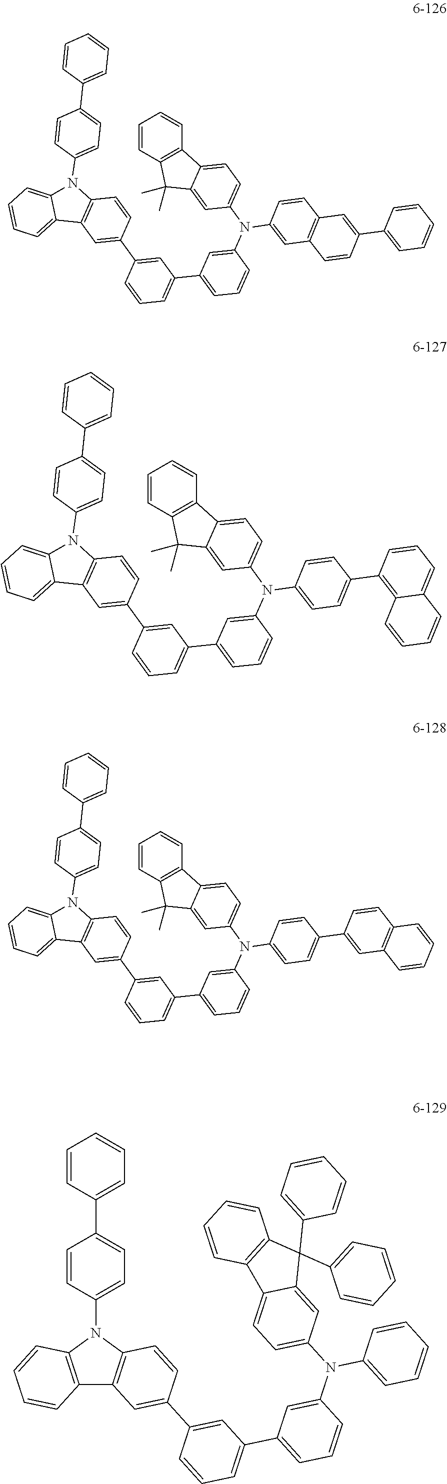 [SMILES: CC1(C)c2ccccc2-c2ccc(N(c3cccc(-c4cccc(-c5ccc6c(c5)c5ccccc5n6-c5ccc(-c6ccccc6)cc5)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5ccc(-c6ccccc6)cc5)c4)c3)cc21 ; c1ccc(-c2ccc(-n3c4ccccc4c4cc(-c5cccc(-c6cccc(N(c7ccccc7)c7ccc8c(c7)C(c7ccccc7)(c7ccccc7)c7ccccc7-8)c6)c5)ccc43)cc2)cc1]

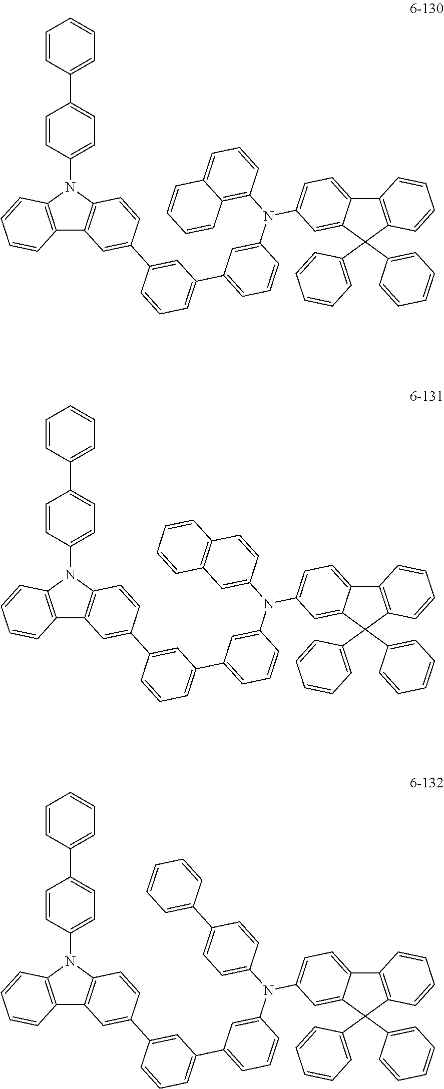 [SMILES: c1ccc(-c2ccc(-n3c4ccccc4c4cc(-c5cccc(-c6cccc(N(c7ccc8c(c7)C(c7ccccc7)(c7ccccc7)c7ccccc7-8)c7cccc8ccccc78)c6)c5)ccc43)cc2)cc1 ; c1ccc(-c2ccc(-n3c4ccccc4c4cc(-c5cccc(-c6cccc(N(c7ccc8c(c7)C(c7ccccc7)(c7ccccc7)c7ccccc7-8)c7ccc8ccccc8c7)c6)c5)ccc43)cc2)cc1 ; c1ccc(-c2ccc(N(c3cccc(-c4cccc(-c5ccc6c(c5)c5ccccc5n6-c5ccc(-c6ccccc6)cc5)c4)c3)c3ccc4c(c3)C(c3ccccc3)(c3ccccc3)c3ccccc3-4)cc2)cc1]

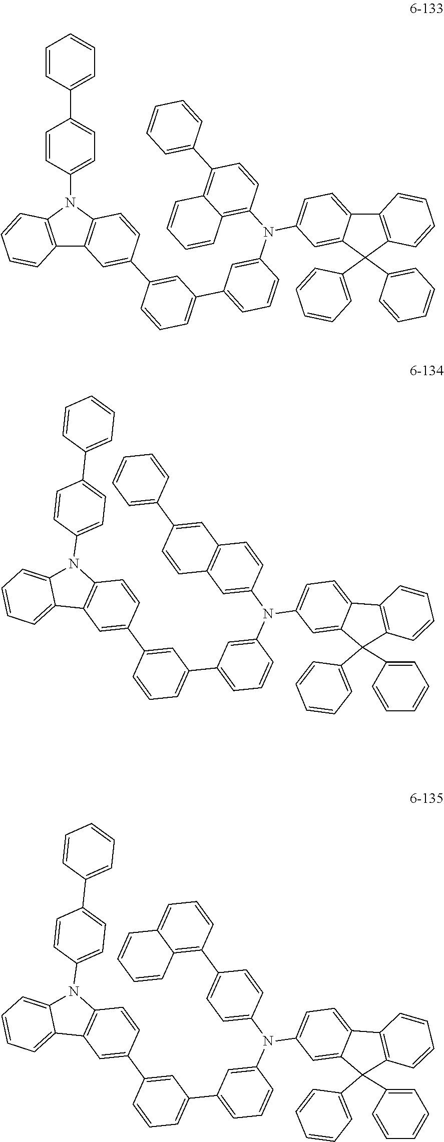 [SMILES: c1ccc(-c2ccc(-n3c4ccccc4c4cc(-c5cccc(-c6cccc(N(c7ccc8c(c7)C(c7ccccc7)(c7ccccc7)c7ccccc7-8)c7ccc(-c8ccccc8)c8ccccc78)c6)c5)ccc43)cc2)cc1 ; c1ccc(-c2ccc(-n3c4ccccc4c4cc(-c5cccc(-c6cccc(N(c7ccc8c(c7)C(c7ccccc7)(c7ccccc7)c7ccccc7-8)c7ccc8cc(-c9ccccc9)ccc8c7)c6)c5)ccc43)cc2)cc1 ; c1ccc(-c2ccc(-n3c4ccccc4c4cc(-c5cccc(-c6cccc(N(c7ccc(-c8cccc9ccccc89)cc7)c7ccc8c(c7)C(c7ccccc7)(c7ccccc7)c7ccccc7-8)c6)c5)ccc43)cc2)cc1]

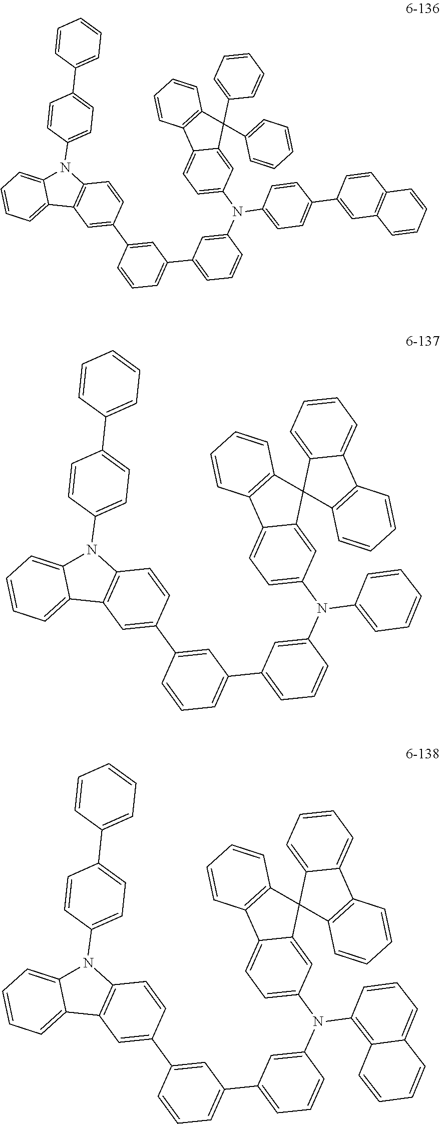 [SMILES: c1ccc(-c2ccc(-n3c4ccccc4c4cc(-c5cccc(-c6cccc(N(c7ccc(-c8ccc9ccccc9c8)cc7)c7ccc8c(c7)C(c7ccccc7)(c7ccccc7)c7ccccc7-8)c6)c5)ccc43)cc2)cc1 ; c1ccc(-c2ccc(-n3c4ccccc4c4cc(-c5cccc(-c6cccc(N(c7ccccc7)c7ccc8c(c7)C7(c9ccccc9-c9ccccc97)c7ccccc7-8)c6)c5)ccc43)cc2)cc1 ; c1ccc(-c2ccc(-n3c4ccccc4c4cc(-c5cccc(-c6cccc(N(c7ccc8c(c7)C7(c9ccccc9-c9ccccc97)c7ccccc7-8)c7cccc8ccccc78)c6)c5)ccc43)cc2)cc1]

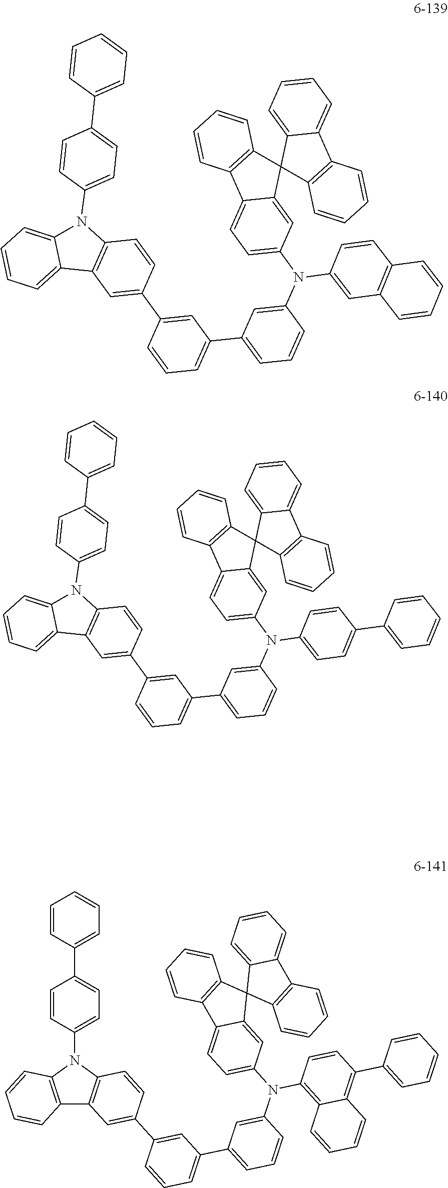 [SMILES: c1ccc(-c2ccc(-n3c4ccccc4c4cc(-c5cccc(-c6cccc(N(c7ccc8c(c7)C7(c9ccccc9-c9ccccc97)c7ccccc7-8)c7ccc8ccccc8c7)c6)c5)ccc43)cc2)cc1 ; c1ccc(-c2ccc(N(c3cccc(-c4cccc(-c5ccc6c(c5)c5ccccc5n6-c5ccc(-c6ccccc6)cc5)c4)c3)c3ccc4c(c3)C3(c5ccccc5-c5ccccc53)c3ccccc3-4)cc2)cc1 ; c1ccc(-c2ccc(-n3c4ccccc4c4cc(-c5cccc(-c6cccc(N(c7ccc8c(c7)C7(c9ccccc9-c9ccccc97)c7ccccc7-8)c7ccc(-c8ccccc8)c8ccccc78)c6)c5)ccc43)cc2)cc1]

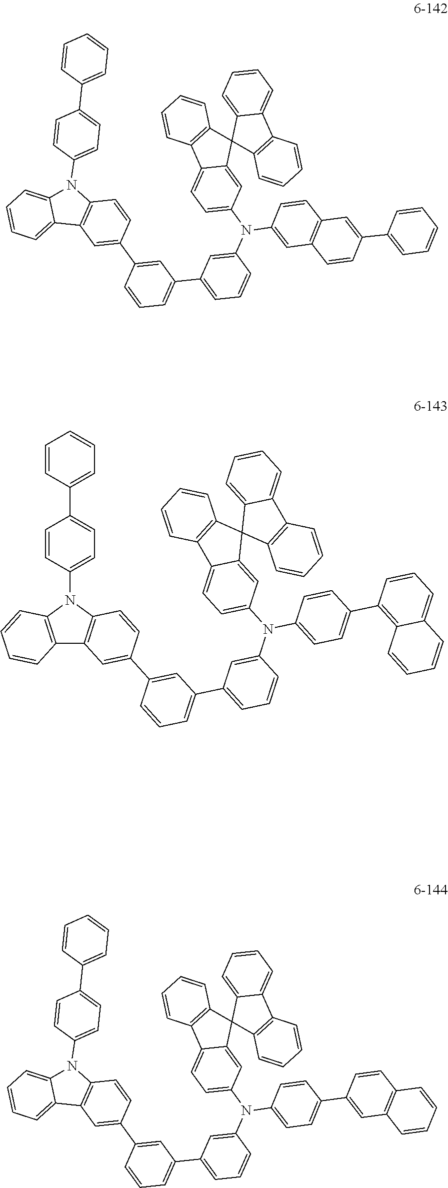 [SMILES: c1ccc(-c2ccc(-n3c4ccccc4c4cc(-c5cccc(-c6cccc(N(c7ccc8c(c7)C7(c9ccccc9-c9ccccc97)c7ccccc7-8)c7ccc8cc(-c9ccccc9)ccc8c7)c6)c5)ccc43)cc2)cc1 ; c1ccc(-c2ccc(-n3c4ccccc4c4cc(-c5cccc(-c6cccc(N(c7ccc(-c8cccc9ccccc89)cc7)c7ccc8c(c7)C7(c9ccccc9-c9ccccc97)c7ccccc7-8)c6)c5)ccc43)cc2)cc1 ; c1ccc(-c2ccc(-n3c4ccccc4c4cc(-c5cccc(-c6cccc(N(c7ccc(-c8ccc9ccccc9c8)cc7)c7ccc8c(c7)C7(c9ccccc9-c9ccccc97)c7ccccc7-8)c6)c5)ccc43)cc2)cc1]

The HTL or buffer layer including a hole-transporting material may further include any suitable hole-transporting material commonly used in OLEDs. Non-limiting examples of the hole-transporting material include a carbazole derivative such as N-phenylcarbazole and polyvinylcarbazole, N,N′-bis(3-methylphenyl)-N,N′-diphenyl-[1,1-biphenyl]-4,4′-diamine (TPD), 4,4′,4″-tris(N-carbazole)triphenylamine (TCTA), and N,N′-di(1-naphthyl)-N,N′-diphenylbenzidine (NPB.

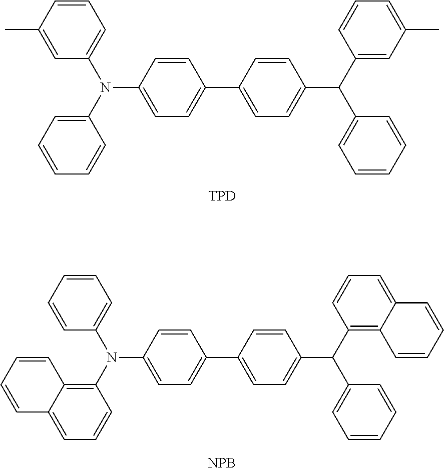

The thickness of the HTL may be about 50 Å to about 2,000 Å, for example, about 100 Å to about 1,500 Å. When the thickness of the HTL is within either of the foregoing ranges, the HTL may have satisfactory hole transport ability without a substantial increase in a driving voltage.

The H-functional layer having both hole injection and hole transport capabilities may include one or more of the materials described above in connection with the HIL and the HTL. The thickness of the H-functional layer may be about 100 Å to about 10,000 Å, for example, about 100 Å to about 1,000 Å. When the thickness of the H-functional layer is within either of the foregoing ranges, the H-functional layer may have satisfactory hole injection and transport abilities without a substantial increase in a driving voltage.

At least one of the HIL, the HTL, and the H-functional layer may include at least one compound represented by one of Formula 300 and Formula 301.

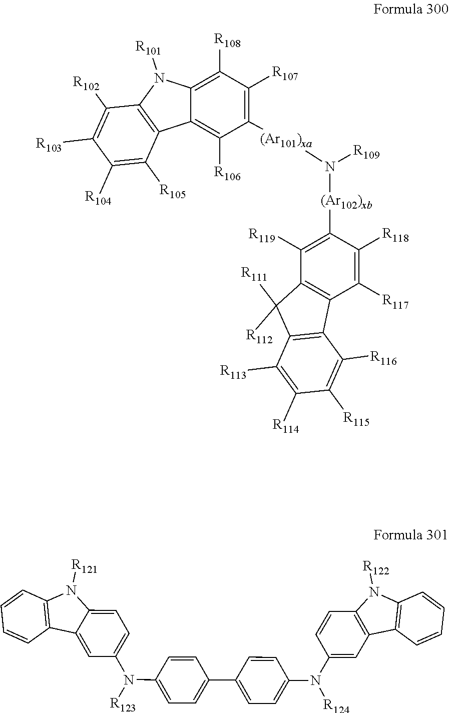

In Formula 300, Ar₁₀₁ and Ar₁₀₂ may each independently be a substituted or unsubstituted C₆-C₆₀ arylene group. For example, Ar₁₀₁ and Ar₁₀₂ may each independently be: a phenylene group, a pentalenylene group, an indenylene group, a naphthylene group, an azulenylene group, a heptalenylene group, a substituted or unsubstituted acenaphthylene group, a fluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, or a pentacenylene group; or a phenylene group, a pentalenylene group, an indenylene group, a naphthylene group, an azulenylene group, a heptalenylene group, a substituted or unsubstituted acenaphthylene group, a fluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, or a pentacenylene group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In Formula 300, xa and xb may each independently be an integer of 0 to 5, or may be 0, 1, or 2. For example, xa may be 1 and xb may be 0, but xa and xb are not limited thereto. In Formula 300 and 301, R₁₀₁ to R₁₀₈, R₁₁₁ to R₁₁₉, and R₁₂₁ to R₁₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group.

In some embodiments, R₅₁ to R₅₈, R₆₁ to R₆₉, R₇₁, and R₇₂ may each independently be a hydrogen atom; a deuterium atom; a halogen atom; a hydroxyl group; a cyano group; a nitro group; an amino group; an amidino group; a hydrazine group; a hydrazone group; a carboxyl group or a salt thereof; a sulfonic acid group or a salt thereof; a phosphoric acid group or a salt thereof; a C₁-C₁₀ alkyl group (e.g., a methyl group, an ethyl group, a propyl group, a butyl group, a pentyl group, and a hexyl group); a C₁-C₁₀ alkoxy group (e.g., a methoxy group, an ethoxy group, a propoxy group, a butoxy group, and a pentoxy); a C₁-C₁₀ alkyl group or a C₁-C₁₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof; a phenyl group; a naphthyl group; an anthryl group; a fluorenyl group; a pyrenyl group; a phenyl group, a naphthyl group, an anthryl group, a fluorenyl group, or a pyrenyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₁₀ alkyl group, or a C₁-C₁₀ alkoxy group. However, R₅₁ to R₅₈, R₆₁ to R₆₉, R₇₁, and R₇₂ are not limited thereto.

In Formula 300, R₁₀₉ may be a phenyl group; a naphthyl group; an anthryl group; a biphenyl group; a pyridinyl group; or a phenyl group, a naphthyl group, an anthryl group, a biphenyl group, or a pyridinyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

According to another embodiment of the present invention, the compound represented by Formula 300 may be represented by Formula 300A, but Formula 300 is not limited to thereto.

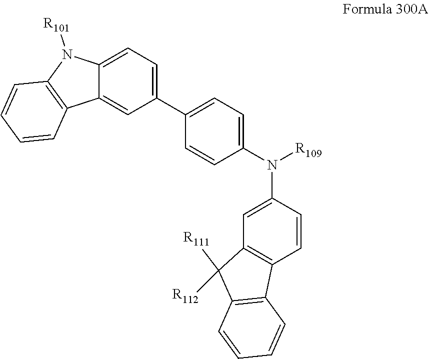

In Formula 300A above, R₁₀₁, R₁₁₁, R₁₁₂, and R₁₀₉ may be defined as described above with respect to Formula 300.

In some embodiments, at least one of the HIL, the HTL, and the H-functional layer may include at least one of Compounds 301 to 320, but these layers are not limited thereto.

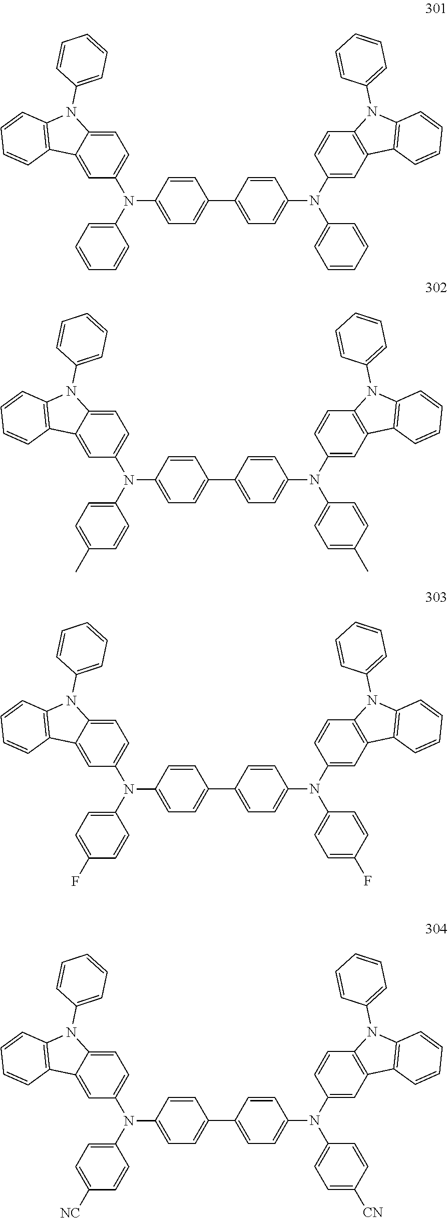 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

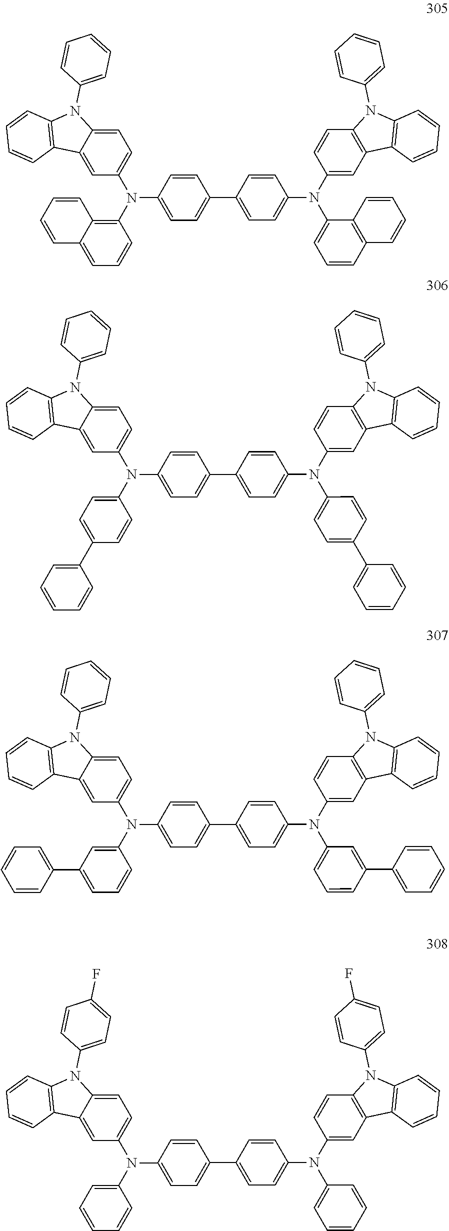 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

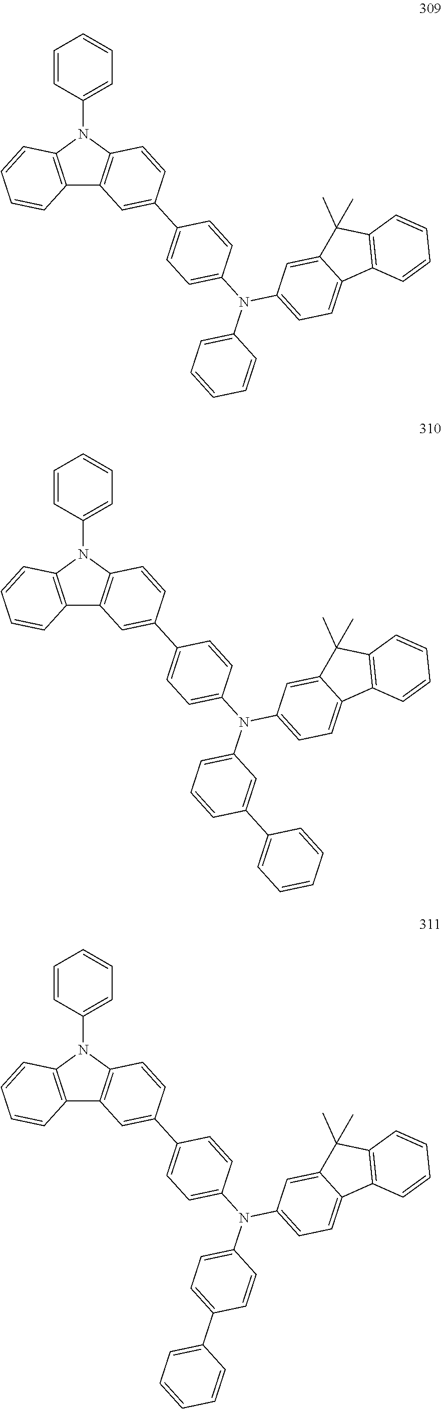 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

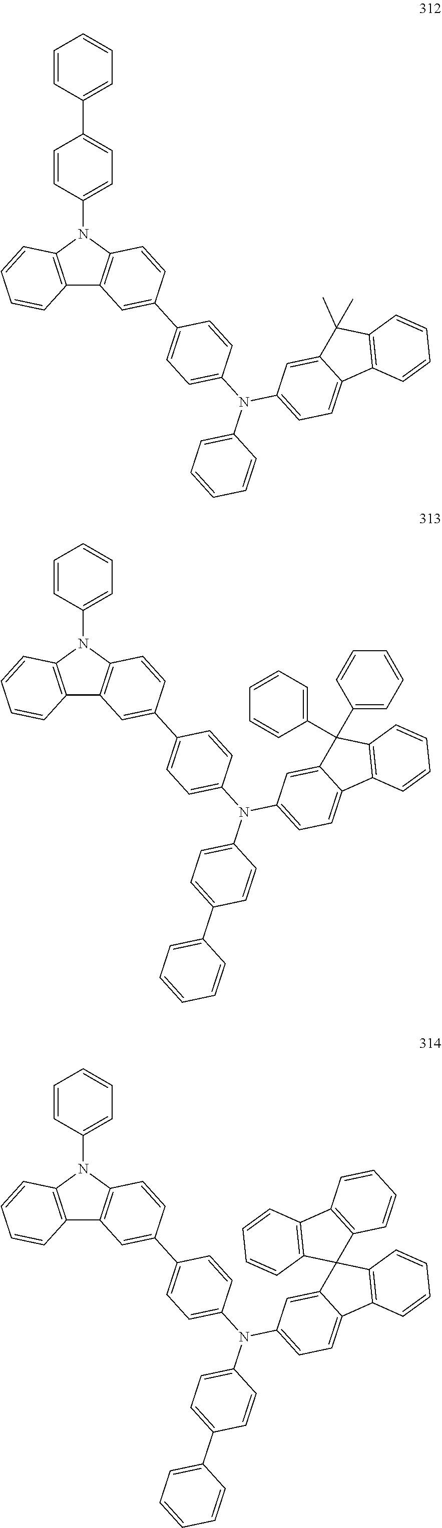 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

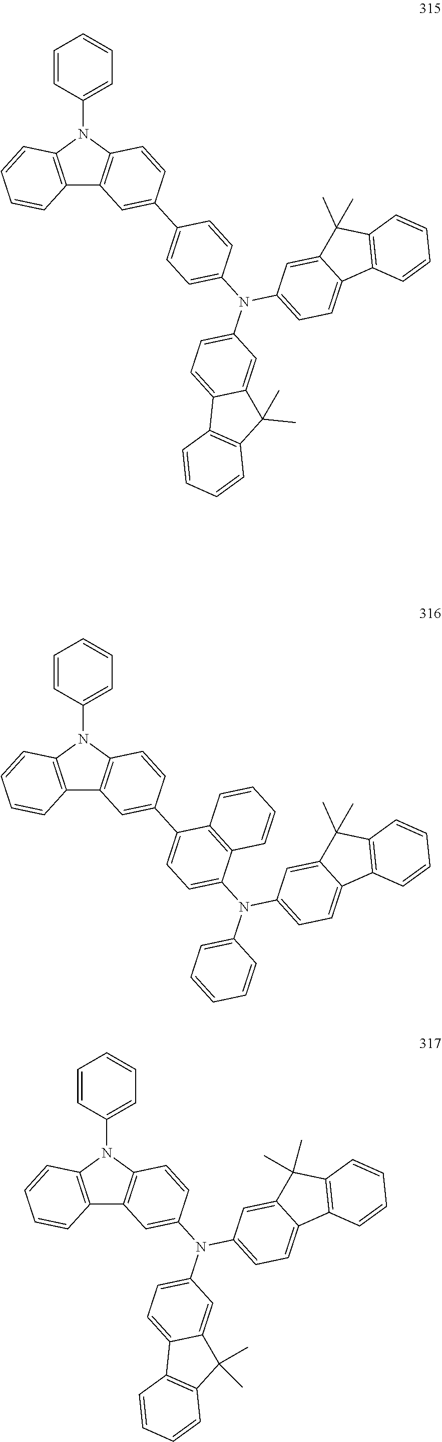 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

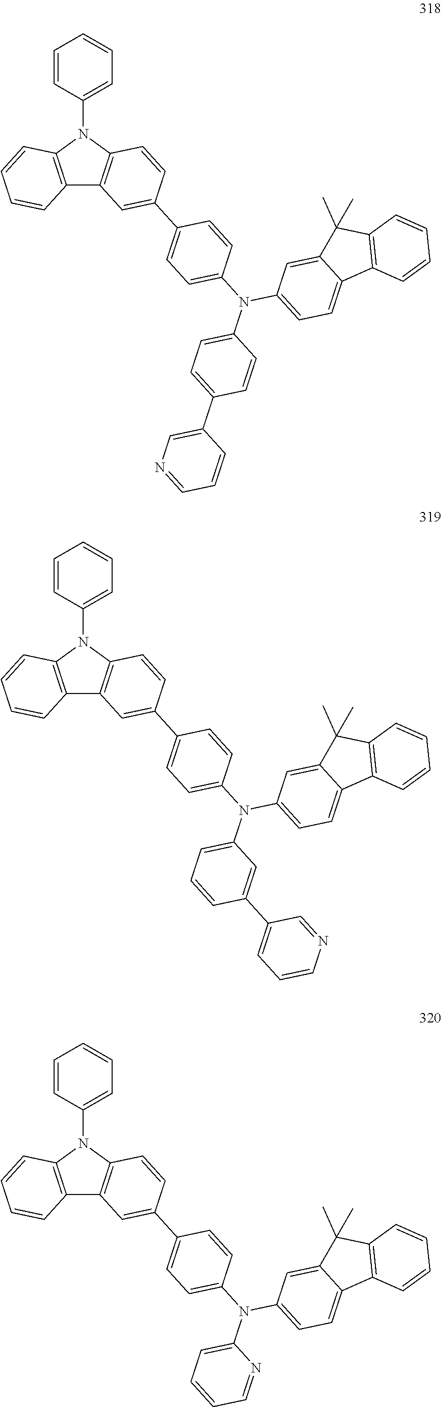 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

To improve conductivity, at least one of the HIL, the HTL, and the H-functional layer may further include a charge-generating material in addition to the material used to form the HIL, the HTL, and/or the H-functional layer as described above.

The charge-generating material may be, for example, a p-dopant. The p-dopant may be one of a quinone derivative, a metal oxide, or a cyano group-containing compound, but the charge-generating material is not limited thereto. Non-limiting examples of the p-dopant include a quinone derivative such as tetracyanoquinonedimethane (TCNQ) and 2,3,5,6-tetrafluoro-tetracyano-1,4-benzoquinonedimethane (F4-TCNQ); a metal oxide such as a tungsten oxide and a molybdenum oxide; and a cyano group-containing compound such as Compound 200.

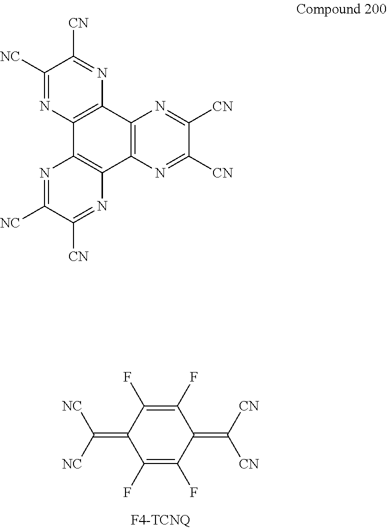 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the HIL, the HTL, or the H-functional layer further includes the charge-generating material, the charge-generating material may be homogeneously dispersed or non-homogeneously distributed in the layer.

A buffer layer may be positioned between the EML and at least one of the HIL, the HTL, and the H-functional layer. In some embodiments, for example, a hole-transporting region includes a buffer layer and a hole transport layer between the emission layer and the first electrode. The buffer layer in the hole-transporting region may be disposed between the hole transport layer and the emission layer. The buffer layer may compensate for an optical resonance distance of light according to a wavelength of the light emitted from the EML, and thus may increase efficiency. The buffer layer may include any suitable material commonly used to form an HIL or an HTL. In some embodiments, for example, the buffer layer in a hole-transporting region that also includes an HTL, may include a hole transporting material. Alternatively, the buffer layer may include the same (or similar) material as at least one of the materials included in the HIL, the HTL, and/or the H-functional layer underneath the buffer layer.

Then, the EML may be formed on the HTL, the H-functional layer, or the buffer layer by various methods, such as vacuum deposition, spin coating, casting, and LB deposition. When the EML is formed by vacuum deposition or spin coating, vacuum deposition conditions or spin coating conditions may be similar to those described above for the formation of the HIL, though the conditions may vary depending on the compound used to form the EML.

The EML may include at least one light-emitting material represented by one of Formulas 1 and 2.

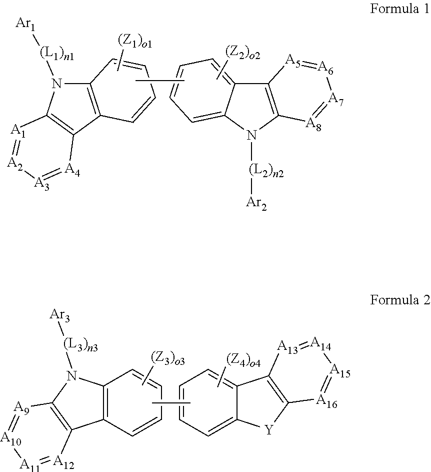

In Formula 1 or Formula 2, A₁ may be CR₁ or N; A₂ may be CR₂ or N; A₃ may be CR₃ or N; A₄ may be CR₄ or N; A₅ may be CR₅ or N; As may be CR₆ or N; A₇ may be CR₇ or N; As may be CR₈ or N; A₉ may be CR₉ or N; A₁₀ may be CR₁₀ or N; A₁ may be CR₁₁ or N; A₁₂ may be CR₁₂ or N; A₁₃ may be CR₁₃ or N; A₁₄ may be CR₁₄ or N; A₁₅ may be CR₁₅ or N; and A₁₆ may be CR₁₆ or N.

For example, in Formula 1 and Formula 2, Y may be O, S, or C(R₃₁)(R₃₂). In some embodiments, in Formula 1 and Formula 2, L₁ and L₃ may each independently be a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₂-C₁₀ heterocycloalkylene group, a substituted or unsubstituted C₂-C₁₀ heterocycloalkenylene group, and a substituted or unsubstituted C₁-C₆₀ heteroarylene group.

In some embodiments, in Formula 1 or Formula 2, L₁ to L₃ may each independently be: i) a C₃-C₁₀ cycloalkylene group, a C₃-C₁₀ cycloalkenylene group, a C₆-C₆₀ arylene group, a C₂-C₁₀ heterocycloalkylene group, a C₂-C₁₀ heterocycloalkenylene group, or a C₁-C₆₀ heteroarylene group; or ii) a C₃-C₁₀ cycloalkylene group, a C₃-C₁₀ cycloalkenylene group, a C₆-C₆₀ arylene group, a C₂-C₁₀ heterocycloalkylene group, a C₂-C₁₀ heterocycloalkenylene group, or a C₁-C₆₀ heteroarylene group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkylene group, a C₃-C₁ cycloalkenylene group, a C₆-C₆₀ arylene group, a C₂-C₁₀ heterocycloalkylene group, a C₂-C₁₀ heterocycloalkenylene group, or a C₁-C₆₀ heteroarylene group substituted with at least one of a C₆-C₆₀ aryl group and a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In some other embodiments, in Formula 1 or Formula 2, L₁ to L₃ may each independently be: i) a C₆-C₆₀ arylene group or a C₁-C₆₀ heteroarylene group; or ii) a C₆-C₆₀ arylene group or a C₁-C₆₀ heteroarylene group substituted with at least one of a C₆-C₆₀ aryl group or a C₁-C₆₀ heteroaryl group; or iii) a C₆-C₆₀ arylene group or a C₁-C₆₀ heteroarylene group substituted with at least one of a C₆-C₆₀ aryl group or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₁-C₆₀ alkoxy group, a C₆-C₆₀ aryl group, or a C₁-C₆₀ heteroaryl group. However, L₁ to L₃ are not limited thereto.

In some other embodiments, in Formula 1 or Formula 2, L₁ to L₃ may each independently be: i) a phenylene group, a fluorenylene group, a pyridylene group, a pyrimidylene group, a triazinylene group, or a quinazolinylene group; or ii) a phenylene group, a fluorenylene group, a pyridylene group, a pyrimidylene group, a triazinylene group, or a quinazolinylene group substituted with at least one of a phenyl group, a naphthyl group, or a pyridyl group; or iii) a phenylene group, a fluorenylene group, a pyridylene group, a pyrimidylene group, a triazinylene group, or a quinazolinylene group substituted with at least one of a deuterium atom, a methyl group, an ethyl group, an n-octyl group, a methoxy group, an ethoxy group, a phenyl group, a naphthyl group, a pyridyl group, or a carbazole group. However, L₁ to L₃ are not limited thereto.

In Formula 1 or Formula 2, n1 indicates the number of Lis, and is an integer from 0 to 3. When n1 is 2 or greater, the Lis may be identical to or different from each other. In Formula 1 or Formula 2, n2 indicates the number of L₂s, and is an integer from 0 to 3. When n2 is 2 or greater, the L₂s may be identical to or different from each other. In Formula 1 or Formula 2, n3 indicates the number of L₃s, and is an integer from 0 to 3. When n3 is 2 or greater, the L₃s may be identical to or different from each other.

In Formula 1 or Formula 2, Ar₁ to Ar₃ may each independently be: i) a C₃-C₁ cycloalkyl group, a C₃-C₁₀ heterocycloalkyl group, a C₃-C₁ cycloalkenyl group, a C₃-C₁₀ heterocycloalkenyl group, a C₆-C₆₀ aryl group, a C₁-C₆₀ heteroaryl group, or —Si(Q₁)(Q₂)(Q₃) (where Q₁ to Q₃ are each independently a substituted or unsubstituted C₁-Cia alkyl group or a substituted or unsubstituted C₆-C₆₀ aryl group); or ii) a C₃-C₁₀ cycloalkyl group, a C₃-C₁₀ heterocycloalkyl group, a C₃-C₁ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁ cycloalkyl group, a C₃-C₁₀ heterocycloalkyl group, a C₃-C₁a cycloalkenyl group, a C₃-C₁a heterocycloalkenyl group, a C₆-C₆₀ aryl group, a C₆-C₆₀ aryloxy group, a C₆-C₆₀ arylthio group, a C₁-C₆₀ heteroaryl group, or —Si(Q₁)(Q₂)(Q₃) (where Q₁ to Q₃ are each independently a substituted or unsubstituted C₁-C₁₀ alkyl group or a substituted or unsubstituted C₆-C₃o aryl group).

In some embodiments, in Formula 1 or Formula 2, Ar₁ to Ar₃ may each independently be: i) a C₆-C₆₀ aryl group, a C₁-C₆₀ heteroaryl group, or —Si(Q₁)(Q₂)(Q₃) (where Q₁ to Q₃ are each independently a C₁-C₁₀ alkyl group or a C₆-C₃o aryl group); or ii) a C₆-C₆₀ aryl group or a C₁-C₆₀ heteroaryl group substituted with at least one of a deuterium atom, a halogen atom, a C₁-C₆₀ alkyl group, a C₆-C₆₀ aryl group, a C₁-C₆₀ heteroaryl group, or —Si(Q₁)(Q₂)(Q₃) (where Q₁ to Q₃ are each independently a C₁-C₁₀ alkyl group or a C₆-C₃o aryl group). However, Ar₁ to Ar₃ are not limited thereto.

In some other embodiments, in Formula 1 or Formula 2, Ar₁ to Ar₃ may each independently be: i) a phenyl group, a pyridyl group, a pyrimidyl group, a triazinyl group, or —Si(Q₁)(Q₂)(Q₃) (where Q₁ to Q₃ are each independently a methyl group, an ethyl group, an n-propyl group, an i-propyl group, or a phenyl group); or ii) a phenyl group, a pyridyl group, a pyrimidyl group, or a triazinyl group substituted with at least one of a deuterium atom, a halogen atom, a phenyl group, a pyridyl group, or —Si(Q₁)(Q₂)(Q₃) (where, Q₁ to Q₃ are each independently a methyl group, an ethyl group, an n-propyl group, an i-propyl group, or a phenyl group). However, Ar₁ to Ar₃ are not limited thereto.

In some other embodiments, in Formula 1 or Formula 2, Ar₁ to Ar₃ may each independently be a moiety represented by one of Formulas H1 to H5, but Ar₁ to Ar₃ are not limited thereto.

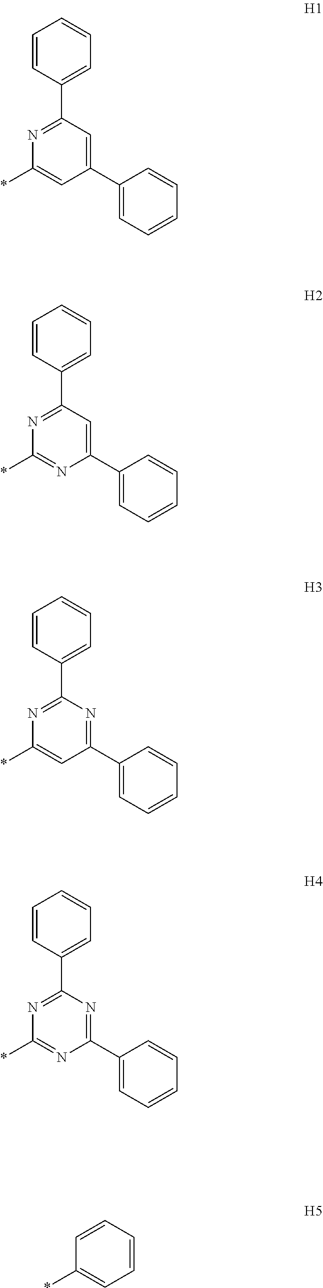 [SMILES: *c1cc(-c2ccccc2)cc(-c2ccccc2)n1 ; *c1nc(-c2ccccc2)cc(-c2ccccc2)n1 ; *c1cc(-c2ccccc2)nc(-c2ccccc2)n1 ; *c1nc(-c2ccccc2)nc(-c2ccccc2)n1 ; *c1ccccc1]

In Formulas H1 to H5 above, * represents a binding site to one of L₁ to L₃ in Formula 1 or Formula 2, or to N in Formula 1 or Formula 2.

In Formula 1 or Formula 2, Z₁, Z₂, R₃₁, and R₃₂ may each independently be: i) a hydrogen atom, a deuterium atom, a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, and a phosphoric acid group or a salt thereof, a C₃-C₁ cycloalkyl group, a C₃-C₁ heterocycloalkyl group, a C₃-C₁ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁a cycloalkyl group, a C₃-C₁₀ heterocycloalkyl group, a C₃-C₁ cycloalkenyl group, a C₃-C₁₀ heterocycloalkenyl group, a C₆-C₆₀ aryl group, or a C₁-C₆₀ heteroaryl group; or iv) a C₃-C₁ cycloalkyl group, a C₃-C₁₀ heterocycloalkyl group, a C₃-C₁ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁ cycloalkyl group, a C₃-C₁₀ heterocycloalkyl group, a C₃-C₁ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In some embodiments, in Formula 1 or Formula 2, Z₁, Z₂, R₃₁, and R₃₂ may each independently be: i) a C₁-C₆₀ alkyl group or a C₁-C₆₀ alkoxy group; or ii) a C₁-C₆₀ alkyl group or a C₁-C₆₀ alkoxy group substituted with at least one of a deuterium atom, a halogen atom, a C₆-C₆₀ aryl group, or a C₁-C₆₀ heteroaryl group; or iii) a C₆-C₆₀ aryl group or a C₁-C₆₀ heteroaryl group; or iv) a C₆-C₆₀ aryl group or a C₁-C₆₀ heteroaryl group substituted with at least one of a deuterium atom, a halogen atom, a C₁-C₆₀ alkyl group, a C₆-C₆₀ aryl group, or a C₁-C₆₀ heteroaryl group. However, Z₁, Z₂, R₃₁, and R₃₂ are not limited thereto.

In some other embodiments, in Formulas 1 to 3, Z₁, Z₂, R₃₁, and R₃₂ may each independently be: i) a methyl group, an ethyl group, an n-propyl group, an iso-propyl group, an n-butyl group, an iso-butyl group, a sec-butyl group, or a tert-butyl group; or ii) a phenyl group, a naphthyl group, or a pyridyl group; or iv) a phenyl group, a naphthyl group, or a pyridyl group substituted with at least one of a methyl group, an ethyl group, an n-propyl group, an iso-propyl group, an n-butyl group, an iso-butyl group, a sec-butyl group, or a tert-butyl group. However, Z₁, Z₂, R₃₁, and R₃₂ are not limited thereto.

In Formulas 1 to 3, R₁ to R₁₆ may each independently be a hydrogen atom, a deuterium atom, a halogen atom, a C₁-C₆₀ alkyl group, a C₆-C₆₀ aryl group, a C₁-C₆₀ heteroaryl group, or —N(Q₁)(Q₂)(Q₃) (where Q₁ to Q₃ are each independently a C₁-C₆₀ alkyl group, a C₆-C₆₀ aryl group, or a C₁-C₆₀ heteroaryl group). 2 or more of R₁ to R₁₆ may optionally combine to form a C₆-C₂₀ saturated ring or a C₆-C₂₀ unsaturated ring.

In some embodiments, in Formula 1 or Formula 2, R₁ to R₁₆ may be a hydrogen atom, and 2 or more of R₁ to R₁₆ may optionally combine to form a C₆-C₂₀ saturated ring or a C₆-C₂₀ unsaturated ring, but R₁ to R₁₆ are not limited thereto.

In Formula 1 or Formula 2, o1 indicates the number of Z₁s, and is an integer of 0 to 3. When o1 is 2 or greater, the Z₁s may be identical to or different from each other. In Formula 1 or Formula 2, o2 indicates the number of Z₂s, and is an integer of 0 to 3. When o2 is 2 or greater, the Z₂s may be identical to or different from each other. In Formula 1 or Formula 2, o3 indicates the number of Z₃s, and is an integer of 0 to 3. When 03 is 2 or greater, the Z₃s may be identical to or different from each other. In Formula 1 or Formula 2, o4 indicates the number of Z₄s, and is an integer of 0 to 3. When o4 is 2 or greater, the Z₄s may be identical to or different from each other.

According to another embodiment of the present invention, Formulas 1 and 2 may be represented by one of Formulas 1-1 to 1-24, but Formulas 1 and 2 are not limited thereto.

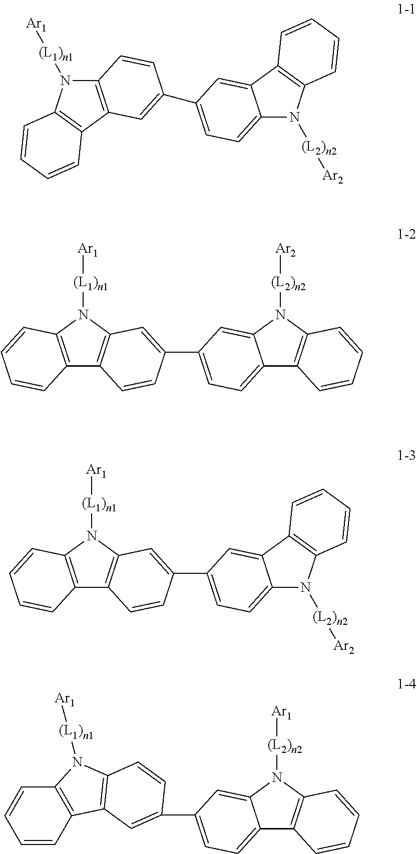

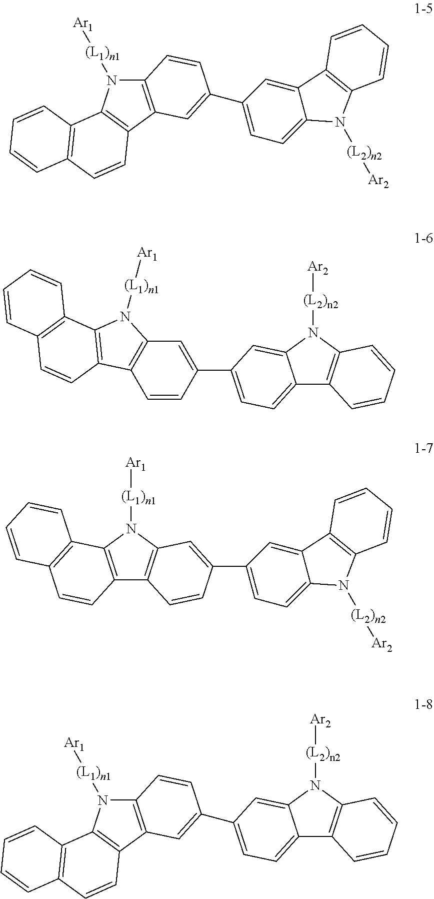

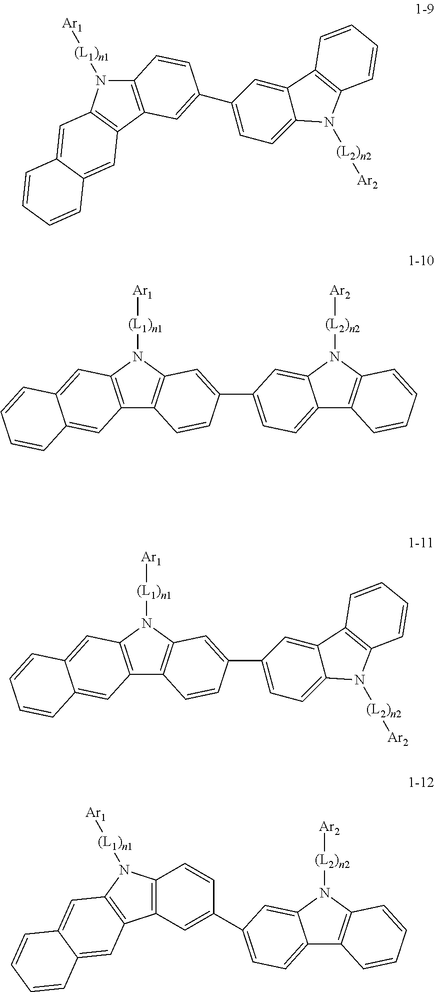

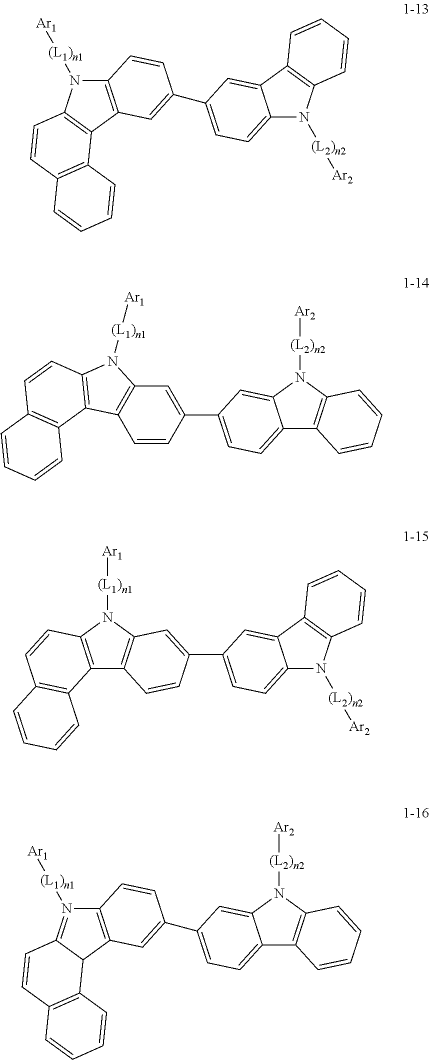

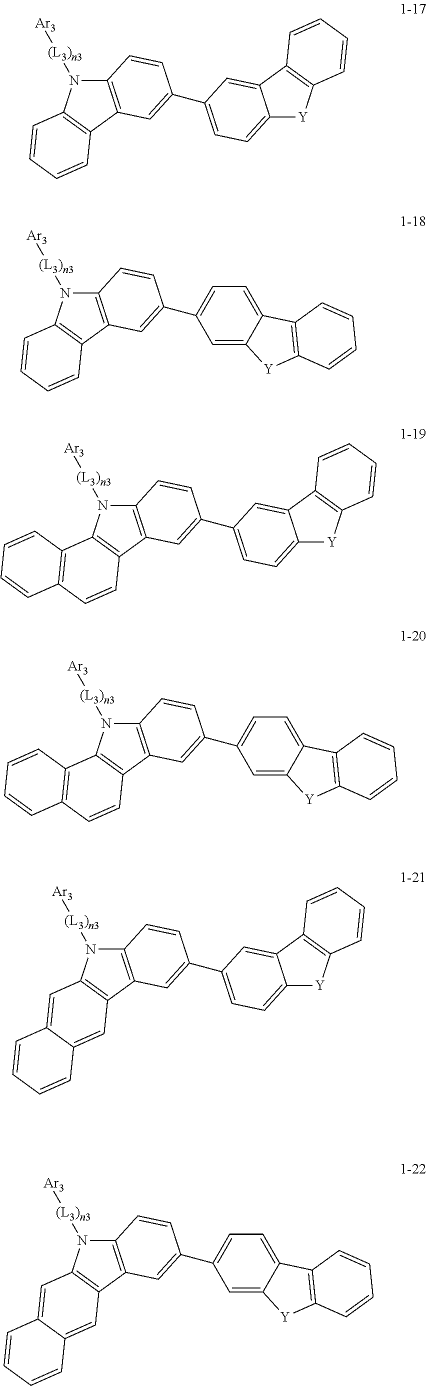

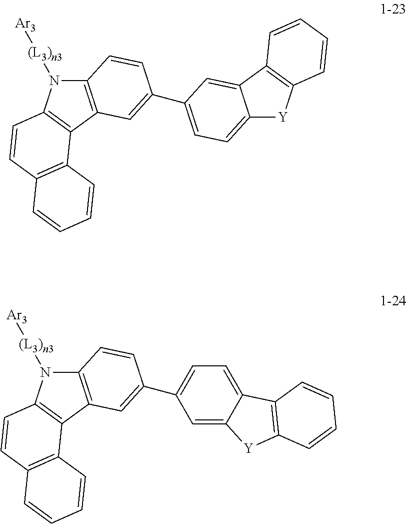

In Formulas 1-1 to 1-24, Y may be 0, 8, or C(R₃₁)(R₃₂); n to n3 may each independently be an integer of 0 to 3; and L₁ to L₃ may each independently be a substituted or unsubstituted C₃-C₁₀ cycloalkylene group, a substituted or unsubstituted C₃-C₁₀ cycloalkenylene group, a substituted or unsubstituted C₆-C₁₀ arylene group, a substituted or unsubstituted C₂-C₁₀ heterocycloalkylene group, a substituted or unsubstituted C₂-C₁₀ heterocycloalkenylene group, or a substituted or unsubstituted C₁-C₆₀ heteroarylene group.

In Formulas 1-1 to 1-24, n1 to n3 may each independently be an integer of 0 to 3. Ar₁ to Ar₃ may each independently be: i) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or ii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In Formulas 1-1 to 1-24, R₃₁ and R₃₂ may each independently be: i) a hydrogen atom, a deuterium atom, a C₁-C₆₀ alkyl group, a C₂-C₆₀ alkenyl group, a C₂-C₆₀ alkynyl group, or a C₁-C₆₀ alkoxy group; or ii) a C₁-C₆₀ alkyl group, a C₂-C₆₀ alkenyl group, a C₂-C₆₀ alkynyl group, or a C₁-C₆₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group; or iii) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group; or iv) a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, or a C₁-C₆₀ heteroaryl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₁-C₆₀ heteroaryl group.

In some other embodiments, the light-emitting material is at least one of Compounds 1 to 108, but the light-emitting material is not limited thereto.

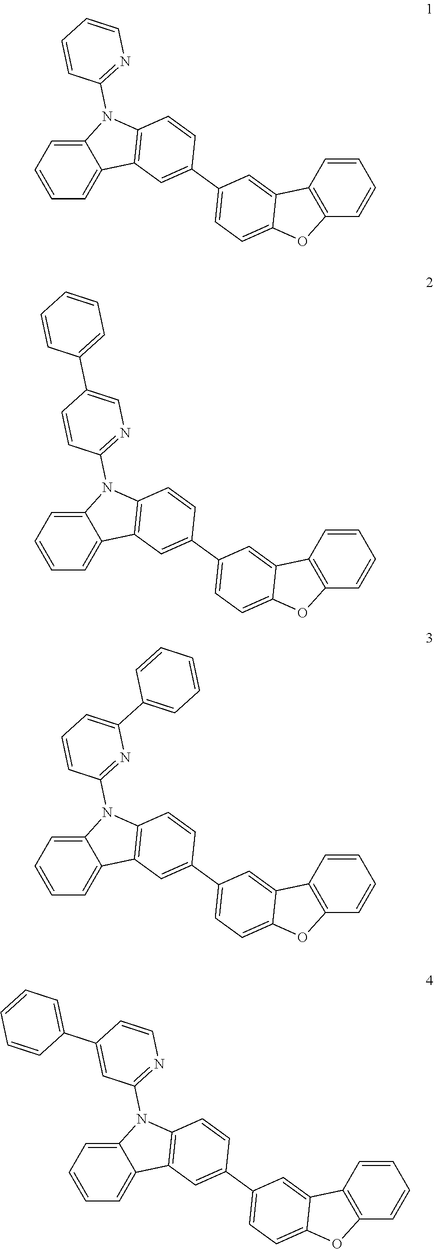 [SMILES: c1ccc(-n2c3ccccc3c3cc(-c4ccc5oc6ccccc6c5c4)ccc32)nc1 ; c1ccc(-c2ccc(-n3c4ccccc4c4cc(-c5ccc6oc7ccccc7c6c5)ccc43)nc2)cc1 ; c1ccc(-c2cccc(-n3c4ccccc4c4cc(-c5ccc6oc7ccccc7c6c5)ccc43)n2)cc1 ; c1ccc(-c2ccnc(-n3c4ccccc4c4cc(-c5ccc6oc7ccccc7c6c5)ccc43)c2)cc1]

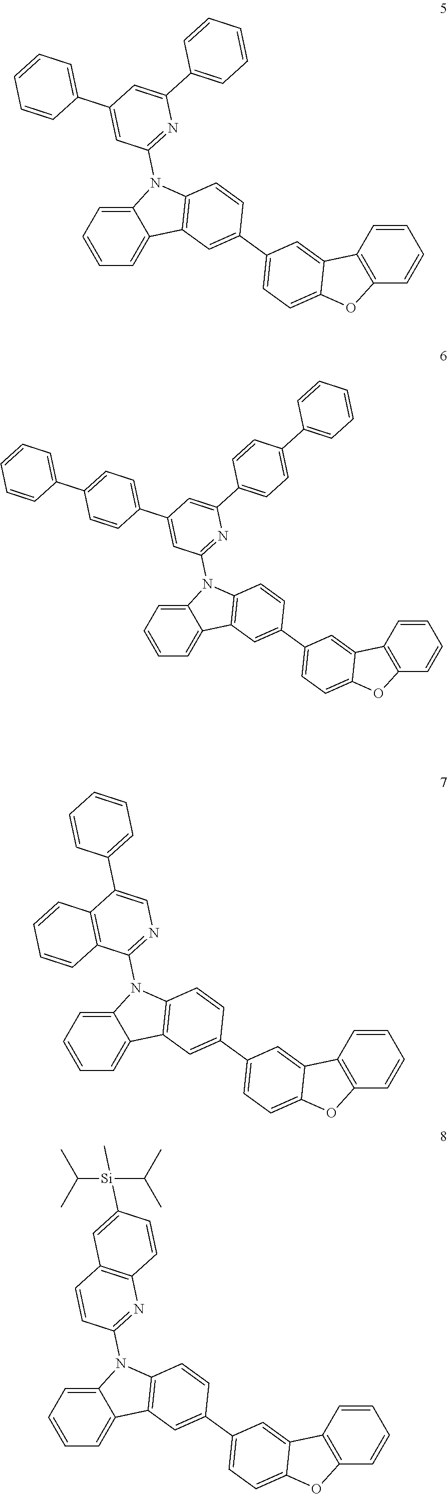 [SMILES: c1ccc(-c2cc(-c3ccccc3)nc(-n3c4ccccc4c4cc(-c5ccc6oc7ccccc7c6c5)ccc43)c2)cc1 ; c1ccc(-c2ccc(-c3cc(-c4ccc(-c5ccccc5)cc4)nc(-n4c5ccccc5c5cc(-c6ccc7oc8ccccc8c7c6)ccc54)c3)cc2)cc1 ; c1ccc(-c2cnc(-n3c4ccccc4c4cc(-c5ccc6oc7ccccc7c6c5)ccc43)c3ccccc23)cc1 ; CC(C)[Si](C)(c1ccc2nc(-n3c4ccccc4c4cc(-c5ccc6oc7ccccc7c6c5)ccc43)ccc2c1)C(C)C]

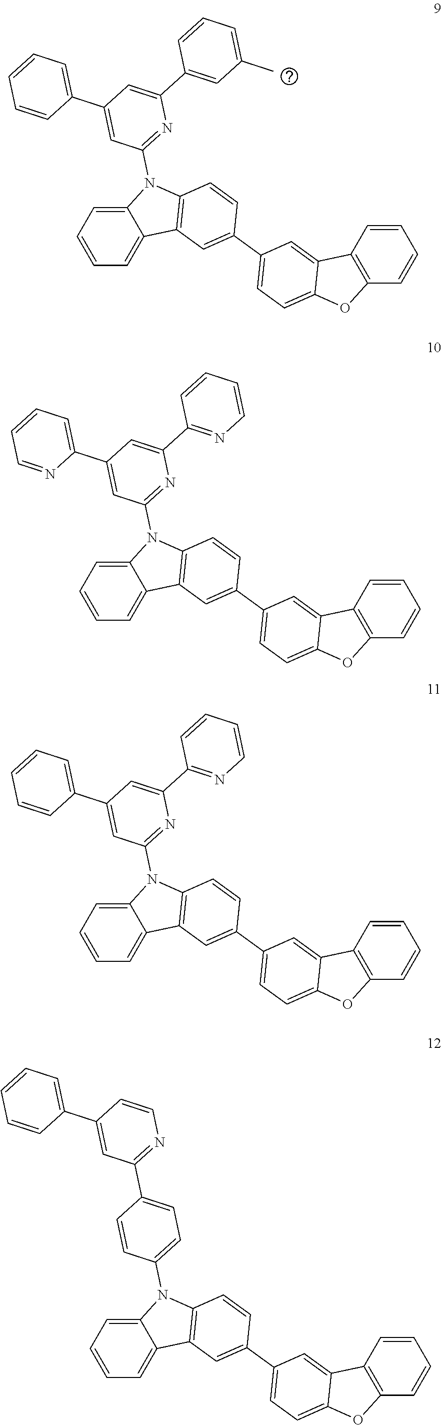 [SMILES: Cc1cccc(-c2cc(-c3ccccc3)cc(-n3c4ccccc4c4cc(-c5ccc6oc7ccccc7c6c5)ccc43)n2)c1 ; c1ccc(-c2cc(-c3ccccn3)nc(-n3c4ccccc4c4cc(-c5ccc6oc7ccccc7c6c5)ccc43)c2)nc1 ; c1ccc(-c2cc(-c3ccccn3)nc(-n3c4ccccc4c4cc(-c5ccc6oc7ccccc7c6c5)ccc43)c2)cc1 ; c1ccc(-c2ccnc(-c3ccc(-n4c5ccccc5c5cc(-c6ccc7oc8ccccc8c7c6)ccc54)cc3)c2)cc1]

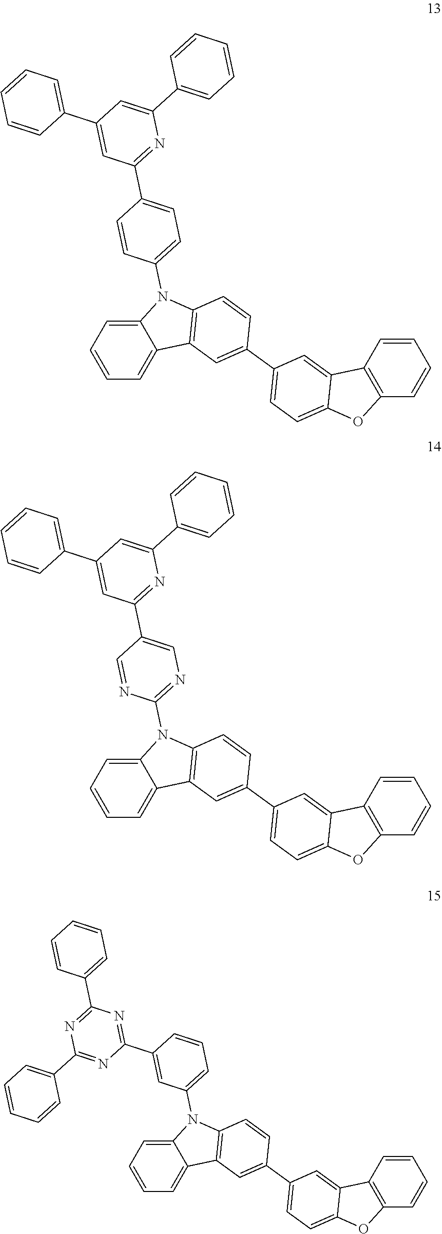 [SMILES: c1ccc(-c2cc(-c3ccccc3)nc(-c3ccc(-n4c5ccccc5c5cc(-c6ccc7oc8ccccc8c7c6)ccc54)cc3)c2)cc1 ; c1ccc(-c2cc(-c3ccccc3)nc(-c3cnc(-n4c5ccccc5c5cc(-c6ccc7oc8ccccc8c7c6)ccc54)nc3)c2)cc1 ; c1ccc(-c2nc(-c3ccccc3)nc(-c3cccc(-n4c5ccccc5c5cc(-c6ccc7oc8ccccc8c7c6)ccc54)c3)n2)cc1]

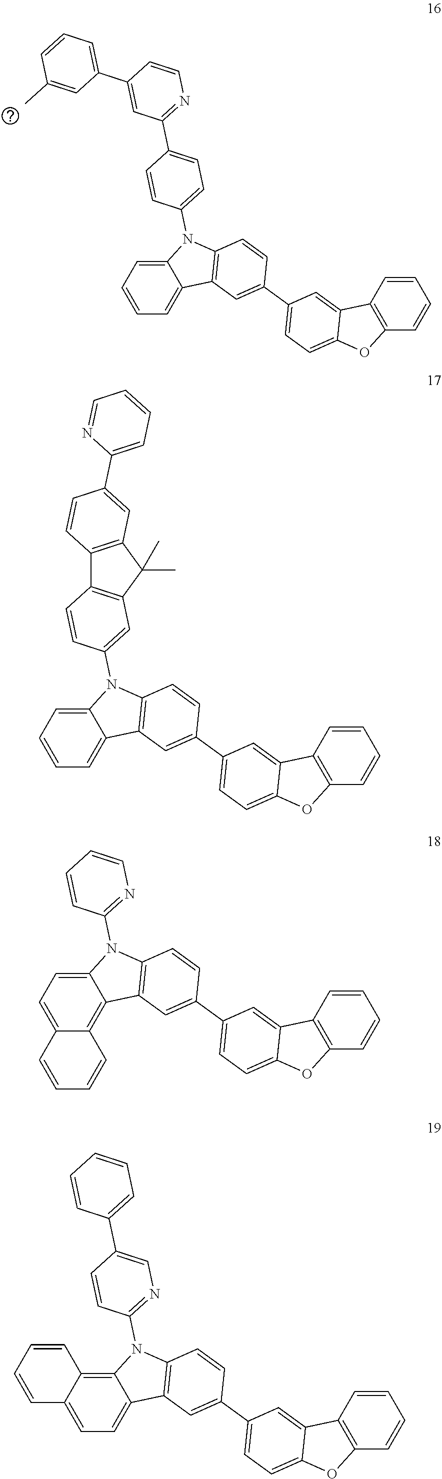 [SMILES: Cc1cccc(-c2ccnc(-c3ccc(-n4c5ccccc5c5cc(-c6ccc7oc8ccccc8c7c6)ccc54)cc3)c2)c1 ; CC1(C)c2cc(-c3ccccn3)ccc2-c2ccc(-n3c4ccccc4c4cc(-c5ccc6oc7ccccc7c6c5)ccc43)cc21 ; c1ccc(-n2c3ccc(-c4ccc5oc6ccccc6c5c4)cc3c3c4ccccc4ccc32)nc1 ; c1ccc(-c2ccc(-n3c4ccc(-c5ccc6oc7ccccc7c6c5)cc4c4ccc5ccccc5c43)nc2)cc1]

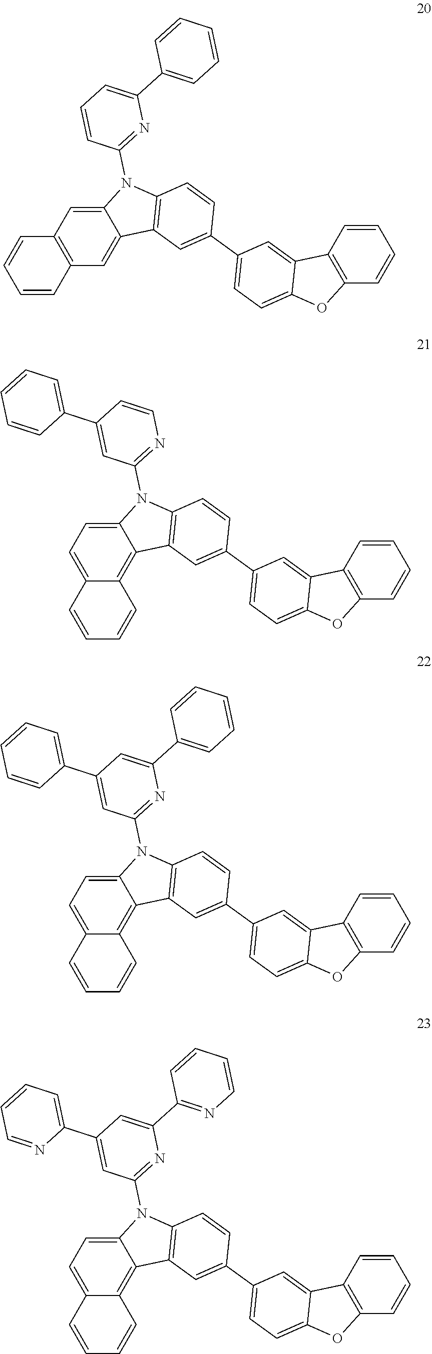 [SMILES: c1ccc(-c2cccc(-n3c4ccc(-c5ccc6oc7ccccc7c6c5)cc4c4cc5ccccc5cc43)n2)cc1 ; c1ccc(-c2ccnc(-n3c4ccc(-c5ccc6oc7ccccc7c6c5)cc4c4c5ccccc5ccc43)c2)cc1 ; c1ccc(-c2cc(-c3ccccc3)nc(-n3c4ccc(-c5ccc6oc7ccccc7c6c5)cc4c4c5ccccc5ccc43)c2)cc1 ; c1ccc(-c2cc(-c3ccccn3)nc(-n3c4ccc(-c5ccc6oc7ccccc7c6c5)cc4c4c5ccccc5ccc43)c2)nc1]

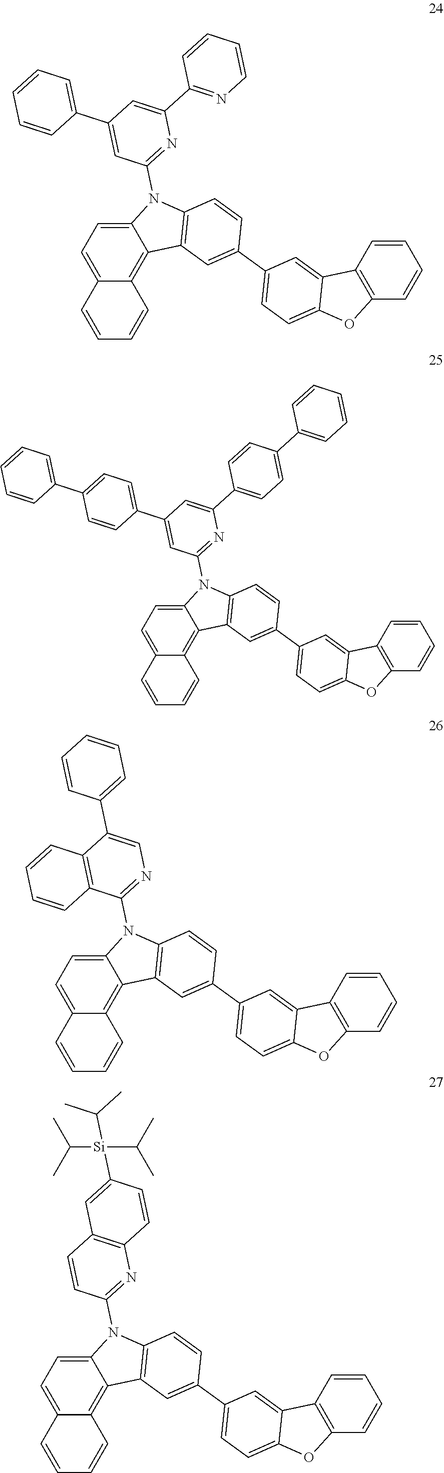

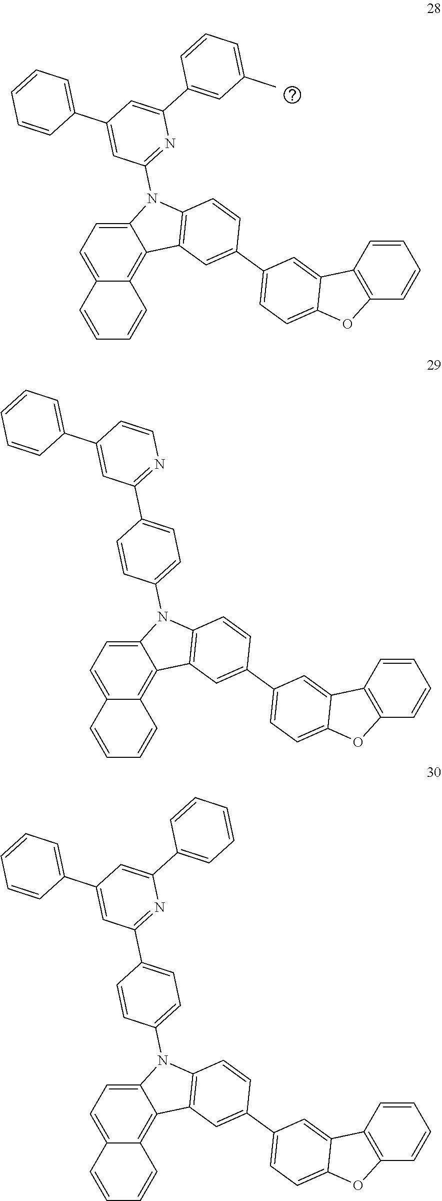 [SMILES: Cc1cccc(-c2cc(-c3ccccc3)cc(-n3c4ccc(-c5ccc6oc7ccccc7c6c5)cc4c4c5ccccc5ccc43)n2)c1 ; c1ccc(-c2ccnc(-c3ccc(-n4c5ccc(-c6ccc7oc8ccccc8c7c6)cc5c5c6ccccc6ccc54)cc3)c2)cc1 ; c1ccc(-c2cc(-c3ccccc3)nc(-c3ccc(-n4c5ccc(-c6ccc7oc8ccccc8c7c6)cc5c5c6ccccc6ccc54)cc3)c2)cc1]

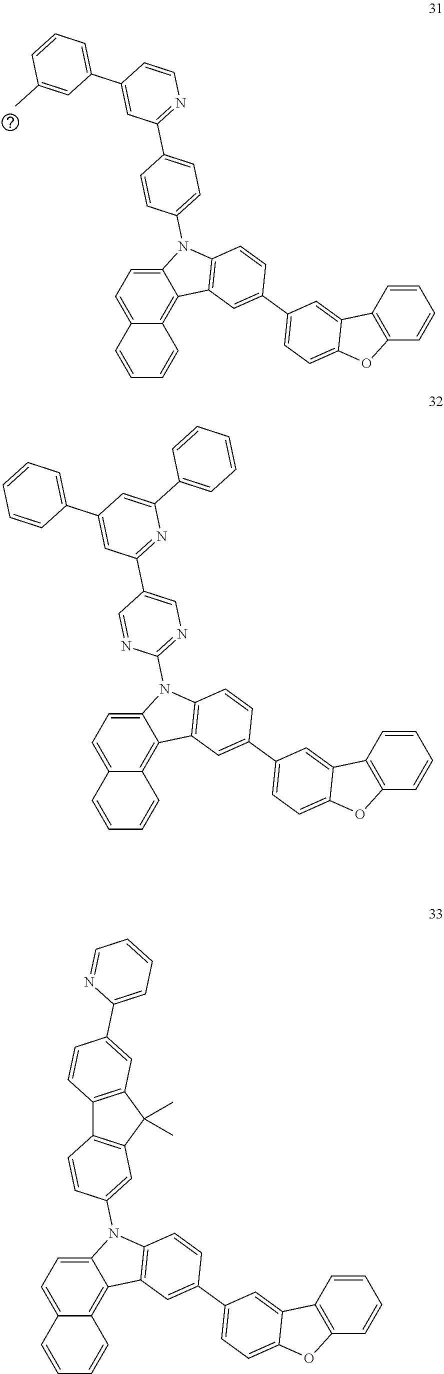 [SMILES: Cc1cccc(-c2ccnc(-c3ccc(-n4c5ccc(-c6ccc7oc8ccccc8c7c6)cc5c5c6ccccc6ccc54)cc3)c2)c1 ; c1ccc(-c2cc(-c3ccccc3)nc(-c3cnc(-n4c5ccc(-c6ccc7oc8ccccc8c7c6)cc5c5c6ccccc6ccc54)nc3)c2)cc1 ; CC1(C)c2cc(-c3ccccn3)ccc2-c2ccc(-n3c4ccc(-c5ccc6oc7ccccc7c6c5)cc4c4c5ccccc5ccc43)cc21]

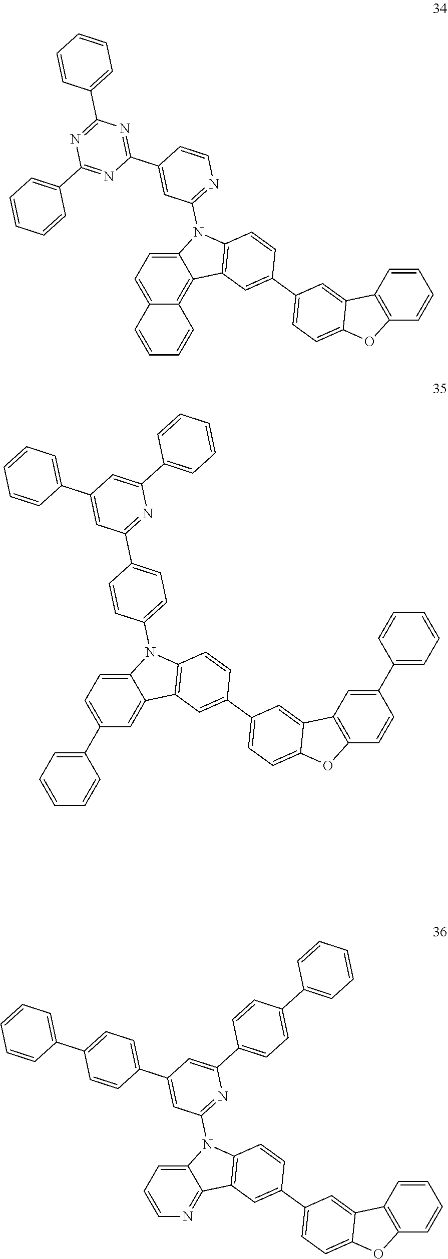 [SMILES: c1ccc(-c2nc(-c3ccccc3)nc(-c3ccnc(-n4c5ccc(-c6ccc7oc8ccccc8c7c6)cc5c5c6ccccc6ccc54)c3)n2)cc1 ; c1ccc(-c2cc(-c3ccccc3)nc(-c3ccc(-n4c5ccc(-c6ccccc6)cc5c5cc(-c6ccc7oc8ccc(-c9ccccc9)cc8c7c6)ccc54)cc3)c2)cc1 ; c1ccc(-c2ccc(-c3cc(-c4ccc(-c5ccccc5)cc4)nc(-n4c5ccc(-c6ccc7oc8ccccc8c7c6)cc5c5ncccc54)c3)cc2)cc1]

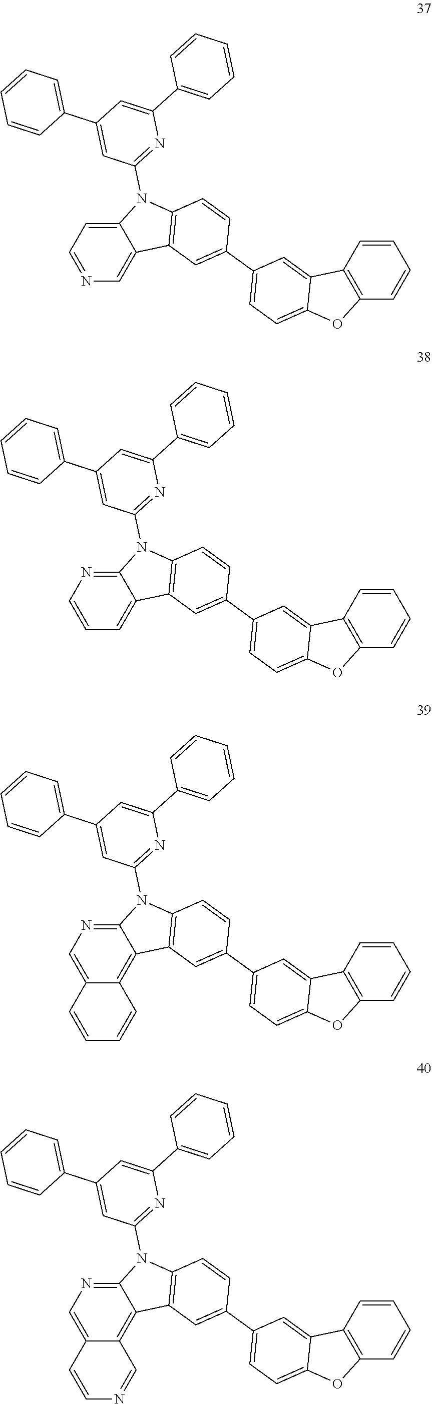 [SMILES: c1ccc(-c2cc(-c3ccccc3)nc(-n3c4ccncc4c4cc(-c5ccc6oc7ccccc7c6c5)ccc43)c2)cc1 ; c1ccc(-c2cc(-c3ccccc3)nc(-n3c4ccc(-c5ccc6oc7ccccc7c6c5)cc4c4cccnc43)c2)cc1 ; c1ccc(-c2cc(-c3ccccc3)nc(-n3c4ccc(-c5ccc6oc7ccccc7c6c5)cc4c4c5ccccc5cnc43)c2)cc1 ; c1ccc(-c2cc(-c3ccccc3)nc(-n3c4ccc(-c5ccc6oc7ccccc7c6c5)cc4c4c5cnccc5cnc43)c2)cc1]

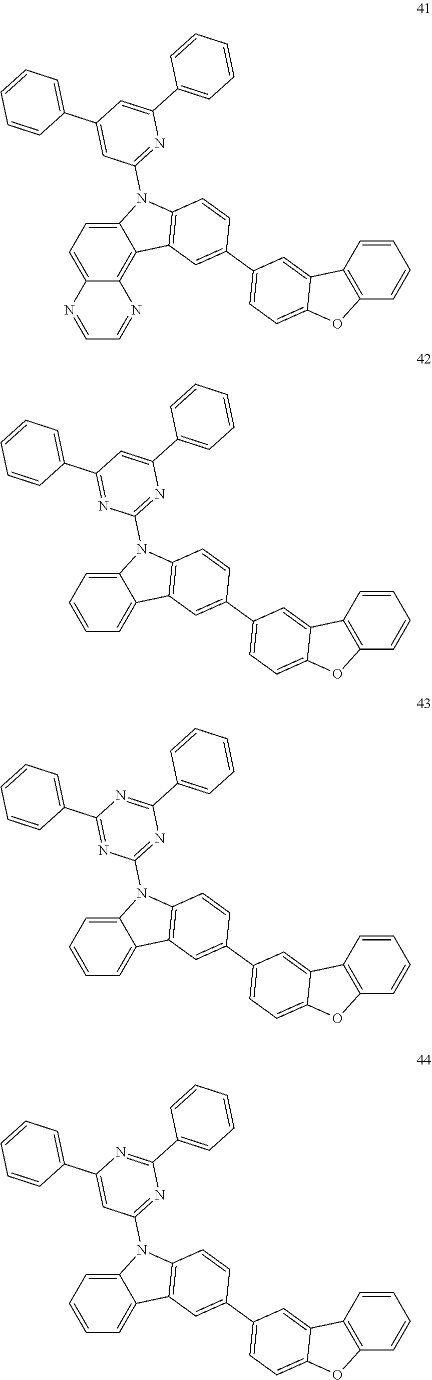 [SMILES: c1ccc(-c2cc(-c3ccccc3)nc(-n3c4ccc(-c5ccc6oc7ccccc7c6c5)cc4c4c5nccnc5ccc43)c2)cc1 ; c1ccc(-c2cc(-c3ccccc3)nc(-n3c4ccccc4c4cc(-c5ccc6oc7ccccc7c6c5)ccc43)n2)cc1 ; c1ccc(-c2nc(-c3ccccc3)nc(-n3c4ccccc4c4cc(-c5ccc6oc7ccccc7c6c5)ccc43)n2)cc1 ; c1ccc(-c2cc(-n3c4ccccc4c4cc(-c5ccc6oc7ccccc7c6c5)ccc43)nc(-c3ccccc3)n2)cc1]

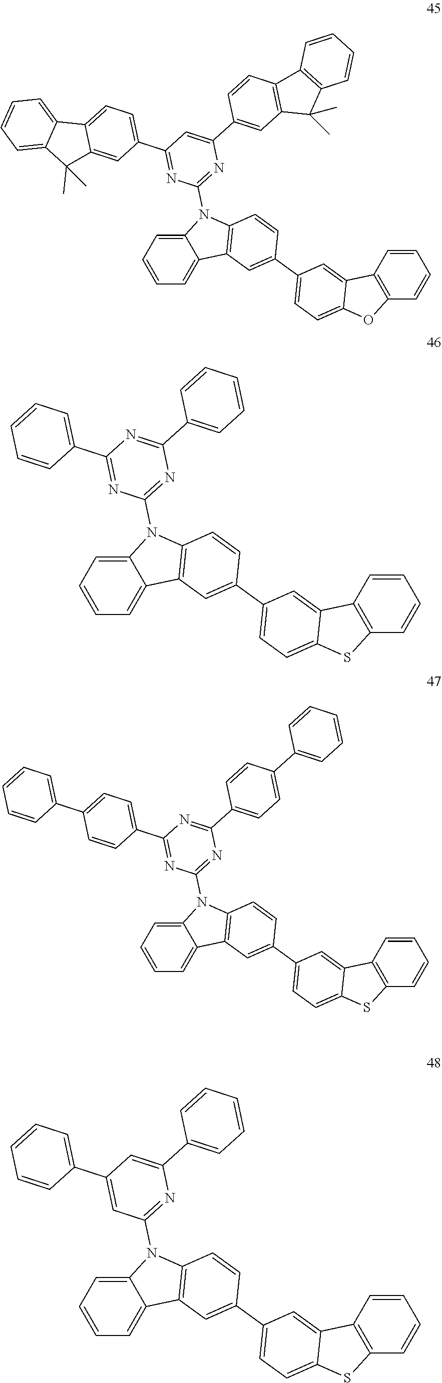 [SMILES: CC1(C)c2ccccc2-c2ccc(-c3cc(-c4ccc5c(c4)C(C)(C)c4ccccc4-5)nc(-n4c5ccccc5c5cc(-c6ccc7oc8ccccc8c7c6)ccc54)n3)cc21 ; c1ccc(-c2nc(-c3ccccc3)nc(-n3c4ccccc4c4cc(-c5ccc6sc7ccccc7c6c5)ccc43)n2)cc1 ; c1ccc(-c2ccc(-c3nc(-c4ccc(-c5ccccc5)cc4)nc(-n4c5ccccc5c5cc(-c6ccc7sc8ccccc8c7c6)ccc54)n3)cc2)cc1 ; c1ccc(-c2cc(-c3ccccc3)nc(-n3c4ccccc4c4cc(-c5ccc6sc7ccccc7c6c5)ccc43)c2)cc1]

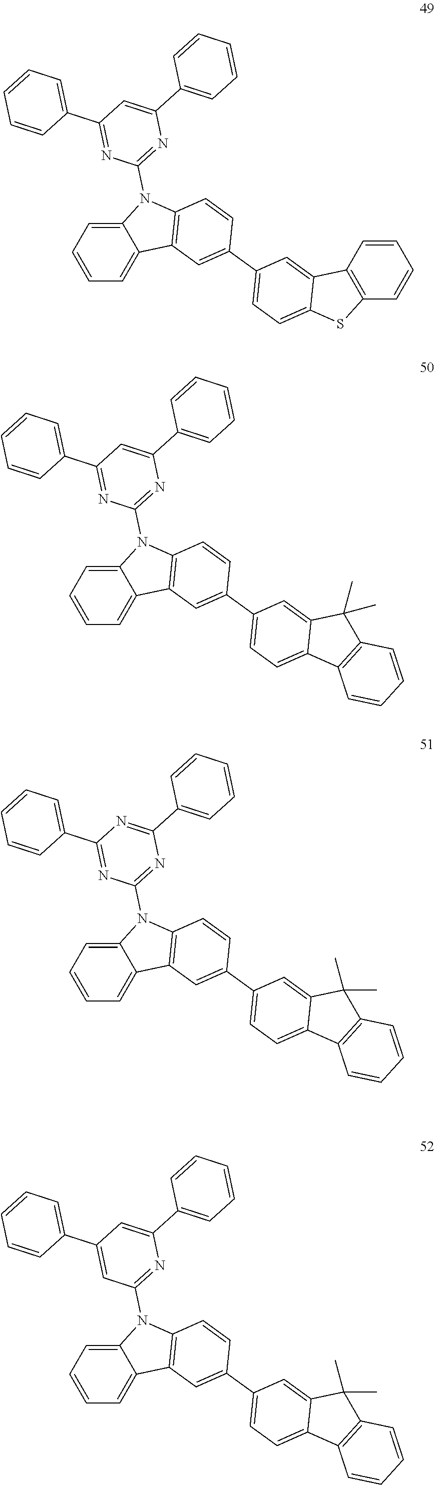 [SMILES: c1ccc(-c2cc(-c3ccccc3)nc(-n3c4ccccc4c4cc(-c5ccc6sc7ccccc7c6c5)ccc43)n2)cc1 ; CC1(C)c2ccccc2-c2ccc(-c3ccc4c(c3)c3ccccc3n4-c3nc(-c4ccccc4)cc(-c4ccccc4)n3)cc21 ; CC1(C)c2ccccc2-c2ccc(-c3ccc4c(c3)c3ccccc3n4-c3nc(-c4ccccc4)nc(-c4ccccc4)n3)cc21 ; CC1(C)c2ccccc2-c2ccc(-c3ccc4c(c3)c3ccccc3n4-c3cc(-c4ccccc4)cc(-c4ccccc4)n3)cc21]

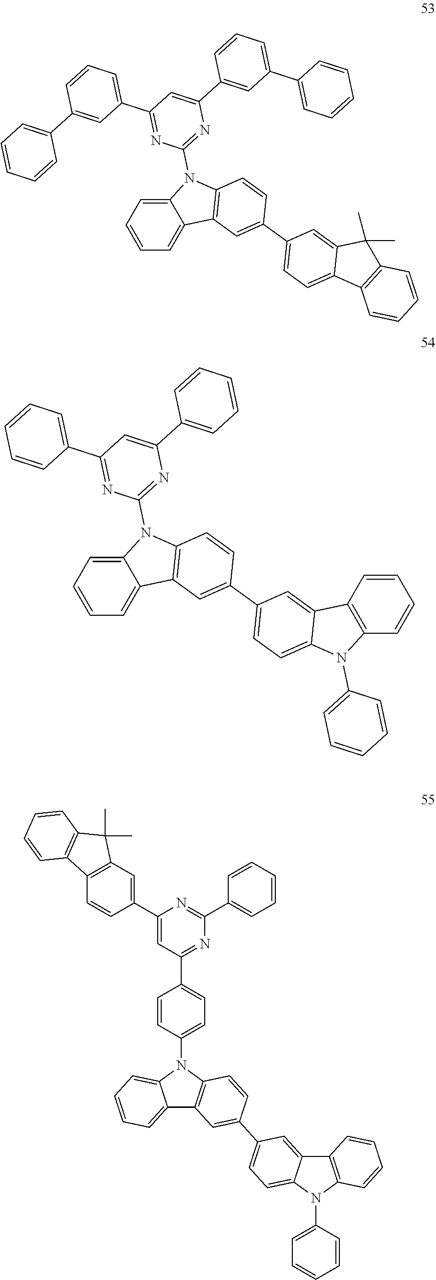 [SMILES: CC1(C)c2ccccc2-c2ccc(-c3ccc4c(c3)c3ccccc3n4-c3nc(-c4cccc(-c5ccccc5)c4)cc(-c4cccc(-c5ccccc5)c4)n3)cc21 ; c1ccc(-c2cc(-c3ccccc3)nc(-n3c4ccccc4c4cc(-c5ccc6c(c5)c5ccccc5n6-c5ccccc5)ccc43)n2)cc1 ; CC1(C)c2ccccc2-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc21]

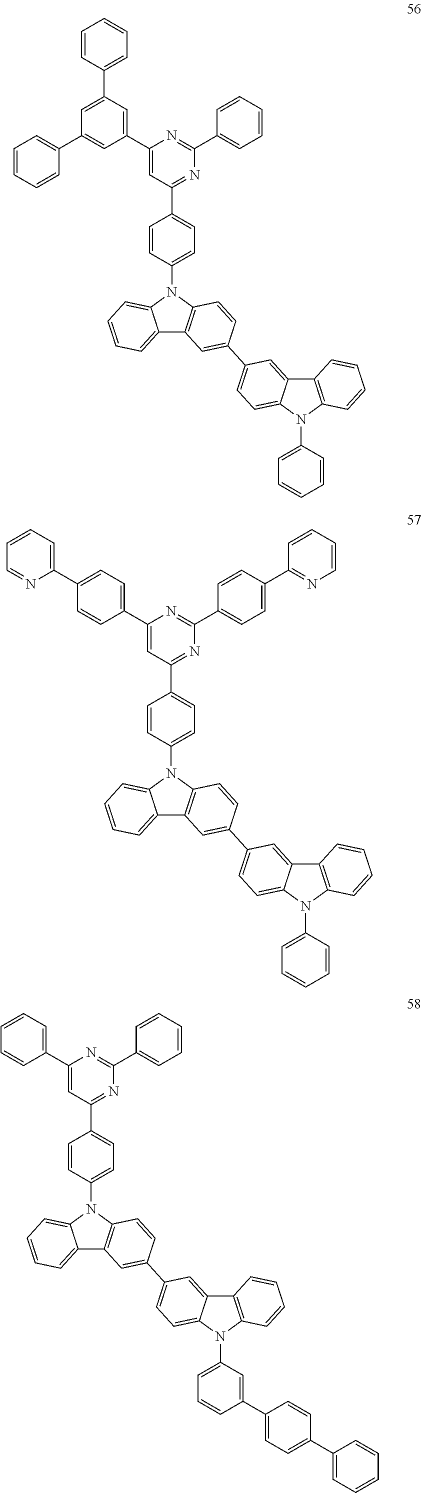

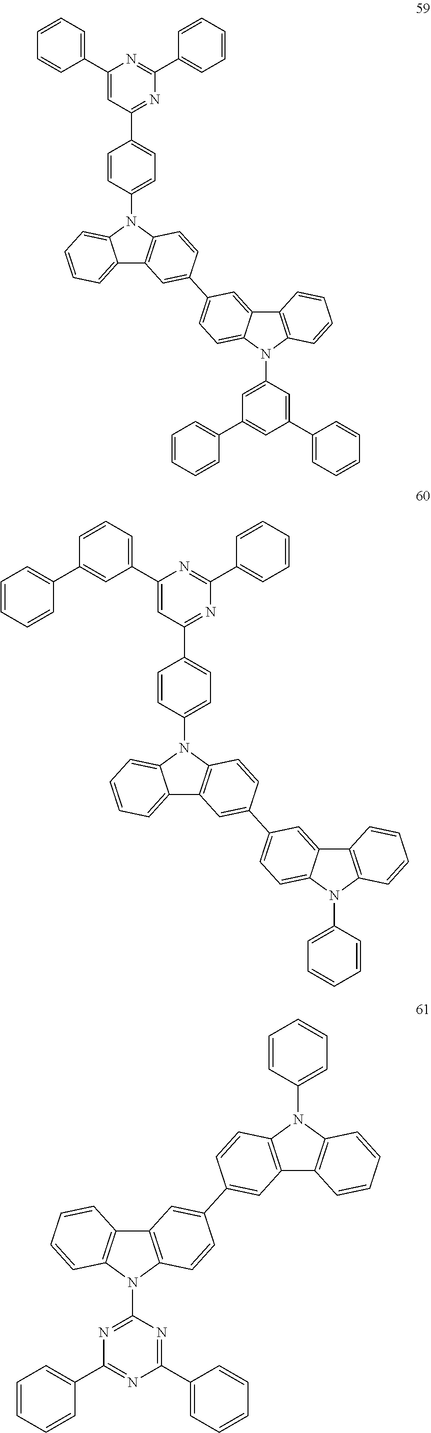 [SMILES: c1ccc(-c2cc(-c3ccccc3)cc(-n3c4ccccc4c4cc(-c5ccc6c(c5)c5ccccc5n6-c5ccc(-c6cc(-c7ccccc7)nc(-c7ccccc7)n6)cc5)ccc43)c2)cc1 ; c1ccc(-c2cccc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

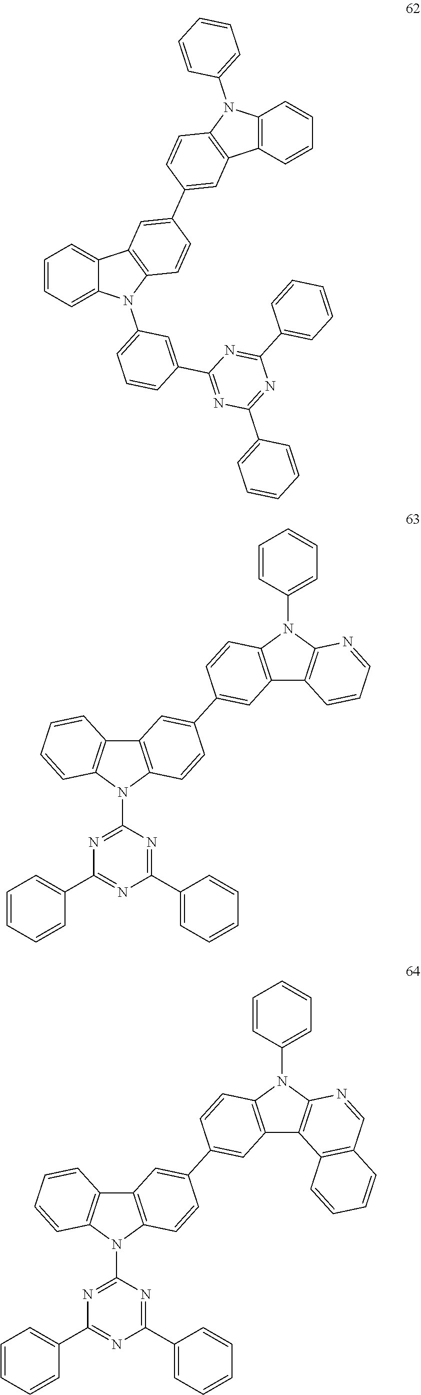

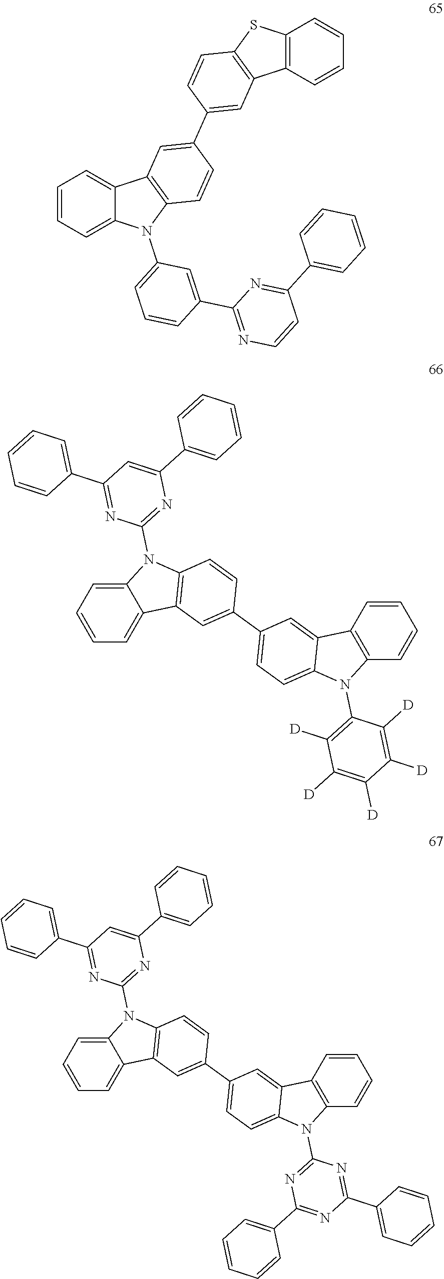 [SMILES: c1ccc(-c2ccnc(-c3cccc(-n4c5ccccc5c5cc(-c6ccc7sc8ccccc8c7c6)ccc54)c3)n2)cc1 ; [2H]c1c([2H])c([2H])c(-n2c3ccccc3c3cc(-c4ccc5c(c4)c4ccccc4n5-c4nc(-c5ccccc5)cc(-c5ccccc5)n4)ccc32)c([2H])c1[2H] ; c1ccc(-c2cc(-c3ccccc3)nc(-n3c4ccccc4c4cc(-c5ccc6c(c5)c5ccccc5n6-c5nc(-c6ccccc6)nc(-c6ccccc6)n5)ccc43)n2)cc1]

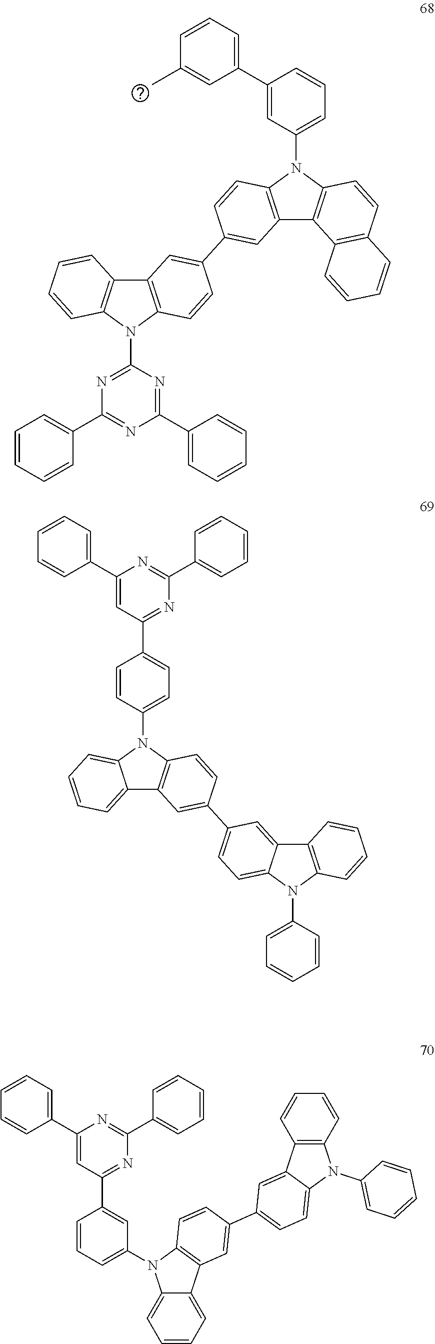

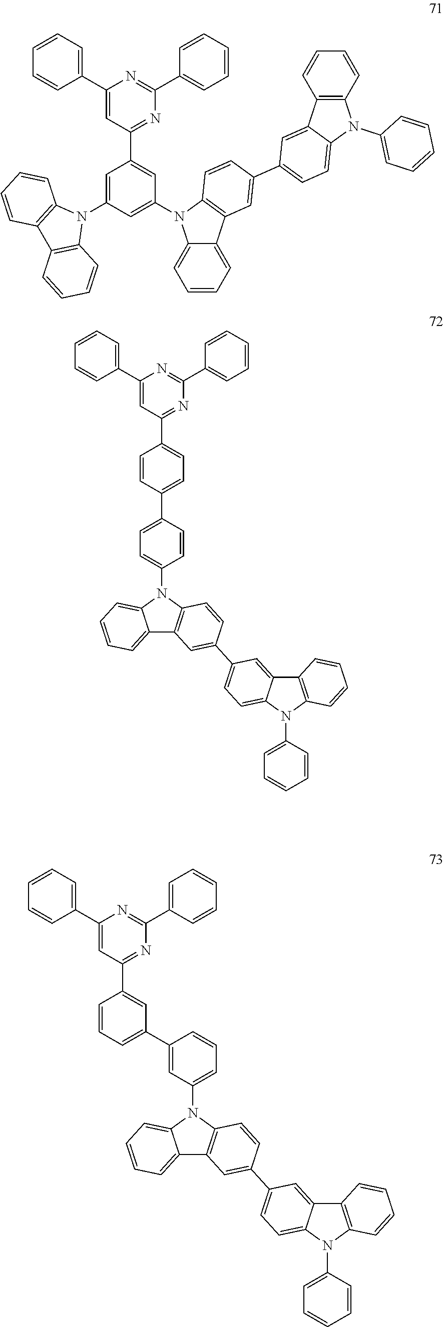 [SMILES: c1ccc(-c2cc(-c3cc(-n4c5ccccc5c5ccccc54)cc(-n4c5ccccc5c5cc(-c6ccc7c(c6)c6ccccc6n7-c6ccccc6)ccc54)c3)nc(-c3ccccc3)n2)cc1 ; c1ccc(-c2cc(-c3ccc(-c4ccc(-n5c6ccccc6c6cc(-c7ccc8c(c7)c7ccccc7n8-c7ccccc7)ccc65)cc4)cc3)nc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)nc(-c3ccccc3)n2)cc1]

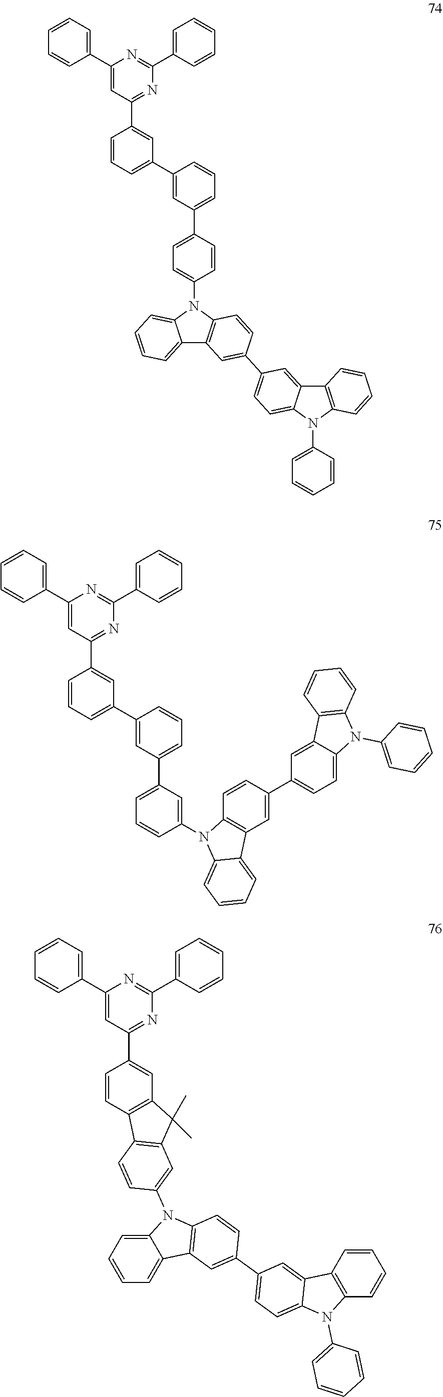 [SMILES: c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1 ; c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)nc(-c3ccccc3)n2)cc1 ; CC1(C)c2cc(-c3cc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21]

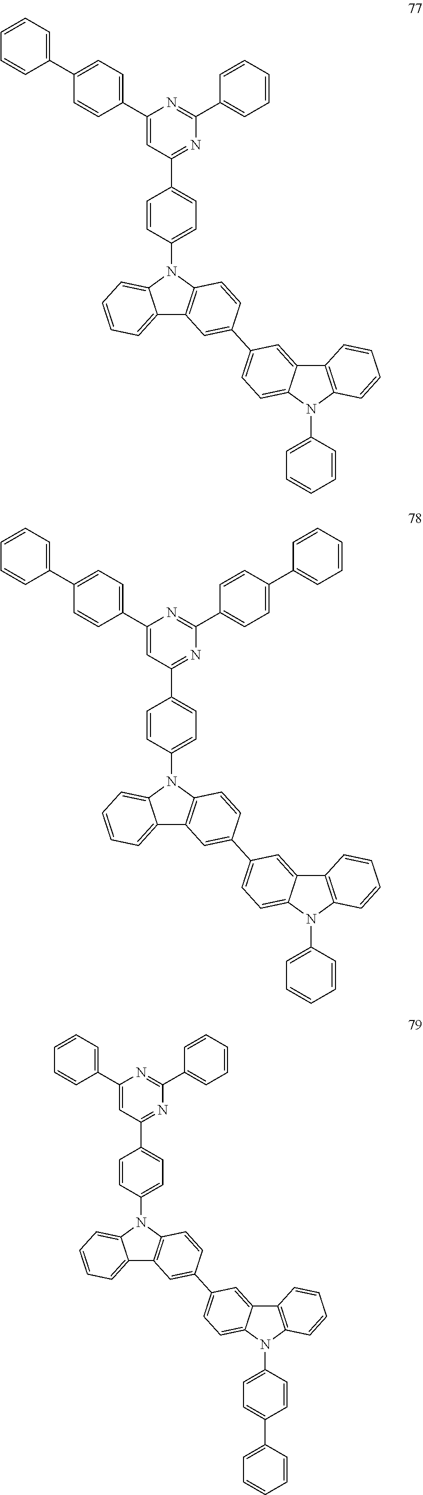

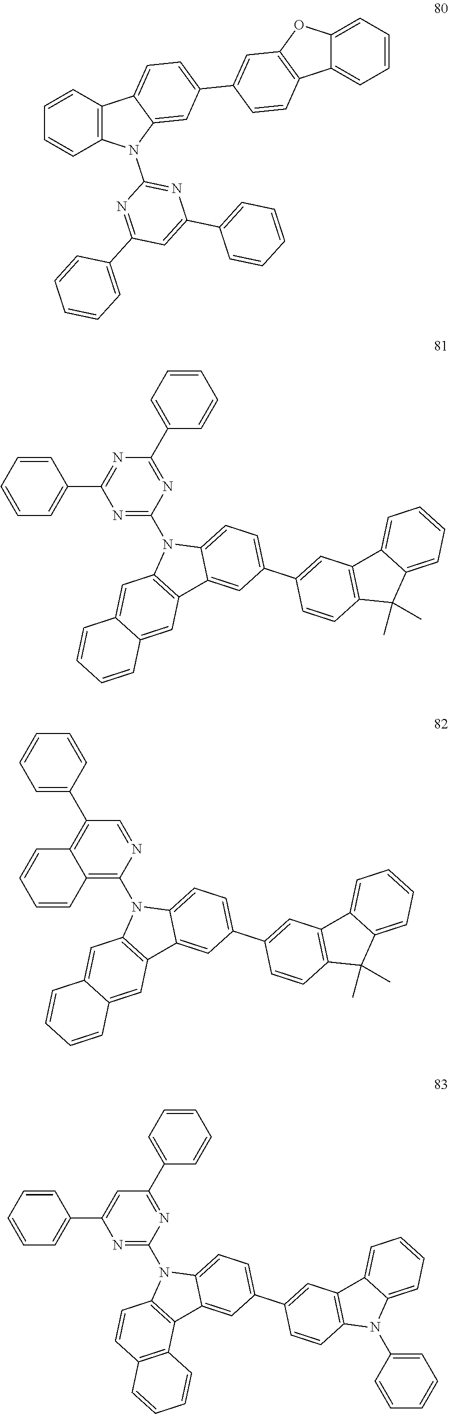 [SMILES: c1ccc(-c2cc(-c3ccccc3)nc(-n3c4ccccc4c4ccc(-c5ccc6c(c5)oc5ccccc56)cc43)n2)cc1 ; CC1(C)c2ccccc2-c2cc(-c3ccc4c(c3)c3cc5ccccc5cc3n4-c3nc(-c4ccccc4)nc(-c4ccccc4)n3)ccc21 ; CC1(C)c2ccccc2-c2cc(-c3ccc4c(c3)c3cc5ccccc5cc3n4-c3ncc(-c4ccccc4)c4ccccc34)ccc21 ; c1ccc(-c2cc(-c3ccccc3)nc(-n3c4ccc(-c5ccc6c(c5)c5ccccc5n6-c5ccccc5)cc4c4c5ccccc5ccc43)n2)cc1]

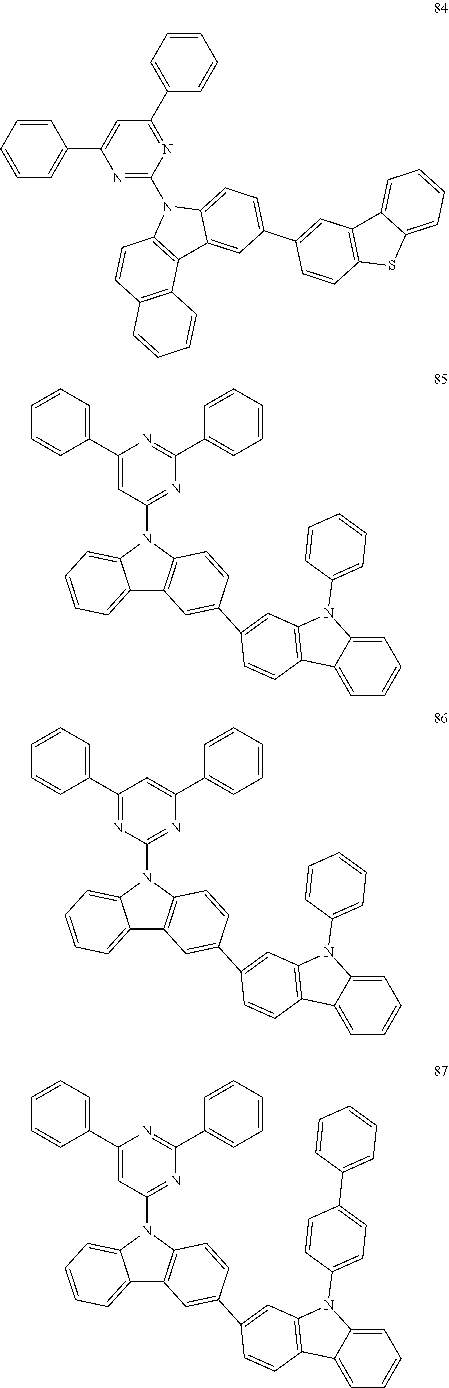 [SMILES: c1ccc(-c2cc(-c3ccccc3)nc(-n3c4ccc(-c5ccc6sc7ccccc7c6c5)cc4c4c5ccccc5ccc43)n2)cc1 ; c1ccc(-c2cc(-n3c4ccccc4c4cc(-c5ccc6c7ccccc7n(-c7ccccc7)c6c5)ccc43)nc(-c3ccccc3)n2)cc1 ; c1ccc(-c2cc(-c3ccccc3)nc(-n3c4ccccc4c4cc(-c5ccc6c7ccccc7n(-c7ccccc7)c6c5)ccc43)n2)cc1 ; c1ccc(-c2ccc(-n3c4ccccc4c4ccc(-c5ccc6c(c5)c5ccccc5n6-c5cc(-c6ccccc6)nc(-c6ccccc6)n5)cc43)cc2)cc1]

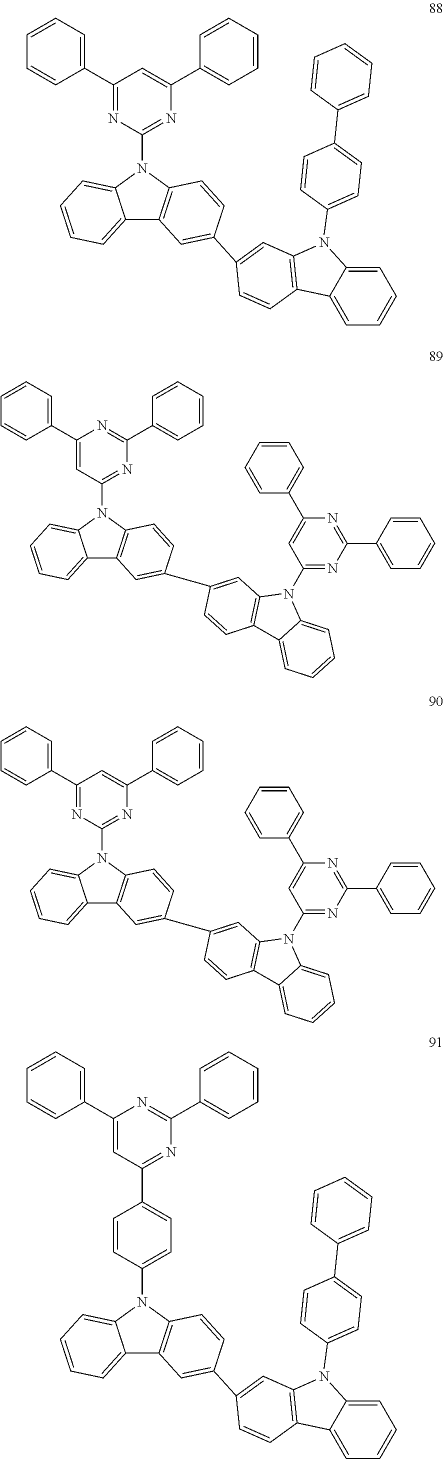 [SMILES: c1ccc(-c2ccc(-n3c4ccccc4c4ccc(-c5ccc6c(c5)c5ccccc5n6-c5nc(-c6ccccc6)cc(-c6ccccc6)n5)cc43)cc2)cc1 ; c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1 ; c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1 ; c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1]

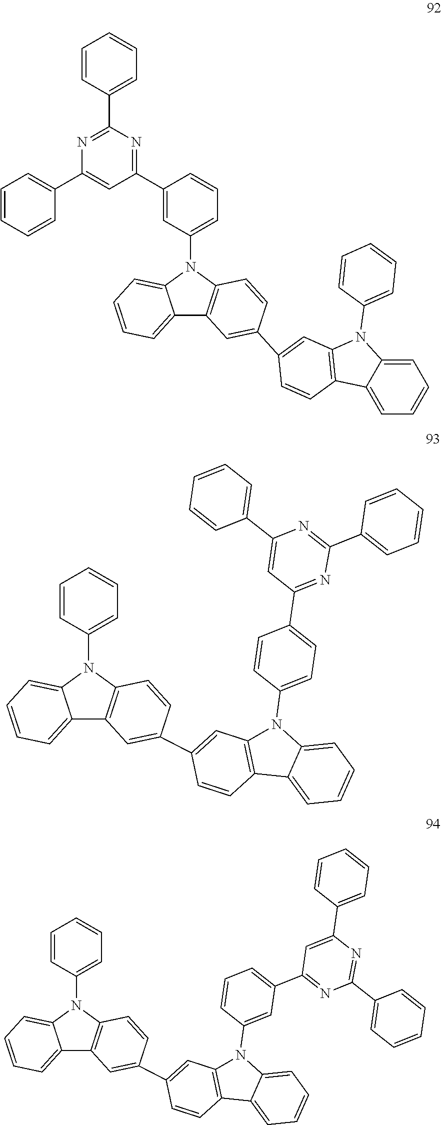 [SMILES: c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1]

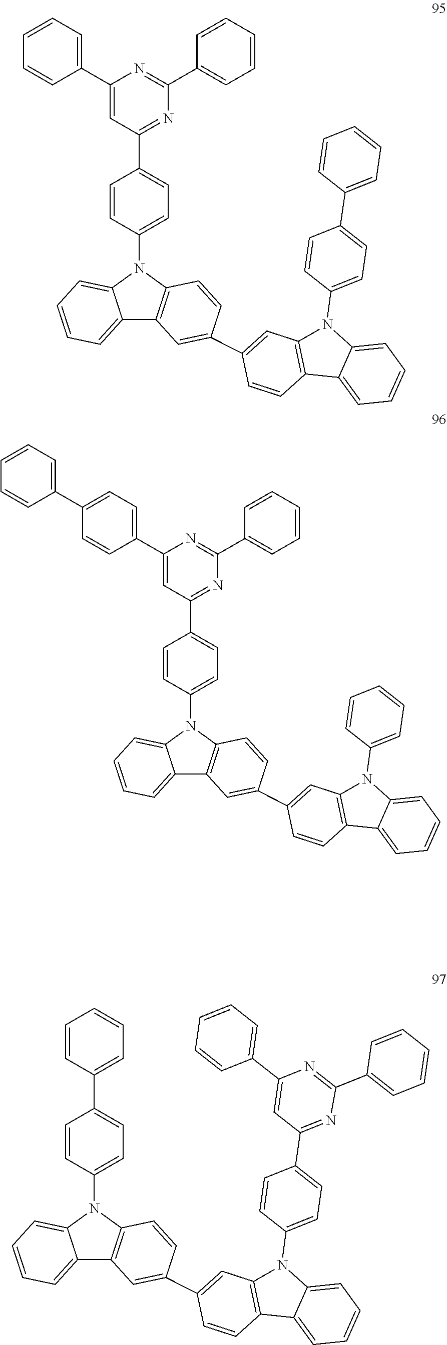 [SMILES: c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1 ; c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1 ; c1ccc(-c2ccc(-n3c4ccccc4c4cc(-c5ccc6c7ccccc7n(-c7ccc(-c8cc(-c9ccccc9)nc(-c9ccccc9)n8)cc7)c6c5)ccc43)cc2)cc1]

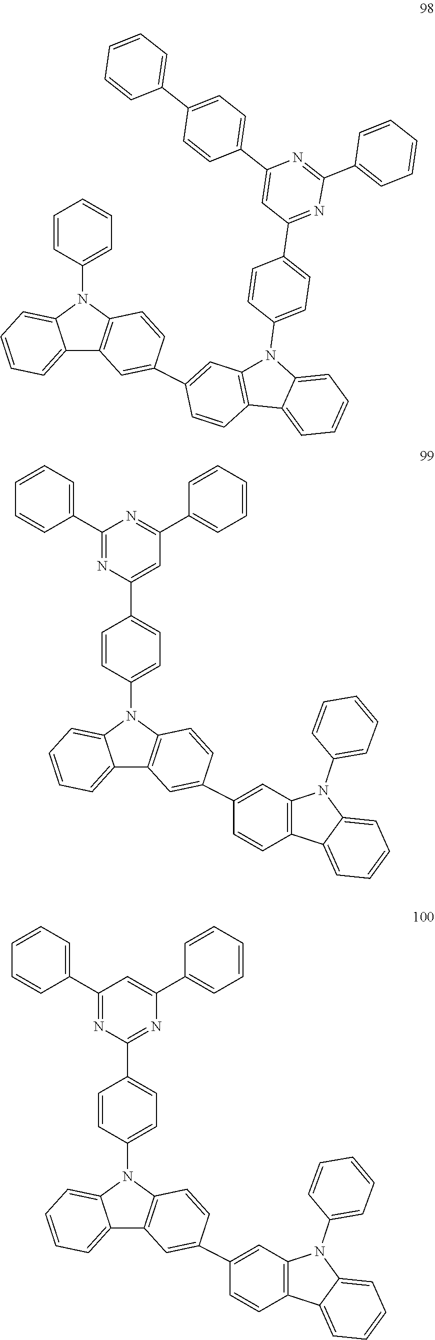

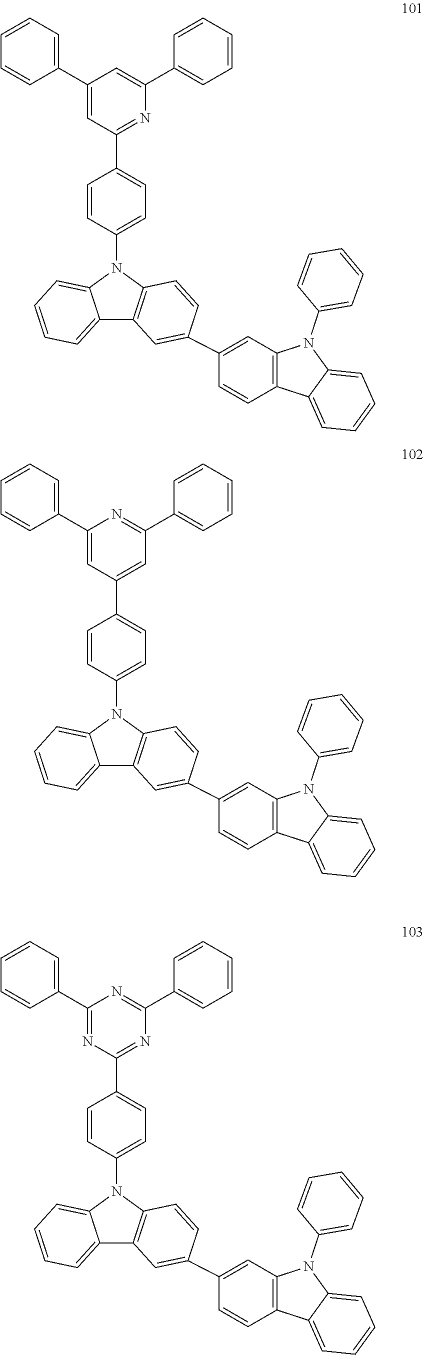 [SMILES: c1ccc(-c2cc(-c3ccccc3)nc(-c3ccc(-n4c5ccccc5c5cc(-c6ccc7c8ccccc8n(-c8ccccc8)c7c6)ccc54)cc3)c2)cc1 ; c1ccc(-c2cc(-c3ccc(-n4c5ccccc5c5cc(-c6ccc7c8ccccc8n(-c8ccccc8)c7c6)ccc54)cc3)cc(-c3ccccc3)n2)cc1 ; c1ccc(-c2nc(-c3ccccc3)nc(-c3ccc(-n4c5ccccc5c5cc(-c6ccc7c8ccccc8n(-c8ccccc8)c7c6)ccc54)cc3)n2)cc1]

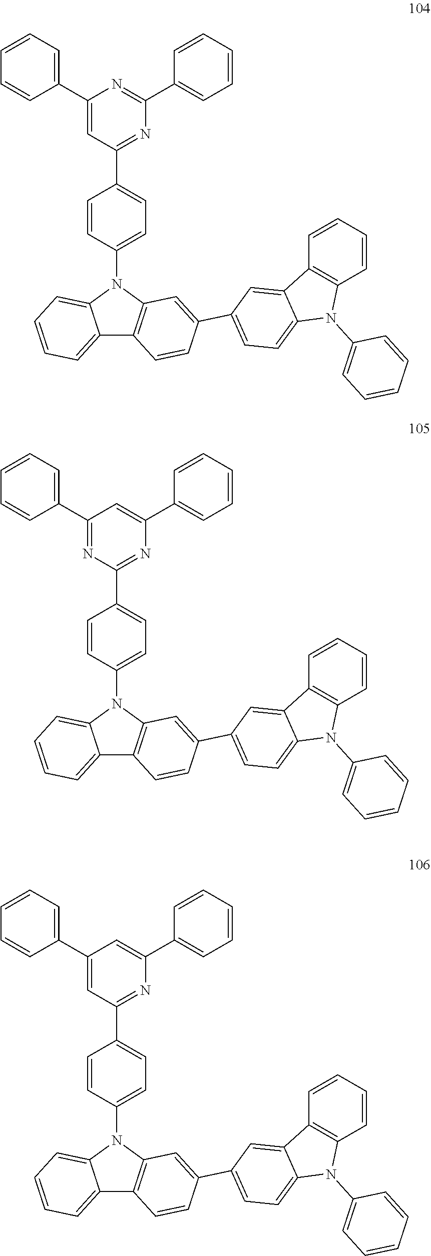 [SMILES: c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)c2)cc1]

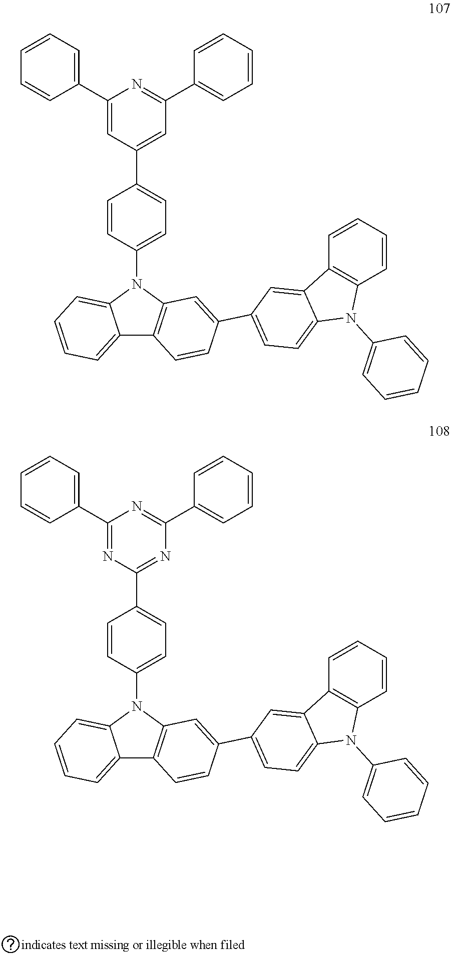 [SMILES: c1ccc(-c2cc(-c3ccc(-n4c5ccccc5c5ccc(-c6ccc7c(c6)c6ccccc6n7-c6ccccc6)cc54)cc3)cc(-c3ccccc3)n2)cc1 ; c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1]

When the OLED is a full color OLED, the EML may be patterned into a red EML, a green EML, and a blue EML. Alternatively, the EML may include at least two of a red EML, green EML, and blue EML, stacked upon one another to emit white light. In some embodiments, the OLED includes a substrate that is partitioned into a first sub-pixel region, a second sub-pixel region, and a third sub-pixel region, and a first electrode is disposed in each of the first, second and third sub-pixel regions of the substrate. The emission layer is disposed between the first electrode and the second electrode. In some embodiments, the emission layer includes a first emission layer disposed in the first sub-pixel region, a second emission layer disposed in the second sub-pixel region, and a third emission layer in the third sub-pixel region. In some embodiments, the first emission layer may emit a first color light, the second emission layer may emit a second color light, and the third emission layer may emit a third color light. In some embodiments, at least one of the first emission layer and/or the second emission layer includes the light emitting material represented by Formula 1 or Formula 2, discussed above. In some embodiments, the first color light may be red, the second color light may be green, and the third color light may be blue.

In some embodiments, the OLED may include a hole-transporting region between the emission layer and the first electrode, and the hole-transporting region may include a first hole-transporting region in the first sub-pixel region, a second hole-transporting region in the second sub-pixel region, and a third hole-transporting region in the third sub-pixel region. In some embodiments, at least one of the first hole-transporting region and/or the second hole-transporting region includes the hole-transporting material of Formula 2(1) or 2(2), as discussed above. In some embodiments, each of the first, second and third hole-transporting regions includes a buffer layer and hole transport layer, and the buffer layer may be disposed between the hole transport layer and the respective emission layer. In some embodiments, the buffer layer includes the hole-transporting material of Formula 2(1) or 2(2), as discussed above. In some embodiments, the buffer layer includes a first buffer layer disposed in the first sub-pixel region, a second buffer layer disposed in the second sub-pixel region and a third buffer layer disposed in the third sub-pixel region. In some embodiments, at least one of the first buffer layer and/or the second buffer layer includes the hole-transporting material of Formula 2(1) or 2(2), as discussed above.

In some embodiments in which the emission layer includes first, second and third emission layers disposed in the first, second and third sub-pixel regions, respectively, and the buffer layer includes first, second and third buffer layers disposed in the first, second and third, sub-pixel regions, respectively, the first emission layer may include the light-emitting material of Formula 1 or Formula 2, and the first buffer layer may include the hole-transporting material of Formula 2(1) or 2(2). In some embodiments, however, the first emission layer may include the light-emitting material of Formula 1 or Formula 2, and the second buffer layer may include the hole-transporting material of Formula 2(1) or 2(2). In some embodiments, the second emission layer may include the light-emitting material of Formula 1 or Formula 2, and the first buffer layer may include the hole-transporting material of Formula 2(1) or 2(2). In some embodiments, the second emission layer may include the light-emitting material of Formula 1 or Formula 2, and the second buffer layer may include the hole-transporting material of Formula 2(1) or 2(2).

The EML may further include an additional light-emitting material commonly used in OLEDs. For example, the EML may further include a host and/or a dopant commonly used in OLEDs. Non-limiting examples of a suitable host include tris(8-quinolinolate)aluminum (Alq₃), 4,4′-N,N′-dicarbazol-biphenyl (CBP), poly(n-vinylcarbazole) (PVK), 9,10-di(naphthalen-2-yl)anthracene (ADN), 4,4′,4″-tris(carbazole-9-yl)triphenylamine (TCTA), 1,3,5-tris(N-phenylbenzimidazole-2-yl)benzene) (TPBI), 3-tert-butyl-9,10-di(naphth-2-yl)anthracene (TBADN), 9,9′-(1,3-phenylene)bis-9H-carbazole (mCP), E3, 1,3-bis[2-(4-tert-butylphenyl)-1,3,4-oxadiazole-5-yl](OXD-7), distyrylarylene (DSA), dmCBP (see below), and Compounds 501 to 509, but the host is not limited thereto.

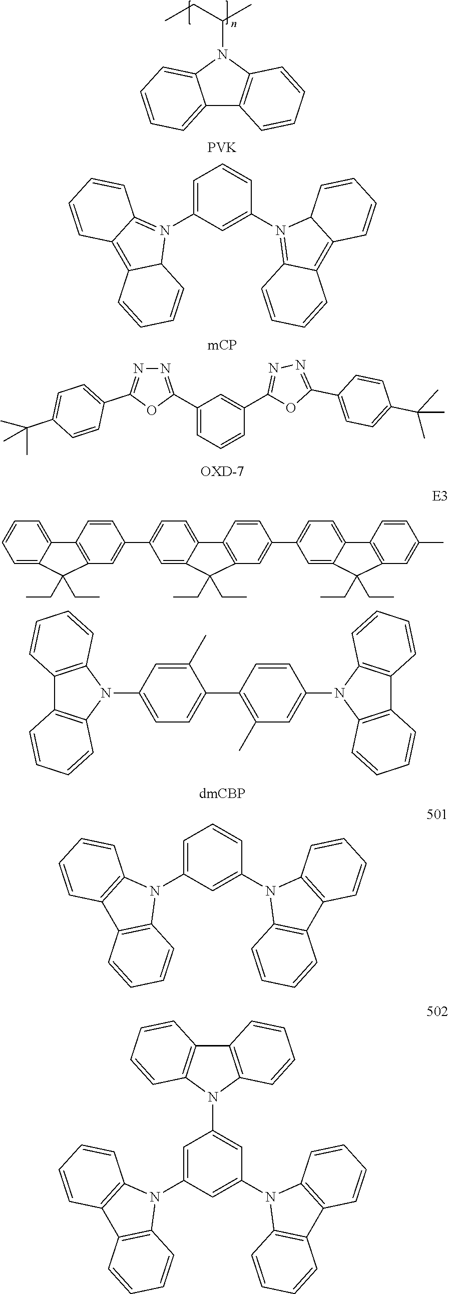

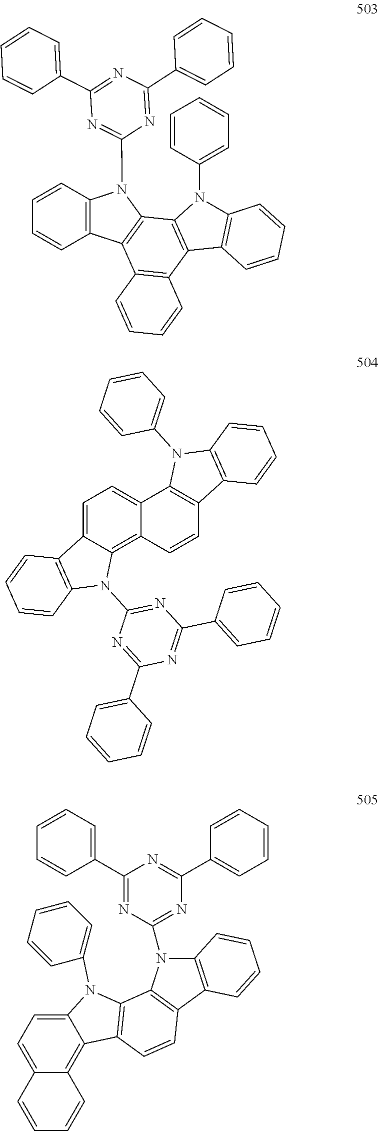

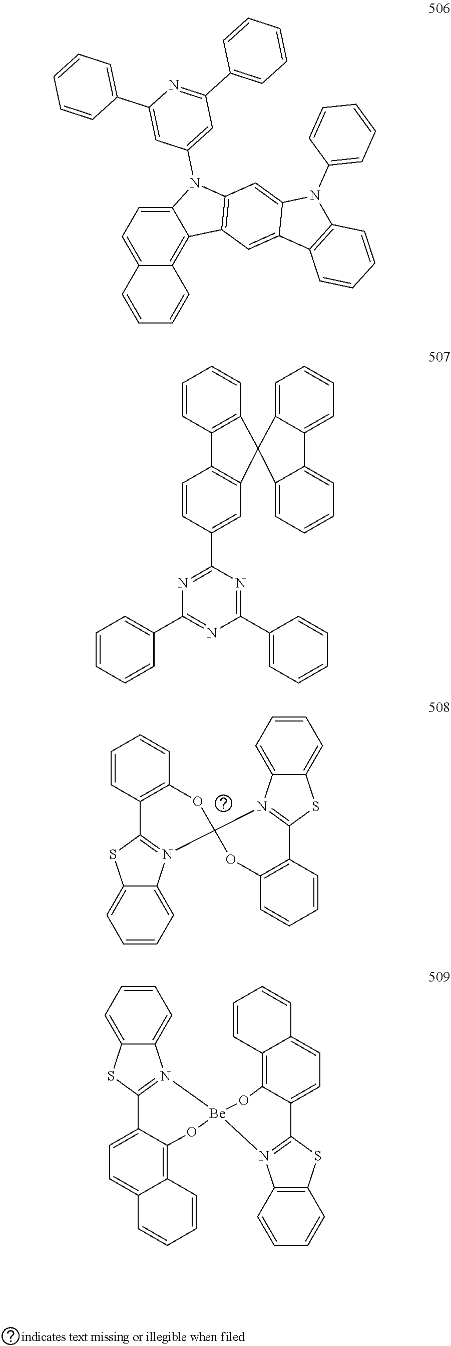

Alternatively, an anthracene-based compound represented by Formula 400 may be used as the host.

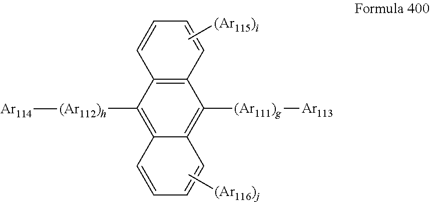

In Formula 400, g, h, i, and j may each independently be an integer of 0 to 4; Ar₁₁₁ and Ar₁₁₂ may each independently be a substituted or unsubstituted C₅-C₆₀ arylene group; and Ar₁₁₃ to Ar₁₁₆ may each independently be a substituted or unsubstituted C₁-C₁ alkyl group or a substituted or unsubstituted C₅-C₆₀ aryl group.
For example, in Formula 400 above, Ar₁₁₁ and Ar₁₁₂ may each independently be a phenylene group, a naphthylene group, a phenanthrenylene group, or a pyrenylene group; or a phenylene group, a naphthylene group, a phenanthrenylene group, a fluorenyl group, or a pyrenylene group substituted with at least one of a phenyl group, a naphthyl group, or an anthryl group. However, Ar₁₁₁ and Ar₁₁₂ are not limited thereto.

In Formula 400 above, g, h, i, and j may each independently be 0, 1, or 2; and Ar₁₁₃ to Ar₁₁₆ may each independently be: a C₁-C₁₀ alkyl group that is substituted with at least one of a phenyl group, a naphthyl group, or an anthryl group; or a phenyl group; a naphthyl group; an anthryl group; a pyrenyl group; a phenanthrenyl group; a fluorenyl group; or a phenyl group, a naphthyl group, an anthryl group, a pyrenyl group, a phenanthrenylene group, or a fluorenyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, or a fluorenyl group; or

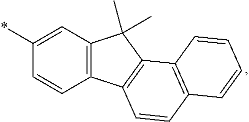 [SMILES: *c1ccc2c(c1)C(C)(C)c1c-2ccc2ccccc12]

where * represents a binding site. However, Ar₁₁₃ to Ar₁₁₆ are not limited thereto.

For example, the anthracene-based compound of Formula 400 may be one of the Compounds below, but Formula 400 is not limited thereto.

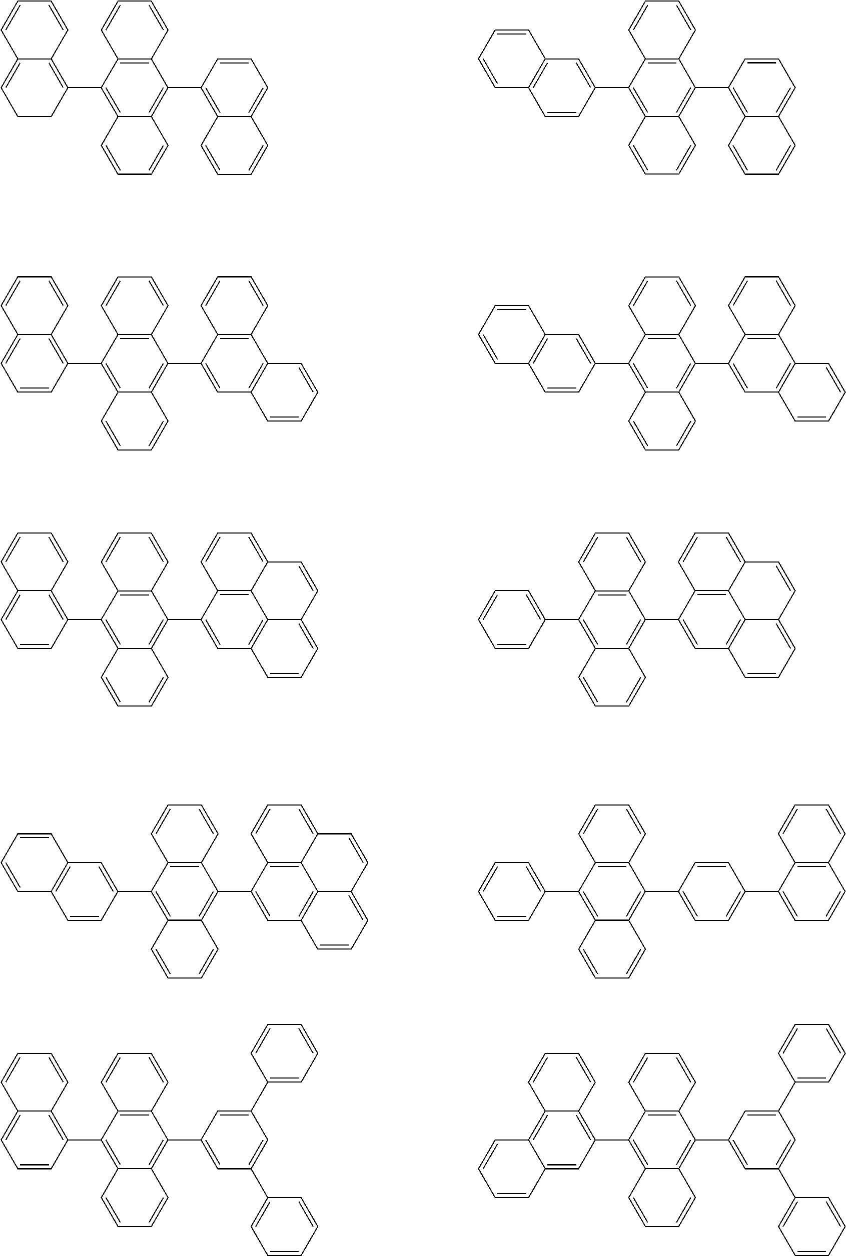

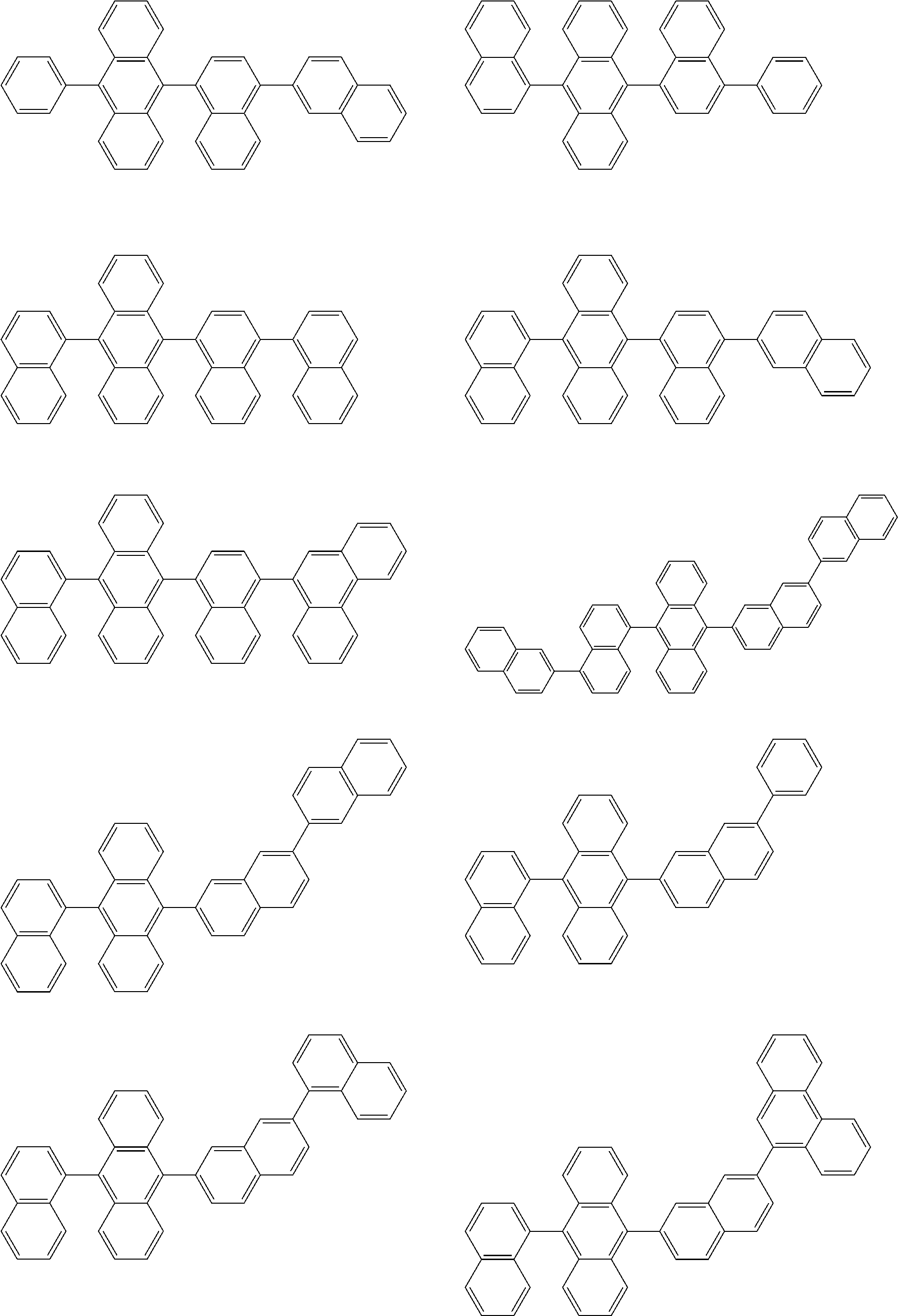

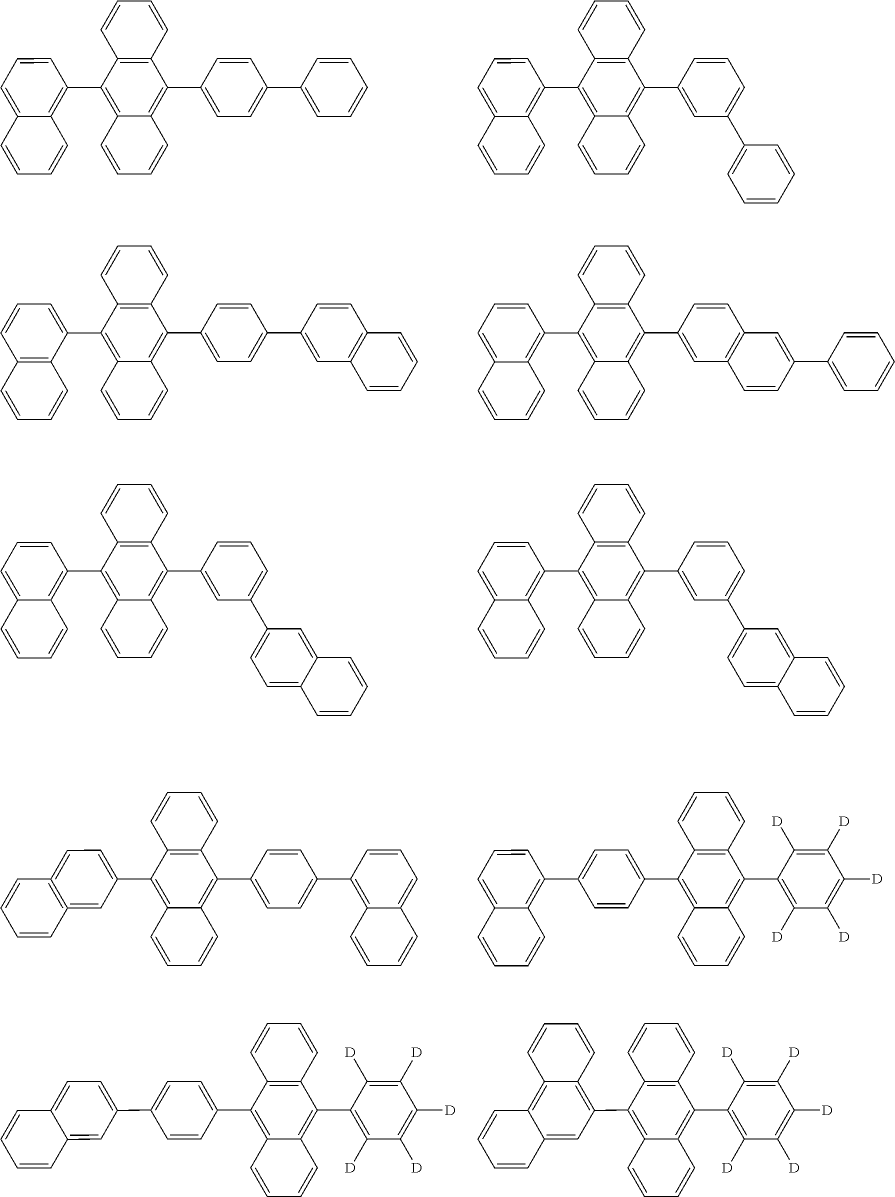

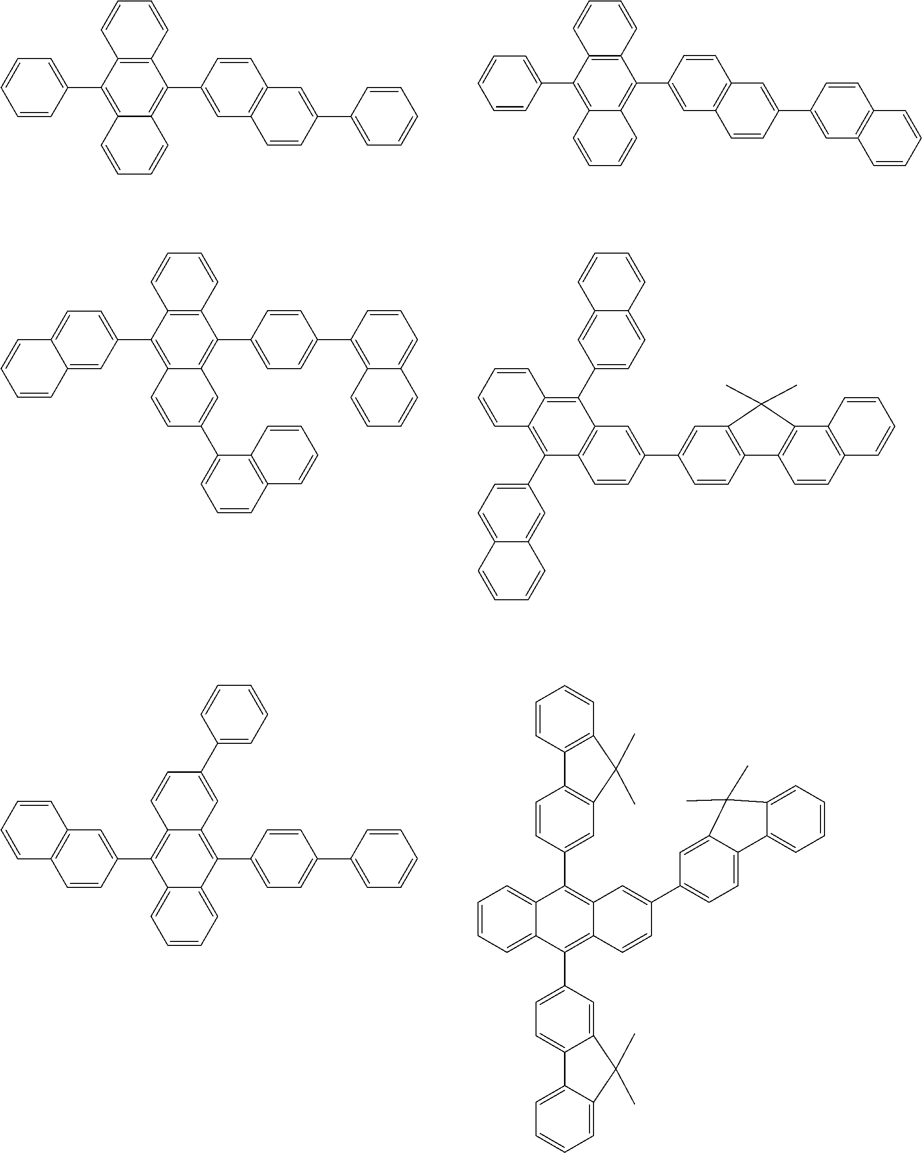

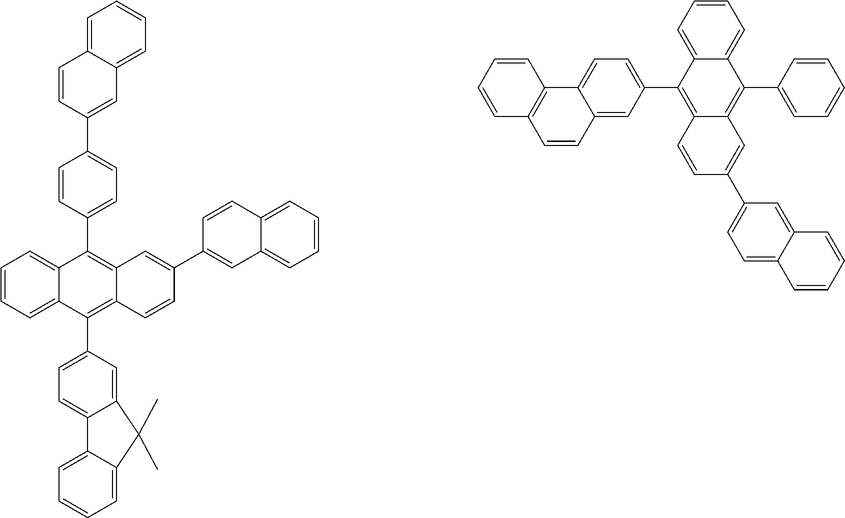

In some embodiments, an anthracene-based compound represented by Formula 401 may be used as the host.

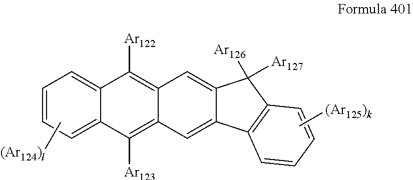

In Formula 401, Ar₁₂₂ to Ar₁₂₅ may be the same as Ar₁₁₃ of Formula 400, and the description of Ar₁₁₃ is fully incorporated here.

In Formula 401, Ar₁₂₆ and Ar₁₂₇ may each independently be a C₁-C₁₀ alkyl group (e.g., a methyl group, an ethyl group, or a propyl group).

In Formula 401, k and l may each independently be an integer from 0 to 4. For example, k and l may each independently be 0, 1, or 2.

In some embodiments, the anthracene-based compound of Formula 401 may be one of the Compounds below, but Formula 401 is not limited thereto.

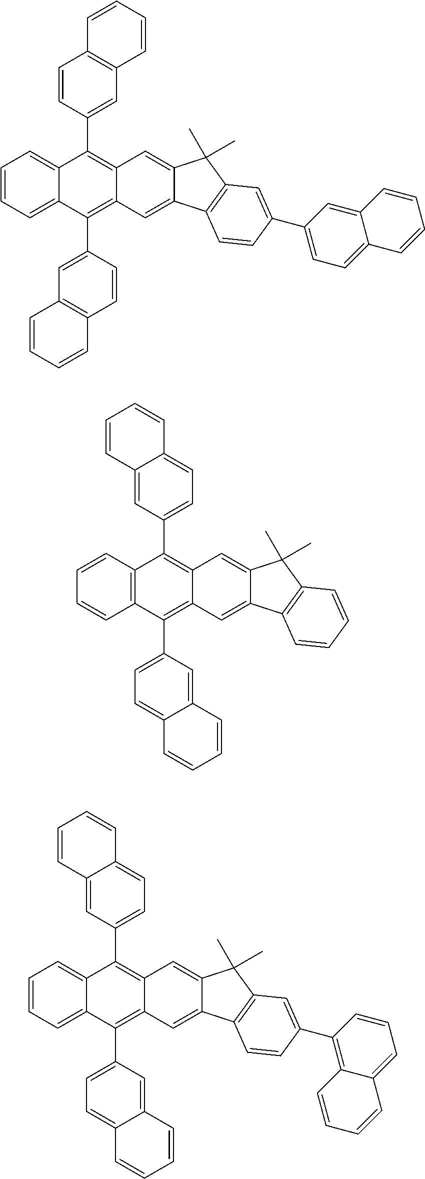

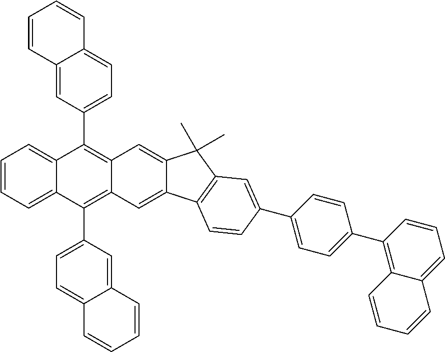 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

The dopant may be at least one of a fluorescent dopant and a phosphorescent. The phosphorescent dopant may be an organometallic complex including Ir, Pt, Os, Re, Ti, Zr, Hf, or a combination of two or more thereof, but is not limited thereto.

Non-limiting examples of the blue dopant include F₂Irpic, (F₂ppy)₂Ir(tmd), Ir(dfppz)₃, ter-fluorene, 4,4′-bis(4-diphenylaminostyryl)biphenyl (DPAVBi), 2,5,8,11-tetra-tert-butyl perylene (TBPe), and 4,4′-bis(2,2-diphenylvinyl)-1,1′-biphenyl (DPVBi), but the blue dopant is not limited thereto.

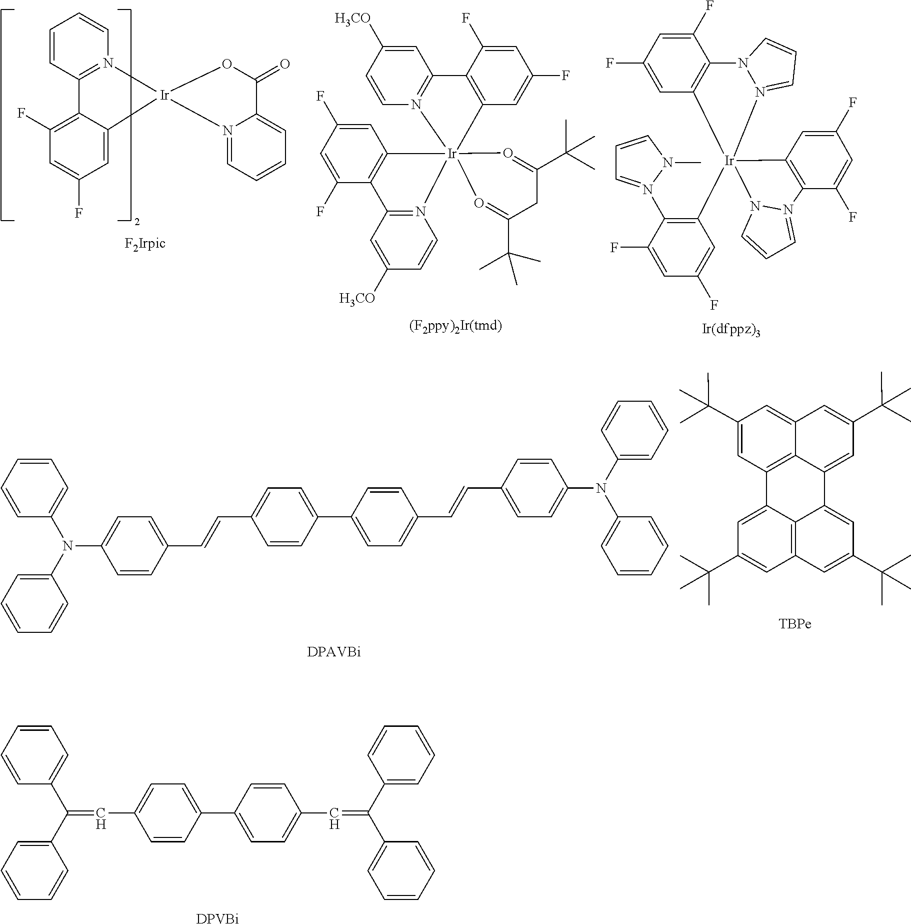

In some embodiments, the compounds below may be used as the red dopant, but the red dopant is not limited thereto. Alternatively, DCM or DCJTB, which are described below, may be used as the red dopant.

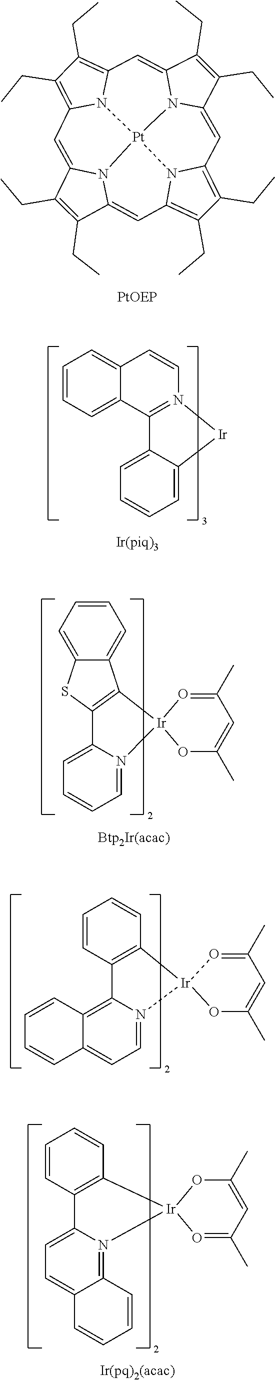

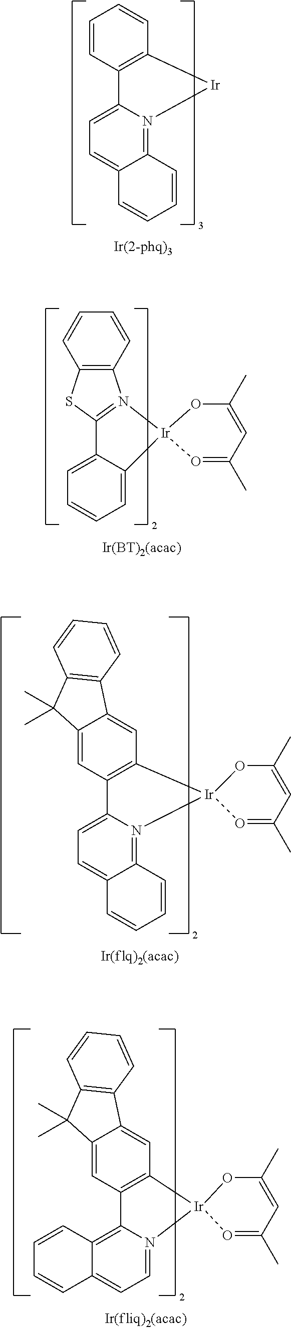

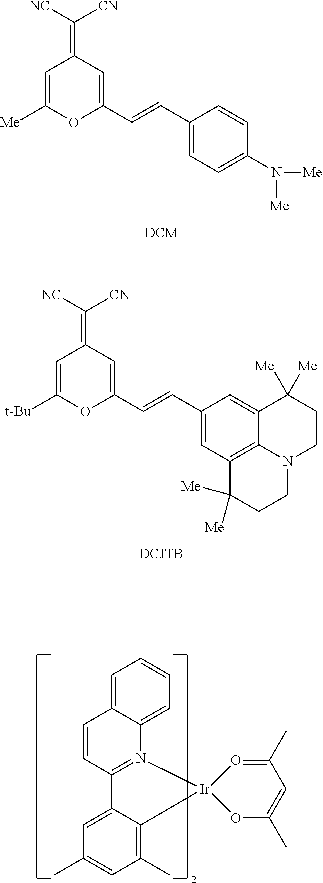

In some embodiments, the compounds below may be used as the green dopant, but the green dopant is not limited thereto. For example, C545T (shown below) may be used as the green dopant.

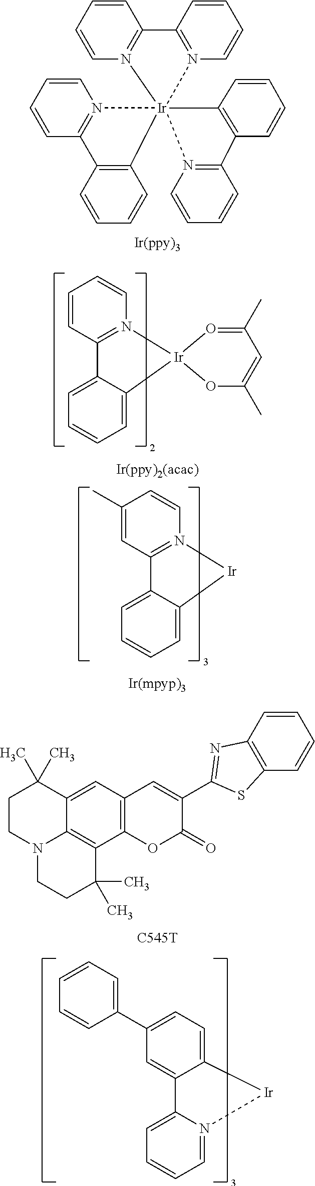

The thickness of the EML may be about 100 Å to about 1,000 Å, for example, about 200 Å to about 600 Å. When the thickness of the EML is within either of the foregoing ranges, the EML may have good light-emitting ability without a substantial increase in driving voltage.

Next, an ETL may be formed on the EML by various methods, such as vacuum deposition, spin coating, and casting. When the ETL is formed by vacuum deposition and spin coating, the vacuum deposition or coating conditions may be similar to those described above for the formation of the HIL, though the deposition and coating conditions may vary depending on the compound used to form the ETL. The ETL may be formed using the above-described material that can stably transport electrons that are injected from an electron-injecting electrode (e.g., a cathode) and an electron-transporting material commonly used in OLEDs may be used. Non-limiting examples of the electron-transporting material include a quinoline derivative, for example, Alq₃, TAZ, Balq, beryllium bis(benzoquinolin-1. 0-olate) (Bebq₂), ADN, and Compounds 201 and 202, but the electron-transporting material is not limited thereto.

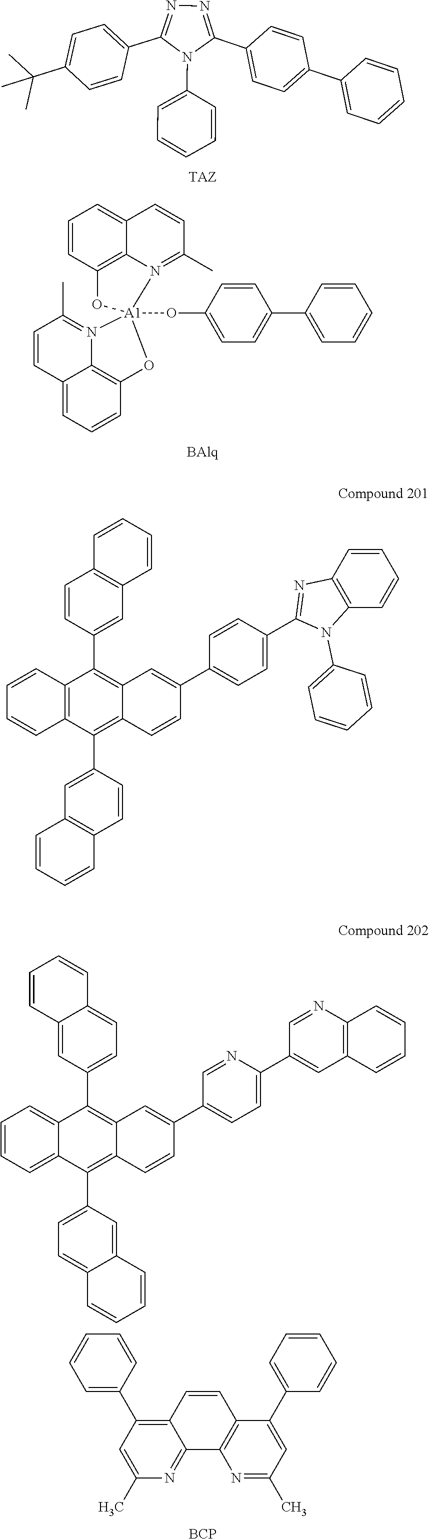

The thickness of the ETL may be about 100 Å to about 1,000 Å, and for example, about 150 Å to about 500 Å. When the thickness of the ETL is within either of the foregoing ranges, the ETL may have satisfactory electron transporting ability without a substantial increase in driving voltage.

In some embodiments, the ETL may further include a metal-containing material in addition to the above-described electron-transporting material.

The metal-containing material may include a lithium (Li) complex. Non-limiting examples of the Li complex include lithium quinolate (LiQ) and Compound 203.

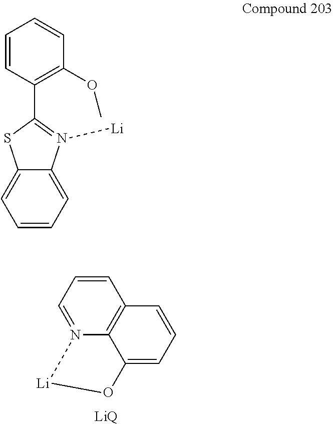

In addition, an EIL, which facilitates injection of electrons from the cathode, may be formed on the ETL. Any suitable electron injecting material may be used to form the EIL.

Any suitable electron-injecting material commonly used in OLEDs, such as LiF, NaCl, CsF, Li₂O, and BaO, may be used as the EIL-forming material. The deposition conditions may be similar to those described above for the formation of the HIL, though the conditions may vary depending on the compound used to form the EIL.

The thickness of the EIL may be about 1 Å to about 100 Å, and for example, about 3 Å to about 90 Å. When the thickness of the ETL is within either of the foregoing ranges, the ETL may have satisfactory electron injection ability without a substantial increase in driving voltage.

A second electrode 17 is on the organic layer 15. The second electrode 17 may be a cathode, which is an electron injecting electrode. Here, a material for the formation of the second electrode 17 may be a metal, an alloy, an electro-conductive compound, each of which have a low work function, or a mixture thereof. In this regard, the second electrode 17 may be formed of lithium (Li), magnesium (Mg), aluminum (Al), aluminum-lithium (Al—Li), calcium (Ca), magnesium-indium (Mg—In), and magnesium-silver (Mg—Ag), and may be formed as a thin film type transmission electrode. In some embodiments, to manufacture a top-emission light-emitting device, the transmission electrode may be formed of indium tin oxide (ITO) or indium zinc oxide (IZO).

Although the organic light-emitting device has been described with reference to FIG. 1, the present invention is not limited thereto.

In addition, when a phosphorescent dopant is used in the EML, an HBL is formed between the HTL and the EML, or between the H-functional layer and the EML, to prevent (or reduce) the diffusion of triplet excitons or holes into the ETL. The HBL may be formed by various methods, such as vacuum deposition, casting and LB deposition. When the HBL is formed by vacuum deposition or spin coating, the vacuum deposition conditions or spin coating conditions may be similar to those described above for the formation of the HIL, though the conditions may vary depending on the compound used to form the HBL. Any suitable hole-blocking material commonly used in OLEDs may be used, and non-limiting examples thereof include an oxadiazole derivative, a triazole derivative, and a phenanthroline derivative. For example, BCP may be used as the HBL-forming material.

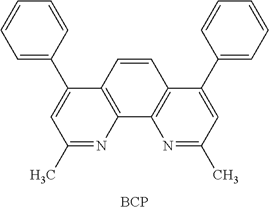 [SMILES: Cc1cc(-c2ccccc2)c2ccc3c(-c4ccccc4)cc(C)nc3c2n1 ; "BCP"]

The thickness of the HBL may be about 20 Å to about 1,000 Å, and for example, about 30 Å to about 300 Å. When the thickness of the HBL is within either of the foregoing ranges, the HBL may have good hole blocking ability without a substantial increase in driving voltage.

The light-emitting material represented by one of Formulas 1 and 2 may have a wide energy gap, and its triplet energy may be suitable for phosphorescent light emission. In addition, an OLED including the above-described light-emitting material exhibits high efficiency.

The hole-transporting material represented by one of Formulas 2(1) and 2(2) has a structure in which a carbazole-based ring is bonded to a first carbon of a first benzene and a second benzene is bonded to a meta position of the first benzene relative to the carbazole-based ring. The first benzene ring, the second benzene ring, first carbon and meta position are shown in Formulas 2(1)′ and 2(2)′. Thus, compared to a compound having a structure in which the second benzene is bonded to the para position of the first benzene relative to the carbazole-based ring, the hole-transporting material according to embodiments of the present invention may have a low (HOMO) energy level (based on the measured value) and slow hole mobility. Hole mobility is generally faster than electron mobility, and thus, an OLED including a compound represented by one of Formulas 2(1) and 2(2) in a hole-transporting region between an anode and an EML may achieve a balance between hole mobility and electron mobility to the EML. In addition, the hole-transporting material may block leakage of electrons from the EML to the HTL (e.g., electrons injected from the second electrode or cathode). Therefore, an OLED including a compound represented by one of Formulas 2(1) and 2(2) in the hole-transporting region may exhibit high efficiency and long lifespan.

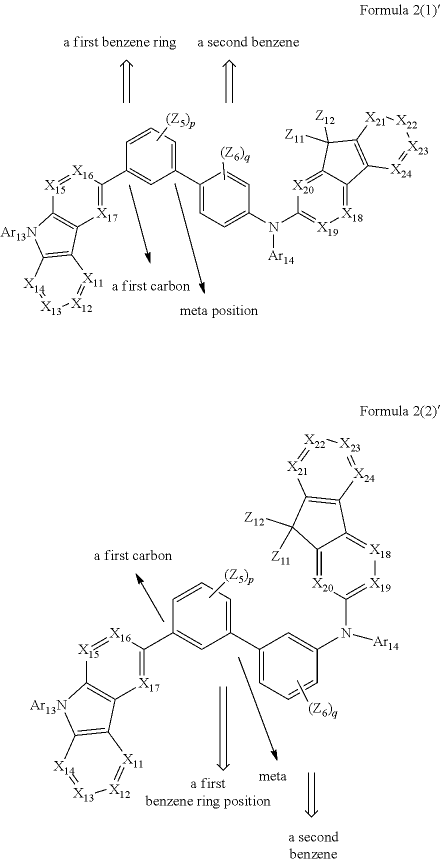

The OLED including the light-emitting material of one of Formulas 1 and 2 and the hole-transporting material of one of Formulas 2(1) and 2(2) may include a suitable material as a host in the EML for phosphorescent emission, and may form excitons in the EML to exhibit high efficiency. Also the leakage of electrons from the EML to the HTL may be minimized (or reduced), and thus, most (or a substantial portion) of the excitons formed in the EML may contribute to light emission. Therefore, when the driving voltage of the OLED increases, a decrease in efficiency is relatively small (e.g., the OLED exhibits low roll-off) The relationship between OLED luminance and efficiency is shown in the graphs in FIGS. 2 and 3.

Accordingly, an OLED including the light-emitting material of one of Formulas 1 and 2 and the hole-transporting material of one of Formulas 2(1) and 2(2) may exhibit low driving voltage, high efficiency, and high color purity.

In particular, the EML including the light-emitting material of one of Formulas 1 and 2 and the HTL including the hole-transporting material of one of Formulas 2(1) and 2(2) may be in contact with each other, but the present invention is not limited thereto.

FIGS. 4 and 5 are cross-sectional views, each schematically illustrating the structure of an OLED 10 according to an embodiment of the present disclosure.

The OLED 10 may include a substrate 11 that is partitioned into a first sub-pixel region, a second sub-pixel region, and a third sub-pixel region. A first electrode may be disposed in each of the first, second, and third sub-pixel regions of the substrate, and a second electrode may be disposed opposite to the first electrode. The OLED 10 may further include a first sub-pixel electrode 13A disposed in the first sub-pixel region of the substrate, a first buffer layer 150A disposed on the first sub-pixel electrode 13A, and a first emission layer 160A disposed on the first buffer layer 150A. Additionally, the OLED 10 may include a second sub-pixel electrode 13B disposed in the second sub-pixel region of the substrate, a second buffer layer 150B disposed on the second sub-pixel electrode 13B, and a second emission layer 160B disposed on the second buffer layer 150B. Further, the OLED 10 may include a third sub-pixel electrode 13C disposed in the third sub-pixel region of the substrate, and a third emission layer 160C disposed on the third sub-pixel electrode 13C.

The first emission layer 160A may include at least one light-emitting material represented by any one of Formulas 1 and 2, and the second buffer layer 150B may include or consist of the at least one hole-transporting material represented by any one of Formulas 2(1) and 2(2). Alternatively, the second emission layer 160B may include at least one light-emitting material represented by any one of Formulas 1 and 2, and the first buffer layer 150A may include or consist of the at least one hole-transporting material represented by any one of Formulas 2(1) and 2(2).

In one or more embodiments, the first emission layer 160A may emit a first color light, the second emission layer 160B may emit a second color light, and the third emission layer 160C may emit a third color light. In one or more embodiments, the first color light may be red, the second color light may be green, and the third color light may be blue.

In one or more embodiments, the second emission layer 160B may include the light emitting material, the first buffer layer 150A may include the hole-transporting material, and the second buffer layer 150B may include at least one compound represented by Formula 300 or 301. In one or more embodiments, the second buffer layer 150B may include at least one of Compounds 301 to 320.

In one or more embodiments, the OLED 10 may further include a hole transport layer 140 disposed between the first and second buffer layers 150A, 150B, and the first, second, and third third sub-pixel electrode 13A, 13B, 13C.

In one or more embodiments, the hole transport layer 140 may include at least one compound represented by one of Formula 300 and Formula 301. In one or more embodiments, the hole transport layer 140 may include at least one of Compounds 301 to 320. In one or more embodiments, the second buffer layer 150B may include the same compound as that included in the hole transport layer 140.

As used herein, the C₁-C₆₀ alkyl group may be an unsubstituted C₁-C₆₀ alkyl group or a substituted C₁-C₆₀ alkyl group. Non-limiting examples of the unsubstituted C₁-C₆₀ alkyl group include a linear or a branched C₁-C₆₀ alkyl group, such as a methyl group, an ethyl group, a propyl group, an iso-butyl group, a sec-butyl group, a pentyl group, an iso-amyl group, and a hexyl group. The substituted C₁-C₆₀ alkyl group refers to the substitution of at least one hydrogen atom of the unsubstituted C₁-C₆₀ alkyl group with a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₁-C₆₀ heteroaryl group, —N(Q₁₁)(Q₁₂), or —Si(Q₁₃)(Q₁₄)(Q₁₅) (where Q₁₁ to Q₁₅ are each independently selected from the group consisting of a hydrogen atom, a C₁-C₆₀ alkyl group, a C₂-C₆₀ alkenyl group, a C₂-C₆₀ alkynyl group, a C₆-C₆₀ aryl group, and a C₁-C₆₀ heteroaryl group).

As used herein, the C₁-C₆₀ alkoxy group may be an unsubstituted C₁-C₆₀ alkoxy group or a substituted C₁-C₆₀ alkoxy group. The unsubstituted C₁-C₆₀ alkoxy group may have a formula of —OA (where, A is an unsubstituted C₁-C₆₀ alkyl group as described above). Non-limiting examples of the unsubstituted C₁-C₆₀ alkoxy group include a methoxy group, an ethoxy group, and an isopropyloxy group. Here, the substituted C₁-C₆₀ alkoxy group refers to the substitution of at least one hydrogen atom of the unsubstituted C₁-C₆₀ alkoxy group with the same substituents as described above in connection with the substituted C₁-C₆₀ alkyl group.

As used herein, the C₂-C₆₀ alkenyl group may be an unsubstituted C₂-C₆₀ alkenyl group or a substituted C₂-C₆₀ alkenyl group. The unsubstituted C₂-C₆₀ alkenyl group refers to an unsubstituted C₂-C₆₀ alkyl group having one or more carbon-carbon double bonds inserted at the body (e.g., the center) or at a terminal end of the alkyl group. Non-limiting examples of the unsubstituted C₂-C₆₀ alkenyl group include an ethenyl group, a propenyl group, and a butenyl group. The substituted C₂-C₆₀ alkenyl group refers to the substitution of at least one hydrogen atom of the unsubstituted C₂-C₆₀ alkenyl group with the same substituents as described above in connection with the substituted C₁-C₆₀ alkyl group.

As used herein, the C₂-C₆₀ alkynyl group may be an unsubstituted C₂-C₆₀ alkynyl group or a substituted C₂-C₆₀ alkynyl group. The unsubstituted C₂-C₆₀ alkynyl group refers to an unsubstituted C₂-C₆₀ alkyl group having one or more carbon-carbon triple bonds inserted at the body (e.g., the center) or at a terminal end of the alkyl group. Non-limiting examples of the unsubstituted C₂-C₆₀ alkynyl group include an ethynyl group and a propenyl group. The substituted C₂-C₆₀ alkenyl group refers to the substitution of at least one hydrogen atom of the unsubstituted C₂-C₆₀ alkynyl group with the same substituents as described above in connection with the substituted C₁-C₆₀ alkyl group.

As used herein, the C₆-C₆₀ aryl group may be an unsubstituted C₆-C₆₀ aryl group or a substituted C₆-C₆₀ aryl group. The unsubstituted C₆-C₆₀ aryl group refers to a monovalent group having a carbocyclic aromatic system having 6 to 60 carbon atoms including at least one aromatic ring. The unsubstituted C₆-C₆₀ arylene group refers to a divalent group having a carbocyclic aromatic system having 6 to 60 carbon atoms including at least one aromatic ring. When the aryl group and the arylene group include two or more rings, the rings may be fused to each other by a single bond. The substituted C₆-C₆₀ aryl group refers to the substitution of at least one hydrogen atom of the aryl group with the same substituents as described above in connection with the substituted C₁-C₆₀ alkyl group. The substituted C₆-C₆₀ arylene group refers to the substitution of at least one hydrogen atom of the arylene group with the same substituents as described above in connection with the substituted C₁-C₆₀ alkyl group.

Non-limiting examples of the substituted or unsubstituted C₆-C₆₀ aryl group include a phenyl group, a C₁-C₁₀ alkylphenyl group (i.e., an ethylphenyl group), a C₁-C₁₀ alkylbiphenyl group (i.e., an ethylbiphenyl group), a halophenyl group (i.e., an o-, m-, and p-fluorophenyl group, a dichlorophenyl group), a dicyanophenyl group, a trifluoromethoxyphenyl group, o-, m-, and p-tolyl group, o-, m-, and p-cumenyl groups, a mosityl group, a phenoxyphenyl group, an (α,α-dimethylbenzene)phenyl group, an (N,N′-dimethyl)aminophenyl group, an (N,N′-diphenyl)aminophenyl group, a pentalenyl group, an indenyl group, a naphthyl group, a halonaphthyl group (i.e., a fluoronaphthyl group), a C₁-C₁₀ alkylnaphthyl group (i.e., a methylnaphthyl group), a C₁-C₁₀ alkoxynaphthyl group (i.e., a methoxynaphthyl group), an anthracenyl group, an azulenyl group, a heptalenyl group, an acenaphthylenyl group, a phenalenyl group, a fluorenyl group, an anthraquinolinyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, an obarenyl group, and a spiro-fluorenyl group. Additional non-limiting examples of the substituted C₆-C₆₀ aryl group may be inferred from the foregoing non-limiting examples of the unsubstituted C₆-C₆₀ aryl group and the substituents described above in connection with the substituted C₁-C₆₀ alkyl group. Non-limiting examples of the substituted or unsubstituted C₆-C₆₀ arylene group may be inferred from the foregoing non-limiting examples of the substituted or unsubstituted C₆-C₆₀ aryl group.

As used herein, the C₁-C₆₀ heteroaryl group may be an unsubstituted C₁-C₆₀ heteroaryl group or a substituted C₁-C₆₀ heteroaryl group. The unsubstituted C₁-C₆₀ heteroaryl group refers to a monovalent group having a system composed of one or more aromatic rings having at least one heteroatom, e.g., N, O, P, and S, as a ring-forming atom, and carbon atoms as the remaining ring atoms. The unsubstituted C₁-C₆₀ heteroarylene group refers to a divalent group having a system composed of one or more aromatic rings having at least one heteroatom, e.g., N, O, P, and S, and carbon atoms as the remaining ring atoms. For example, when the heteroaryl group and the heteroarylene group each include two or more rings, the rings may be fused to each other or connected to each other via a single bond. The substituted C₁-C₆₀ heteroaryl group refers to the substitution of at least one hydrogen atom of the heteroaryl group with the same substituents described above in connection with the C₁-C₆₀ alkyl group. The substituted C₁-C₆₀ heteroarylene group refers to the substitution of at least one hydrogen atom of the heteroarylene group with the same substituents described above in connection with the C₁-C₆₀ alkyl group.

Non-limiting examples of the unsubstituted C₁-C₆₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzimidazolyl group, an imidazopyridinyl group, an imidazopyrimidinyl group, a furanyl group, a thiophenyl group, a benzofuranyl group, a benzothiophenyl group, a dibenzofuranyl group, and a dibenzothiophenyl group. Non-limiting examples of the substituted C₁-C₆₀ heteroaryl group may be inferred from the foregoing non-limiting examples of the unsubstituted C₁-C₆₀ heteroaryl group and the substituents described above in connection with the substituted C₁-C₆₀ alkyl group. Non-limiting examples of the substituted or unsubstituted C₁-C₆₀ heteroarylene group may be inferred from the foregoing non-limiting examples of the substituted or unsubstituted C₁-C₆₀ heteroaryl groups.

The substituted or unsubstituted C₆-C₆₀ aryloxy group refers to a group represented by —OA₂ (where A₂ is a substituted or unsubstituted C₆-C₆₀ aryl group as described above). The substituted or unsubstituted C₆-C₆₀ arylthio group refers to a group represented by —SA₃ (where A₃ is a substituted or unsubstituted C₆-C₆₀ aryl group as described above).

Hereinafter, embodiments of the present invention will be described by reference to the following examples. However, these examples are presented for illustrative purposes only, and are not intended to limit the scope of the present invention

### EXAMPLE

### Example 1

As an anode, ITO/Ag/ITO layers having a thickness of 7 nm/100 nm/7 nm, respectively, were deposited on a glass substrate which was cut to a size of 50 mm×50 mm×0.7 mm, and then sonicated (ultrasonically washed) in isopropyl alcohol for 30 minutes and sonicated in pure water for 30 minutes, and then cleaned by irradiation of ultraviolet rays for 10 minutes and exposure to ozone. The glass substrate was then loaded into a vacuum deposition device.

Compound B (shown below) was vacuum-deposited on the ITO layer, which is the anode, to form an HIL having a thickness of 1,200 Å, and Compound 6-12 was deposited on the HIL to a thickness of 350 Å to form an HTL.

Compound 49 (as a host) and Compound D(1) (as a dopant; shown below) were co-deposited at a weight ratio of 10:1 on the HTL to form an EML having a thickness of 400 Å.

Then, Compound 201 and LiQ were co-deposited at a weight ratio of 1:1 on the EML to form an ETL having a thickness of 300 Å. LiQ was deposited on the ETL to form an EIL having a thickness of 5 Å, followed by depositing Mg—Ag at a weight ratio of 10:1 on the EIL to form a second electrode (cathode) having a thickness of 130 Å, thereby completing the manufacture of an OLED.

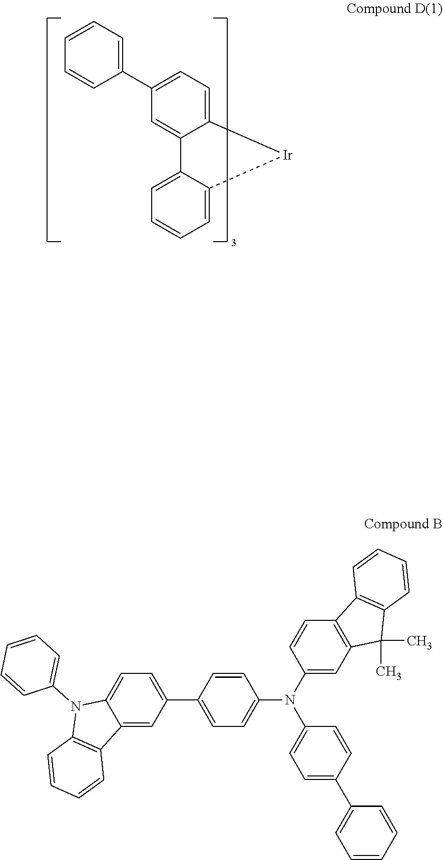

### Example 2

An OLED was manufactured as in Example 1, except that Compound 6-132 was used instead of Compound 6-12 to form the HTL, and Compound 61 was used instead of Compound 49 to form the EML.

### Example 3

An OLED was manufactured as in Example 1, except that Compound 6-84 was used instead of Compound 6-12 to form the HTL, and Compound 80 was used instead of Compound 49 to form the EML.

### Example 4

An OLED was manufactured as in Example 1, except that Compound 6-36 was used instead of Compound 6-12 to form the HTL, and Compound 99 was used instead of Compound 49 to form the EML.

### Example 5

An OLED was manufactured as in Example 1, except that Compound 6-4 was used instead of Compound 6-12 to form the HTL, and Compound 104 was used instead of Compound 49 to form the EML.

### Example 6

An OLED was manufactured as in Example 1, except that Compound 6-10 was used instead of Compound 6-12 to form the HTL, and Compound 50 was used instead of Compound 49 to form the EML.

### Example 7

An OLED was manufactured as in Example 1, except that Compound 34 and Compound D(2) (shown below) were used instead of Compound 49 and Compound D(1) (shown above), respectively, to form the EML.

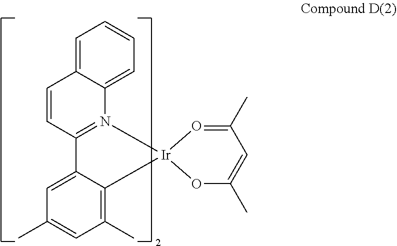

### Example 8

An OLED was manufactured as in Example 7, except that Compound 6-132 was used instead of Compound 6-12 to form the HTL, and Compound 32 was used instead of Compound 34 to form the EML.

### Example 9

An OLED was manufactured as in Example 7, except that Compound 6-84 was used instead of Compound 6-12 to form the HTL, and Compound 81 was used instead of Compound 34 to form the EML.

### Example 10

An OLED was manufactured as in Example 7, except that Compound 6-36 was used instead of Compound 6-12 to form the HTL, and Compound 82 was used instead of Compound 34 to form the EML.

### Example 11

An OLED was manufactured as in Example 7, except that Compound 6-4 was used instead of Compound 6-12 to form the HTL, and Compound 83 was used instead of Compound 34 to form the EML.

### Example 12

An OLED was manufactured as in Example 7, except that Compound 6-10 was used instead of Compound 6-12 to form the HTL, and Compound 84 was used instead of Compound 34 to form the EML.

### Comparative Example 1

An OLED was manufactured as in Example 1, except that Compound A (shown below) was used instead of Compound 6-12 to form the HTL, and Compound 61 was used instead of Compound 49 to form the EML.

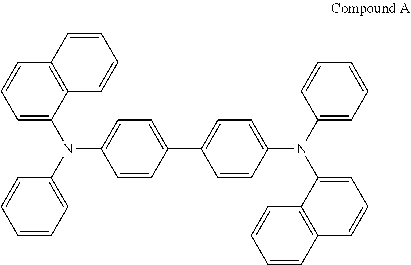 [SMILES: c1ccc(N(c2ccc(-c3ccc(N(c4ccccc4)c4cccc5ccccc45)cc3)cc2)c2cccc3ccccc23)cc1]

### Comparative Example 2

An OLED was manufactured as in Example 1, except that Compound B (shown below) was used instead of Compound 6-12 to form the HTL, and Compound 61 was used instead of Compound 49 to form the EML.

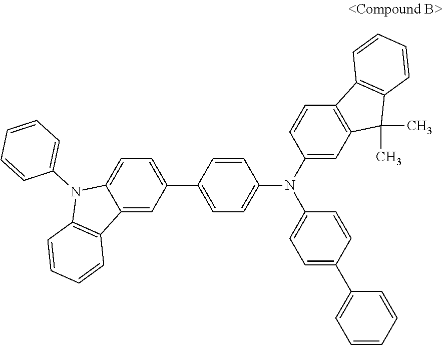 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

### Comparative Example 3

An OLED was manufactured as in Example 7, except that Compound A (shown above) was used instead of Compound 6-12 to form the HTL, and Compound 83 was used instead of Compound 34 to form the EML.

### Comparative Example 4

An OLED was manufactured as in Example 7, except that Compound B (shown above) was used instead of Compound 6-12 to form the HTL, and Compound 83 was used instead of Compound 34 to form the EML.

### Evaluation Example

The driving voltages, current densities, efficiencies, and color purities of the OLEDs of Examples 1 to 12 and Comparative Examples 1 to 4 were evaluated by supplying power from a voltage and current meter (a Source Measurement Unit 236 obtained from Keithley Instruments Inc.) and by a luminance meter (a PR650 Spectrascan Colorimeter obtained from Photo Research, Inc.). The OLEDs of Example 1 to 6 and Comparative Examples 1 and 2 were evaluated at a luminance of 9,000 cd/m², and the OLEDs of Example 7 to 12 and Comparative Examples 3 and 4 were measured at a luminance of 3,000 cd/m². The results are shown in Table 1.

TABLE 1

| | Driving | Current | Lumi- | | Color | |
|---|---|---|---|---|---|---|
| | voltage | density | nance | Power | coordinates | |
| | (V) | (mA/cm²) | (cd/A) | (lm/W) | CIE_x | CIE_y |
| Example 1 | 4.8 | 8.6 | 104.4 | 69.0 | 0.227 | 0.732 |
| Example 2 | 4.4 | 8.7 | 103.1 | 73.2 | 0.212 | 0.742 |
| Example 3 | 4.5 | 8.7 | 103.8 | 73.2 | 0.308 | 0.672 |
| Example 4 | 4.9 | 8.9 | 101.6 | 65.0 | 0.229 | 0.734 |
| Example 5 | 4.6 | 8.9 | 101.5 | 69.1 | 0.287 | 0.690 |
| Example 6 | 4.5 | 8.9 | 101.3 | 71.4 | 0.220 | 0.737 |
| Example 7 | 4.5 | 7.3 | 41.0 | 28.7 | 0.657 | 0.341 |
| Example 8 | 4.7 | 7.1 | 42.4 | 28.2 | 0.651 | 0.347 |
| Example 9 | 4.6 | 7.6 | 39.4 | 26.8 | 0.661 | 0.337 |
| Example 10 | 5.0 | 7.4 | 40.7 | 25.7 | 0.669 | 0.329 |
| Example 11 | 4.8 | 7.3 | 41.1 | 26.9 | 0.659 | 0.339 |
| Example 12 | 4.9 | 7.3 | 41.1 | 26.5 | 0.652 | 0.348 |
| Comparative | 4.6 | 12.4 | 72.4 | 49.5 | 0.293 | 0.685 |
| Example 1 | | | | | | |
| Comparative | 4.6 | 12.3 | 73.5 | 49.7 | 0.279 | 0.695 |
| Example 2 | | | | | | |
| Comparative | 4.7 | 9.8 | 30.6 | 20.3 | 0.671 | 0.327 |
| Example 3 | | | | | | |
| Comparative | 4.6 | 9.5 | 31.4 | 21.7 | 0.658 | 0.340 |
| Example 4 | | | | | | |

Referring to Table 1 above, it can be seen that the OLEDs of Examples 1 to 12 exhibit lower driving voltages, higher efficiencies, and better color purities than the OLEDs of Comparative Example 1 to 4.

As described above, according to aspects of one or more embodiments of the present invention, an organic light-emitting device may exhibit a low driving voltage, high efficiency, and high color purities.

While certain exemplary embodiments of the present invention have been illustrated and described, it will be understood by those of ordinary skill in the art that various changes may be made to the disclosed embodiments without departing from the spirit and scope of the present invention as defined by the following claims.

What is claimed is:

1. An organic light-emitting device, comprising:
a substrate comprising a first sub-pixel region, a second sub-pixel region, and a third sub-pixel region;
a first sub-pixel electrode disposed in the first sub-pixel region of the substrate,
a first buffer layer disposed on the first sub-pixel electrode,
a first emission layer disposed on the first buffer layer,
a second sub-pixel electrode disposed in the second sub-pixel region of the substrate,
a second buffer layer disposed on the second sub-pixel electrode,
a second emission layer disposed on the second buffer layer,
a third sub-pixel electrode disposed in the third sub-pixel region of the substrate,
a third emission layer disposed on the third sub-pixel electrode, with the proviso that either one of conditions (i) and (ii) below is met:
(i) the first emission layer comprises at least one light-emitting material represented by any one of Formulas 1-1, 1-2, 1-5, 1-6, 1-9, 1-10, 1-13, 1-14, and 1-17 to 1-24, and
the second buffer layer consists of the at least one hole-transporting material represented by any one of Formulas 2(1) and 2(2), or
(ii) the second emission layer comprises at least one light-emitting material represented by any one of Formulas 1-1, 1-2, 1-5, 1-6, 1-9, 1-10, 1-13, 1-14, and 1-17 to 1-24, and
the first buffer layer consists of the at least one hole-transporting material represented by any one of Formulas 2(1) and 2(2); 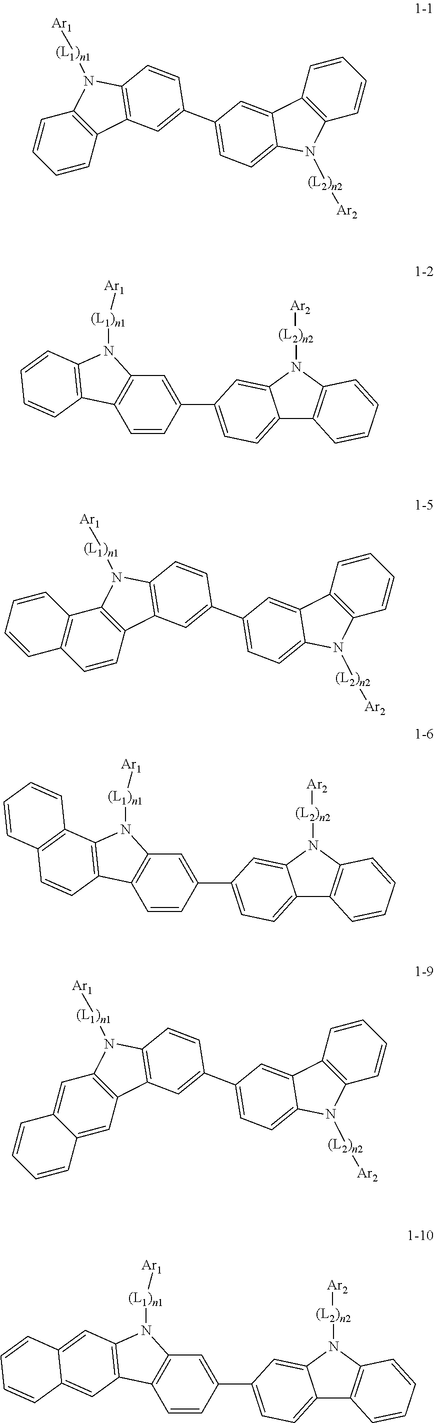 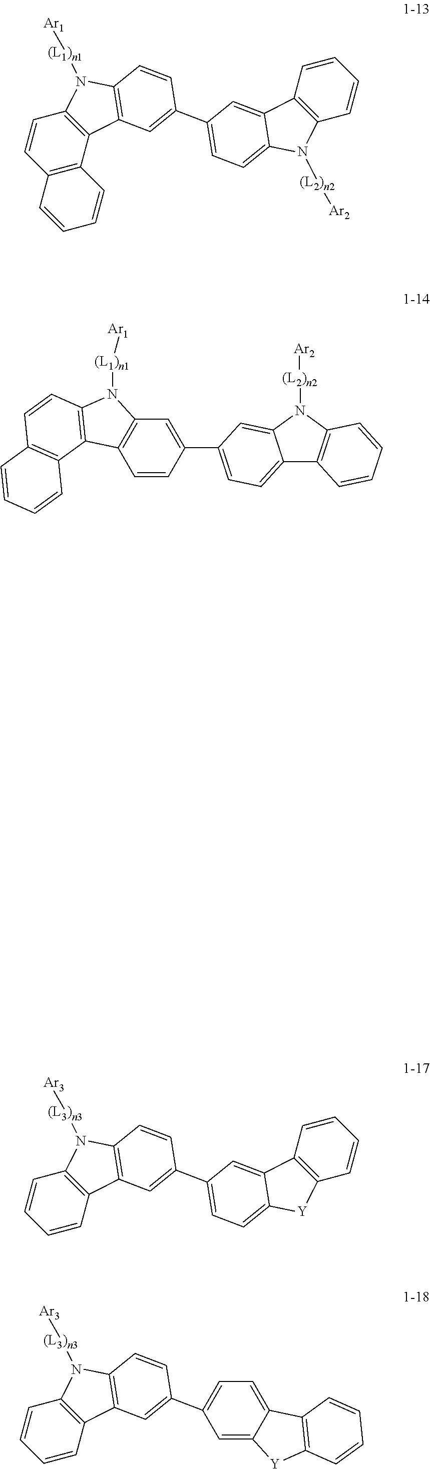 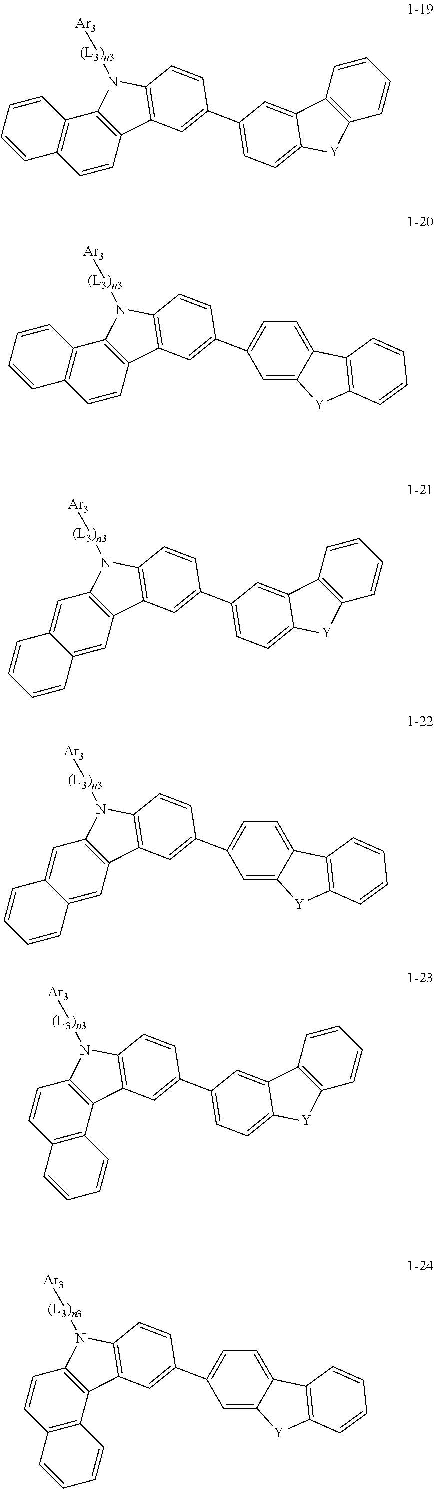
wherein, in Formulae 1-1, 1-2, 1-5, 1-6, 1-9, 1-10, 1-13, 1-14, and 1-17 to 1-24,
Y is O, S, or C(R₃₁)(R₃₂);
L₁ and L₂ are each independently selected from a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₁-C₁₀ heterocycloalkylene group, and a substituted or unsubstituted C₁-C₁₀ heterocycloalkenylene group;
L₃ is selected from a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₁-C₁₀ heterocycloalkylene group, a substituted or unsubstituted C₁-C₁₀ heterocycloalkenylene group, and a substituted or unsubstituted C₁-C₆₀ heteroarylene group;
n1 to n3 are each independently an integer of 0 to 3;
Ar₁ and Ar₂ are each independently selected from
i) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, and —Si(Q₁)(Q₂)(Q₃) (here, Q₁ to Q₃ are each independently a substituted or unsubstituted C₁-C₁₀ alkyl group or a substituted or unsubstituted C₆-C₃₀ aryl group); and
ii) a C₃-C₁₀ cycloalkyl group, a C₁-C₁₀ heterocycloalkyl group, a C₃-C₁₀ cycloalkenyl group, a C₁-C₁₀ heterocycloalkenyl group, and a C₆-C₆₀ aryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, and
—Si(Q₁)(Q₂)(Q₃) (here, Q₁ to Q₃ are each independently a substituted or unsubstituted C₁-C₁ alkyl group or a substituted or unsubstituted C₆-C₃₀ aryl group);
Ar₃ is selected from
i) a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₁-C₆₀ heteroaryl group, and —Si(Q₁)(Q₂)(Q₃) (here, Q₁ to Q₃ are each independently a substituted or unsubstituted C₁-C₁ alkyl group or a substituted or unsubstituted C₆-C₃₀ aryl group); and
ii) a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, and a C₁-C₆₀ heteroaryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, a C₁-C₆₀ heteroaryl group, and —Si(Q₁)(Q₂)(Q₃) (here, Q₁ to Q₃ are each independently a substituted or unsubstituted C₁-C₁ alkyl group or a substituted or unsubstituted C₆-C₃₀ aryl group);
R₃₁, and R₃₂ are each independently selected from:
i) a hydrogen atom, a deuterium atom, a C₁-C₆₀ alkyl group, a C₂-C₆₀ alkenyl group, a C₂-C₆₀ alkynyl group, and a C₁-C₆₀ alkoxy group;
ii) a C₁-C₆₀ alkyl group, a C₂-C₆₀ alkenyl group, a C₂-C₆₀ alkynyl group, and a C₁-C₆₀ alkoxy group, each substituted with at least one substituent selected from a deuterium atom, a halogen atom, a hydroxyl group, a cyano group, a nitro group, an amino group, an amidino group, a hydrazine, a hydrazone, a carboxyl group or a salt thereof, a sulfonic acid or a salt thereof, and a phosphoric acid or a salt thereof, a C₃-C₁₀ cycloalkyl group, a C₁-C₁₀ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group;
iii) a C₃-C₁ cycloalkyl group, C₁-C₁ heterocycloalkyl group, a C₃-C₁ cycloalkenyl group, a C₁-C₁ heterocycloalkenyl group, a C₆-C₆₀ aryl group, and a C₁-C₆₀ heteroaryl group; and
iv) a C₃-C₁ cycloalkyl group, a C₁-C₁ heterocycloalkyl group, a C₃-C₁ cycloalkenyl group, a C₁-C₁ heterocycloalkenyl group, a C₆-C₆₀ aryl group, and a C₁-C₆₀ heteroaryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁a cycloalkyl group, a C₁-C₁ heterocycloalkyl group, a C₃-C₁ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group;
o1 to o4 are each independently an integer of 0 to 3; 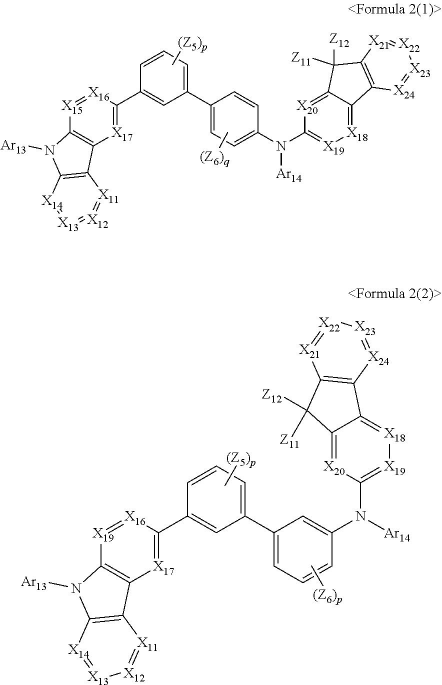
wherein, in Formulae 2(1) and 2(2),
X₁₁ is CR₁₁ or N; X₁₂ is CR₁₂ or N; X₁₃ is CR₁₃ or N; X₁₄ is CR₁₄ or N; X₁₅ is CR₁₅ or N; X₁₆ is CR₁₆ or N; X₁₇ is CR₁₇ or N; X₁₈ is CR₁₈ or N; X₁₉ is CR₁₉ or N; X₂₀ is CR₂₀ or N; X₂₁ is CR₂₁ or N; X₂₂ is CR₂₂ or N; X₂₃ is CR₂₃ or N; and X₂₄ is CR₂₄ or N;
Z₅, Z₆, and R₁₁ to R₂₄ are each independently selected from:
i) a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
ii) a C₁-C₆₀ alkyl group, a C₂-C₆₀ alkenyl group, a C₂-C₆₀ alkynyl group, and a C₁-C₆₀ alkoxy group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group;
iii) a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, and a C₁-C₆₀ heteroaryl group;
iv) a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, and a C₁-C₆₀ heteroaryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group; and
v) —N(Q₁₁)(Q₁₂), —Si(Q₁₃)(Q₁₄)(Q₁₅), and —B(Q₁₆)(Q₁₇) (here, Q₁₁ and Q₁₇ are each independently a C₁-C₆₀ alkyl group, a C₁-C₆₀ alkoxy group, a C₆-C₆₀ aryl group, or a C₂-C₆₀ heteroaryl group);
Ar₁₃ and Ar₁₄ are each independently selected from:
i) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, and a C₁-C₆₀ heteroaryl group; and
ii) a C₃-C₁₀ cycloalkyl group, a C₁-C₁₀ heterocycloalkyl group, a C₃-C₁₀ cycloalkenyl group, a C₁-C₁ heterocycloalkenyl group, a C₆-C₆₀ aryl group, and a C₁-C₆₀ heteroaryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group;
Z₁₁ and Z₁₂ are each independently selected from:
i) a C₁-C₆₀ alkyl group, a C₂-C₆₀ alkenyl group, a C₂-C₆₀ alkynyl group, and a C₁-C₆₀ alkoxy group;
ii) a C₁-C₆₀ alkyl group, a C₂-C₆₀ alkenyl group, a C₂-C₆₀ alkynyl group, and a C₁-C₆₀ alkoxy group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group;
iii) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, and a C₁-C₆₀ heteroaryl group; and
iv) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, and a C₁-C₆₀ heteroaryl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₆-C₆₀ aryloxy group, a C₆-C₆₀ arylthio group, and a C₁-C₆₀ heteroaryl group; and
p and q are each independently an integer from 1 to 4.

2. The organic light-emitting device of claim 1, wherein:
Ar₁ and Ar₂ are each independently selected from:
i) a C₆-C₆₀ aryl group and —Si(Q₁)(Q₂)(Q₃) (here, Q₁ to Q₃ are each independently a C₁-C₁ alkyl group or a C₆-C₃₀ aryl group); and
ii) a C₆-C₆₀ aryl group substituted with at least one substituent selected from a deuterium atom, a halogen atom, a C₁-C₆₀ alkyl group, a C₆-C₆₀ aryl group, and —Si(Q₁)(Q₂)(Q₃) (here, Q₁ to Q₃ are each independently a C₁-C₁ alkyl group or a C₆-C₃₀ aryl group). Ar₃ is selected from:
i) a C₆-C₆₀ aryl group, a C₁-C₆₀ heteroaryl group, and —Si(Q₁)(Q₂)(Q₃) (here, Q₁ to Q₃ are each independently a C₁-C₁ alkyl group or a C₆-C₃₀ aryl group); and
ii) a C₆-C₆₀ aryl group and a C₁-C₆₀ heteroaryl group, each substituted with at least one substituent selected from a deuterium atom, a halogen atom, a C₁-C₆₀ alkyl group, a C₆-C₆₀ aryl group, a C₁-C₆₀ heteroaryl group, and —Si(Q₁)(Q₂)(Q₃) (here, Q₁ to Q₃ are each independently a C₁-C₁₀ alkyl group or a C₆-C₃₀ aryl group).

3. The organic light-emitting device of claim 1, wherein:
X₁₁ is C(R₁₁), X₁₂ is C(R₁₂), X₁₃ is C(R₁₃), X₁₄ is C(R₁₄), X₁₅ is C(R₁₅), X₁₆ is C(R₁₆), X₁₇ is C(R₁₇), X₁₈ is C(R₁₈), X₁₉ is C(R₁₉), X₂₀ is C(R₂₀), X₂₁ is C(R₂₁), X₂₂ is C(R₂₂), X₂₃ is C(R₂₃), and X₂₄ is C(R₂₄).

4. The organic light-emitting device of claim 1, wherein:
Ar₁₃ and Ar₁₄ are each independently selected from
i) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, and a triazinyl group; and
ii) a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, and a triazinyl group, each substituted with at least one substituent selected from a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthryl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinyl group, a carbazolyl group, and a triazinyl group.

5. The organic light-emitting device of claim 1, wherein:
Z₅, Z₆, Z₁₁, Z₁₂, and R₁₁ to R₂₄ may each independently be a methyl group, an ethyl group, a propyl group, a butyl group, a pentyl group, a hexyl group, a heptyl group, or a moiety represented by one of Formulas 3-1 to 3-20: 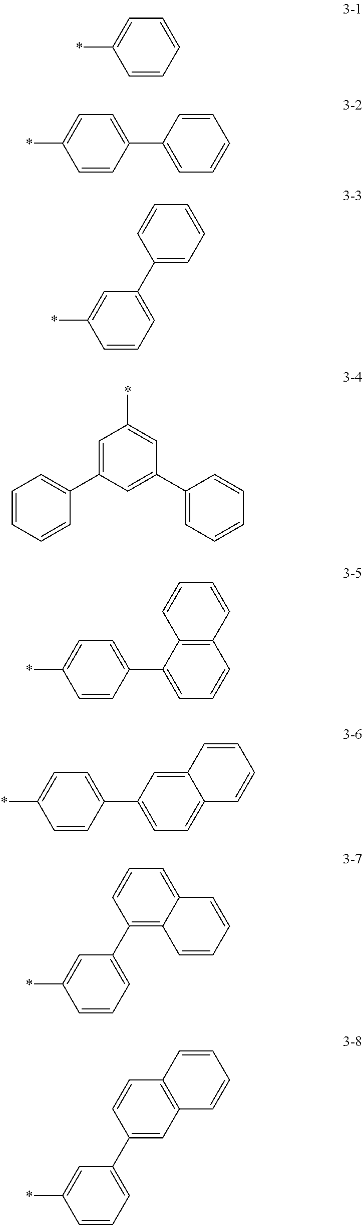 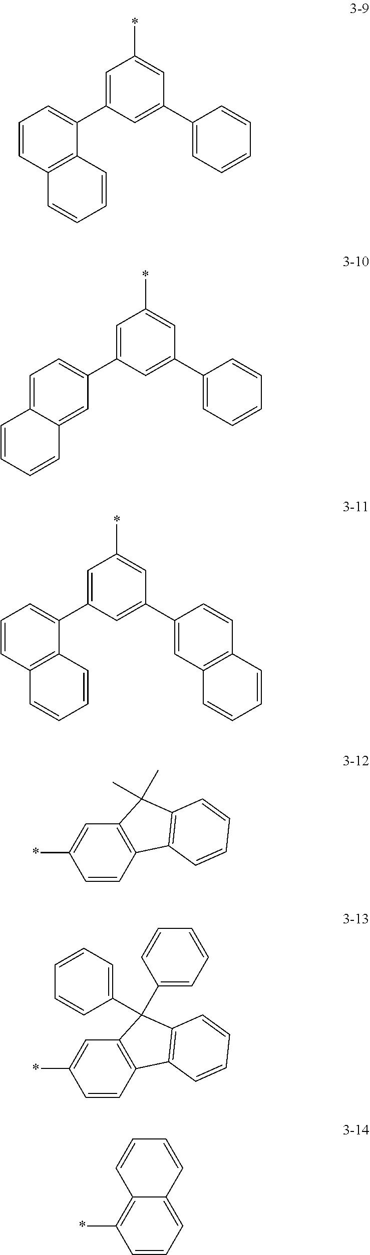 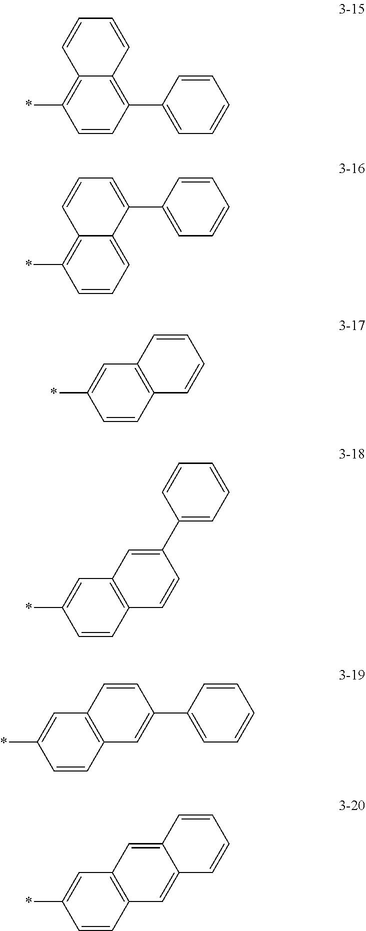
wherein, in Formula 3-1 to 3-20:
* represents a carbon atom of a fluorene-based ring of Formula 2(1) or Formula 2(2).

6. The organic light-emitting device of claim 1, wherein:
the hole-transporting material is at least one of Compounds 6-1 to 6-144:

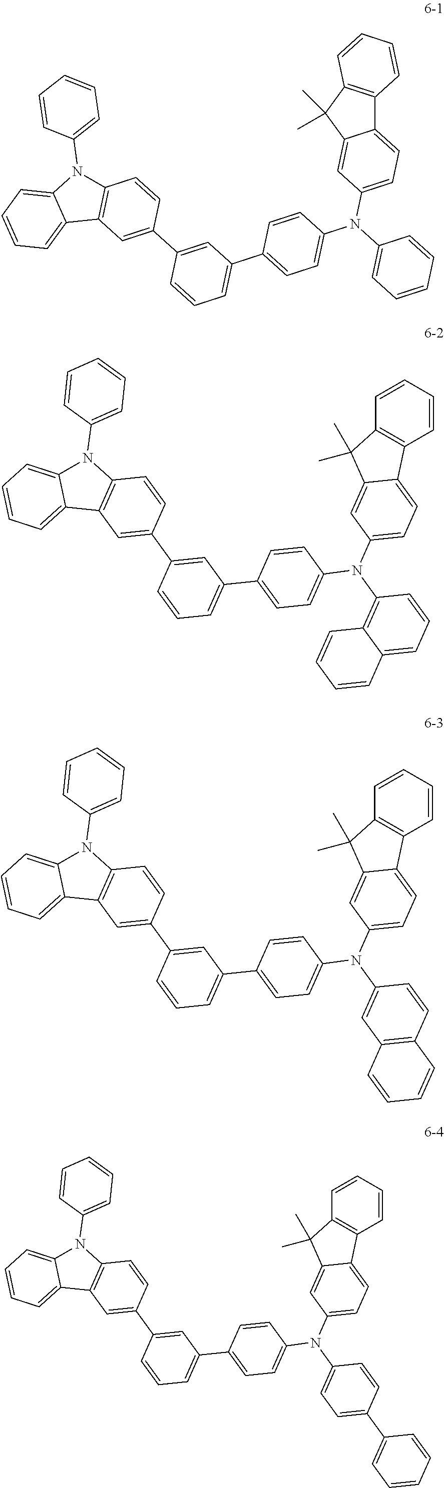 [SMILES: CC1(C)c2ccccc2-c2ccc(N(c3ccccc3)c3ccc(-c4cccc(-c5ccc6c(c5)c5ccccc5n6-c5ccccc5)c4)cc3)cc21 ; CC1(C)c2ccccc2-c2ccc(N(c3ccc(-c4cccc(-c5ccc6c(c5)c5ccccc5n6-c5ccccc5)c4)cc3)c3cccc4ccccc34)cc21 ; CC1(C)c2ccccc2-c2ccc(N(c3ccc(-c4cccc(-c5ccc6c(c5)c5ccccc5n6-c5ccccc5)c4)cc3)c3ccc4ccccc4c3)cc21 ; CC1(C)c2ccccc2-c2ccc(N(c3ccc(-c4ccccc4)cc3)c3ccc(-c4cccc(-c5ccc6c(c5)c5ccccc5n6-c5ccccc5)c4)cc3)cc21]

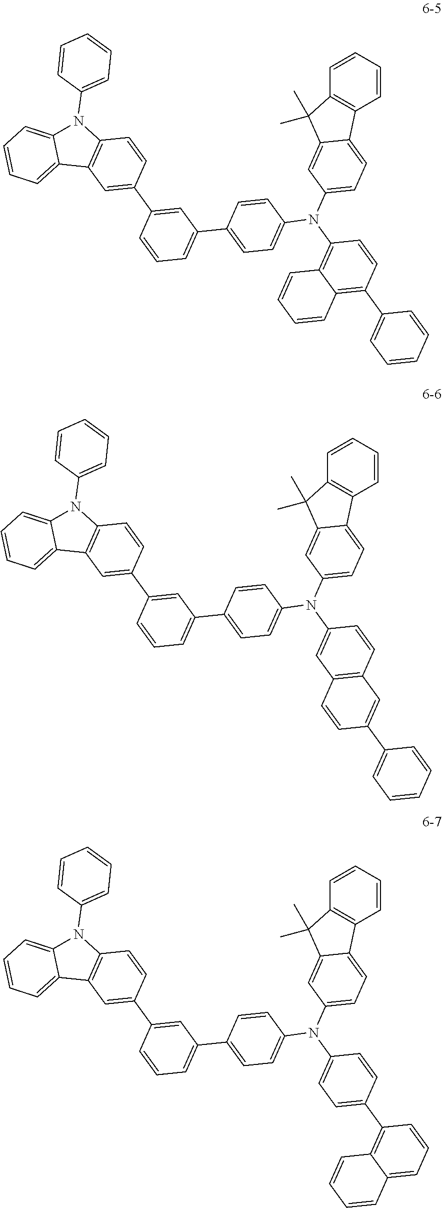 [SMILES: CC1(C)c2ccccc2-c2ccc(N(c3ccc(-c4cccc(-c5ccc6c(c5)c5ccccc5n6-c5ccccc5)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5ccccc5)c4)cc3)c3ccc4cc(-c5ccccc5)ccc4c3)cc21 ; CC1(C)c2ccccc2-c2ccc(N(c3ccc(-c4cccc(-c5ccc6c(c5)c5ccccc5n6-c5ccccc5)c4)cc3)c3ccc(-c4cccc5ccccc45)cc3)cc21]

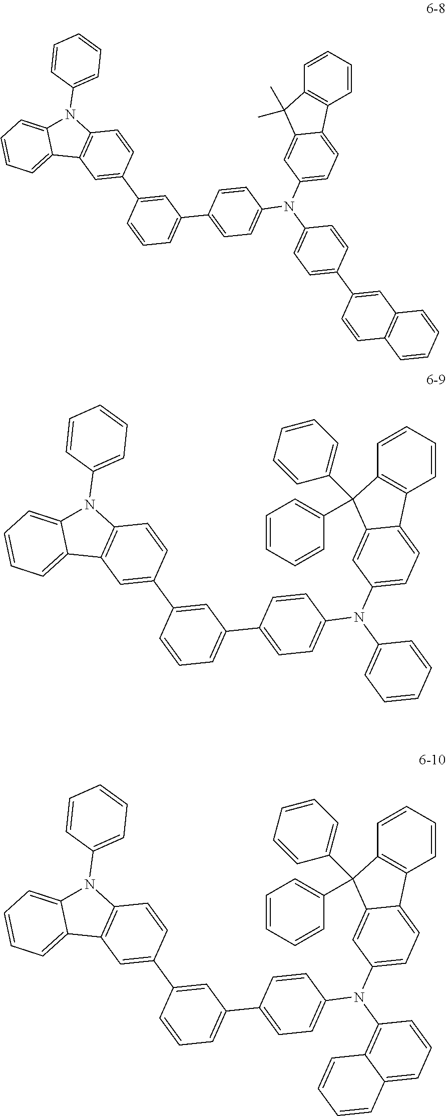 [SMILES: CC1(C)c2ccccc2-c2ccc(N(c3ccc(-c4cccc(-c5ccc6c(c5)c5ccccc5n6-c5ccccc5)c4)cc3)c3ccc(-c4ccc5ccccc5c4)cc3)cc21 ; c1ccc(N(c2ccc(-c3cccc(-c4ccc5c(c4)c4ccccc4n5-c4ccccc4)c3)cc2)c2ccc3c(c2)C(c2ccccc2)(c2ccccc2)c2ccccc2-3)cc1 ; c1ccc(-n2c3ccccc3c3cc(-c4cccc(-c5ccc(N(c6ccc7c(c6)C(c6ccccc6)(c6ccccc6)c6ccccc6-7)c6cccc7ccccc67)cc5)c4)ccc32)cc1]

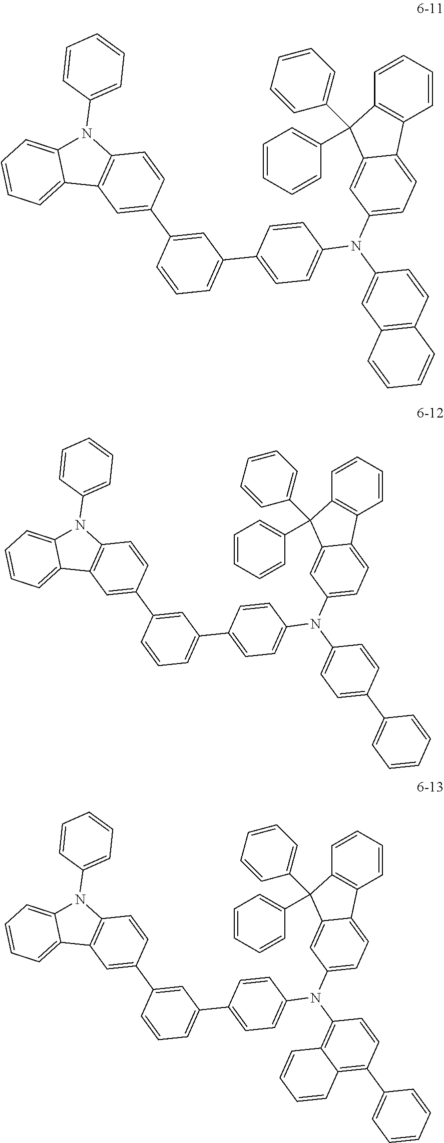 [SMILES: c1ccc(-n2c3ccccc3c3cc(-c4cccc(-c5ccc(N(c6ccc7c(c6)C(c6ccccc6)(c6ccccc6)c6ccccc6-7)c6ccc7ccccc7c6)cc5)c4)ccc32)cc1 ; c1ccc(-c2ccc(N(c3ccc(-c4cccc(-c5ccc6c(c5)c5ccccc5n6-c5ccccc5)c4)cc3)c3ccc4c(c3)C(c3ccccc3)(c3ccccc3)c3ccccc3-4)cc2)cc1 ; c1ccc(-c2ccc(N(c3ccc(-c4cccc(-c5ccc6c(c5)c5ccccc5n6-c5ccccc5)c4)cc3)c3ccc4c(c3)C(c3ccccc3)(c3ccccc3)c3ccccc3-4)c3ccccc23)cc1]

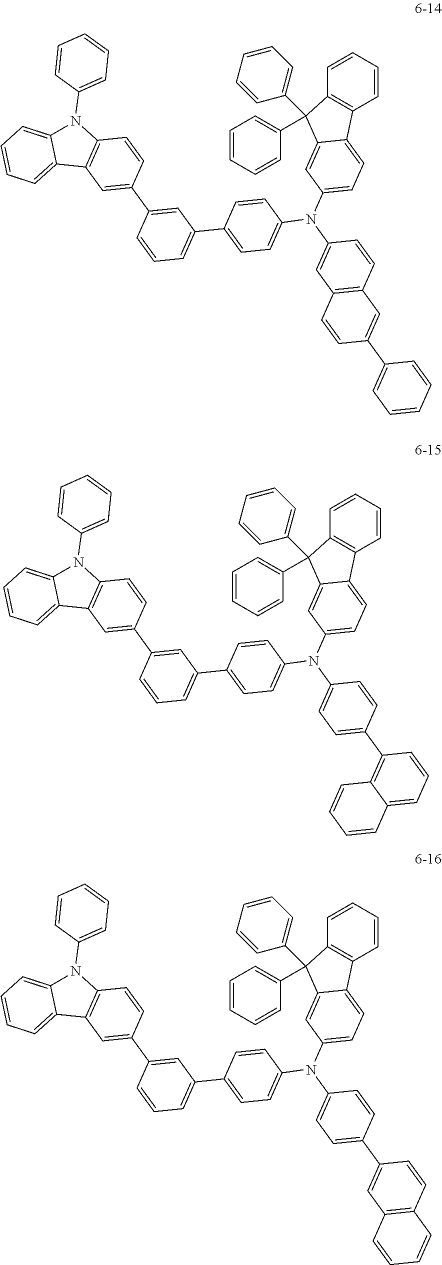 [SMILES: c1ccc(-c2ccc3cc(N(c4ccc(-c5cccc(-c6ccc7c(c6)c6ccccc6n7-c6ccccc6)c5)cc4)c4ccc5c(c4)C(c4ccccc4)(c4ccccc4)c4ccccc4-5)ccc3c2)cc1 ; c1ccc(-n2c3ccccc3c3cc(-c4cccc(-c5ccc(N(c6ccc(-c7cccc8ccccc78)cc6)c6ccc7c(c6)C(c6ccccc6)(c6ccccc6)c6ccccc6-7)cc5)c4)ccc32)cc1 ; c1ccc(-n2c3ccccc3c3cc(-c4cccc(-c5ccc(N(c6ccc(-c7ccc8ccccc8c7)cc6)c6ccc7c(c6)C(c6ccccc6)(c6ccccc6)c6ccccc6-7)cc5)c4)ccc32)cc1]

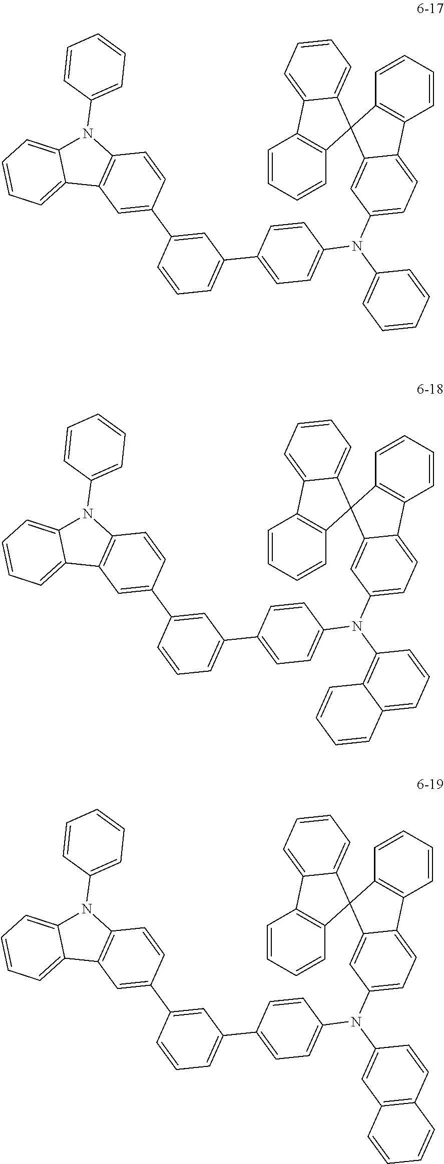 [SMILES: c1ccc(N(c2ccc(-c3cccc(-c4ccc5c(c4)c4ccccc4n5-c4ccccc4)c3)cc2)c2ccc3c(c2)C2(c4ccccc4-c4ccccc42)c2ccccc2-3)cc1 ; c1ccc(-n2c3ccccc3c3cc(-c4cccc(-c5ccc(N(c6ccc7c(c6)C6(c8ccccc8-c8ccccc86)c6ccccc6-7)c6cccc7ccccc67)cc5)c4)ccc32)cc1 ; c1ccc(-n2c3ccccc3c3cc(-c4cccc(-c5ccc(N(c6ccc7c(c6)C6(c8ccccc8-c8ccccc86)c6ccccc6-7)c6ccc7ccccc7c6)cc5)c4)ccc32)cc1]

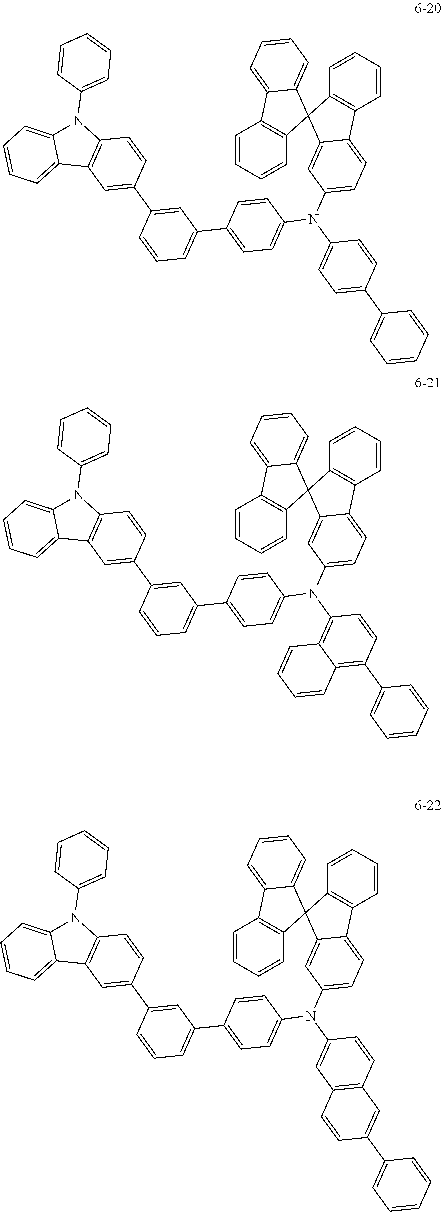 [SMILES: c1ccc(-c2ccc(N(c3ccc(-c4cccc(-c5ccc6c(c5)c5ccccc5n6-c5ccccc5)c4)cc3)c3ccc4c(c3)C3(c5ccccc5-c5ccccc53)c3ccccc3-4)cc2)cc1 ; c1ccc(-c2ccc(N(c3ccc(-c4cccc(-c5ccc6c(c5)c5ccccc5n6-c5ccccc5)c4)cc3)c3ccc4c(c3)C3(c5ccccc5-c5ccccc53)c3ccccc3-4)c3ccccc23)cc1 ; c1ccc(-c2ccc3cc(N(c4ccc(-c5cccc(-c6ccc7c(c6)c6ccccc6n7-c6ccccc6)c5)cc4)c4ccc5c(c4)C4(c6ccccc6-c6ccccc64)c4ccccc4-5)ccc3c2)cc1]

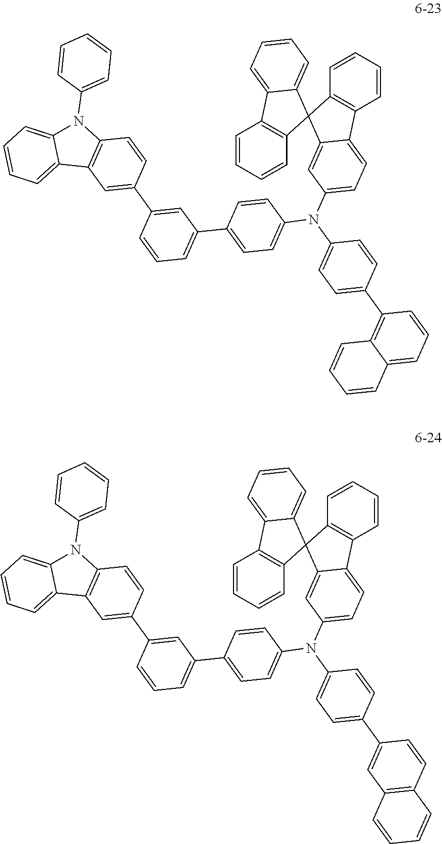 [SMILES: c1ccc(-n2c3ccccc3c3cc(-c4cccc(-c5ccc(N(c6ccc(-c7cccc8ccccc78)cc6)c6ccc7c(c6)C6(c8ccccc8-c8ccccc86)c6ccccc6-7)cc5)c4)ccc32)cc1 ; c1ccc(-n2c3ccccc3c3cc(-c4cccc(-c5ccc(N(c6ccc(-c7ccc8ccccc8c7)cc6)c6ccc7c(c6)C6(c8ccccc8-c8ccccc86)c6ccccc6-7)cc5)c4)ccc32)cc1]

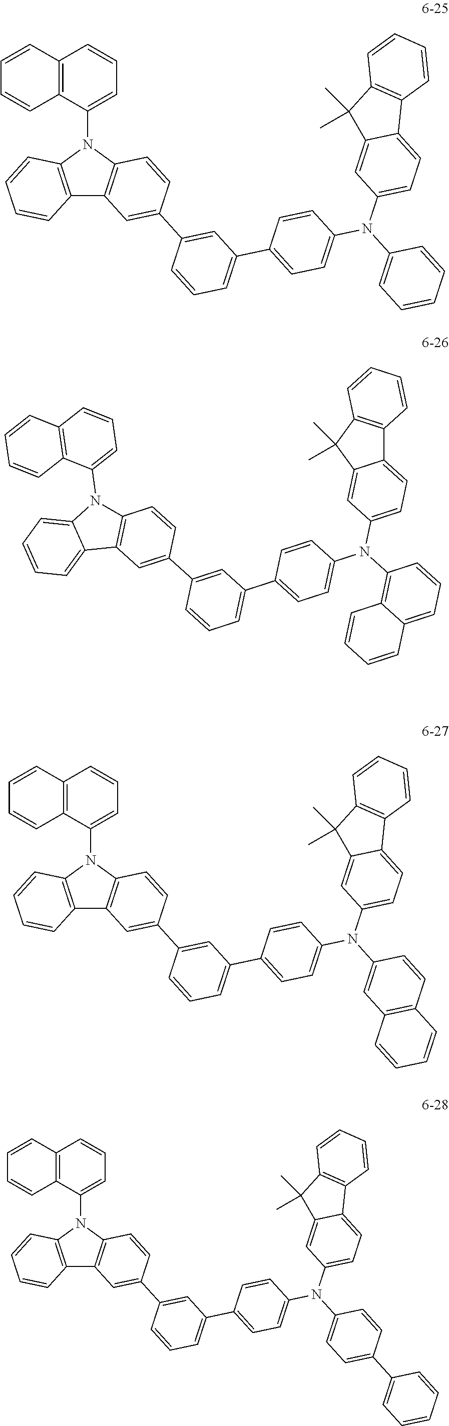 [SMILES: CC1(C)c2ccccc2-c2ccc(N(c3ccccc3)c3ccc(-c4cccc(-c5ccc6c(c5)c5ccccc5n6-c5cccc6ccccc56)c4)cc3)cc21 ; CC1(C)c2ccccc2-c2ccc(N(c3ccc(-c4cccc(-c5ccc6c(c5)c5ccccc5n6-c5cccc6ccccc56)c4)cc3)c3cccc4ccccc34)cc21 ; CC1(C)c2ccccc2-c2ccc(N(c3ccc(-c4cccc(-c5ccc6c(c5)c5ccccc5n6-c5cccc6ccccc56)c4)cc3)c3ccc4ccccc4c3)cc21 ; CC1(C)c2ccccc2-c2ccc(N(c3ccc(-c4ccccc4)cc3)c3ccc(-c4cccc(-c5ccc6c(c5)c5ccccc5n6-c5cccc6ccccc56)c4)cc3)cc21]

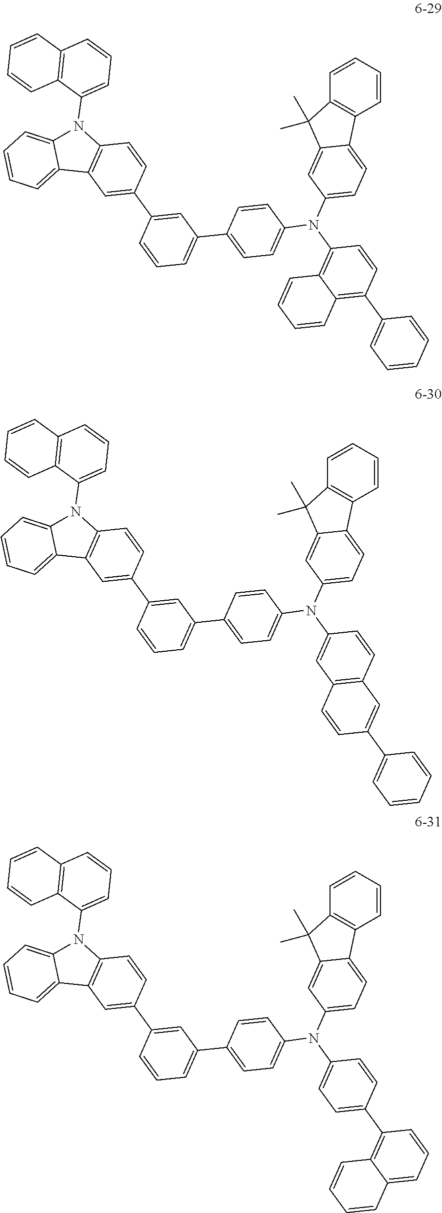 [SMILES: CC1(C)c2ccccc2-c2ccc(N(c3ccc(-c4cccc(-c5ccc6c(c5)c5ccccc5n6-c5cccc6ccccc56)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5cccc6ccccc56)c4)cc3)c3ccc4cc(-c5ccccc5)ccc4c3)cc21 ; CC1(C)c2ccccc2-c2ccc(N(c3ccc(-c4cccc(-c5ccc6c(c5)c5ccccc5n6-c5cccc6ccccc56)c4)cc3)c3ccc(-c4cccc5ccccc45)cc3)cc21]

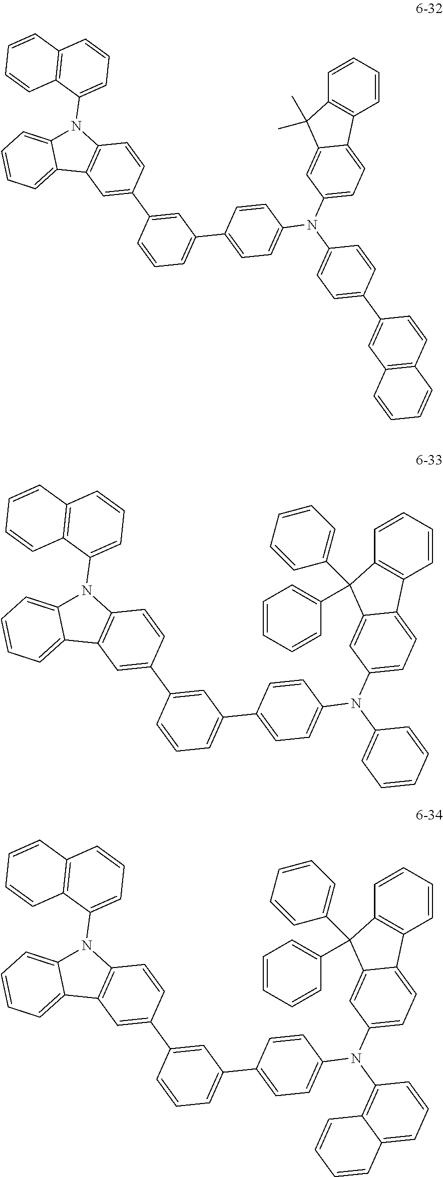 [SMILES: CC1(C)c2ccccc2-c2ccc(N(c3ccc(-c4cccc(-c5ccc6c(c5)c5ccccc5n6-c5cccc6ccccc56)c4)cc3)c3ccc(-c4ccc5ccccc5c4)cc3)cc21 ; c1ccc(N(c2ccc(-c3cccc(-c4ccc5c(c4)c4ccccc4n5-c4cccc5ccccc45)c3)cc2)c2ccc3c(c2)C(c2ccccc2)(c2ccccc2)c2ccccc2-3)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4cccc5ccccc45)cc32)cc1]

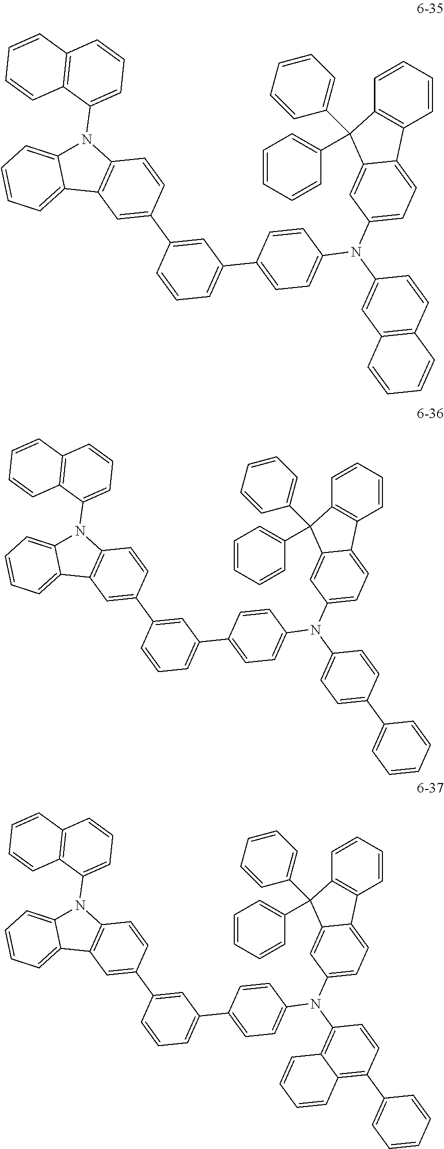 [SMILES: c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc5ccccc5c4)cc32)cc1 ; c1ccc(-c2ccc(N(c3ccc(-c4cccc(-c5ccc6c(c5)c5ccccc5n6-c5cccc6ccccc56)c4)cc3)c3ccc4c(c3)C(c3ccccc3)(c3ccccc3)c3ccccc3-4)cc2)cc1 ; c1ccc(-c2ccc(N(c3ccc(-c4cccc(-c5ccc6c(c5)c5ccccc5n6-c5cccc6ccccc56)c4)cc3)c3ccc4c(c3)C(c3ccccc3)(c3ccccc3)c3ccccc3-4)c3ccccc23)cc1]

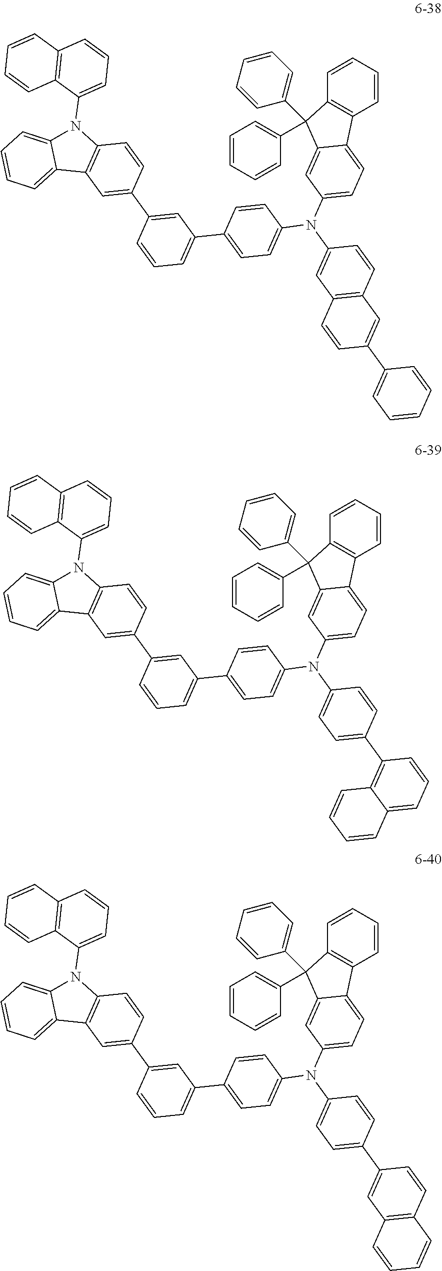 [SMILES: c1ccc(-c2ccc3cc(N(c4ccc(-c5cccc(-c6ccc7c(c6)c6ccccc6n7-c6cccc7ccccc67)c5)cc4)c4ccc5c(c4)C(c4ccccc4)(c4ccccc4)c4ccccc4-5)ccc3c2)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc(-c5cccc6ccccc56)cc4)cc32)cc1 ; c1ccc(C2(c3ccccc3)c3ccccc3-c3ccc(N(c4ccc(-c5cccc(-c6ccc7c(c6)c6ccccc6n7-c6cccc7ccccc67)c5)cc4)c4ccc(-c5ccc6ccccc6c5)cc4)cc32)cc1]

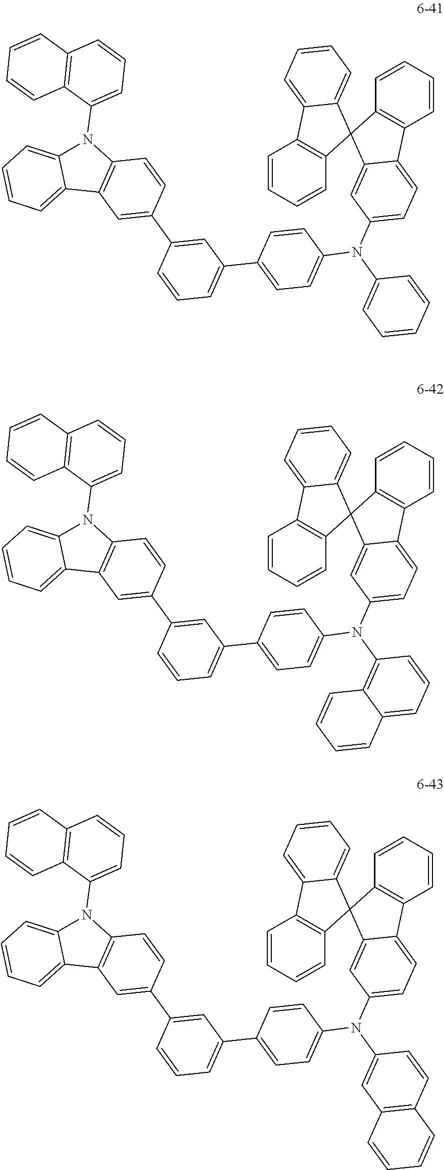 [SMILES: c1ccc(N(c2ccc(-c3cccc(-c4ccc5c(c4)c4ccccc4n5-c4cccc5ccccc45)c3)cc2)c2ccc3c(c2)C2(c4ccccc4-c4ccccc42)c2ccccc2-3)cc1 ; c1cc(-c2ccc(N(c3ccc4c(c3)C3(c5ccccc5-c5ccccc53)c3ccccc3-4)c3cccc4ccccc34)cc2)cc(-c2ccc3c(c2)c2ccccc2n3-c2cccc3ccccc23)c1 ; c1cc(-c2ccc(N(c3ccc4c(c3)C3(c5ccccc5-c5ccccc53)c3ccccc3-4)c3ccc4ccccc4c3)cc2)cc(-c2ccc3c(c2)c2ccccc2n3-c2cccc3ccccc23)c1]

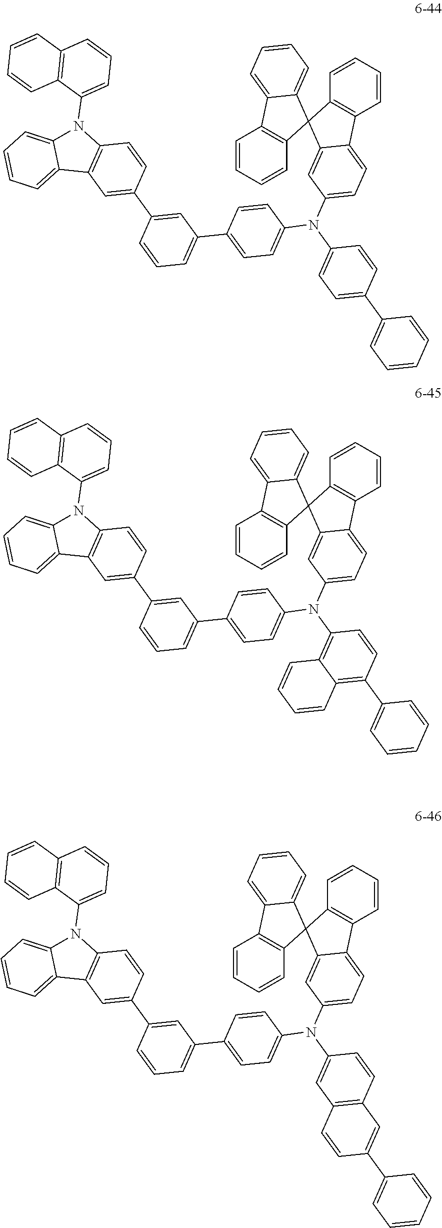 [SMILES: c1ccc(-c2ccc(N(c3ccc(-c4cccc(-c5ccc6c(c5)c5ccccc5n6-c5cccc6ccccc56)c4)cc3)c3ccc4c(c3)C3(c5ccccc5-c5ccccc53)c3ccccc3-4)cc2)cc1 ; c1ccc(-c2ccc(N(c3ccc(-c4cccc(-c5ccc6c(c5)c5ccccc5n6-c5cccc6ccccc56)c4)cc3)c3ccc4c(c3)C3(c5ccccc5-c5ccccc53)c3ccccc3-4)c3ccccc23)cc1 ; c1ccc(-c2ccc3cc(N(c4ccc(-c5cccc(-c6ccc7c(c6)c6ccccc6n7-c6cccc7ccccc67)c5)cc4)c4ccc5c(c4)C4(c6ccccc6-c6ccccc64)c4ccccc4-5)ccc3c2)cc1]

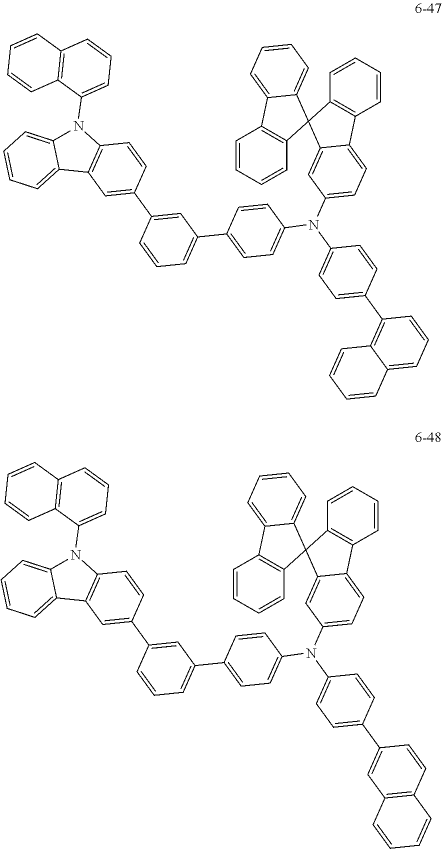 [SMILES: c1cc(-c2ccc(N(c3ccc(-c4cccc5ccccc45)cc3)c3ccc4c(c3)C3(c5ccccc5-c5ccccc53)c3ccccc3-4)cc2)cc(-c2ccc3c(c2)c2ccccc2n3-c2cccc3ccccc23)c1 ; c1cc(-c2ccc(N(c3ccc(-c4ccc5ccccc5c4)cc3)c3ccc4c(c3)C3(c5ccccc5-c5ccccc53)c3ccccc3-4)cc2)cc(-c2ccc3c(c2)c2ccccc2n3-c2cccc3ccccc23)c1]

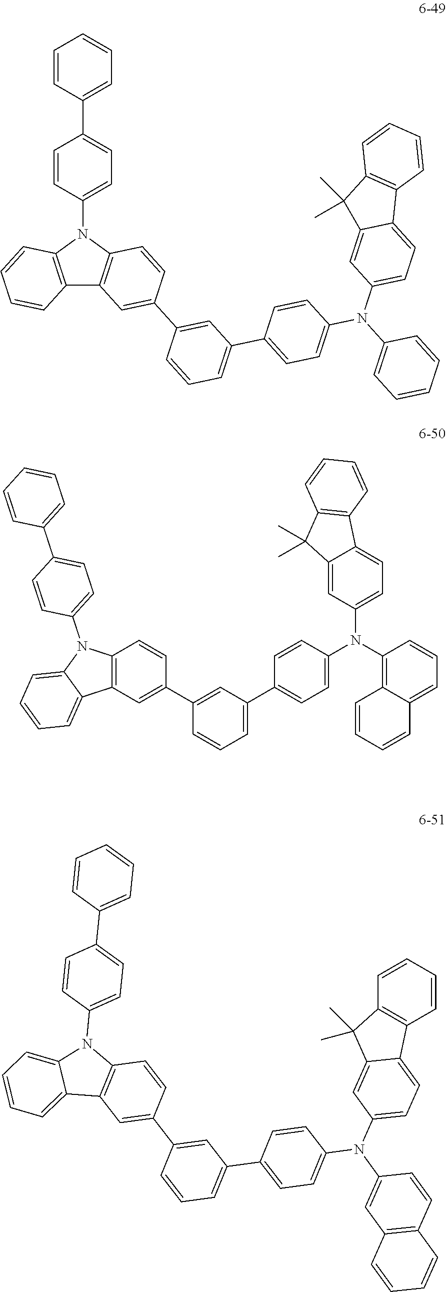 [SMILES: CC1(C)c2ccccc2-c2ccc(N(c3ccccc3)c3ccc(-c4cccc(-c5ccc6c(c5)c5ccccc5n6-c5ccc(-c6ccccc6)cc5)c4)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3cccc4ccccc34)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc4ccccc4c3)cc21]

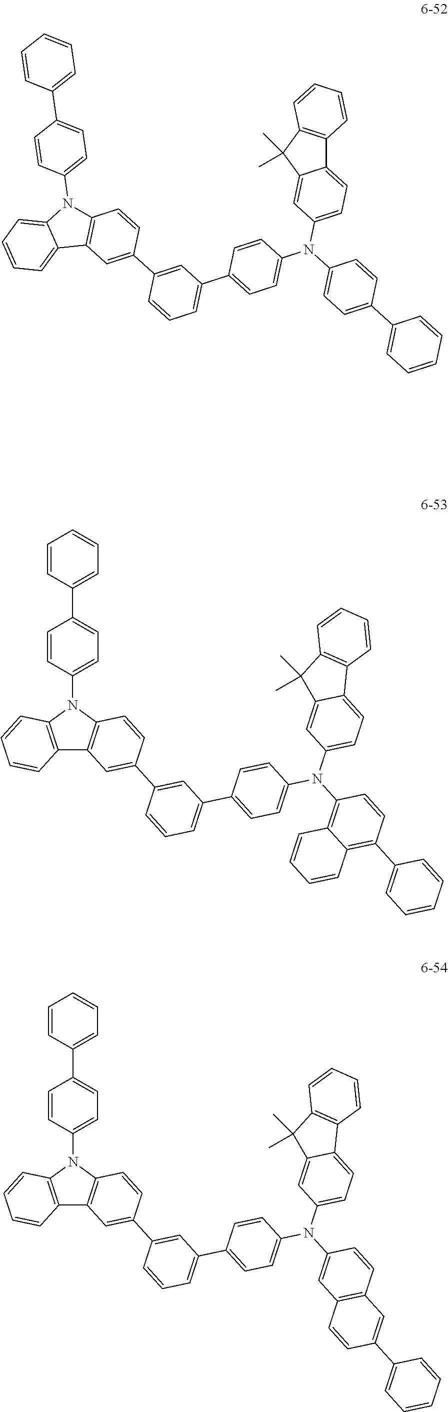 [SMILES: CC1(C)c2ccccc2-c2ccc(N(c3ccc(-c4ccccc4)cc3)c3ccc(-c4cccc(-c5ccc6c(c5)c5ccccc5n6-c5ccc(-c6ccccc6)cc5)c4)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4ccccc4)c4ccccc34)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc4cc(-c5ccccc5)ccc4c3)cc21]

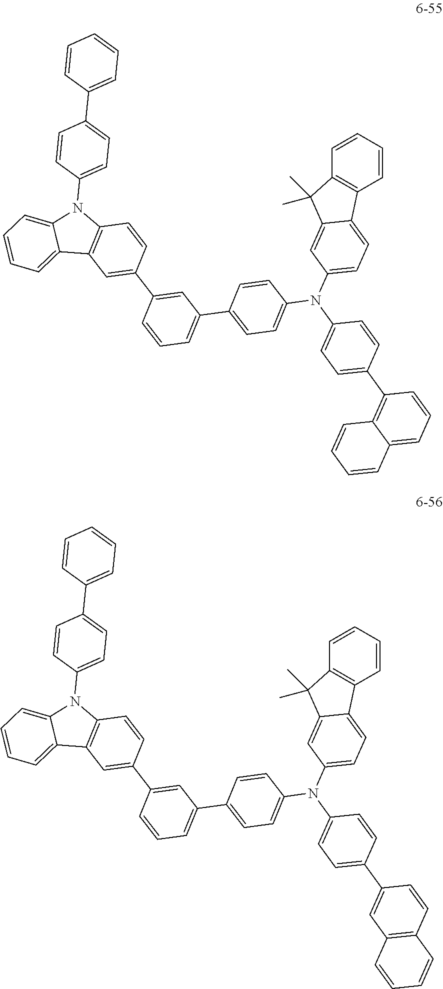 [SMILES: CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4cccc5ccccc45)cc3)cc21 ; CC1(C)c2ccccc2-c2ccc(N(c3ccc(-c4cccc(-c5ccc6c(c5)c5ccccc5n6-c5ccc(-c6ccccc6)cc5)c4)cc3)c3ccc(-c4ccc5ccccc5c4)cc3)cc21]

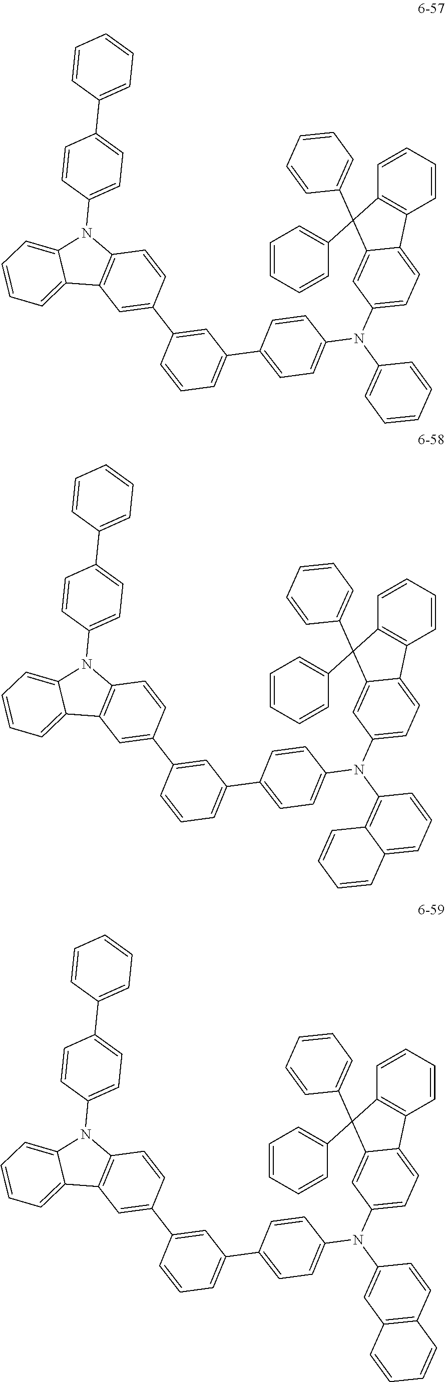 [SMILES: c1ccc(-c2ccc(-n3c4ccccc4c4cc(-c5cccc(-c6ccc(N(c7ccccc7)c7ccc8c(c7)C(c7ccccc7)(c7ccccc7)c7ccccc7-8)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7cccc8ccccc78)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc8ccccc8c7)cc6)c5)ccc43)cc2)cc1]

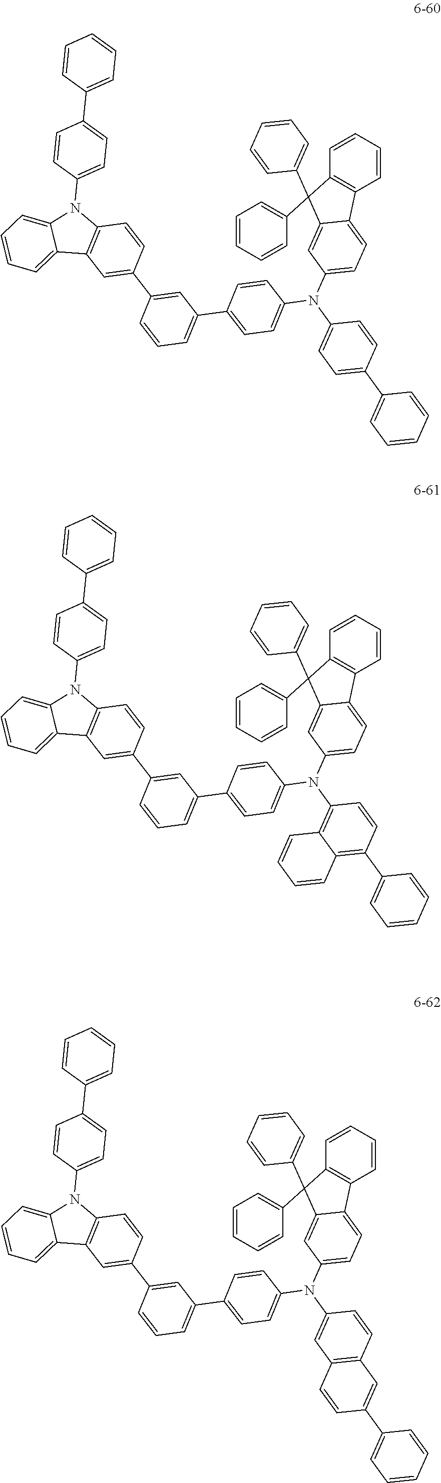 [SMILES: c1ccc(-c2ccc(N(c3ccc(-c4cccc(-c5ccc6c(c5)c5ccccc5n6-c5ccc(-c6ccccc6)cc5)c4)cc3)c3ccc4c(c3)C(c3ccccc3)(c3ccccc3)c3ccccc3-4)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc(-c8ccccc8)c8ccccc78)cc6)c5)ccc43)cc2)cc1 ; c1ccc(-c2ccc(-n3c4ccccc4c4cc(-c5cccc(-c6ccc(N(c7ccc8c(c7)C(c7ccccc7)(c7ccccc7)c7ccccc7-8)c7ccc8cc(-c9ccccc9)ccc8c7)cc6)c5)ccc43)cc2)cc1]

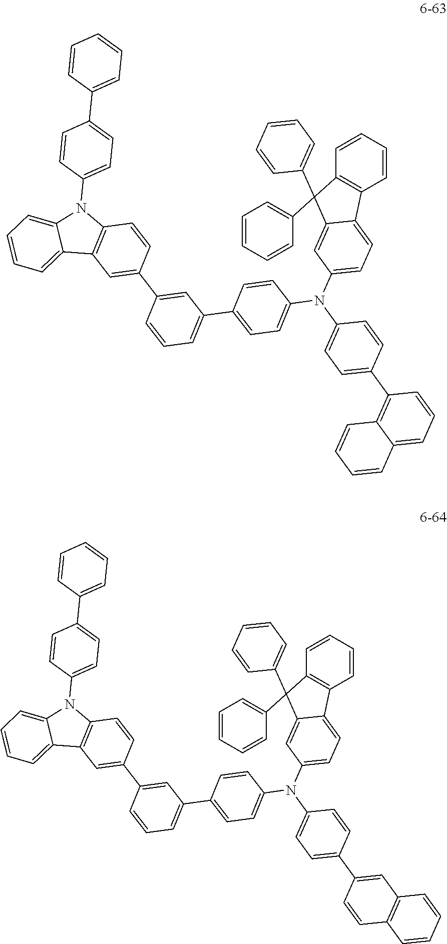 [SMILES: c1ccc(-c2ccc(-n3c4ccccc4c4cc(-c5cccc(-c6ccc(N(c7ccc(-c8cccc9ccccc89)cc7)c7ccc8c(c7)C(c7ccccc7)(c7ccccc7)c7ccccc7-8)cc6)c5)ccc43)cc2)cc1 ; c1ccc(-c2ccc(-n3c4ccccc4c4cc(-c5cccc(-c6ccc(N(c7ccc(-c8ccc9ccccc9c8)cc7)c7ccc8c(c7)C(c7ccccc7)(c7ccccc7)c7ccccc7-8)cc6)c5)ccc43)cc2)cc1]

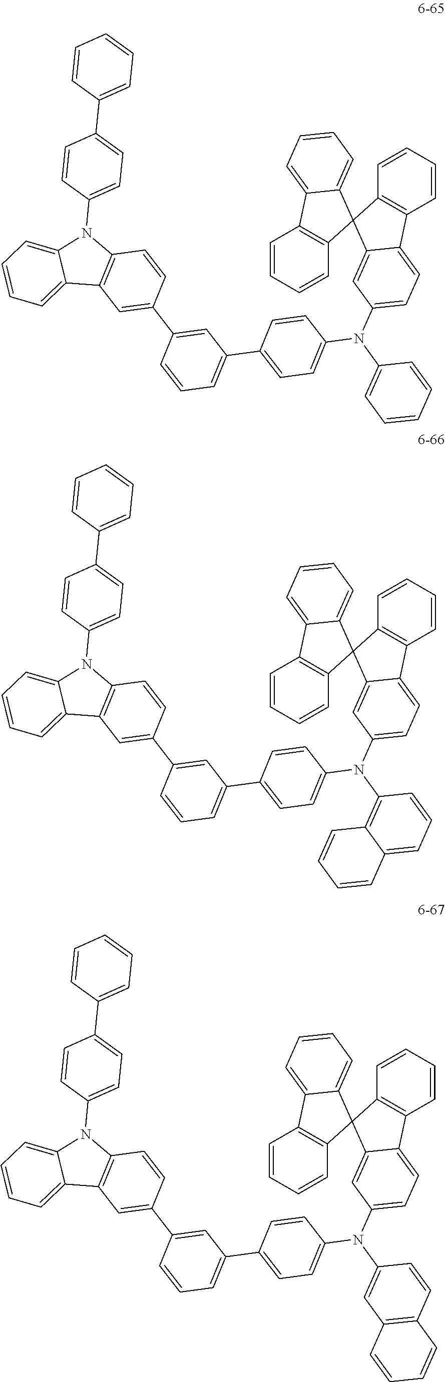 [SMILES: c1ccc(-c2ccc(-n3c4ccccc4c4cc(-c5cccc(-c6ccc(N(c7ccccc7)c7ccc8c(c7)C7(c9ccccc9-c9ccccc97)c7ccccc7-8)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7cccc8ccccc78)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc8ccccc8c7)cc6)c5)ccc43)cc2)cc1]

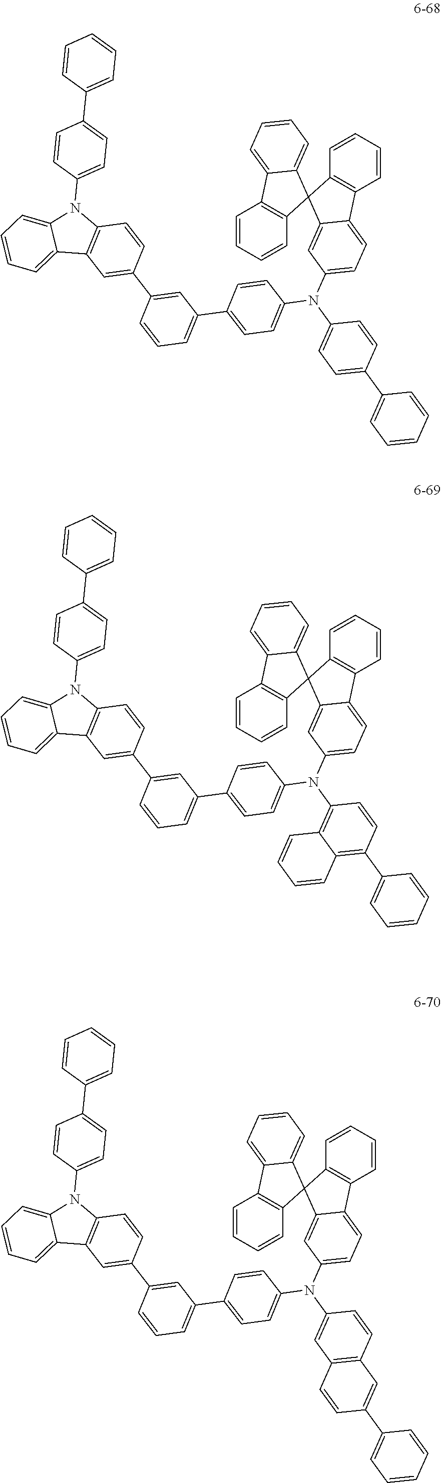 [SMILES: c1ccc(-c2ccc(N(c3ccc(-c4cccc(-c5ccc6c(c5)c5ccccc5n6-c5ccc(-c6ccccc6)cc5)c4)cc3)c3ccc4c(c3)C3(c5ccccc5-c5ccccc53)c3ccccc3-4)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc(-c8ccccc8)c8ccccc78)cc6)c5)ccc43)cc2)cc1 ; c1ccc(-c2ccc(-n3c4ccccc4c4cc(-c5cccc(-c6ccc(N(c7ccc8c(c7)C7(c9ccccc9-c9ccccc97)c7ccccc7-8)c7ccc8cc(-c9ccccc9)ccc8c7)cc6)c5)ccc43)cc2)cc1]

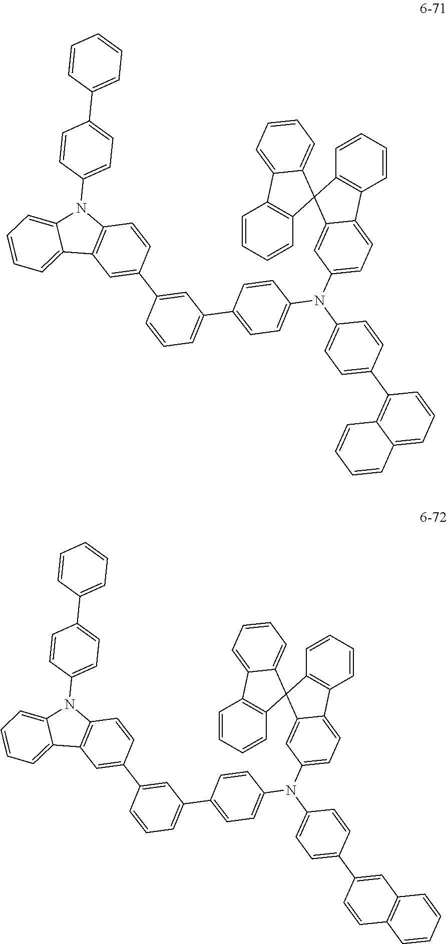 [SMILES: c1ccc(-c2ccc(-n3c4ccccc4c4cc(-c5cccc(-c6ccc(N(c7ccc(-c8cccc9ccccc89)cc7)c7ccc8c(c7)C7(c9ccccc9-c9ccccc97)c7ccccc7-8)cc6)c5)ccc43)cc2)cc1 ; c1ccc(-c2ccc(-n3c4ccccc4c4cc(-c5cccc(-c6ccc(N(c7ccc(-c8ccc9ccccc9c8)cc7)c7ccc8c(c7)C7(c9ccccc9-c9ccccc97)c7ccccc7-8)cc6)c5)ccc43)cc2)cc1]

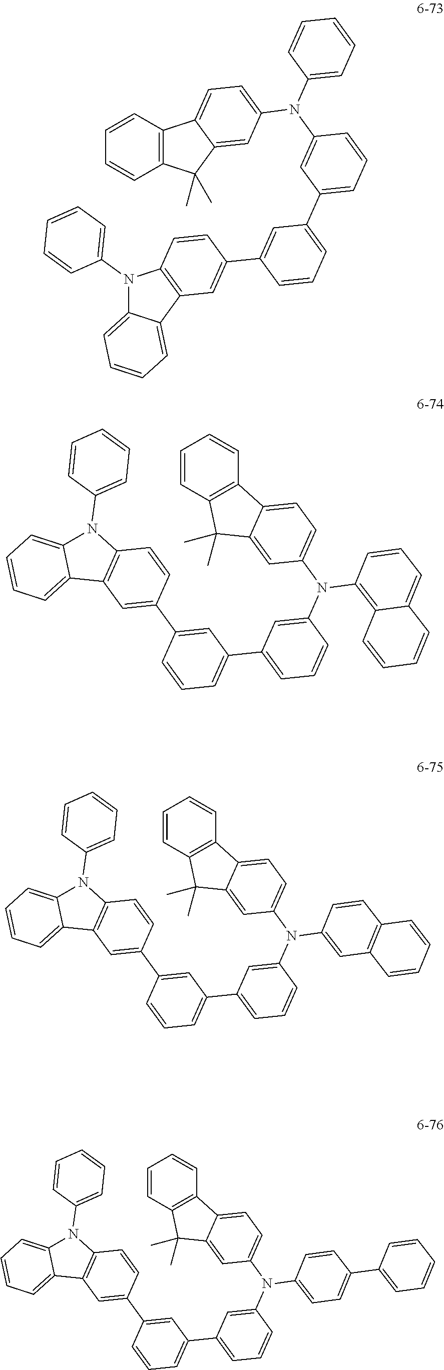 [SMILES: CC1(C)c2ccccc2-c2ccc(N(c3ccccc3)c3cccc(-c4cccc(-c5ccc6c(c5)c5ccccc5n6-c5ccccc5)c4)c3)cc21 ; CC1(C)c2ccccc2-c2ccc(N(c3cccc(-c4cccc(-c5ccc6c(c5)c5ccccc5n6-c5ccccc5)c4)c3)c3cccc4ccccc34)cc21 ; CC1(C)c2ccccc2-c2ccc(N(c3cccc(-c4cccc(-c5ccc6c(c5)c5ccccc5n6-c5ccccc5)c4)c3)c3ccc4ccccc4c3)cc21 ; CC1(C)c2ccccc2-c2ccc(N(c3ccc(-c4ccccc4)cc3)c3cccc(-c4cccc(-c5ccc6c(c5)c5ccccc5n6-c5ccccc5)c4)c3)cc21]

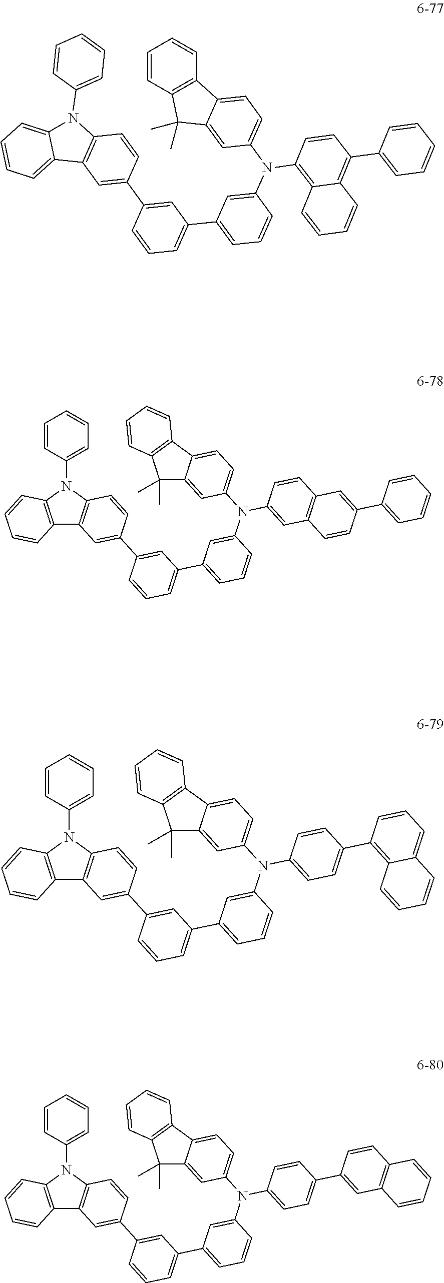 [SMILES: CC1(C)c2ccccc2-c2ccc(N(c3cccc(-c4cccc(-c5ccc6c(c5)c5ccccc5n6-c5ccccc5)c4)c3)c3ccc(-c4ccccc4)c4ccccc34)cc21 ; CC1(C)c2ccccc2-c2ccc(N(c3cccc(-c4cccc(-c5ccc6c(c5)c5ccccc5n6-c5ccccc5)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5ccccc5)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5ccccc5)c4)c3)cc21]

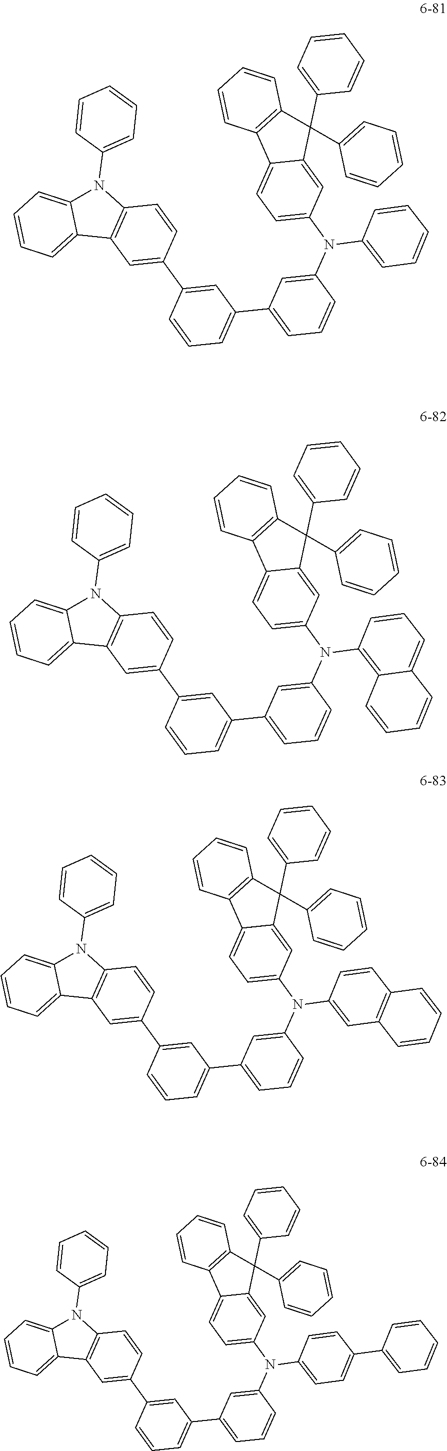 [SMILES: c1ccc(N(c2cccc(-c3cccc(-c4ccc5c(c4)c4ccccc4n5-c4ccccc4)c3)c2)c2ccc3c(c2)C(c2ccccc2)(c2ccccc2)c2ccccc2-3)cc1 ; c1ccc(-n2c3ccccc3c3cc(-c4cccc(-c5cccc(N(c6ccc7c(c6)C(c6ccccc6)(c6ccccc6)c6ccccc6-7)c6cccc7ccccc67)c5)c4)ccc32)cc1 ; c1ccc(-n2c3ccccc3c3cc(-c4cccc(-c5cccc(N(c6ccc7c(c6)C(c6ccccc6)(c6ccccc6)c6ccccc6-7)c6ccc7ccccc7c6)c5)c4)ccc32)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

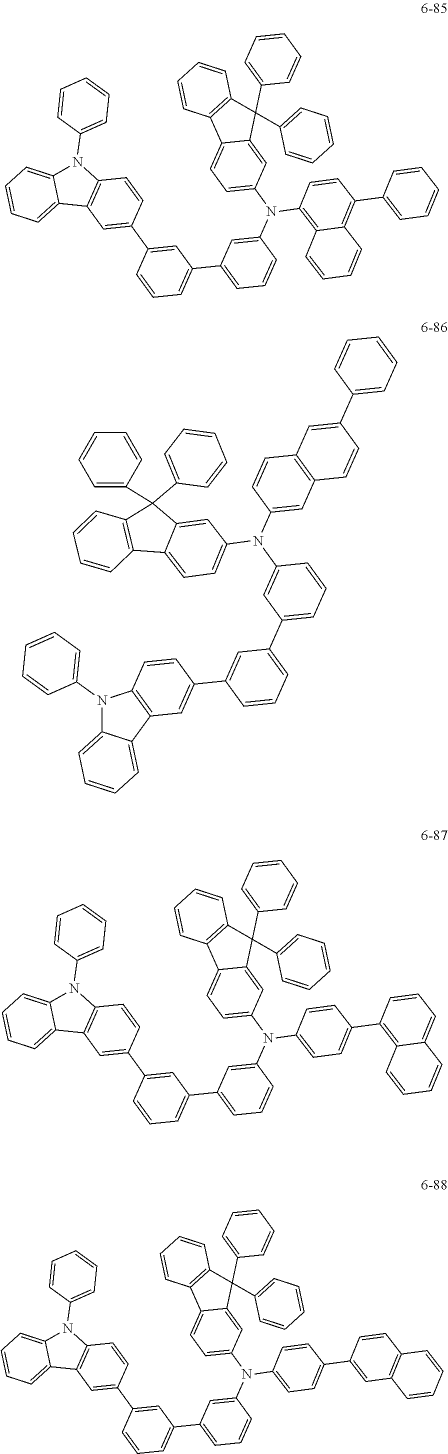

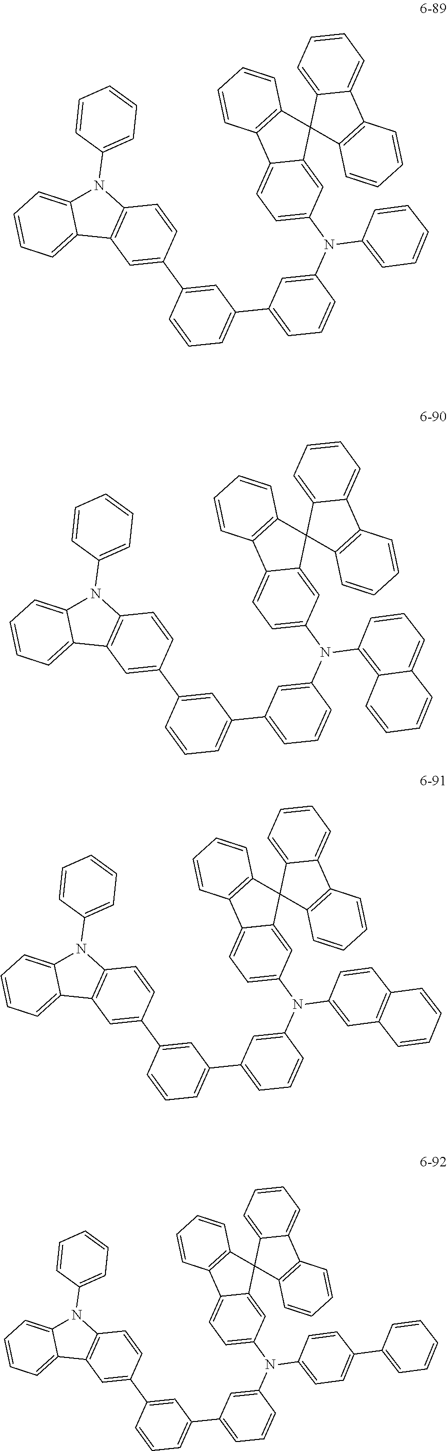 [SMILES: c1ccc(N(c2cccc(-c3cccc(-c4ccc5c(c4)c4ccccc4n5-c4ccccc4)c3)c2)c2ccc3c(c2)C2(c4ccccc4-c4ccccc42)c2ccccc2-3)cc1 ; c1ccc(-n2c3ccccc3c3cc(-c4cccc(-c5cccc(N(c6ccc7c(c6)C6(c8ccccc8-c8ccccc86)c6ccccc6-7)c6cccc7ccccc67)c5)c4)ccc32)cc1 ; c1ccc(-n2c3ccccc3c3cc(-c4cccc(-c5cccc(N(c6ccc7c(c6)C6(c8ccccc8-c8ccccc86)c6ccccc6-7)c6ccc7ccccc7c6)c5)c4)ccc32)cc1 ; c1ccc(-c2ccc(N(c3cccc(-c4cccc(-c5ccc6c(c5)c5ccccc5n6-c5ccccc5)c4)c3)c3ccc4c(c3)C3(c5ccccc5-c5ccccc53)c3ccccc3-4)cc2)cc1]

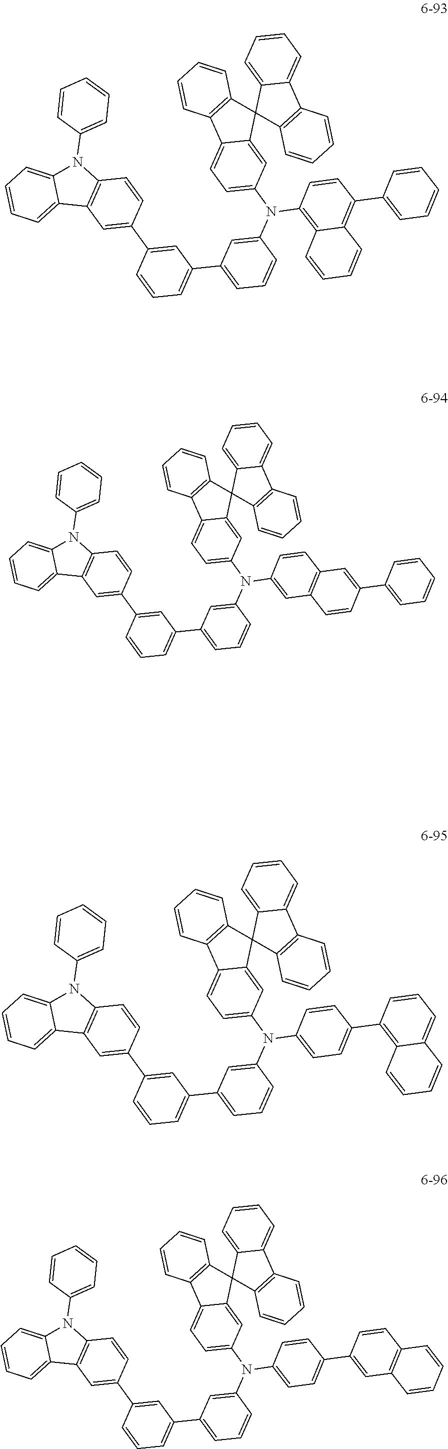

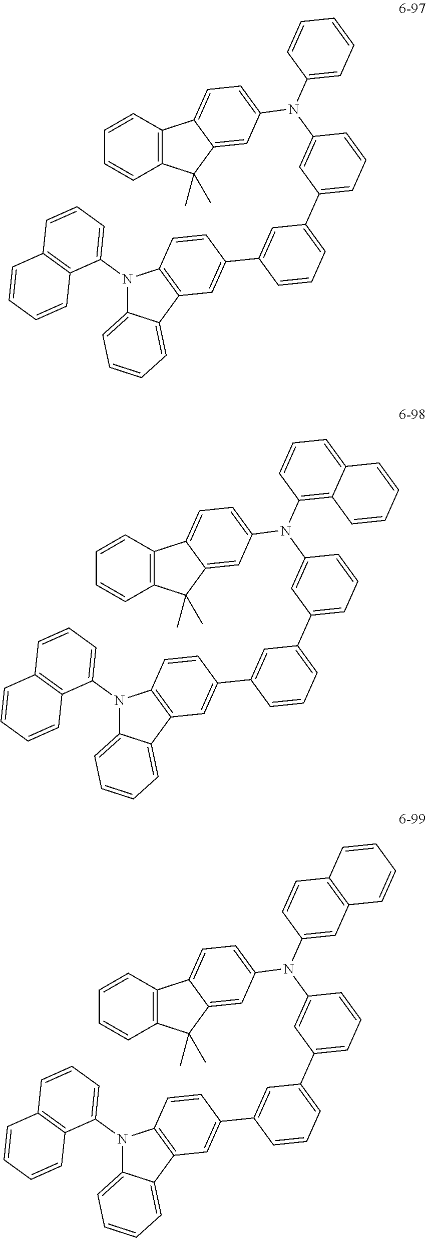 [SMILES: CC1(C)c2ccccc2-c2ccc(N(c3ccccc3)c3cccc(-c4cccc(-c5ccc6c(c5)c5ccccc5n6-c5cccc6ccccc56)c4)c3)cc21 ; CC1(C)c2ccccc2-c2ccc(N(c3cccc(-c4cccc(-c5ccc6c(c5)c5ccccc5n6-c5cccc6ccccc56)c4)c3)c3cccc4ccccc34)cc21 ; CC1(C)c2ccccc2-c2ccc(N(c3cccc(-c4cccc(-c5ccc6c(c5)c5ccccc5n6-c5cccc6ccccc56)c4)c3)c3ccc4ccccc4c3)cc21]

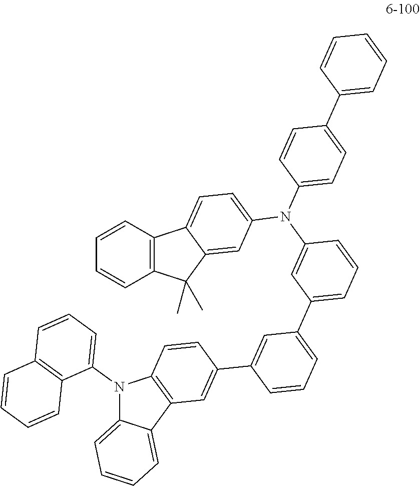 [SMILES: CC1(C)c2ccccc2-c2ccc(N(c3ccc(-c4ccccc4)cc3)c3cccc(-c4cccc(-c5ccc6c(c5)c5ccccc5n6-c5cccc6ccccc56)c4)c3)cc21]

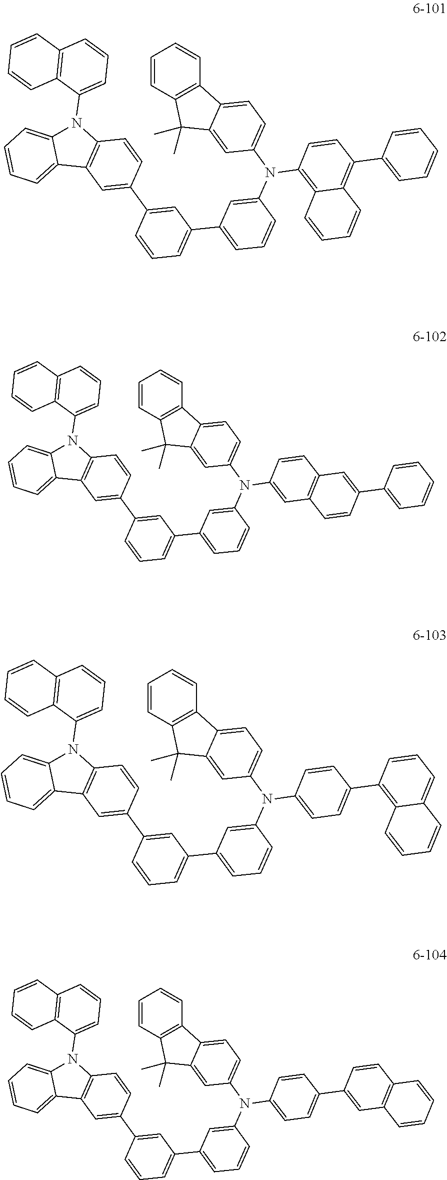 [SMILES: CC1(C)c2ccccc2-c2ccc(N(c3cccc(-c4cccc(-c5ccc6c(c5)c5ccccc5n6-c5cccc6ccccc56)c4)c3)c3ccc(-c4ccccc4)c4ccccc34)cc21 ; CC1(C)c2ccccc2-c2ccc(N(c3cccc(-c4cccc(-c5ccc6c(c5)c5ccccc5n6-c5cccc6ccccc56)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5cccc6ccccc56)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5cccc6ccccc56)c4)c3)cc21]

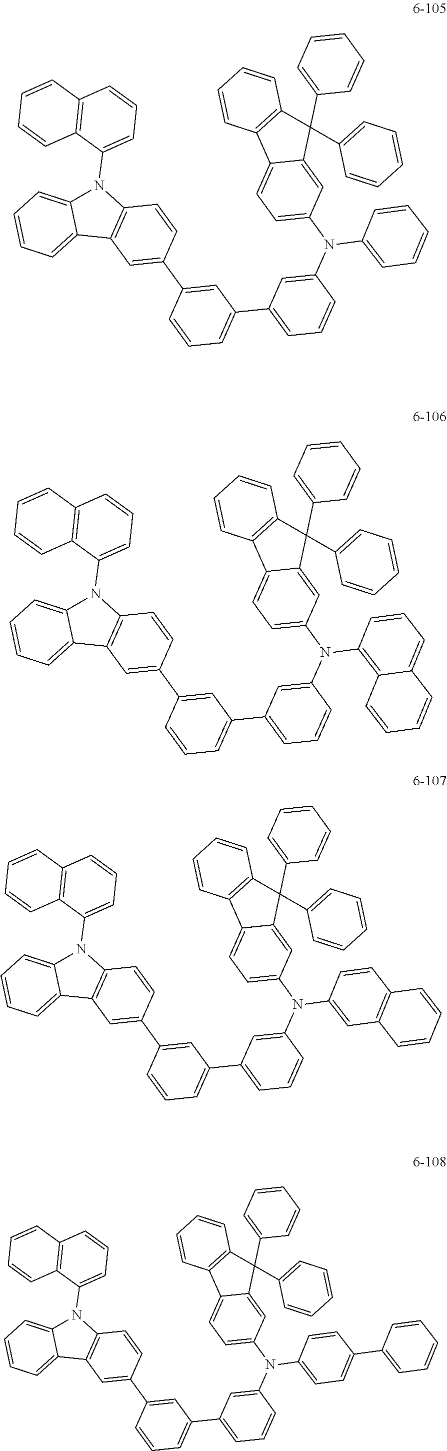 [SMILES: c1ccc(N(c2cccc(-c3cccc(-c4ccc5c(c4)c4ccccc4n5-c4cccc5ccccc45)c3)c2)c2ccc3c(c2)C(c2ccccc2)(c2ccccc2)c2ccccc2-3)cc1 ; c1ccc(C2(c3ccccc3)c3ccccc3-c3ccc(N(c4cccc(-c5cccc(-c6ccc7c(c6)c6ccccc6n7-c6cccc7ccccc67)c5)c4)c4cccc5ccccc45)cc32)cc1 ; c1ccc(C2(c3ccccc3)c3ccccc3-c3ccc(N(c4cccc(-c5cccc(-c6ccc7c(c6)c6ccccc6n7-c6cccc7ccccc67)c5)c4)c4ccc5ccccc5c4)cc32)cc1 ; c1ccc(-c2ccc(N(c3cccc(-c4cccc(-c5ccc6c(c5)c5ccccc5n6-c5cccc6ccccc56)c4)c3)c3ccc4c(c3)C(c3ccccc3)(c3ccccc3)c3ccccc3-4)cc2)cc1]

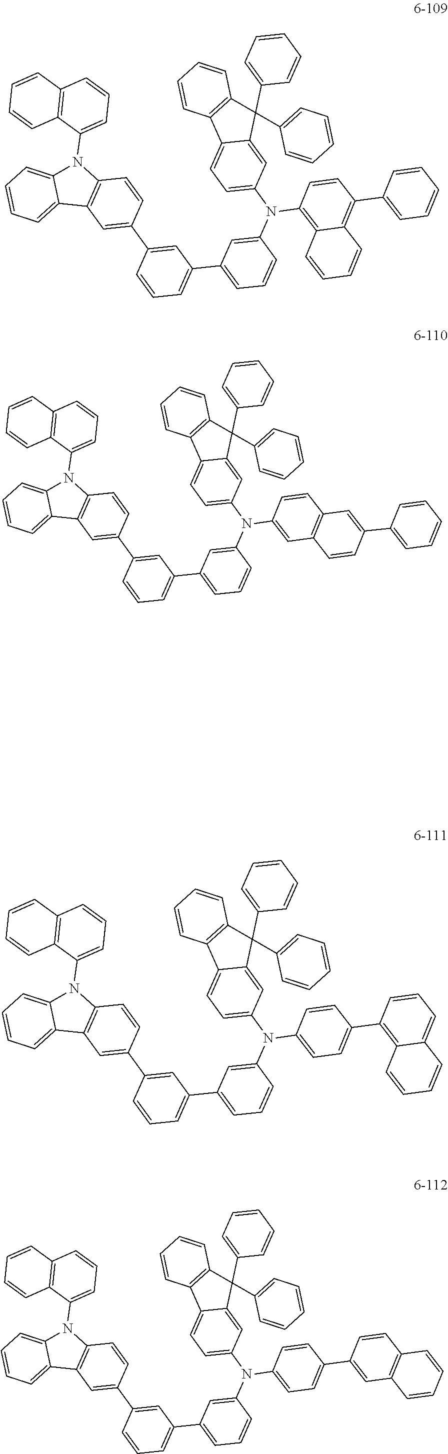

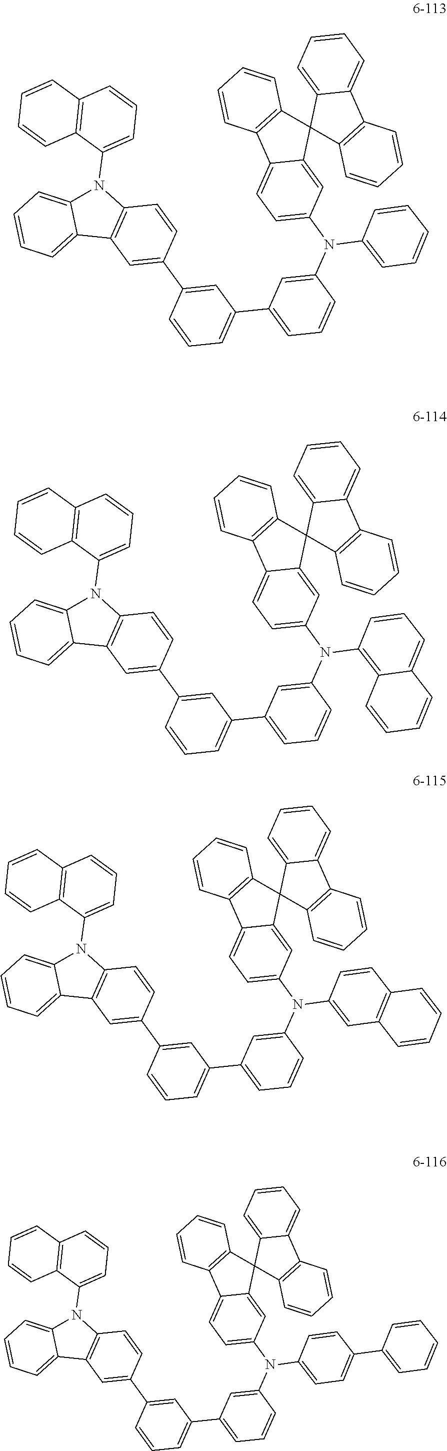 [SMILES: c1ccc(N(c2cccc(-c3cccc(-c4ccc5c(c4)c4ccccc4n5-c4cccc5ccccc45)c3)c2)c2ccc3c(c2)C2(c4ccccc4-c4ccccc42)c2ccccc2-3)cc1 ; c1cc(-c2cccc(N(c3ccc4c(c3)C3(c5ccccc5-c5ccccc53)c3ccccc3-4)c3cccc4ccccc34)c2)cc(-c2ccc3c(c2)c2ccccc2n3-c2cccc3ccccc23)c1 ; c1cc(-c2cccc(N(c3ccc4c(c3)C3(c5ccccc5-c5ccccc53)c3ccccc3-4)c3ccc4ccccc4c3)c2)cc(-c2ccc3c(c2)c2ccccc2n3-c2cccc3ccccc23)c1 ; c1ccc(-c2ccc(N(c3cccc(-c4cccc(-c5ccc6c(c5)c5ccccc5n6-c5cccc6ccccc56)c4)c3)c3ccc4c(c3)C3(c5ccccc5-c5ccccc53)c3ccccc3-4)cc2)cc1]

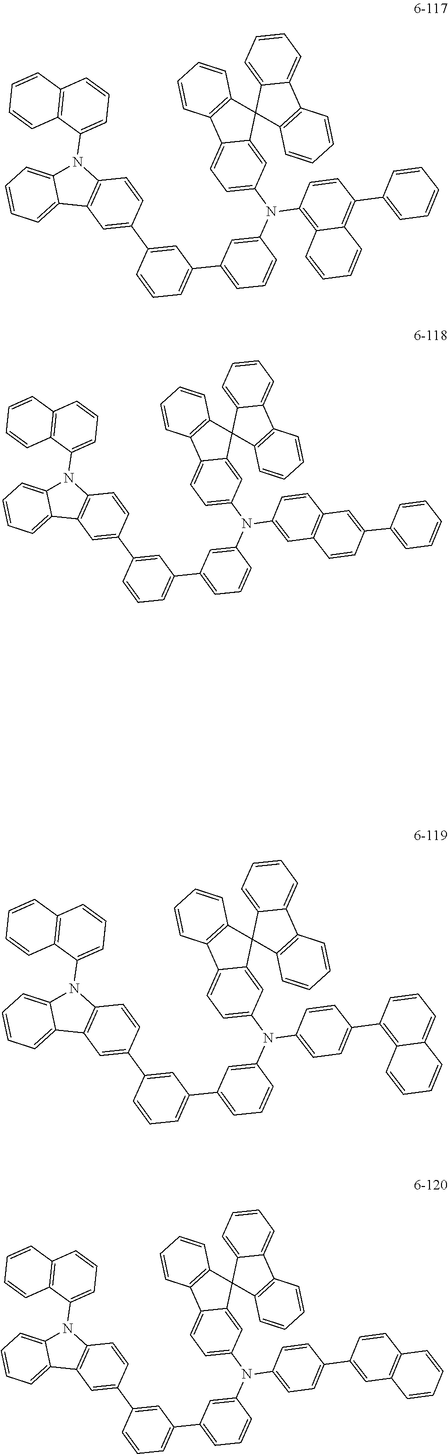

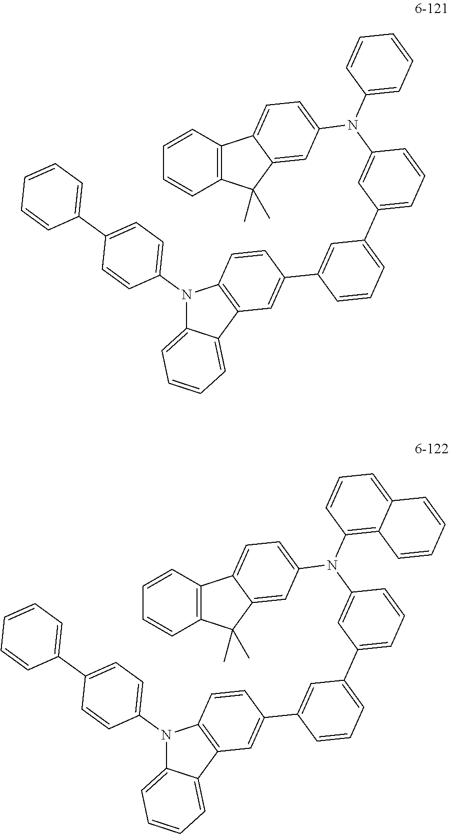 [SMILES: CC1(C)c2ccccc2-c2ccc(N(c3ccccc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3cccc(-c4cccc(-c5ccc6c(c5)c5ccccc5n6-c5ccc(-c6ccccc6)cc5)c4)c3)c3cccc4ccccc34)cc21]

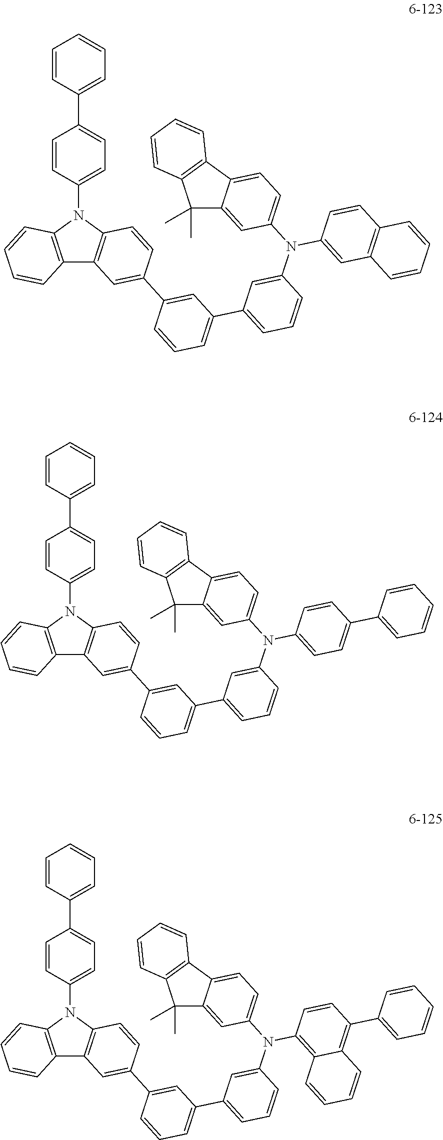 [SMILES: CC1(C)c2ccccc2-c2ccc(N(c3cccc(-c4cccc(-c5ccc6c(c5)c5ccccc5n6-c5ccc(-c6ccccc6)cc5)c4)c3)c3ccc4ccccc4c3)cc21 ; CC1(C)c2ccccc2-c2ccc(N(c3ccc(-c4ccccc4)cc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3cccc(-c4cccc(-c5ccc6c(c5)c5ccccc5n6-c5ccc(-c6ccccc6)cc5)c4)c3)c3ccc(-c4ccccc4)c4ccccc34)cc21]

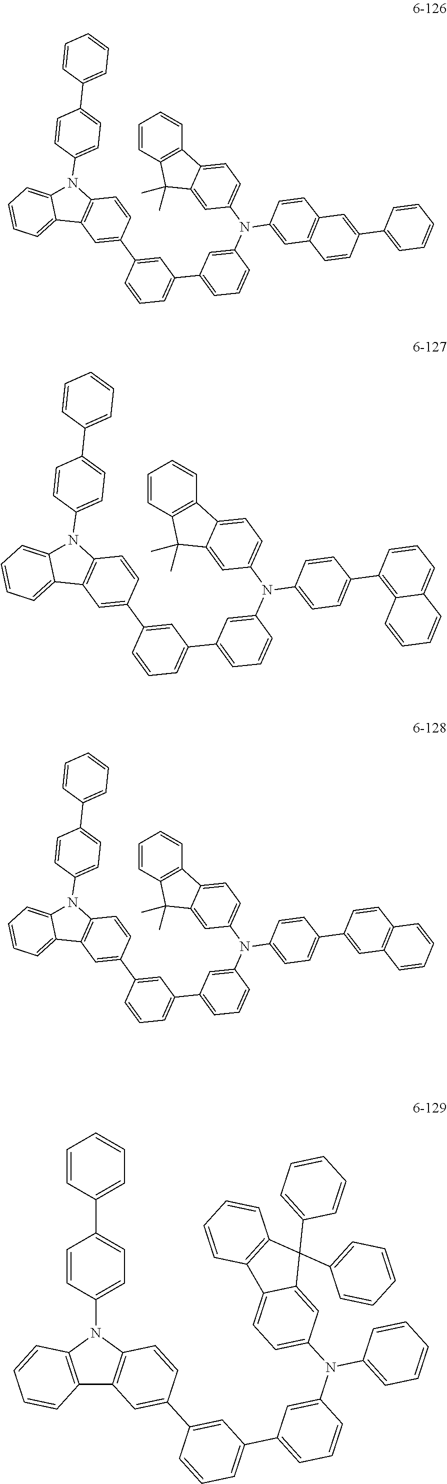 [SMILES: CC1(C)c2ccccc2-c2ccc(N(c3cccc(-c4cccc(-c5ccc6c(c5)c5ccccc5n6-c5ccc(-c6ccccc6)cc5)c4)c3)c3ccc4cc(-c5ccccc5)ccc4c3)cc21 ; CC1(C)c2ccccc2-c2ccc(N(c3ccc(-c4cccc5ccccc45)cc3)c3cccc(-c4cccc(-c5ccc6c(c5)c5ccccc5n6-c5ccc(-c6ccccc6)cc5)c4)c3)cc21 ; CC1(C)c2ccccc2-c2ccc(N(c3ccc(-c4ccc5ccccc5c4)cc3)c3cccc(-c4cccc(-c5ccc6c(c5)c5ccccc5n6-c5ccc(-c6ccccc6)cc5)c4)c3)cc21 ; c1ccc(-c2ccc(-n3c4ccccc4c4cc(-c5cccc(-c6cccc(N(c7ccccc7)c7ccc8c(c7)C(c7ccccc7)(c7ccccc7)c7ccccc7-8)c6)c5)ccc43)cc2)cc1]

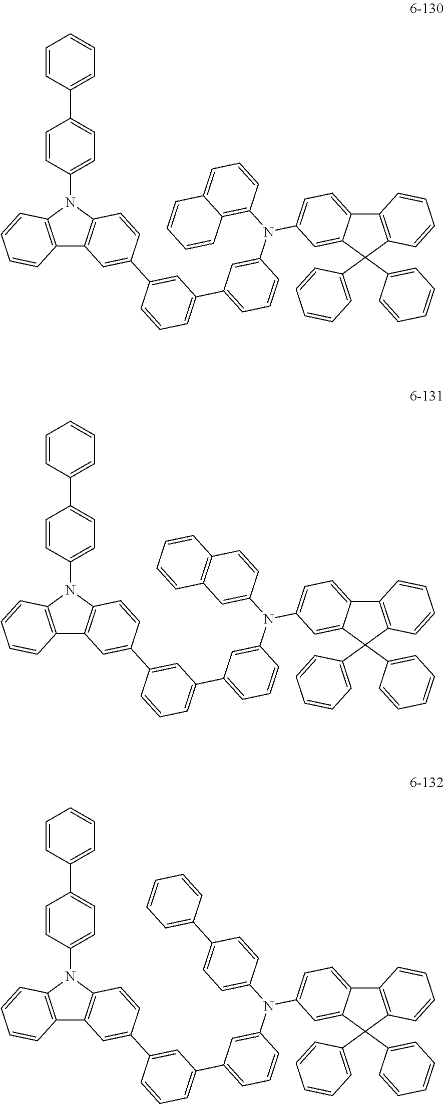 [SMILES: c1ccc(-c2ccc(-n3c4ccccc4c4cc(-c5cccc(-c6cccc(N(c7ccc8c(c7)C(c7ccccc7)(c7ccccc7)c7ccccc7-8)c7cccc8ccccc78)c6)c5)ccc43)cc2)cc1 ; c1ccc(-c2ccc(-n3c4ccccc4c4cc(-c5cccc(-c6cccc(N(c7ccc8c(c7)C(c7ccccc7)(c7ccccc7)c7ccccc7-8)c7ccc8ccccc8c7)c6)c5)ccc43)cc2)cc1 ; c1ccc(-c2ccc(N(c3cccc(-c4cccc(-c5ccc6c(c5)c5ccccc5n6-c5ccc(-c6ccccc6)cc5)c4)c3)c3ccc4c(c3)C(c3ccccc3)(c3ccccc3)c3ccccc3-4)cc2)cc1]

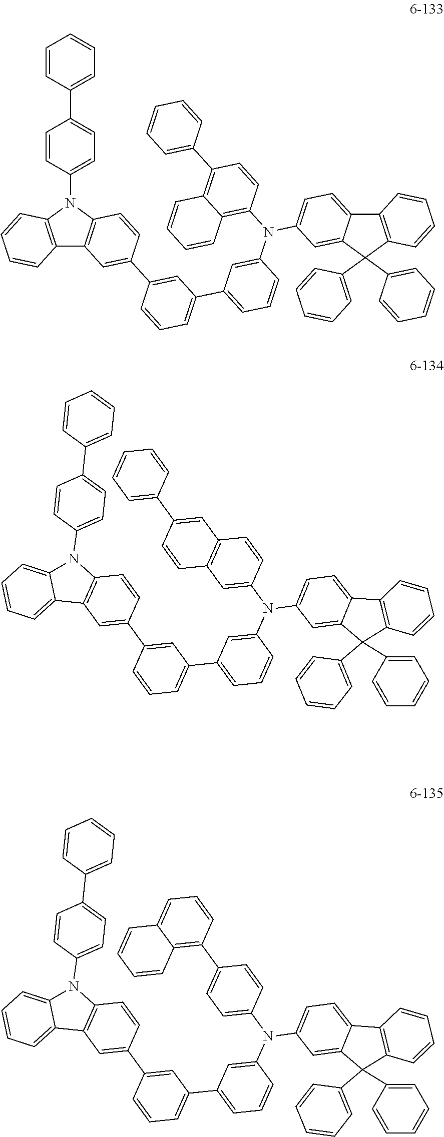 [SMILES: c1ccc(-c2ccc(-n3c4ccccc4c4cc(-c5cccc(-c6cccc(N(c7ccc8c(c7)C(c7ccccc7)(c7ccccc7)c7ccccc7-8)c7ccc(-c8ccccc8)c8ccccc78)c6)c5)ccc43)cc2)cc1 ; c1ccc(-c2ccc(-n3c4ccccc4c4cc(-c5cccc(-c6cccc(N(c7ccc8c(c7)C(c7ccccc7)(c7ccccc7)c7ccccc7-8)c7ccc8cc(-c9ccccc9)ccc8c7)c6)c5)ccc43)cc2)cc1 ; c1ccc(-c2ccc(-n3c4ccccc4c4cc(-c5cccc(-c6cccc(N(c7ccc(-c8cccc9ccccc89)cc7)c7ccc8c(c7)C(c7ccccc7)(c7ccccc7)c7ccccc7-8)c6)c5)ccc43)cc2)cc1]

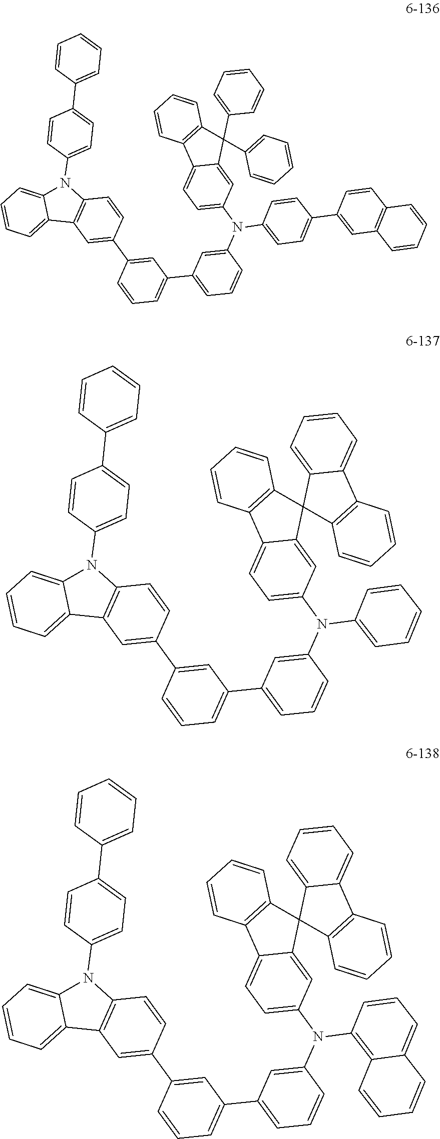 [SMILES: c1ccc(-c2ccc(-n3c4ccccc4c4cc(-c5cccc(-c6cccc(N(c7ccc(-c8ccc9ccccc9c8)cc7)c7ccc8c(c7)C(c7ccccc7)(c7ccccc7)c7ccccc7-8)c6)c5)ccc43)cc2)cc1 ; c1ccc(-c2ccc(-n3c4ccccc4c4cc(-c5cccc(-c6cccc(N(c7ccccc7)c7ccc8c(c7)C7(c9ccccc9-c9ccccc97)c7ccccc7-8)c6)c5)ccc43)cc2)cc1 ; c1ccc(-c2ccc(-n3c4ccccc4c4cc(-c5cccc(-c6cccc(N(c7ccc8c(c7)C7(c9ccccc9-c9ccccc97)c7ccccc7-8)c7cccc8ccccc78)c6)c5)ccc43)cc2)cc1]

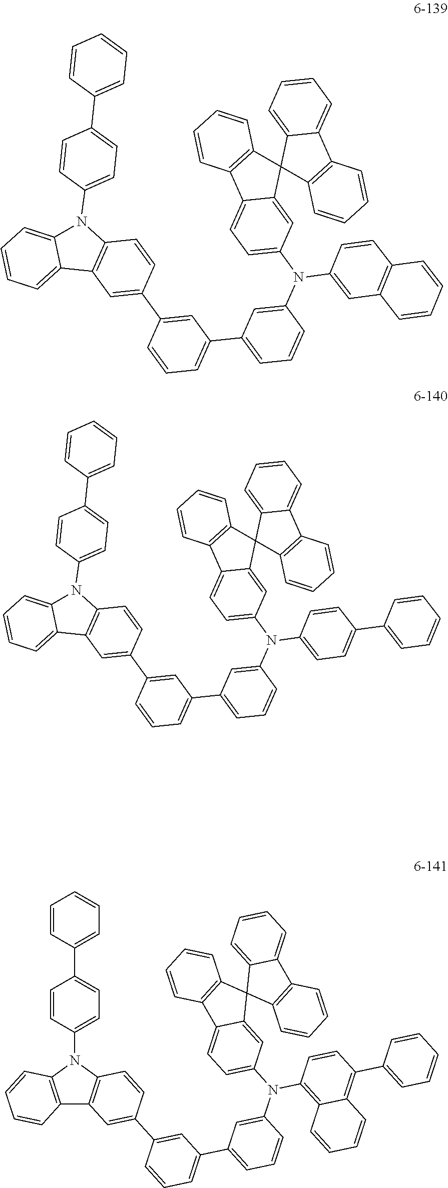 [SMILES: c1ccc(-c2ccc(-n3c4ccccc4c4cc(-c5cccc(-c6cccc(N(c7ccc8c(c7)C7(c9ccccc9-c9ccccc97)c7ccccc7-8)c7ccc8ccccc8c7)c6)c5)ccc43)cc2)cc1 ; c1ccc(-c2ccc(N(c3cccc(-c4cccc(-c5ccc6c(c5)c5ccccc5n6-c5ccc(-c6ccccc6)cc5)c4)c3)c3ccc4c(c3)C3(c5ccccc5-c5ccccc53)c3ccccc3-4)cc2)cc1 ; c1ccc(-c2ccc(-n3c4ccccc4c4cc(-c5cccc(-c6cccc(N(c7ccc8c(c7)C7(c9ccccc9-c9ccccc97)c7ccccc7-8)c7ccc(-c8ccccc8)c8ccccc78)c6)c5)ccc43)cc2)cc1]

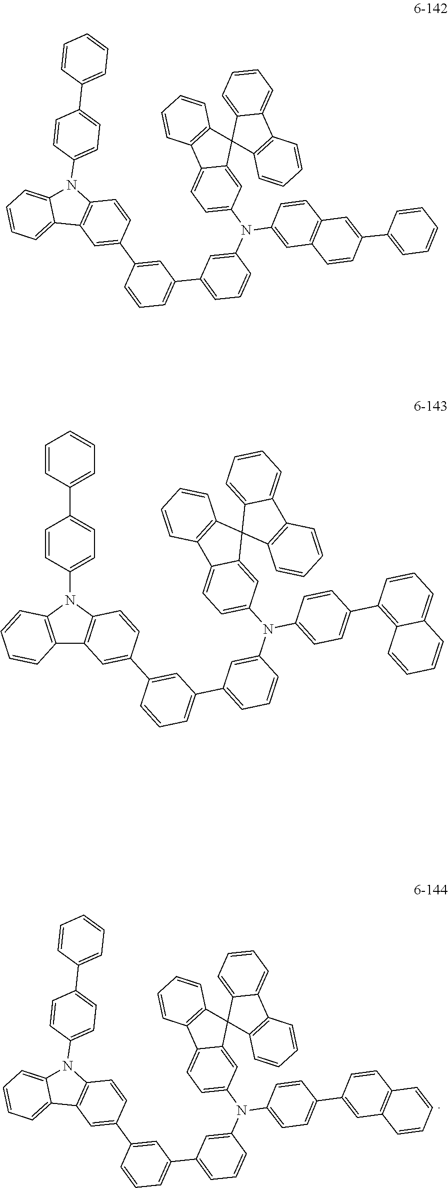 [SMILES: c1ccc(-c2ccc(-n3c4ccccc4c4cc(-c5cccc(-c6cccc(N(c7ccc8c(c7)C7(c9ccccc9-c9ccccc97)c7ccccc7-8)c7ccc8cc(-c9ccccc9)ccc8c7)c6)c5)ccc43)cc2)cc1 ; c1ccc(-c2ccc(-n3c4ccccc4c4cc(-c5cccc(-c6cccc(N(c7ccc(-c8cccc9ccccc89)cc7)c7ccc8c(c7)C7(c9ccccc9-c9ccccc97)c7ccccc7-8)c6)c5)ccc43)cc2)cc1 ; c1ccc(-c2ccc(-n3c4ccccc4c4cc(-c5cccc(-c6cccc(N(c7ccc(-c8ccc9ccccc9c8)cc7)c7ccc8c(c7)C7(c9ccccc9-c9ccccc97)c7ccccc7-8)c6)c5)ccc43)cc2)cc1]

7. The organic light-emitting device of claim 1, wherein:
the first emission layer emits a red color light, the second emission layer emits a green color light, and the third emission layer emits a blue color light.

8. The organic light-emitting device of claim 1, wherein
the second emission layer comprises the light emitting material,
the first buffer layer comprises the hole-transporting material, and
the second buffer layer comprises at least one compound represented by Formula 300 or 301: 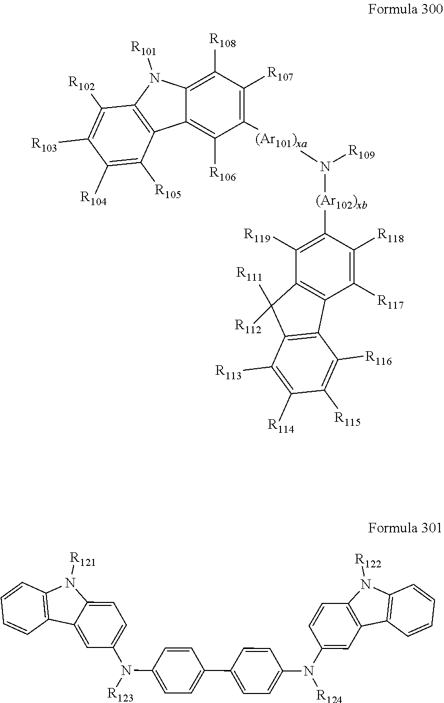
wherein in Formula 300, Ar₁₀₁ and Ar₁₀₂ may each independently be a substituted or unsubstituted C₆-C₆₀ arylene group,
xa and xb may each independently be an integer of 0 to 5,
R₁₀₁ to R₁₀₈, R₁₁₁ to R₁₁₉, and R₁₂₁ to R₁₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group,
R₅₁ to R₅₈, R₆₁ to R₆₉, R₇₁, and R₇₂ may each independently be a hydrogen atom; a deuterium atom; a halogen atom; a hydroxyl group; a cyano group; a nitro group; an amino group; an amidino group; a hydrazine group; a hydrazone group; a carboxyl group or a salt thereof; a sulfonic acid group or a salt thereof; a phosphoric acid group or a salt thereof; a C₁-C₁₀ alkyl group; a C₁-C₁₀ alkoxy group; a C₁-C₁₀ alkyl group or a C₁-C₁₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof; a phenyl group; a naphthyl group; an anthryl group; a fluorenyl group; a pyrenyl group; a phenyl group, a naphthyl group, an anthryl group, a fluorenyl group, or a pyrenyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₁ alkyl group, or a C₁-C₁ alkoxy group, and
R₁₀₉ is:
a phenyl group; a naphthyl group; an anthryl group; a biphenyl group; or
a pyridinyl group; or
a phenyl group, a naphthyl group, an anthryl group, a biphenyl group, or a pyridinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

9. The organic light-emitting device of claim 8, wherein
the second buffer layer comprises at least one of Compounds 301 to 320:

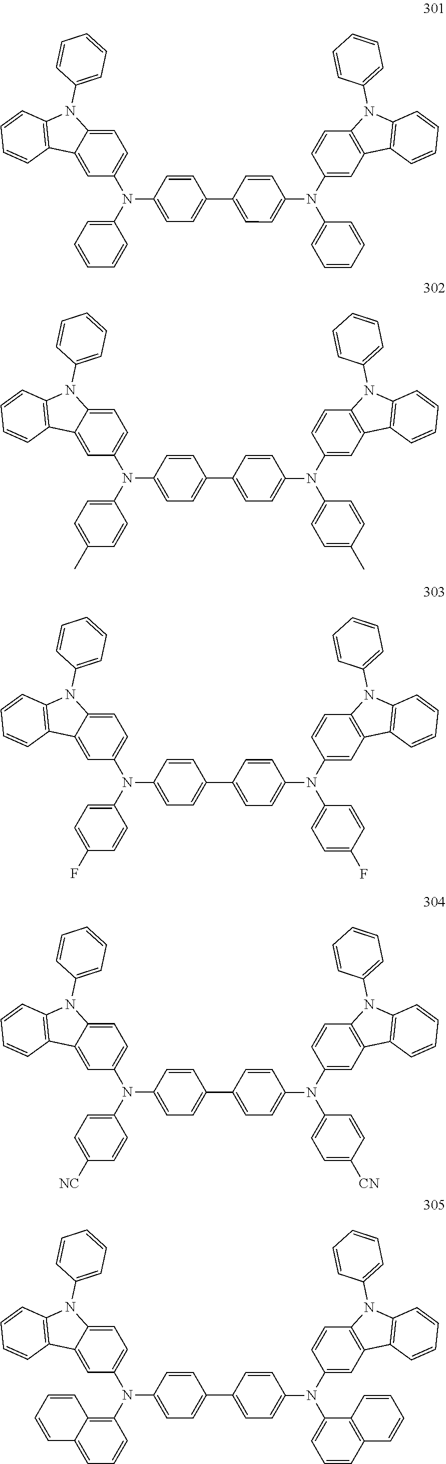

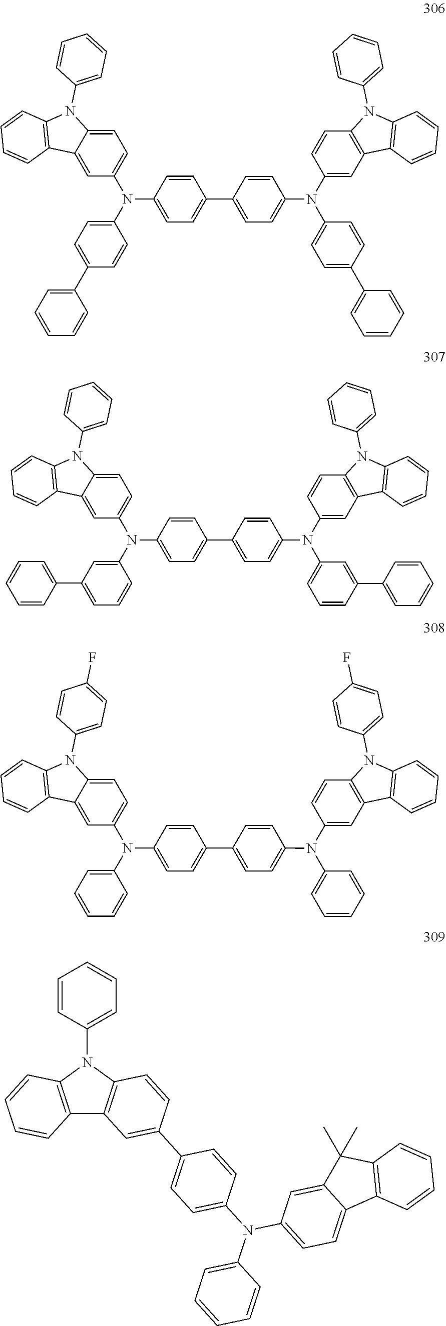 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

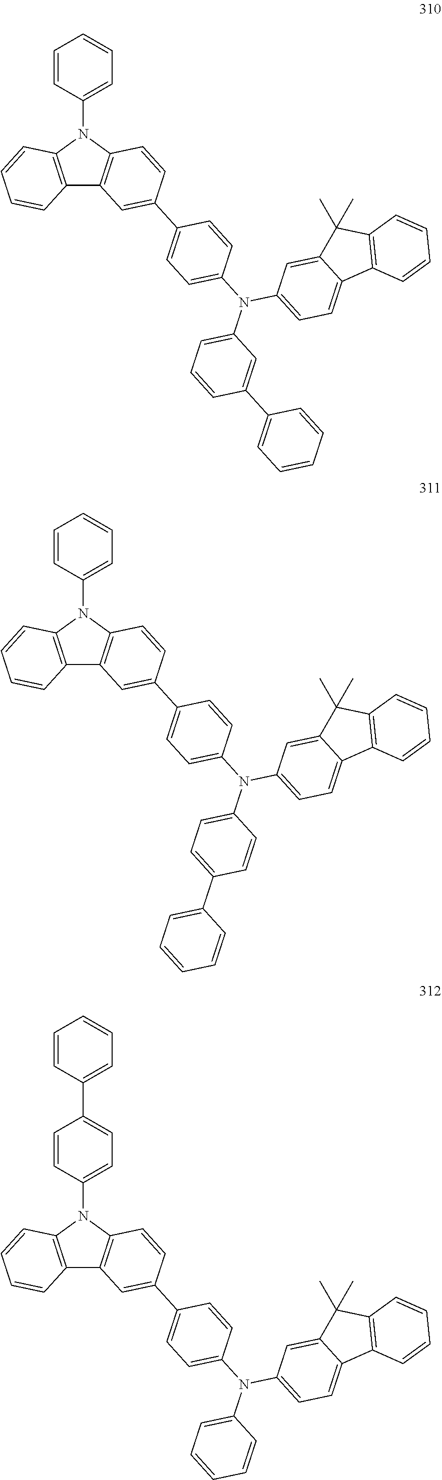 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

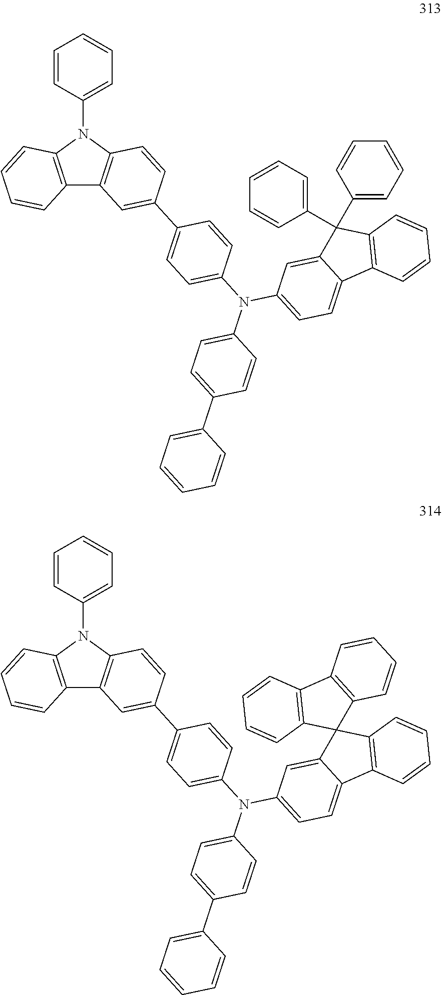 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

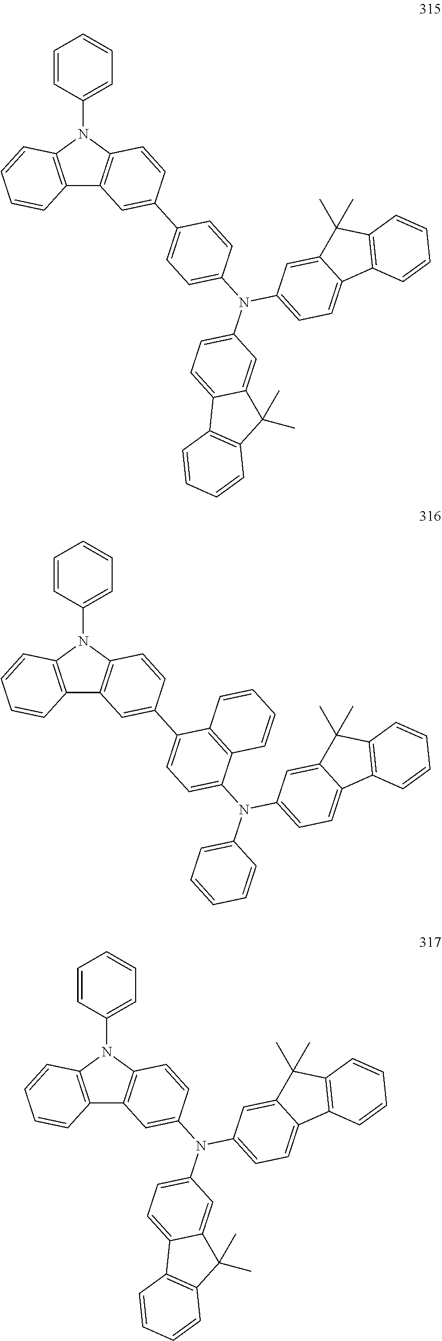 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

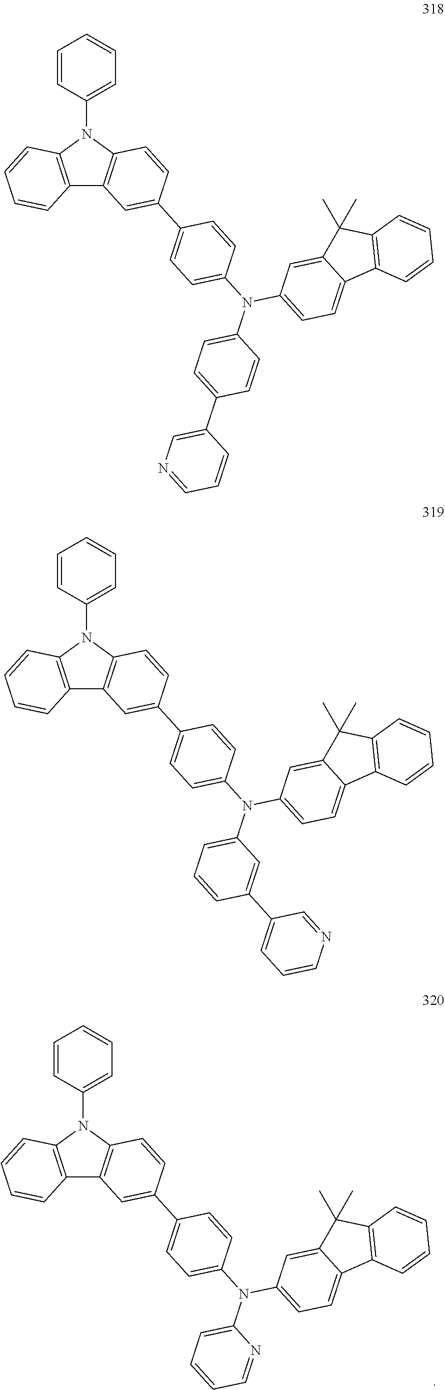 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

10. The organic light-emitting device of claim 1, wherein
the organic light-emitting device further comprises a hole transport layer disposed between the first and second buffer layers and the first, second, and third third sub-pixel electrodes.

11. The organic light-emitting device of claim 10, wherein
the hole transport layer includes at least one compound represented by one of Formula 300 and Formula 301: 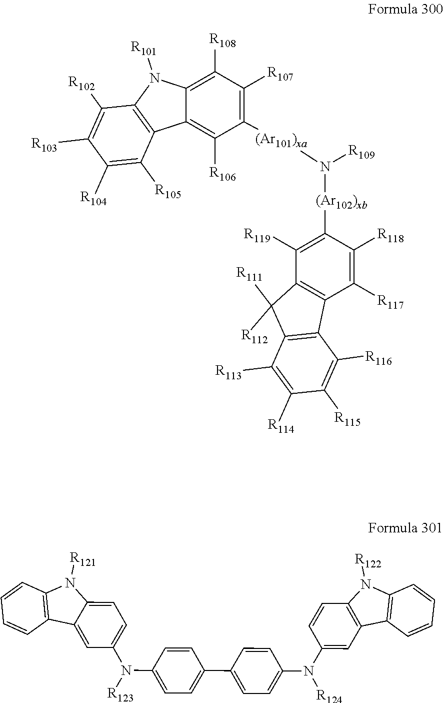
wherein in Formula 300, Ar₁₀₁ and Ar₁₀₂ may each independently be a substituted or unsubstituted C₆-C₆₀ arylene group,
xa and xb may each independently be an integer of 0 to 5,
R₁₀₁ to R₁₀₈, R₁₁₁ to R₁₁₉, and R₁₂₁ to R₁₂₄ may each independently be a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group,
R₅₁ to R₅₈, R₆₁ to R₆₉, R₇₁, and R₇₂ may each independently be a hydrogen atom;
a deuterium atom; a halogen atom; a hydroxyl group; a cyano group; a nitro group; an amino group; an amidino group; a hydrazine group; a hydrazone group; a carboxyl group or a salt thereof; a sulfonic acid group or a salt thereof; a phosphoric acid group or a salt thereof; a C₁-C₁₀ alkyl group; a C₁-C₁₀ alkoxy group; a C₁-C₁₀ alkyl group or a C₁-C₁₀ alkoxy group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof; a phenyl group; a naphthyl group; an anthryl group; a fluorenyl group; a pyrenyl group; a phenyl group, a naphthyl group, an anthryl group, a fluorenyl group, or a pyrenyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a C₁-C₁₀ alkyl group, or a C₁-C₁₀ alkoxy group, and
R₁₀₉ is:
a phenyl group; a naphthyl group; an anthryl group; a biphenyl group; or
a pyridinyl group; or
a phenyl group, a naphthyl group, an anthryl group, a biphenyl group, or a pyridinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

12. The organic light-emitting device of claim 10, wherein:
the hole transport layer includes at least one of Compounds 301 to 320:

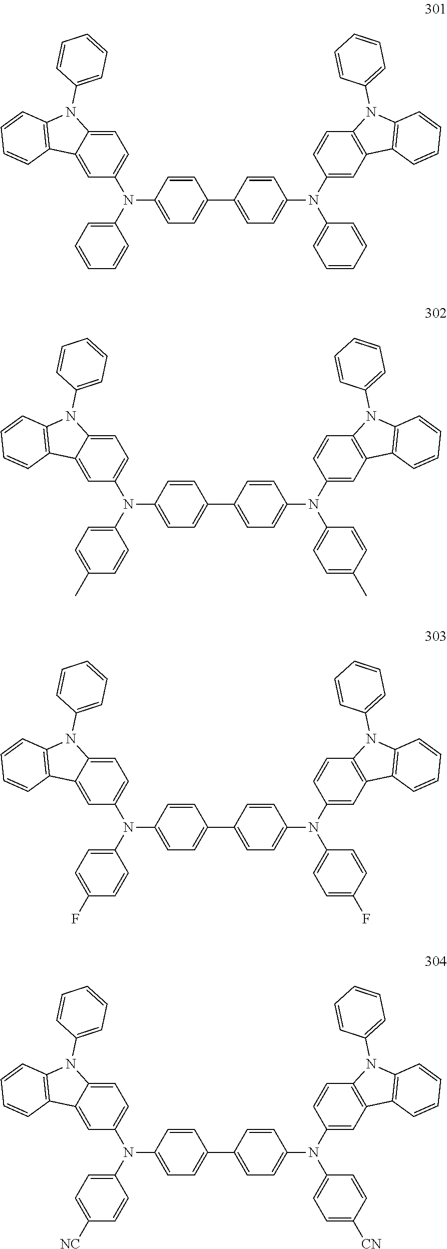 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

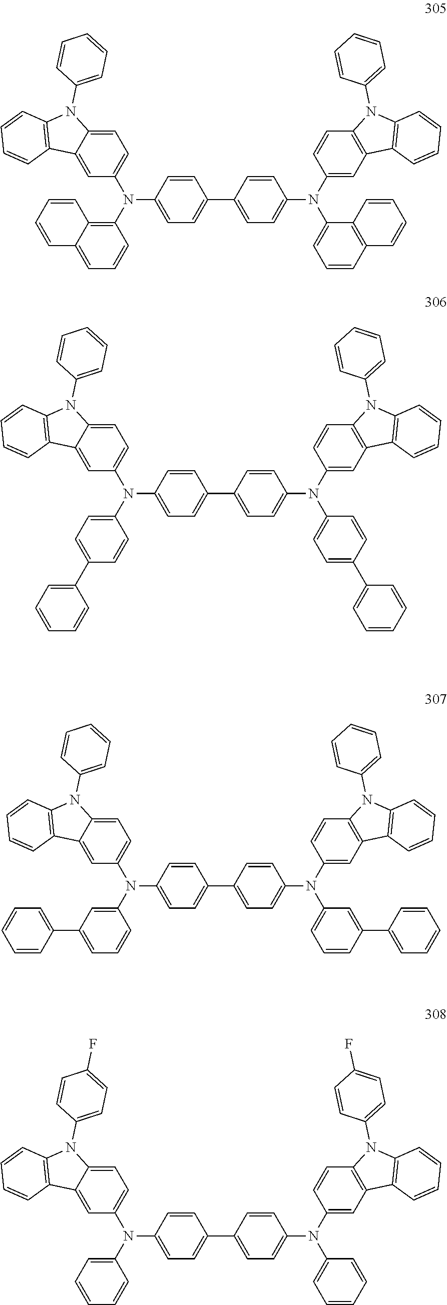 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

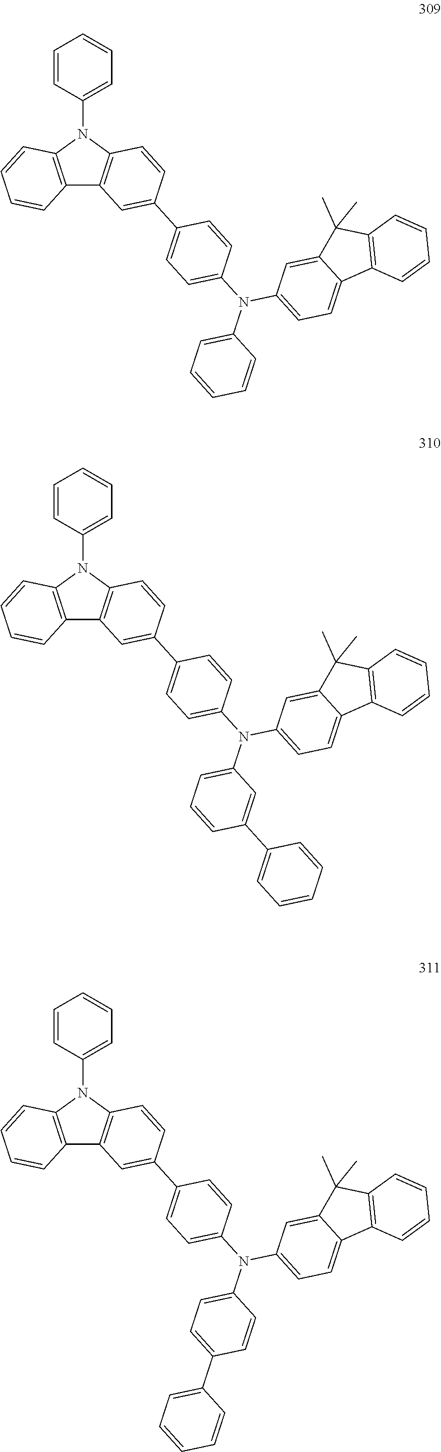 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

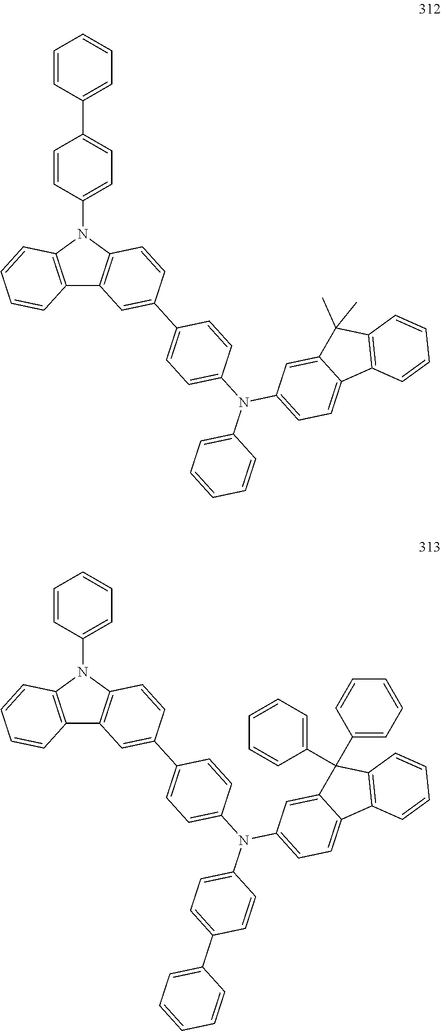 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

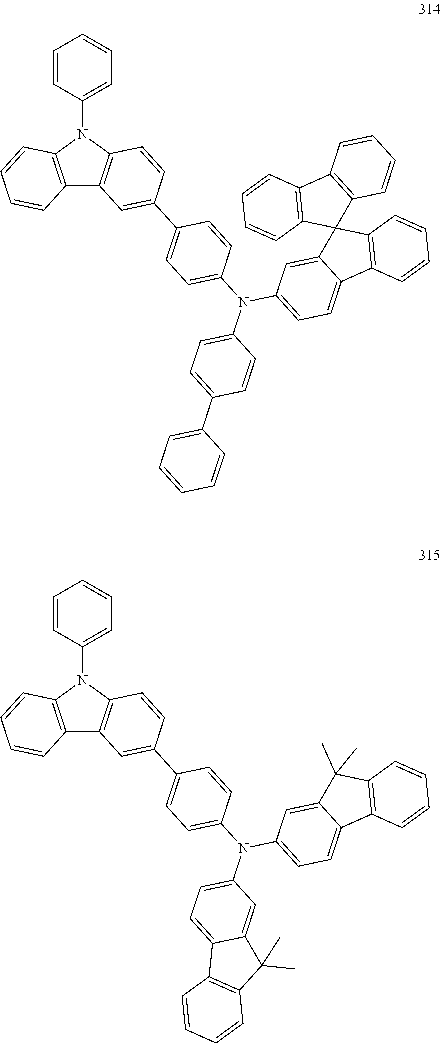 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

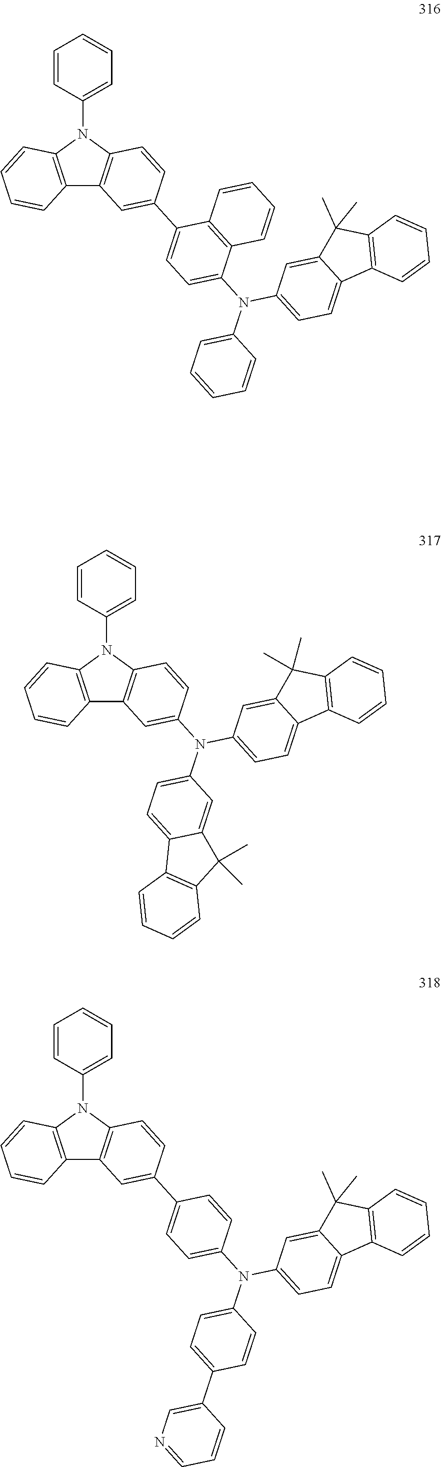 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

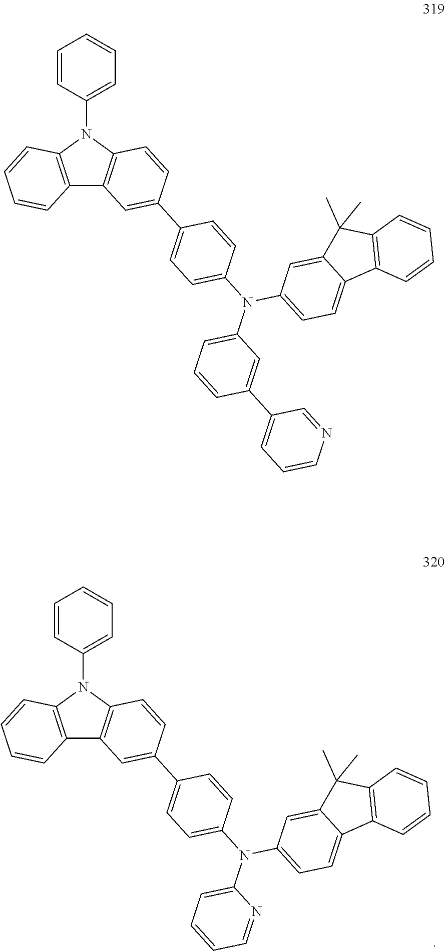 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

13. The organic light-emitting device of claim 10, wherein the second buffer layer includes the same compound as included in the hole transport layer.
